(19) United States
(12) Patent Application Publication
(10) Pub. No.: US 2015/0017576 A1
(43) Pub. Date: Jan. 15, 2015

(54) PATTERN FORMING METHOD, METHOD FOR SELECTING HEATING TEMPERATURE IN PATTERN FORMING METHOD, EXTREME ULTRAVIOLET-SENSITIVE RESIN COMPOSITION, RESIST FILM, MANUFACTURING METHOD OF ELECTRONIC DEVICE USING THE SAME, AND ELECTRONIC DEVICE

(71) Applicant: FUJIFILM Corporation, Tokyo (JP)

(72) Inventors: Naoki INOUE, Haibara-gun (JP); Hiroo TAKIZAWA, Haibara-gun (JP); Hideaki TSUBAKI, Haibara-gun (JP)

(73) Assignee: FUJIFILM CORPORATION, Tokyo (JP)

(21) Appl. No.: 14/499,708

(22) Filed: Sep. 29, 2014

Related U.S. Application Data
(63) Continuation of application No. PCT/JP2013/060406, filed on Mar. 29, 2013.

(30) Foreign Application Priority Data
Mar. 29, 2012 (JP) 2012-078093

(51) Int. Cl. G03F 7/38; G03F 7/038; G03F 7/20

(52) U.S. Cl. CPC G03F 7/38; G03F 7/2002; G03F 7/0388
USPC 430/9; 430/325; 430/326; 430/270.1; 430/311

(57) ABSTRACT

There is provided a pattern forming method comprising, in order: (i) a step of forming a film by using an extreme ultraviolet-sensitive resin composition containing (A) a resin having an acid-decomposable group; (ii) a step of exposing the film by using an extreme ultraviolet ray; (iii) a step of heating the film; and (iv) a step of developing the film to form a pattern, wherein in the step (ii), an optical image formed by exposure on the surface of the film is an optical image having a line part with a line width of 20 nm or less as an exposed area or an unexposed area, and, the heating temperature T_{PEB}(° C.) in the step (iii) satisfies the specific formula.

### CROSS REFERENCE TO RELATED APPLICATION

This is a continuation of International Application No. PCT/JP2013/060406 filed on Mar. 29, 2013, and claims priority from Japanese Patent Application No. 2012-078093 filed on Mar. 29, 2012, the entire disclosures of which are incorporated therein by reference.

### TECHNICAL FIELD

The present invention relates to a pattern forming method, a method for selecting a heating temperature in a pattern forming method, an extreme ultraviolet-sensitive resin composition, and a resist film, which are suitably used in the ultramicrolithography process such as production of VLSI and a high-capacity microchip or in other photofabrication processes, and also relates to a manufacturing method of an electronic device using the same, and an electronic device. More specifically, the present invention relates to a pattern forming method, a method for selecting a heating temperature in a pattern forming method, an extreme ultraviolet-sensitive resin composition, and a resist film, which can be suitably used for semiconductor device microfabrication using EUV light (wavelength: near 13 nm), and also relates to a manufacturing method of an electronic device using the same, and an electronic device.

### BACKGROUND ART

In the process of producing a semiconductor device such as IC and LSI, microfabrication by lithography using a photoresist composition has been conventionally performed. Recently, with the increase in integration of an integrated circuit, formation of an ultrafine pattern in the sub-micron or quarter-micron region is required. To cope with this requirement, the exposure wavelength also tends to become shorter, for example, from g line to i line or further to KrF excimer laser light. At present, other than the excimer laser light, development of lithography using electron beam, X-ray or EUV light is also proceeding.

In particular, the extreme ultraviolet (EUV light) lithography is positioned as a next-generation or next-next-generation pattern formation technology and a high-sensitivity and high-resolution resist composition is being demanded. However, when more pattern miniaturization is attempted by using extreme ultraviolet (EUV light) lithography, this causes a problem that deterioration of the pattern profile is liable to occur.

In this way, high resolution is in a trade-off relationship with the pattern profile, and it is very important how to satisfy both of these properties at the same time.

As for the pattern forming method using extreme ultraviolet (EUV light) lithography, there is known, for example, a technique where a resin having a group formed by substituting for a hydrogen atom of a carboxyl group by a specific acid-labile aromatic ring is used as the base resin (for example, JP-A-2010-237661 (the term “JP-A” as used herein means an “unexamined published Japanese patent application”) and JP-A-2010-237662).

However, along with further pattern miniaturization, successful formation of a line pattern with a line width of 20 nm or less is believed to be strongly demanded in the future and although, for example, in JP-A-2010-237661 and JP-A-2010-237662, the line edge roughness (LWR) performance of a line-and-space pattern with a line width of 35 nm is evaluated, no examination is made of an ultrafine pattern with a line width of 20 nm or less.

### SUMMARY OF INVENTION

The present invention has been made under these circumstances, and an object of the present invention is to provide a pattern forming method capable of forming a pattern having a line part with a line width of 20 nm or less while satisfying high resolution, good pattern cross-sectional profile and high roughness performance all at the same time, a method for selecting a heating temperature in a pattern forming method, an extreme ultraviolet-sensitive resin composition, a resist film, a manufacturing method of an electronic device using the same, and an electronic device.

That is, the present invention is as follows.

[1] A pattern forming method comprising, in order,

(i) a step of forming a film by using an extreme ultraviolet-sensitive resin composition containing (A) a resin having an acid-decomposable group,

(ii) a step of exposing the film by using an extreme ultraviolet ray,

(iii) a step of heating the film, and

(iv) a step of developing the film to form a pattern,

wherein,

in the step (ii), an optical image formed by exposure on the surface of the film is an optical image having a line part with a line width of 20 nm or less as an exposed area or an unexposed area, and,

the heating temperature T_{PEB}(° C.) in the step (iii) satisfies the following formula (1):

[glass transition temperature (Tg) of the resin (A)−30](° C.)≦T_{PEB}≦glass transition temperature (Tg) (° C.) of the resin (A) (1)

[2] The pattern forming method as described in [1] above,

wherein,

the method further comprises (v) a step of heating the pattern, after the step (iv), and,

the heating temperature T_{PDB}(° C.) in the step (v) satisfies the following formula (2):

[glass transition temperature (Tg) of the resin (A)−20](° C.)≦T_{PDB}≦[glass transition temperature (Tg)(° C.) of the resin (A)+10](° C.) (2)

[3] The pattern forming method as described in [1] or [2] above,

wherein,

the extreme ultraviolet-sensitive resin composition further contains (B) a compound capable of generating an acid upon irradiation with an actinic ray or radiation, and

a volume of the acid generated from the compound (B) upon irradiation with an actinic ray or radiation is 240 Å³ or more.

[4] The pattern forming method as described in any one of [1] to [3] above,

wherein the resin (A) is a resin further containing a repeating unit represented by the following formula (4):

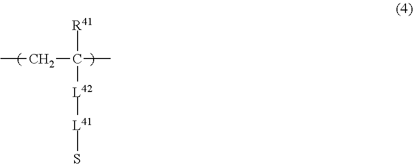

wherein R⁴¹ represents a hydrogen atom or a methyl group,

L⁴¹ represents a single bond or a divalent linking group,

L⁴² represents a divalent linking group, and

S represents a structural moiety capable of decomposing upon irradiation with an actinic ray or radiation to generate an acid on the side chain.

[5] The pattern forming method as described in any one of [1] to [4] above,

wherein the pattern is a positive pattern.

[6] The pattern forming method as described in [5] above,

wherein the resin (A) is a resin containing a repeating unit represented by the following formula (VI):

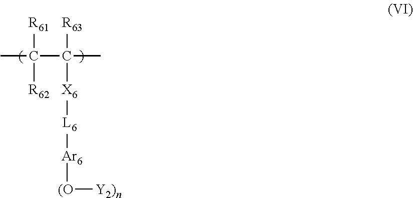

wherein

each of R₆₁, R₆₂ and R₆₃ independently represents a hydrogen atom, an alkyl group, a cycloalkyl group, a halogen atom, a cyano group or an alkoxycarbonyl group, provided that R₆₂ may combine with Ar₆ to form a ring and in this case, R₆₂ represents a single bond or an alkylene group,

X₆ represents a single bond, —COO— or —CONR₆₄—, and R₆₄ represents a hydrogen atom or an alkyl group,

L₆ represents a single bond or an alkylene group,

Ar₆ represents a (n+1)-valent aromatic ring group and in the case of combining with R₆₂ to form a ring, represents a (n+2)-valent aromatic ring group,

Y₂ represents a hydrogen atom or a group capable of leaving by the action of an acid, and in the case where a plurality of Y₂ are present, each Y₂ may be the same as or different from every other Y₂, provided that at least one Y₂ represents a group capable of leaving by the action of an acid; and

n represents an integer of 1 to 4.

[7] The pattern forming method as described in [6] above,

wherein Y₂ in formula (VI) is a structure represented by the following formula (VI-A):

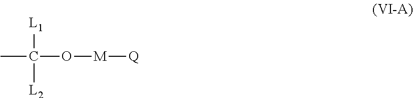

wherein each of L₁ and L₂ independently represents a hydrogen atom, an alkyl group, a cycloalkyl group, a monovalent aromatic ring group, or a group formed by combining an alkylene group and a monovalent aromatic ring group,

M represents a single bond or a divalent linking group,

Q represents an alkyl group, a cycloalkyl group which may contain a heteroatom, a monovalent aromatic ring group which may contain a heteroatom, an amino group, an ammonium group, a mercapto group, a cyano group or an aldehyde group, and at least two members of Q, M and L₁ may combine to form a ring.

[8] A method for selecting a heating temperature in a pattern forming method,

wherein the pattern forming method comprises, in order,

(i) a step of forming a film by using an extreme ultraviolet-sensitive resin composition containing (A) a resin having an acid-decomposable group,

(ii) a step of exposing the film by using an extreme ultraviolet ray,

(iii) a step of heating the film, and

(iv) a step of developing the film to form a pattern, and wherein,

in the step (ii), an optical image formed by exposure on the surface of the film is an optical image having a line part with a line width of 20 nm or less as an exposed area or an unexposed area, and,

the method for selecting a heating temperature comprises selecting the heating temperature T_{PEB} in the step (iii) to satisfy the following formula (1):

[glass transition temperature (Tg) of the resin (A)−30](° C.)≦T_{PEB}≦glass transition temperature (Tg)(° C.) of the resin (A) (1)

[9] The method for selecting a heating temperature in a pattern forming method as described in [8] above,

wherein,

the pattern forming method further comprises (v) a step of heating the pattern, after the step (iv), and,

the method for selecting a heating temperature further comprises selecting the heating temperature T_{PDB}(° C.) in the step (v) to satisfy the following formula (2):

[glass transition temperature (Tg) of the resin (A)−20](° C.)≦T_{PDB}≦[glass transition temperature (Tg)(° C.) of the resin (A)+10](° C.) (2)

[10] An extreme ultraviolet-sensitive resin composition used in the pattern forming method described in any one of [1] to [7] above.
[11] A resist film formed using the extreme ultraviolet-sensitive composition described in [10] above.
[12] A method for manufacturing an electronic device, comprising the pattern forming method described in any one of [1] to [7] above.
[13] An electronic device manufactured by the manufacturing method of an electronic device described in [12] above.

According to the present invention, a pattern forming method capable of forming a pattern having a line part with a line width of 20 nm or less while satisfying high resolution, good pattern cross-sectional profile and high roughness performance all at the same time, a method for selecting a heating temperature in a pattern forming method, an extreme ultraviolet-sensitive resin composition, a resist film, a manufacturing method of an electronic device using the same, and an electronic device can be provided.

### DESCRIPTION OF EMBODIMENTS

The mode for carrying out the present invention is described in detail below.

In the description of the present invention, when a group (atomic group) is denoted without specifying whether substituted or unsubstituted, the group encompasses both a group having no substituent and a group having a substituent. For example, “an alkyl group” recited without specifying whether substituted or unsubstituted encompasses not only an alkyl group having no substituent (unsubstituted alkyl group) but also an alkyl group having a substituent (substituted alkyl group).

In the present invention, the “volume of an acid” means the volume of a region occupied by a van der Waals sphere based on the van der Waals radius of an atom constituting the acid. Specifically, the “volume of an acid” is a volume calculated as follows. That is, first, the most stable conformation of the acid is determined by a molecular force field calculation using an MM3 method. Next, with respect to this most stable conformation, a van der Waals volume is computed by a molecular orbital calculation using a PM3 method. The obtained van der Waals volume is referred to as the “volume of an acid”.

In the description of the present invention, the “light” means an extreme ultraviolet ray (EUV light).

Also, in the description of the present invention, unless otherwise indicated, the “exposure” means exposure to an extreme ultraviolet ray (EUV light).

The pattern forming method of the present invention is described below.

The pattern forming method of the present invention is a pattern forming method comprising, in order,

(i) a step of forming a film by using an extreme ultraviolet-sensitive resin composition containing (A) a resin having an acid-decomposable group,

(ii) a step of exposing the film by using an extreme ultraviolet ray,

(iii) a step of heating the film, and

(iv) a step of developing the film to form a pattern, wherein:

in the step (ii), an optical image formed by exposure on the surface of the film is an optical image having a line part with a line width of 20 nm or less as an exposed area or an unexposed area, and, the heating temperature T_{PEB}(° C.) in the step (iii) satisfies the following formula (1):

[glass transition temperature (Tg) of the resin (A)−30](° C.)≦T_{PEB}≦glass transition temperature (Tg)(° C.) of the resin (A) (1)

According to the pattern forming method of the present invention, a pattern having a line part with a line width of 20 nm or less can be formed while satisfying high resolution, good pattern cross-sectional profile and high roughness performance all at the same time. The reason therefor is not clearly known but is presumed as follows.

First, as the heating temperature T_{PEB} in the step (iii) is higher, the acid generated in the exposed area of the resist film tends to more readily diffuse into the unexposed area.

When the heating temperature T_{PEB} becomes higher than the glass transition temperature (Tg) of the resin having an acid-decomposable group (hereinafter, sometimes referred to as “acid-decomposable resin”), more vigorous diffusion of the acid into the unexposed is likely to occur. As a result, although the detailed mechanism is unknown, in the case where the line part with a line width of 20 nm or less in the optical part is an unexposed area and the developer is an alkali developer, the cross-sectional profile of the pattern is liable to become a tapered profile, and in the case where the line part with a line width of 20 nm or less in the optical image is an exposed area and the developer is an organic solvent-containing developer (hereinafter, sometimes referred to as “organic developer”), the cross-sectional profile of the pattern becomes a reverse-tapered profile. In turn, moreover, the roughness performance is considered to be also deteriorated.

This time, the present inventors have found that in addition to the existence of the above-described phenomenon, when the resist film is exposed to an extreme ultraviolet ray (EUV light) to form an optical image having a line part with a line width of 20 nm or less as an exposed area or an unexposed area, the phenomenon becomes particularly outstanding.

Also, the present inventors have found that when the heating temperature T_{PEB} becomes higher than the glass transition temperature (Tg)(° C.), in the case where the line part with a line width of 20 nm or less in the optical part is an unexposed area and the developer is an alkali developer, the tapered pattern is liable to cause a line break, and in the case where the line part with a line width of 20 nm or less in the optical image is an exposed area and the developer is an organic developer, the reverse-tapered pattern readily collapses, making it very difficult to resolve the line part with a line width of 20 nm or less (in other words, to realize excellent resolution).

Furthermore, the present inventors have found that that when the heating temperature T_{PEB} becomes lower than the [glass transition temperature (Tg)−30](° C.), in the case where the line part with a line width of 20 nm or less in the optical part is an unexposed area and the developer is an alkali developer, the reverse-tapered pattern readily collapses, and in the case where the line part with a line width of 20 nm or less in the optical image is an exposed area and the developer is an organic developer, the tapered pattern is liable to cause a line break, similarly making it very difficult to resolve the line part with a line width of 20 nm or less (in other words, to realize excellent resolution).

In the pattern forming method of the present invention, the heating temperature T_{PEB} is not more than the glass transition temperature (Tg)(° C.) of the acid-decomposable resin, whereby diffusion of the acid into the unexposed area is suppressed to a degree causing no problem in the formation of a pattern having a line part with a line width of 20 nm or less. This is considered to enable resolving the line part having a line width of 20 nm or less with a good cross-sectional profile and at the same time, providing excellent roughness performance.

Also, the heating temperature T_{PEB} is not less than the [glass transition temperature (Tg) of the resin (A)−30](° C.), whereby the acid diffuses to a degree causing no problem in the formation of a pattern having a line part with a line width of 20 nm or less. This is considered to enable resolving the line part having a line width of 20 nm or less with a good cross-sectional profile and at the same time, providing excellent roughness performance.

The extreme ultraviolet-sensitive resin composition which can be used in the present invention is described below.

The extreme ultraviolet-sensitive resin composition is, for example, a positive or negative composition and is typically a positive resist composition. Also, the extreme ultraviolet-sensitive resin composition is typically a chemical amplification resist composition.

In addition, the present invention also relates to the extreme ultraviolet-sensitive resin composition used in the pattern forming method of the present invention.

The configuration of this composition is described below.

[1] (A) Resin having an acid-decomposable group

The extreme ultraviolet-sensitive resin composition for use in the present invention contains (A) a resin having an acid-decomposable group (hereinafter, sometimes referred to as “resin (A)” or “acid-decomposable resin”).

The resin (A) is a resin having an acid-decomposable group and is a resin having an acid-decomposable group in either one or both of the main chain and the side chain of the resin.

The acid-decomposable group is typically a group capable of decomposing by the action of an acid to produce a polar group, in other words, a group capable of decomposing by the action of an acid to increase the solubility of the resin (A) for an alkali developer. Furthermore, the acid-decomposable group is typically also a group capable of decomposing by the action of an acid to decrease the solubility of the resin (A) of an organic solvent-containing developer.

Preferred examples of the polar group include a phenolic hydroxyl group, a carboxyl group, a fluorinated alcohol group (preferably hexafluoroisopropanol), and a sulfonic acid group.

The group preferred as the acid-decomposable group is a group where a hydrogen atom of the polar group above is substituted for by a group capable of leaving by the action of an acid.

Examples of the group capable of leaving by the action of an acid include —C(R₃₆)(R₃₇)(R₃₈), —C(R₃₆)(R₃₇)(OR₃₉) and —C(R₀₁)(R₀₂)(OR₃₉).

In the formulae, each of R₃₆ to R₃₉ independently represents an alkyl group, a cycloalkyl group, an aryl group, an aralkyl group or an alkenyl group. R₃₆ and R₃₇ may combine with each other to form a ring.

Each of R₀₁ and R₀₂ independently represents a hydrogen atom, an alkyl group, a cycloalkyl group, an aryl group, an aralkyl group or an alkenyl group.

The resin (A) has an acid-decomposable group and thereby works out to a resin capable of increasing the solubility for an alkali developer or a resin capable of decreasing the solubility for an organic solvent-containing developer.

The resin (A) preferably contains (a) a repeating unit having an acid-decomposable group.

The repeating unit (a) includes, for example, a repeating unit represented by the following formula (V):

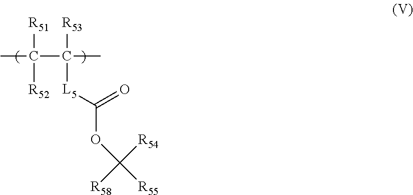

In formula (V), each of R₅₁, R₅₂ and R₅₃ independently represents a hydrogen atom, an alkyl group, a cycloalkyl group, a halogen atom, a cyano group or an alkoxycarbonyl group. R₅₂ may combine with L₅ to form a ring, and in this case, R₅₂ represents an alkylene group.

L₅ represents a single bond or a divalent linking group, and in the case of forming a ring with R₅₂, L₅ represents a trivalent linking group.

R₅₄ represents an alkyl group, and each of R₅₅ and R₅₆ independently represents a hydrogen atom, an alkyl group, a cycloalkyl group, a monovalent aromatic ring group, or an aralkyl group. R₅₅ and R₅₆ may combine with each other to form a ring. However, R₅₅ and R₅₆ are not a hydrogen atom at the same time.

Formula (V) is described in more detail.

The alkyl group of R₅₁ to R₅₃ in formula (V) is preferably an alkyl group having a carbon number of 20 or less, such as methyl group, ethyl group, propyl group, isopropyl group, n-butyl group, sec-butyl group, hexyl group, 2-ethylhexyl group, octyl group and dodecyl group, which may have a substituent. The alkyl group is more preferably an alkyl group having a carbon number of 8 or less, still more preferably an alkyl group having a carbon number of 3 or less.

As the alkyl group contained in the alkoxycarbonyl group, the same alkyl group as in R₅₁ to R₅₃ is preferred.

The cycloalkyl group may be either monocyclic or polycyclic. The cycloalkyl group is preferably a monocyclic cycloalkyl group having a carbon number of 3 to 8, such as cyclopropyl group, cyclopentyl group and cyclohexyl group, which may have a substituent.

The halogen atom includes fluorine atom, chlorine atom, bromine atom and iodine atom, with fluorine atom being preferred.

Preferred examples of the substituent on each of these groups include an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group. The carbon number of the substituent is preferably 8 or less.

In the case where R₅₂ is an alkylene group and forms a ring with L₅, the alkylene group is preferably an alkylene group having a carbon number of 1 to 8, such as methylene group, ethylene group, propylene group, butylene group, hexylene group and octylene group, more preferably an alkylene group having a carbon number of 1 to 4, still more preferably an alkylene group having a carbon number of 1 to 2. The ring formed by combining R₅₂ and L₅ is preferably a 5- or 6-membered ring.

In formula (V), each of R₅₁ and R₅₃ is preferably a hydrogen atom, an alkyl group or a halogen atom, more preferably a hydrogen atom, a methyl group, an ethyl group, a trifluoromethyl group (—CF₃), a hydroxymethyl group (—CH₂—OH), a chloromethyl group (—CH₂—Cl) or a fluorine atom (—F). R₅₂ is preferably a hydrogen atom, an alkyl group, a halogen atom or an alkylene group (forms a ring with L₅), more preferably a hydrogen atom, a methyl group, an ethyl group, a trifluoromethyl group (—CF₃), a hydroxymethyl group (—CH₂—OH), a chloromethyl group (—CH₂—Cl), a fluorine atom (—F), a methylene group (forms a ring with L₅) or an ethylene group (forms a ring with L₅).

Examples of the divalent linking group represented by L₅ include an alkylene group, a divalent aromatic ring group, —COO-L₁-, —O-L₁-, and a group formed by combining two or more of these groups. Here, L₁ represents an alkylene group, a cycloalkylene group, a divalent aromatic ring group, or a group formed by combining an alkylene group and a divalent aromatic ring group.

L₅ is preferably a single bond, a group represented by —COO-L₁-, or a divalent aromatic ring group. L₁ is preferably an alkylene group having a carbon number of 1 to 5, more preferably a methylene group or a propylene group. The divalent aromatic ring group is preferably a 1,4-phenylene group, a 1,3-phenylene group, a 1,2-phenylene group or a 1,4-naphthylene group, more preferably a 1,4-phenylene group.

In the case where L₅ combines with R₅₂ to form a ring, preferred examples of the trivalent linking group represented by L₅ include groups formed by removing one arbitrary hydrogen atom from specific examples above of the divalent linking group represented by L₅.

The alkyl group of R₅₄ to R₅₆ is preferably an alkyl group having a carbon number of 1 to 20, more preferably an alkyl group having a carbon number of 1 to 10, still more preferably an alkyl group having a carbon number of 1 to 4, such as methyl group, ethyl group, n-propyl group, isopropyl group, n-butyl group, isobutyl group and tert-butyl group.

The cycloalkyl group represented by R₅₅ and R₅₆ is preferably a cycloalkyl group having a carbon number of 3 to 20 and may be a monocyclic cycloalkyl group such as cyclopentyl group and cyclohexyl group, or a polycyclic cycloalkyl group such as norbornyl group, adamantyl group, tetracyclodecanyl group and tetracyclododecanyl group.

The ring formed by combining R₅₅ and R₅₆ with each other is preferably a ring having a carbon number of 3 to 20 and may be a monocyclic ring such as cyclopentyl group and cyclohexyl group, or a polycyclic ring such as norbornyl group, adamantyl group, tetracyclodecanyl group and tetracyclododecanyl group. In the case where R₅₅ and R₅₆ combine with each other to form a ring, R₅₄ is preferably an alkyl group having a carbon number of 1 to 3, more preferably a methyl group or an ethyl group.

The monovalent aromatic ring group represented by R₅₅ and R₅₆ is preferably a monovalent aromatic ring group having a carbon number of 6 to 20 and may be monocyclic or polycyclic or may have a substituent. Examples thereof include a phenyl group, a 1-naphthyl group, a 2-naphthyl group, a 4-methylphenyl group, and a 4-methoxyphenyl group. In the case where either one of R₅₅ and R₅₆ is a hydrogen atom, the other is preferably a monovalent aromatic ring group.

The aralkyl group represented by R₅₅ and R₅₆ may be monocyclic or polycyclic or may have a substituent and is preferably an aralkyl group having a carbon number of 7 to 21, and examples thereof include a benzyl group and a 1-naphthylmethyl group.

The synthesis method of the monomer corresponding to the repeating unit represented by formula (V) is not particularly limited, and synthesis methods for general polymerizable group-containing esters can be applied.

Specific examples of the repeating unit (a) represented by formula (V) are illustrated below, but the present invention is not limited thereto.

In specific examples, each of Rx and Xa₁ represents a hydrogen atom, CH₃, CF₃ or CH₂OH, and each of Rxa and Rxb independently represents an alkyl group having a carbon number of 1 to 4, an aryl group having a carbon number of 6 to 18, or an aralkyl group having a carbon number of 7 to 19. Z represents a substituent. p represents 0 or a positive integer and is preferably 0 to 2, more preferably 0 or 1. In the case where a plurality of Z's are present, each may be the same as or different from every other. From the standpoint of increasing the contrast of dissolution for the organic solvent-containing developer between before and after acid decomposition, Z is suitably a hydrogen atom or a group composed of only carbon atom and is preferably, for example, a linear or branched alkyl group or a cycloalkyl group.

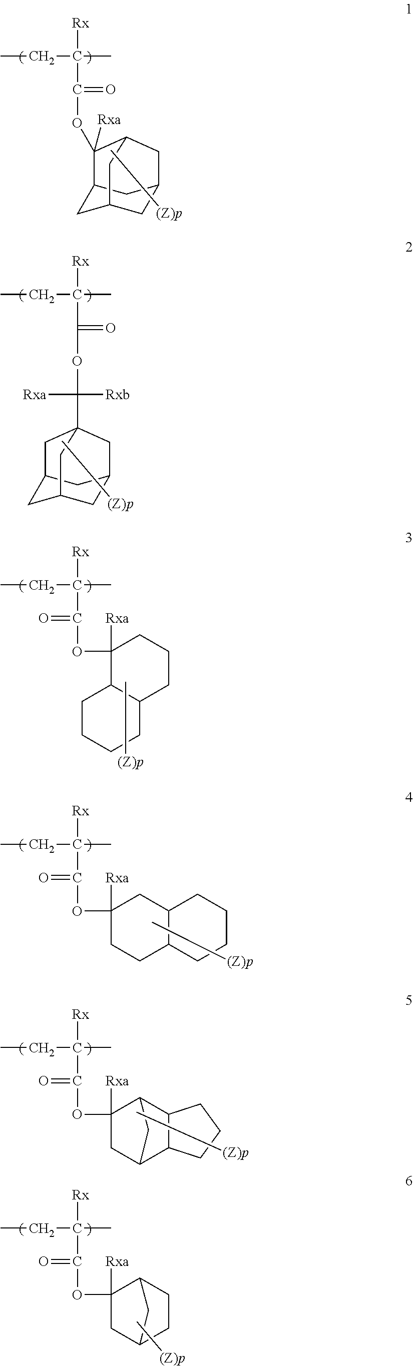

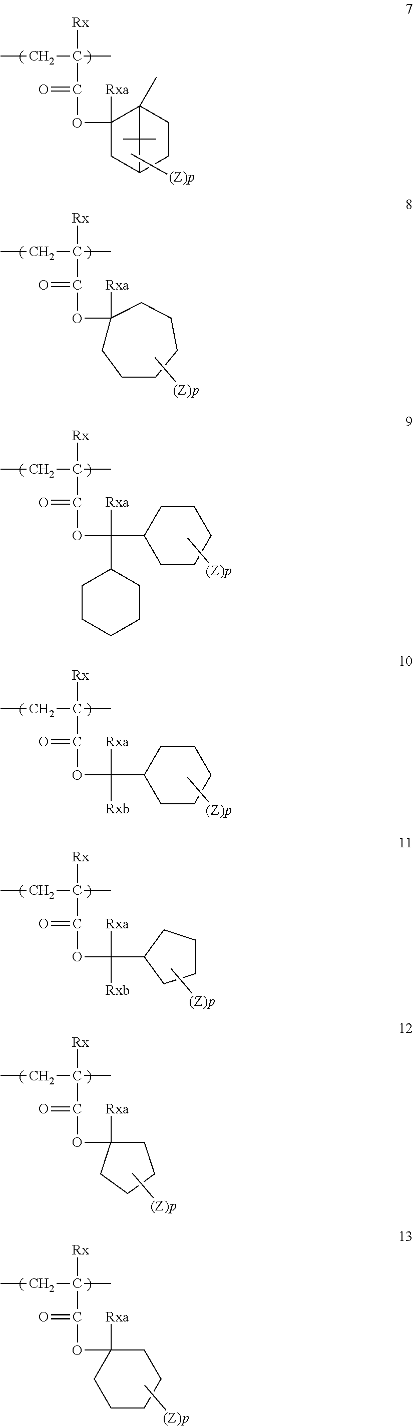

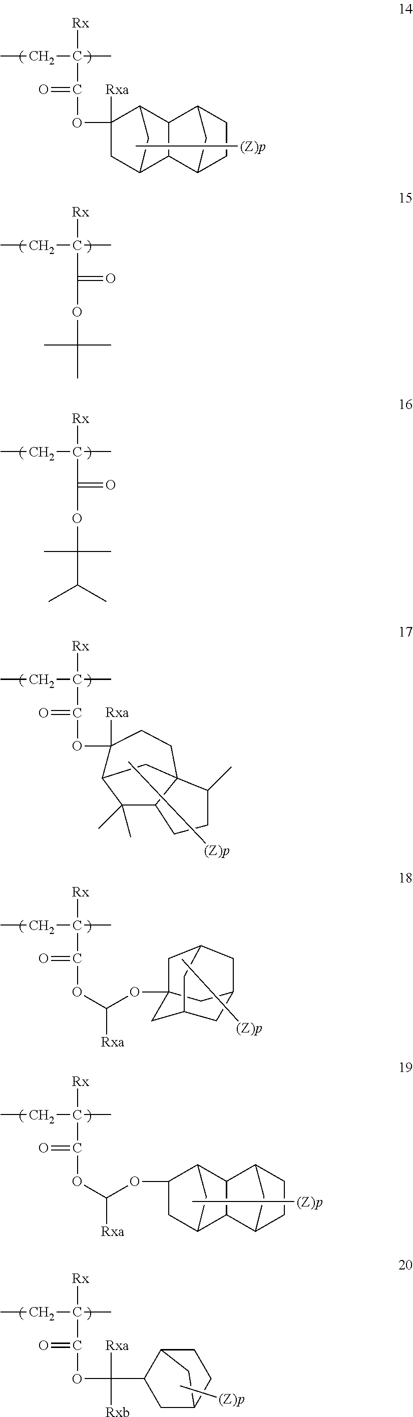

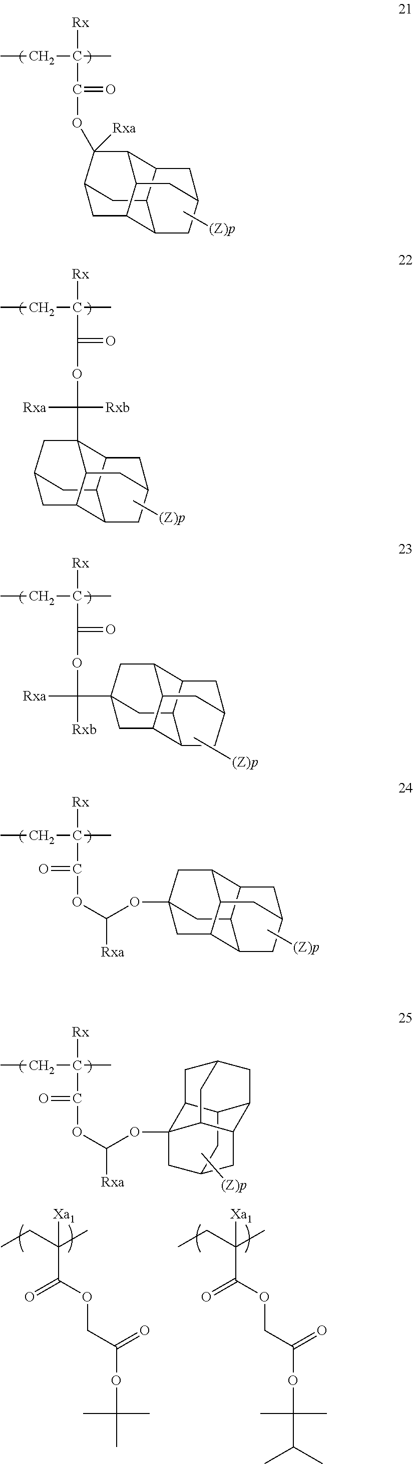

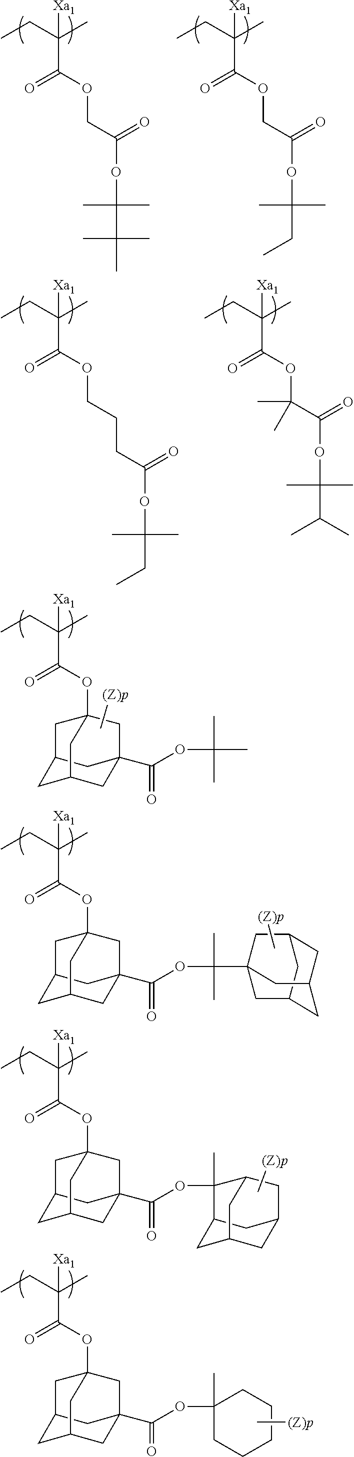

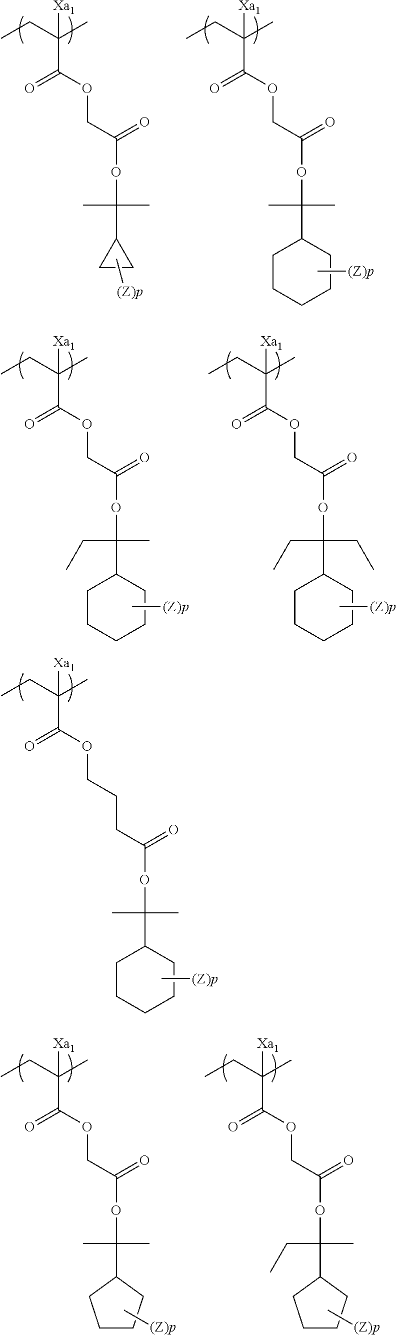

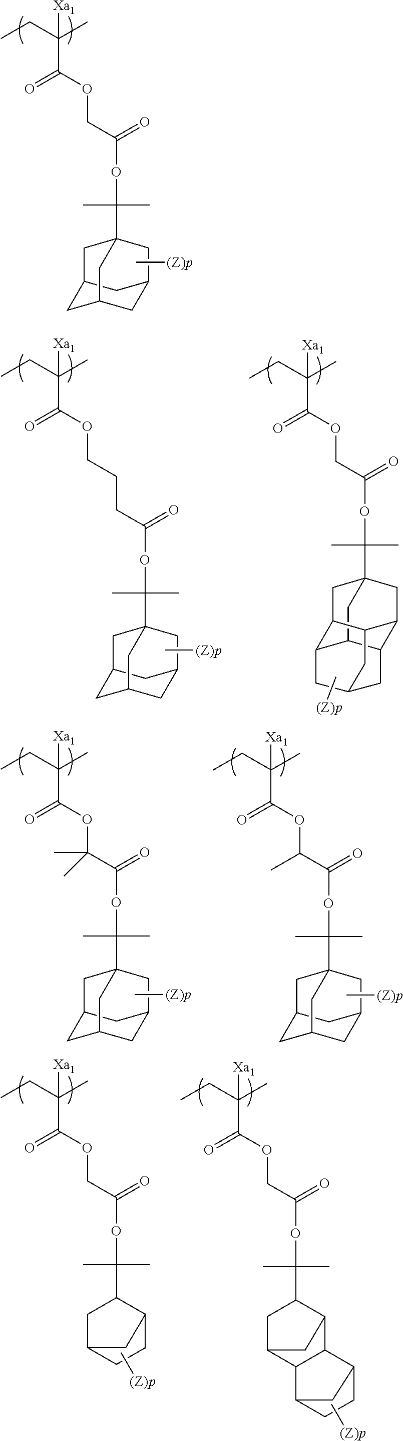

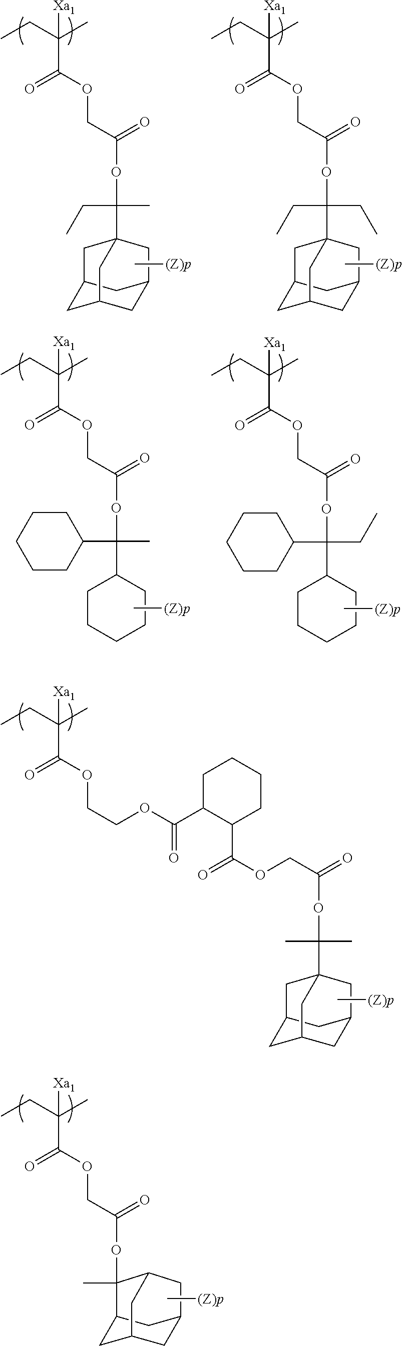

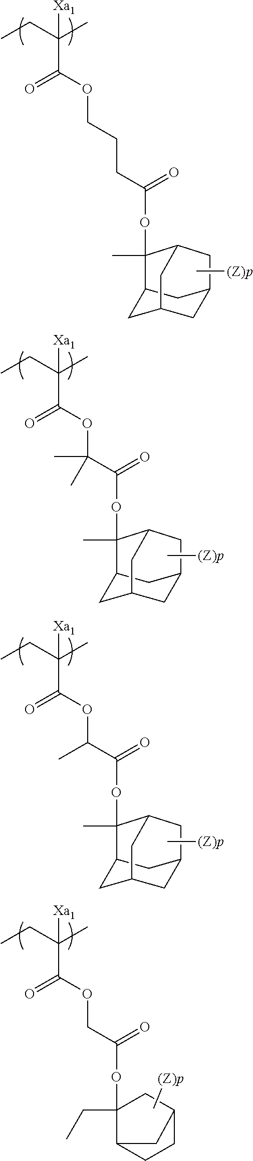

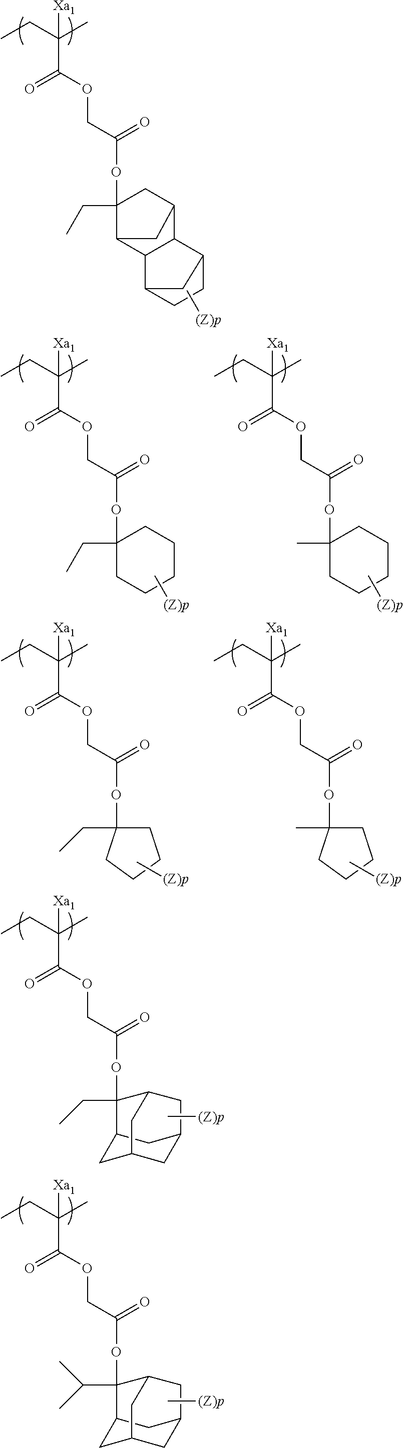

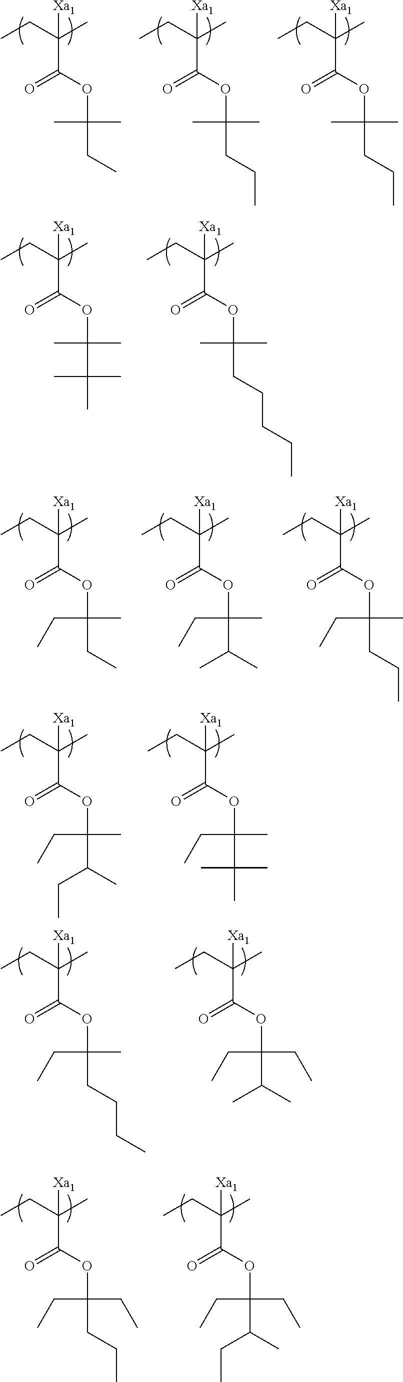

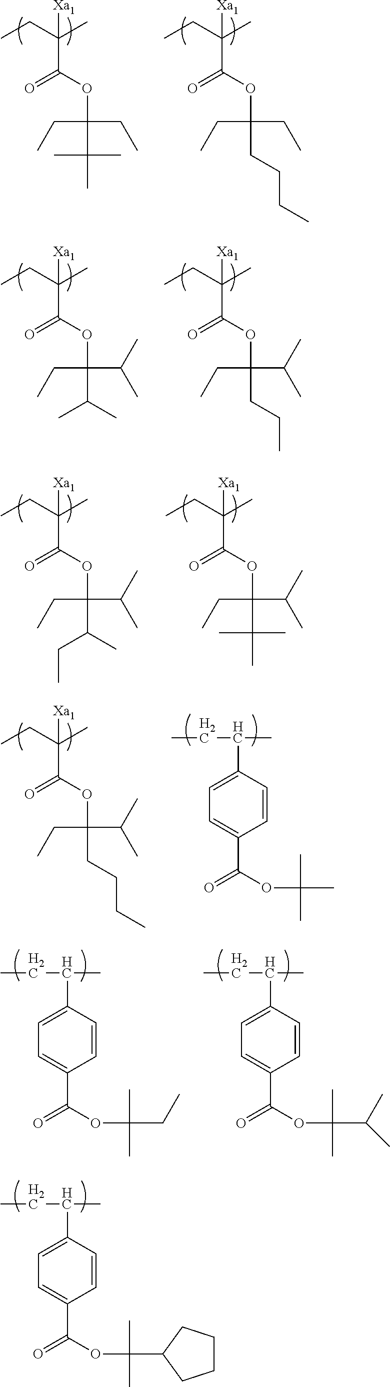

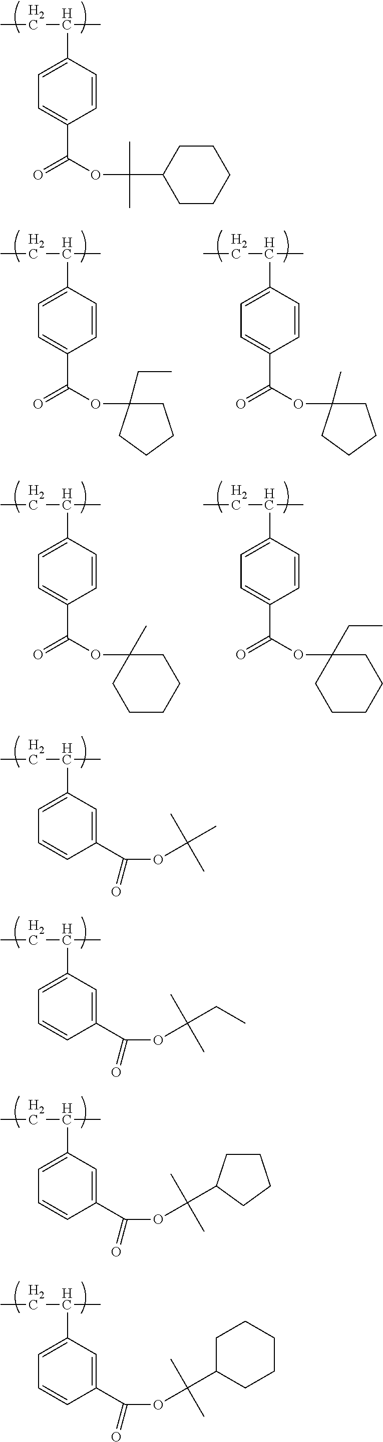

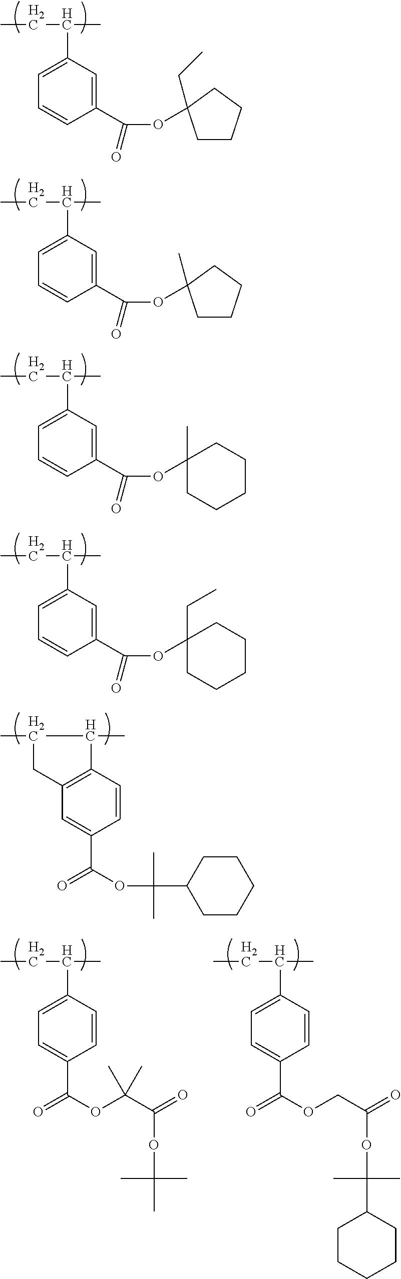

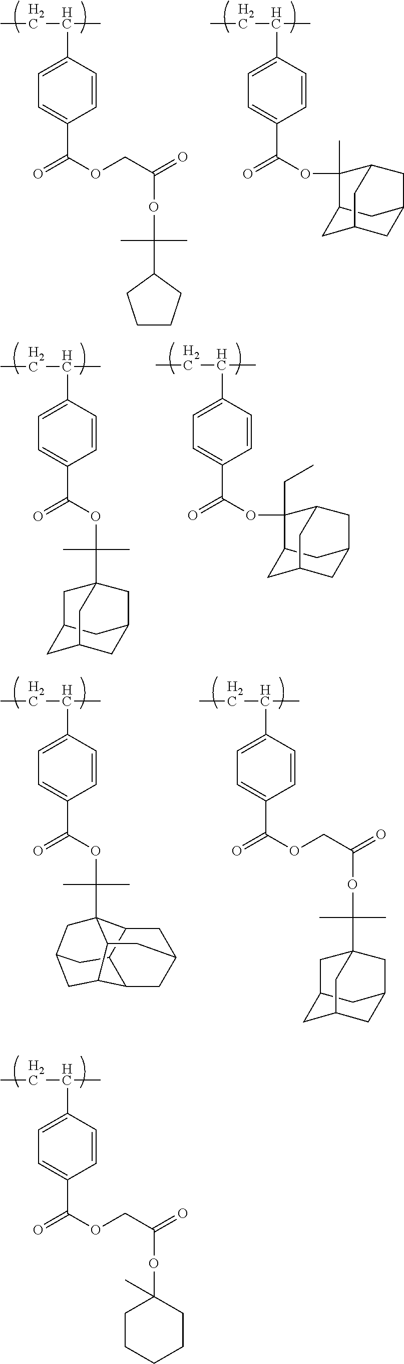

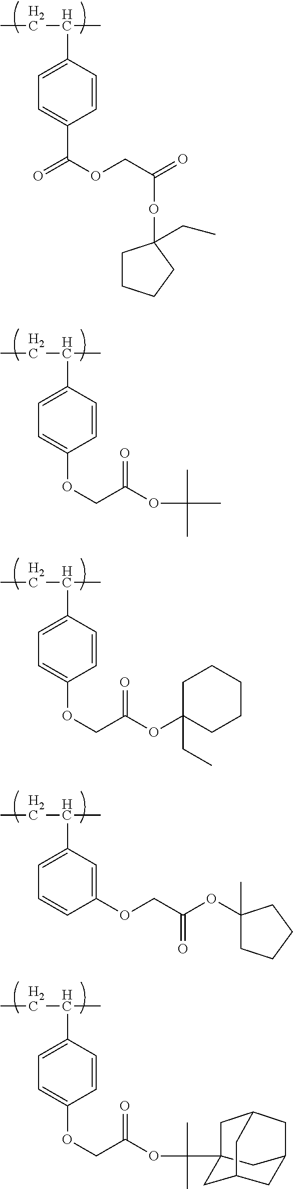

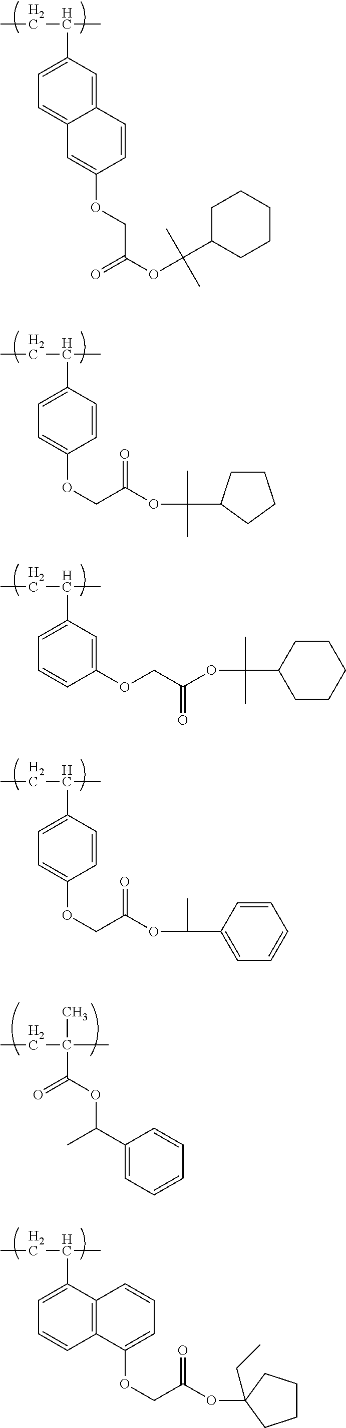

Moreover, as the repeating unit (a), a repeating unit represented by the following formula (VI) can be also exemplified.

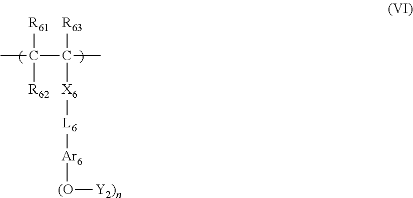

In formula (VI), each of R₆₁, R₆₂ and R₆₃ independently represents a hydrogen atom, an alkyl group, a cycloalkyl group, a halogen atom, a cyano group or an alkoxycarbonyl group.

R₆₂ may combine with Ar₆ to form a ring, and in this case, R₆₂ represents a single bond or an alkylene group.

X₆ represents a single bond, —COO— or —CONR₆₄—, and R₆₄ represents a hydrogen atom or an alkyl group.

L₆ represents a single bond or an alkylene group.

Ar₆ represents an (n+1)-valent aromatic ring group and in the case of combining with R₆₂ to form a ring, Ar₆ represents an (n+2)-valent aromatic ring group.

Y₂ represents a hydrogen atom or a group capable of leaving by the action of an acid, and when a plurality of Y₂s exist, each Y₂ may be same as or different from every other Y₂, provided that at least one Y₂ represents a group capable of leaving by the action of an acid.

n represents an integer of 1 to 4.

Formula (VI) is described in more detail below.

The alkyl group of R₆₁ to R₆₃ in formula (VI) is preferably an alkyl group having a carbon number of 20 or less, such as methyl group, ethyl group, propyl group, isopropyl group, n-butyl group, sec-butyl group, hexyl group, 2-ethylhexyl group, octyl group and dodecyl group, which may have a substituent, more preferably an alkyl group having a carbon number of 8 or less.

As the alkyl group contained in the alkoxycarbonyl group, the same as the alkyl group in R₆₁ to R₆₃ is preferred.

The cycloalkyl group may be either monocyclic or polycyclic and is preferably a monocyclic cycloalkyl group having a carbon number of 3 to 8, such as cyclopropyl group, cyclopentyl group and cyclohexyl group, which may have a substituent.

The halogen atom includes fluorine atom, chlorine atom, bromine atom and iodine atom, with fluorine atom being preferred.

In the case where R₆₂ represents an alkylene group, the alkylene group is preferably an alkylene group having a carbon atom of 1 to 8, such as methylene group, ethylene group, propylene group, butylene group, hexylene group and octylene group, which may have a substituent.

Examples of the alkyl group of R₆₄ in —CONR₆₄— (R₆₄ represents a hydrogen atom or an alkyl group) represented by X₆ are the same as those of the alkyl group of R₆₁ to R₆₃.

X₆ is preferably a single bond, —COO— or —CONH—, more preferably a single bond or —COO—.

The alkylene group in L₆ is preferably an alkylene group having a carbon number of 1 to 8, such as methylene group, ethylene group, propylene group, butylene group, hexylene group and octylene group, which may have a substituent. The ring formed by combining R₆₂ and L₆ is preferably a 5- or 6-membered ring.

Ar₆ represents an (n+1)-valent aromatic ring. The divalent aromatic ring group when n is 1 may have a substituent, and preferred examples of the divalent aromatic ring group include an arylene group having a carbon number of 6 to 18, such as phenylene group, tolylene group and naphthylene group, and a divalent aromatic ring group containing a heterocyclic ring such as thiophene, furan, pyrrole, benzothiophene, benzofuran, benzopyrrole, triazine, imidazole, benzimidazole, triazole, thiadiazole and thiazole.

Specific examples of the (n+1)-valent aromatic ring group when n is an integer of 2 or more include groups formed by removing arbitrary (n−1) hydrogen atoms from the above-described specific examples of the divalent aromatic ring group.

The (n+1)-valent aromatic ring group may further have a substituent.

Examples of the substituent which may be substituted on the above-described alkyl group, cycloalkyl group, alkoxycarbonyl group, alkylene group and (n+1)-valent aromatic ring group are the same as specific examples of the substituent which may be substituted on each of the groups represented by R₅₁ to R₅₃ in formula (V).

n is preferably 1 or 2, more preferably 1.

Each of n Y₂s independently represents a hydrogen atom or a group capable of leaving by the action of an acid, and when a plurality of Y₂s exist, each Y₂ may be same as or different from every other Y₂, at least one of Y₂s represents a group capable of leaving by the action of an acid, provided that at least one of n Y₂s represents a group capable of leaving by the action of an acid.

Examples of the group Y₂ capable of leaving by the action of an acid include —C(R₃₆)(R₃₇)(R₃₈), —C(═O)—O—C(R₃₆)(R₃₇)(R₃₈), —C(R₀₁)(R₀₂)(OR₃₉), —C(R₀₁)(R₀₂)—C(═O)—O—C(R₃₆)(R₃₇)(R₃₈) and —CH(R₃₆)(Ar).

In the formulae, each of R₃₆ to R₃₉ independently represents an alkyl group, a cycloalkyl group, a monovalent aromatic ring group, a group formed by combining an alkylene group and a monovalent aromatic ring group, or an alkenyl group. R₃₆ and R₃₇ may combine with each other to form a ring.

Each of R₀₁ and R₀₂ independently represents a hydrogen atom, an alkyl group, a cycloalkyl group, a monovalent aromatic ring group, a group formed by combining an alkylene group and a monovalent aromatic ring group, or an alkenyl group.

Ar represents a monovalent aromatic ring group.

The alkyl group of R₃₆ to R₃₉, R₀₁ and R₀₂ is preferably an alkyl group having a carbon number of 1 to 8, and examples thereof include a methyl group, an ethyl group, a propyl group, an n-butyl group, a sec-butyl group, a hexyl group, and an octyl group.

The cycloalkyl group of R₃₆ to R₃₉, R₀₁ and R₀₂ may be monocyclic or polycyclic. The monocyclic cycloalkyl group is preferably a cycloalkyl group having a carbon number of 3 to 8, and examples thereof include a cyclopropyl group, a cyclobutyl group, a cyclopentyl group, a cyclohexyl group, and a cyclooctyl group. The polycyclic cycloalkyl group is preferably a cycloalkyl group having a carbon number of 6 to 20, and examples thereof include an adamantyl group, a norbornyl group, an isoboronyl group, a camphanyl group, a dicyclopentyl group, an α-pinel group, a tricyclodecanyl group, a tetracyclododecyl group, and an androstanyl group. Incidentally, a part of carbon atoms in the cycloalkyl group may be substituted with a heteroatom such as oxygen atom.

The monovalent aromatic ring group of R₃₆ to R₃₉, R₀₁, R₀₂ and Ar is preferably a monovalent aromatic ring group having a carbon number of 6 to 10, and examples thereof include an aryl group such as phenyl group, naphthyl group and anthryl group, and a divalent aromatic ring group containing a heterocyclic ring such as thiophene, furan, pyrrole, benzothiophene, benzofuran, benzopyrrole, triazine, imidazole, benzimidazole, triazole, thiadiazole and thiazole.

The group formed by combining an alkylene group and a monovalent aromatic ring group of R₃₆ to R₃₉, R₀₁ and R₀₂ is preferably an aralkyl group having a carbon number of 7 to 12, and examples thereof include a benzyl group, a phenethyl group and a naphthylmethyl group.

The alkenyl group of R₃₆ to R₃₉, R₀₁ and R₀₂ is preferably an alkenyl group having a carbon number of 2 to 8, and examples thereof include a vinyl group, an allyl group, a butenyl group, and a cyclohexenyl group.

The ring formed by combining R₃₆ and R₃₇ with each other may be monocyclic or polycyclic. The monocyclic ring structure is preferably a cycloalkyl structure having a carbon number of 3 to 8, and examples thereof include a cyclopropane structure, a cyclobutane structure, a cyclopentane structure, a cyclohexane structure, a cycloheptane structure, and a cyclooctane structure. The polycyclic ring structure is preferably a cycloalkyl structure having a carbon number of 6 to 20, and examples thereof include an adamantane structure, a norbornane structure, a dicyclopentane structure, a tricyclodecane structure, and a tetracyclododecane structure. Incidentally, a part of carbon atoms in the cycloalkyl structure may be substituted with a heteroatom such as oxygen atom.

Each of these groups as R₃₆ to R₃₉, R₀₁, R₀₂ and Ar may have a substituent, and examples of the substituent include an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group. The carbon number of the substituent is preferably 8 or less.

The group Y₂ capable of leaving by the action of an acid is more preferably a structure represented by the following formula (VI-A):

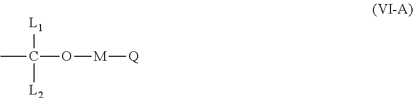

In the formula, each of L₁ and L₂ independently represents a hydrogen atom, an alkyl group, a cycloalkyl group, a monovalent aromatic ring group, or a group formed by combining an alkylene group and a monovalent aromatic ring group.

M represents a single bond or a divalent linking group.

Q represents an alkyl group, a cycloalkyl group which may contain a heteroatom, a monovalent aromatic ring group which may contain a heteroatom, an amino group, an ammonium group, a mercapto group, a cyano group or an aldehyde group.

At least two members of Q, M and L₁ may combine to form a ring (preferably a 5- or 6-membered ring).

The alkyl group as L₁ and L₂ is, for example, an alkyl group having a carbon number of 1 to 8, and specific preferred examples thereof include a methyl group, an ethyl group, a propyl group, an n-butyl group, a sec-butyl group, a hexyl group, and an octyl group.

The cycloalkyl group as L₁ and L₂ is, for example, a cycloalkyl group having a carbon number of 3 to 15, and specific preferred examples thereof include a cyclopentyl group, a cyclohexyl group, a norbornyl group, and an adamantyl group.

The monovalent aromatic ring group as L₁ and L₂ is, for example, an aryl group having a carbon number of 6 to 15, and specific preferred examples thereof include a phenyl group, a tolyl group, a naphthyl group, and an anthryl group.

The group formed by combining an alkylene group and a monovalent aromatic ring group as L₁ and L₂ is, for example, an aralkyl group having a carbon number of 6 to 20, such as benzyl group and phenethyl group.

Examples of the divalent linking group as M include an alkylene group (such as methylene group, ethylene group, propylene group, butylene group, hexylene group and octylene group), a cycloalkylene group (such as cyclopentylene group, cyclohexylene group and adamantylene group), an alkenylene group (such as vinylene group, propenylene group and butenylene group), a divalent aromatic ring group (such as phenylene group, tolylene group and naphthylene group), —S—, —O—, —CO—, —SO₂—, —N(R₀)—, and a divalent linking group formed by combining a plurality thereof. Here, R₀ is a hydrogen atom or an alkyl group (for example, an alkyl group having a carbon number of 1 to 8, and specific examples thereof include a methyl group, an ethyl group, a propyl group, an n-butyl group, a sec-butyl group, a hexyl group, and an octyl group).

Examples of the alkyl group as Q are the same as those of the alkyl group of L₁ and L₂.

Examples of the heteroatom-free aliphatic hydrocarbon ring group and the heteroatom-free monovalent aromatic ring group in the cycloalkyl group which may contain a heteroatom and the monovalent aromatic ring group which may contain a heteroatom as Q include the cycloalkyl group and monovalent aromatic ring group described above for L₁ and L₂, and the carbon number is preferably from 3 to 15.

Examples of the heteroatom-containing cycloalkyl group and the heteroatom-containing monovalent aromatic ring group include a group having a heterocyclic structure such as thiirane, cyclothiolane, thiophene, furan, pyrrole, benzothiophene, benzofuran, benzopyrrole, triazine, imidazole, benzimidazole, triazole, thiadiazole, thiazole and pyrrolidone, but the structure is not limited thereto as long as it is a structure generally called a heterocyclic ring (a ring composed of carbon and a heteroatom, or a ring composed of a heteroatom).

Examples of the ring which may be formed by combining at least two members of Q, M and L₁ include an oxygen atom-containing 5- or 6-membered ring formed by combining at least two members of Q, M and L₁ and thereby forming, for example, a propylene group or a butylene group.

In formula (VI-A), each of the groups represented by L₁, L₂, M and Q may have a substituent, and examples of the substituent include those described above as the substituent which may be substituted on R₃₆ to R₃₉, R₀₁, R₀₂ and Ar. The carbon number of the substituent is preferably 8 or less.

The group represented by -M-Q is preferably a group composed of 1 to 30 carbons, more preferably a group composed of 5 to 20 carbons.

As specific preferred examples of the repeating unit (a), specific examples of the repeating unit represented by formula (VI) are illustrated below, but the present invention is not limited thereto.

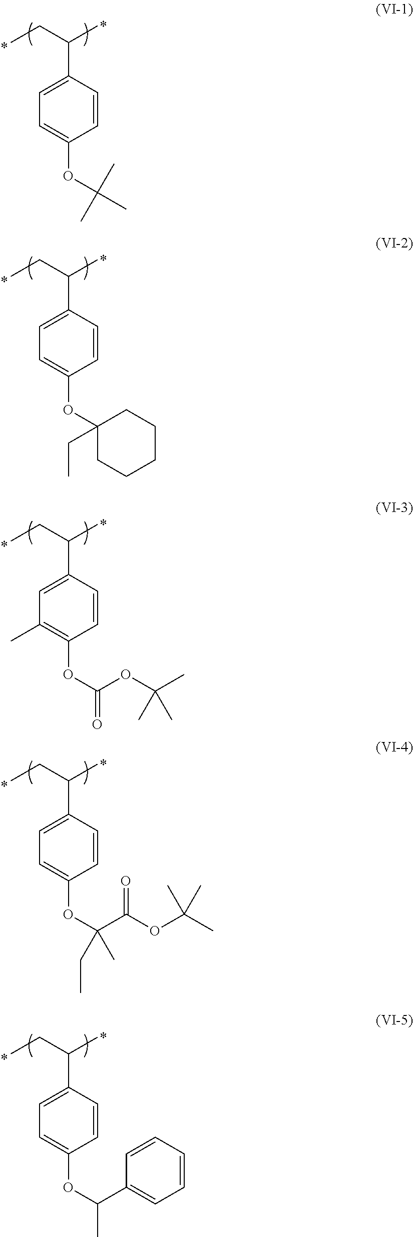

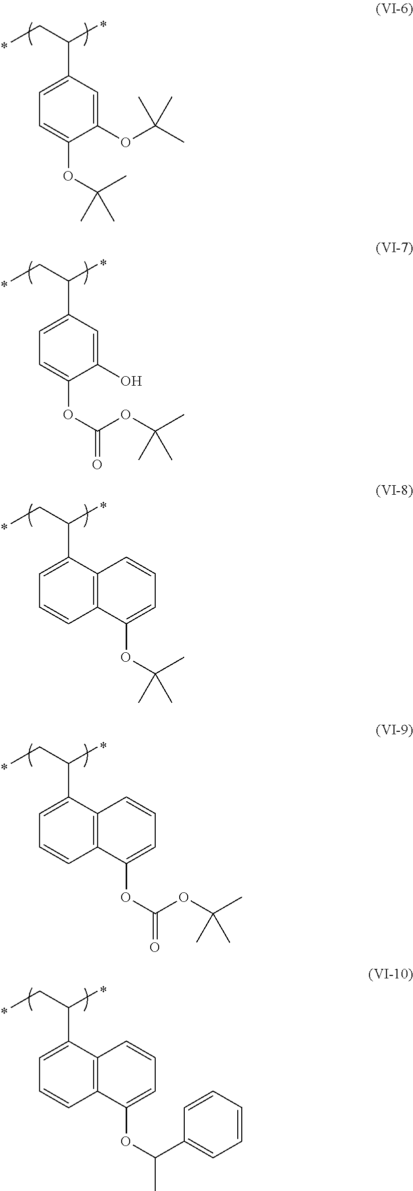

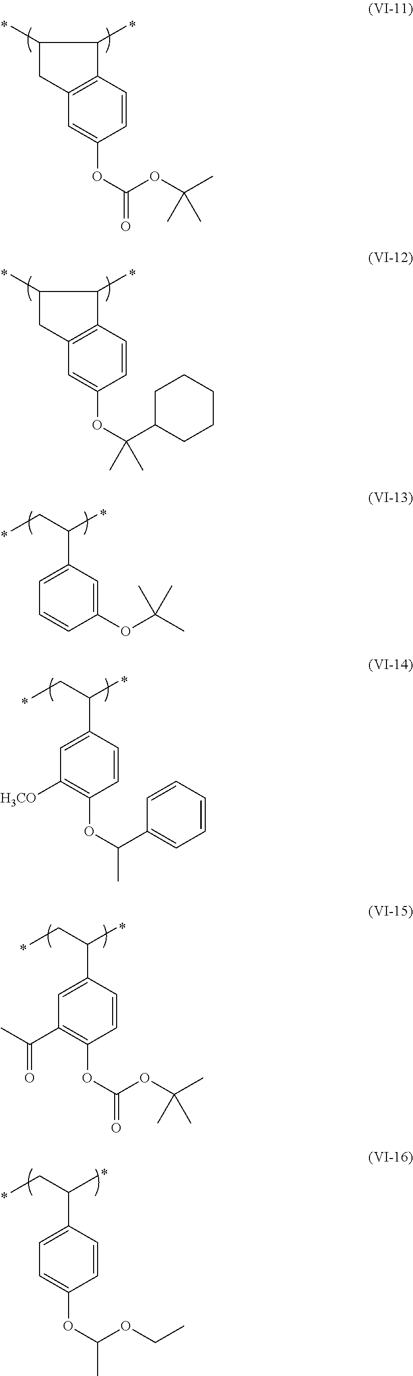

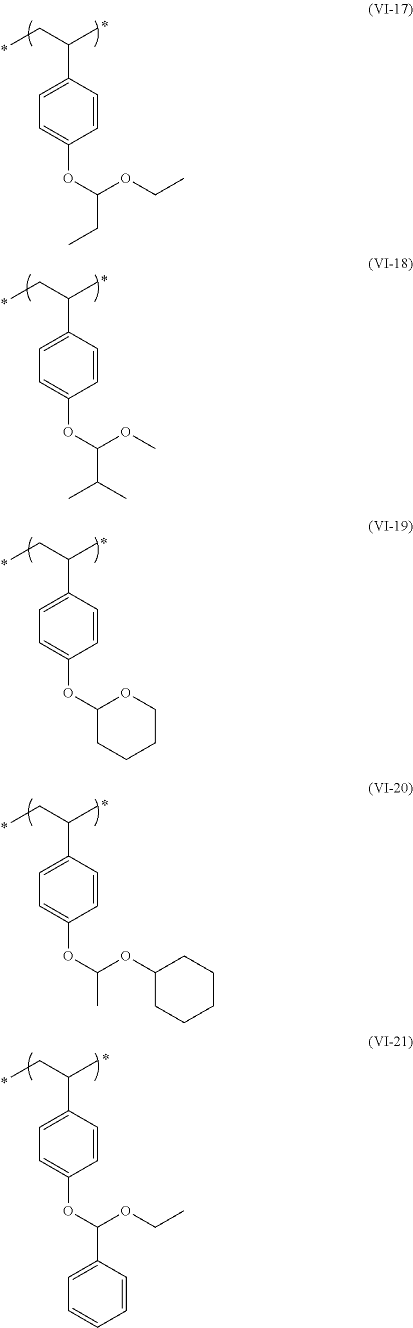

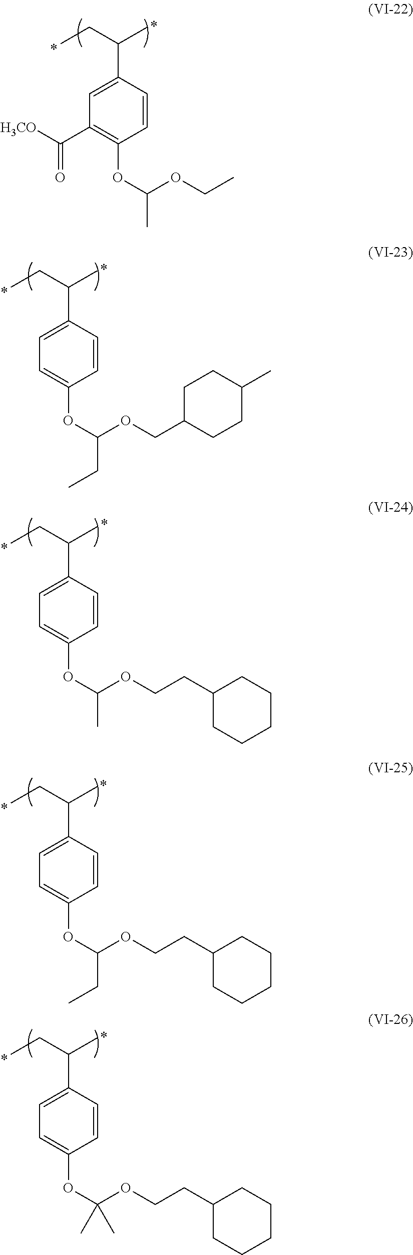

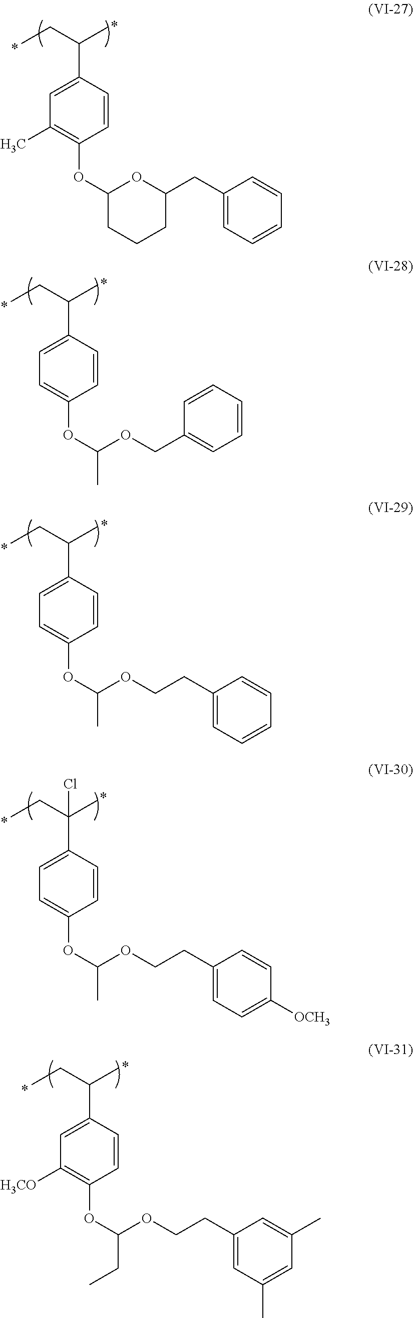

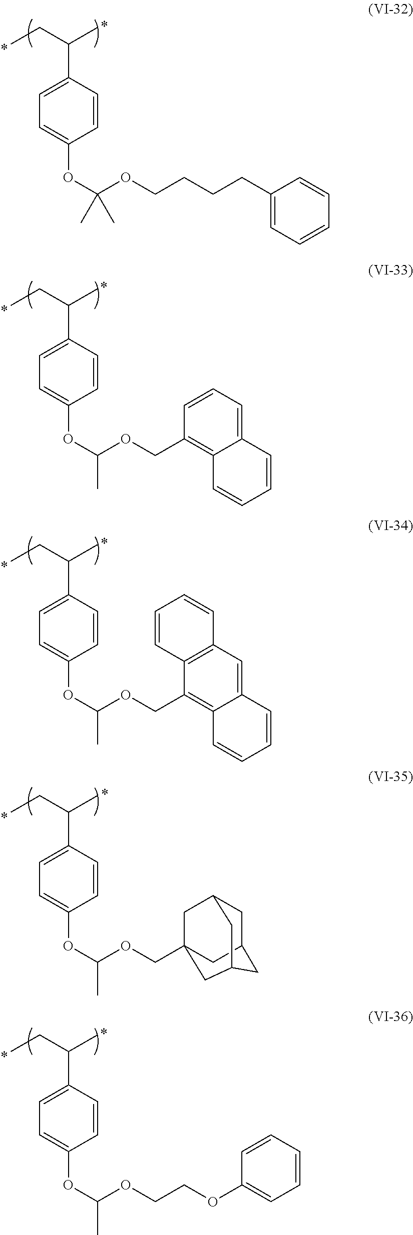

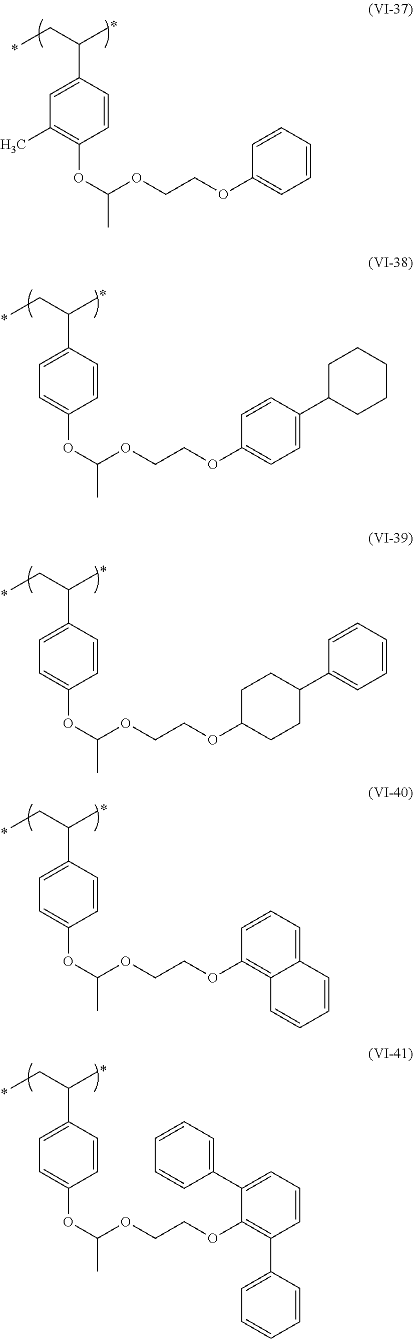

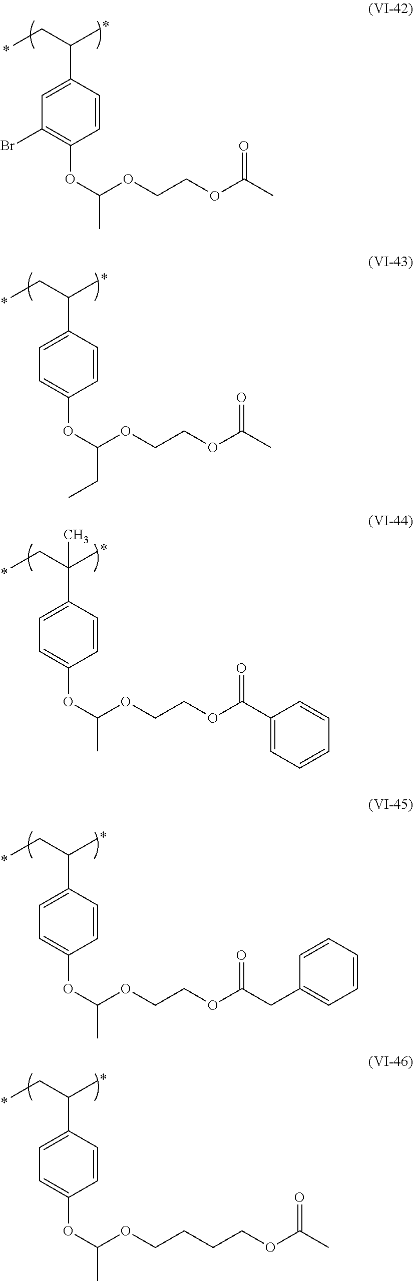

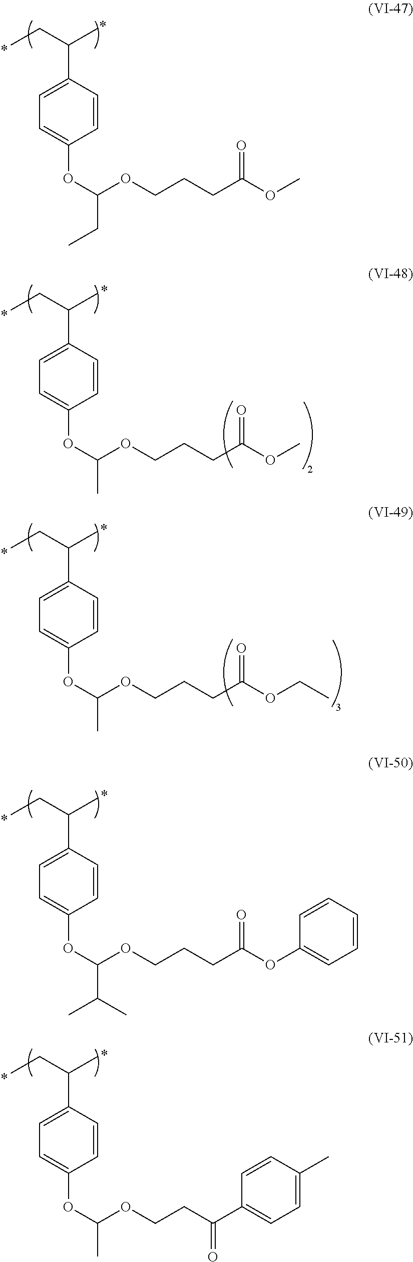

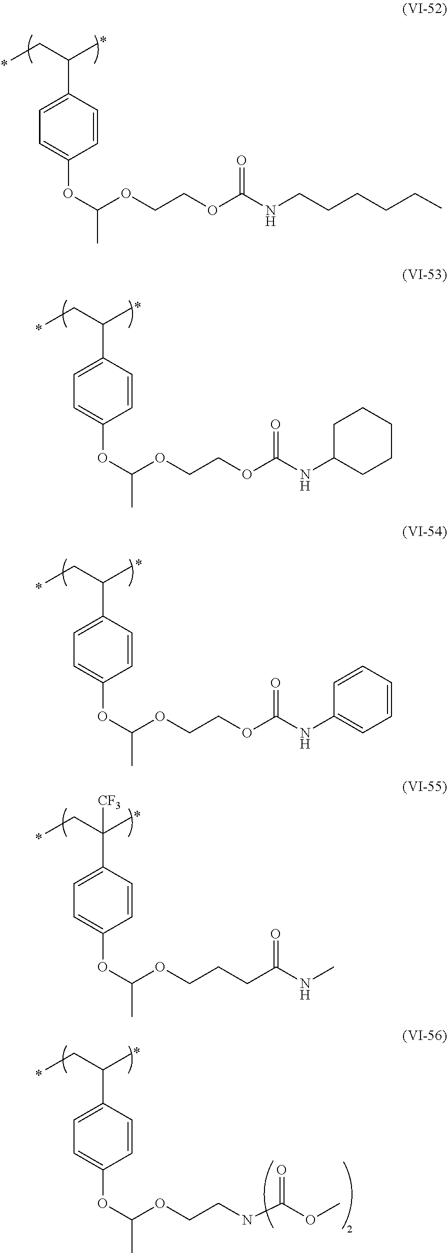

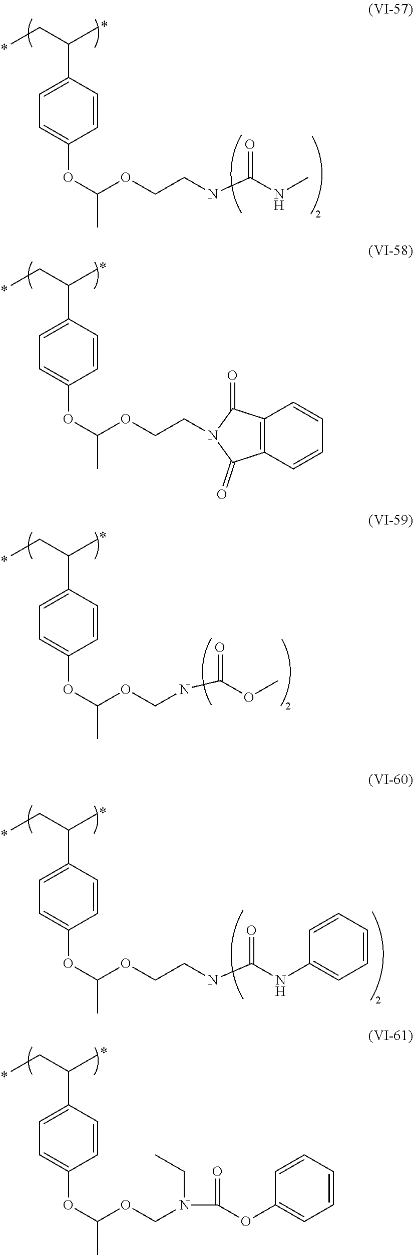

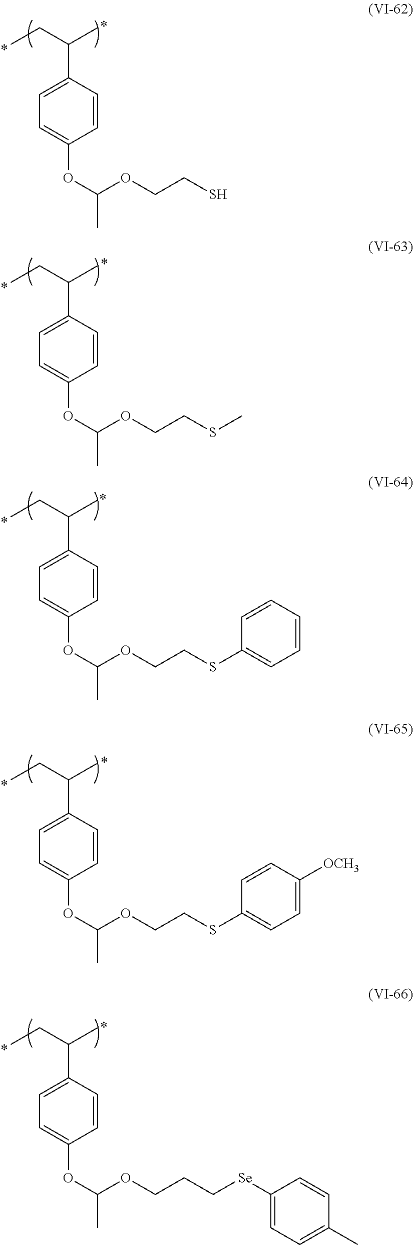

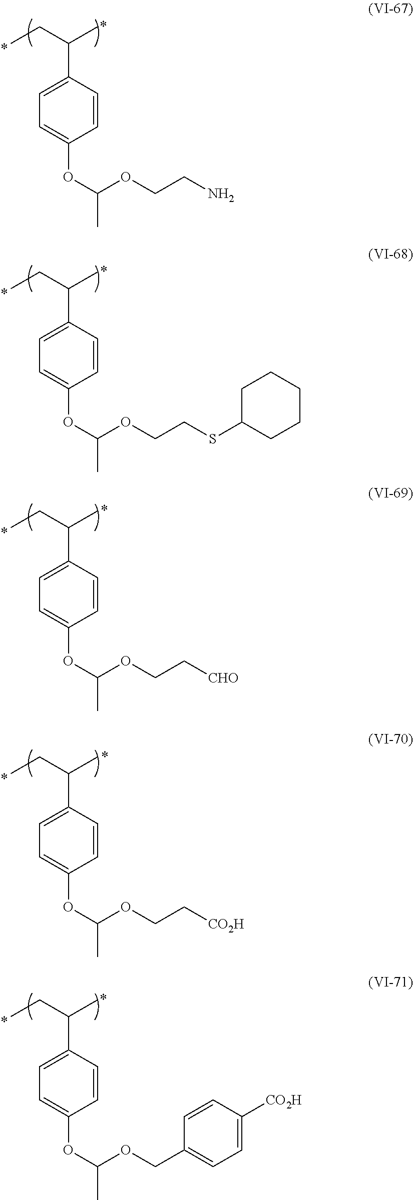

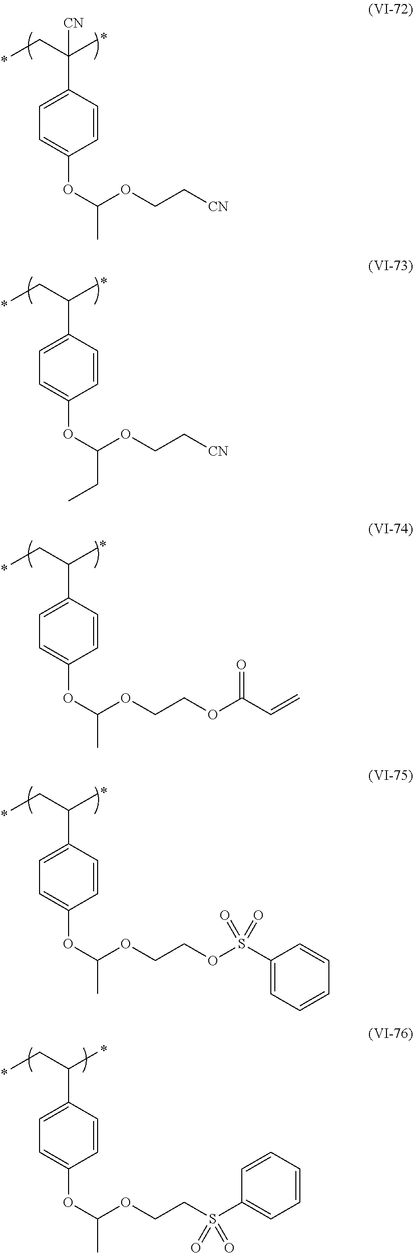

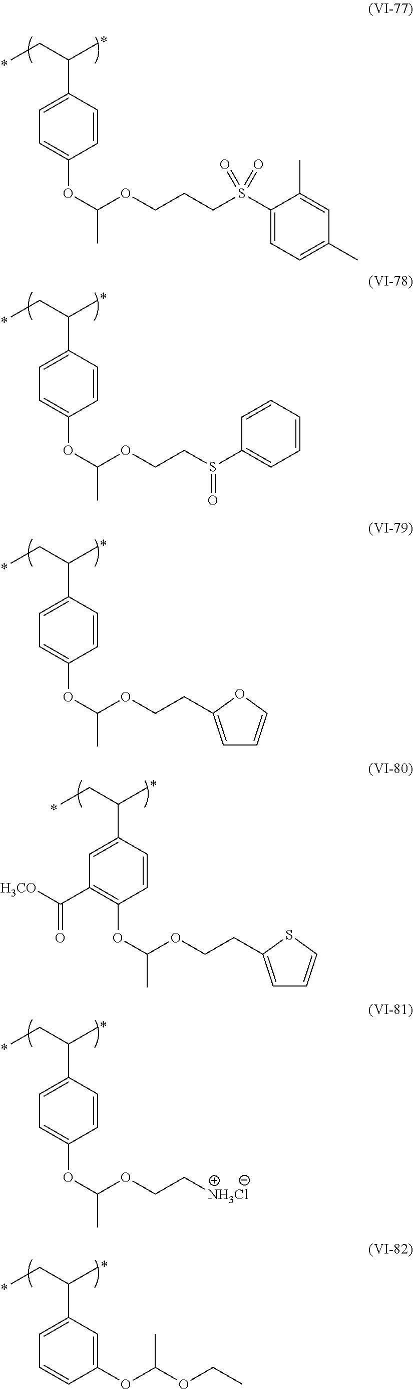

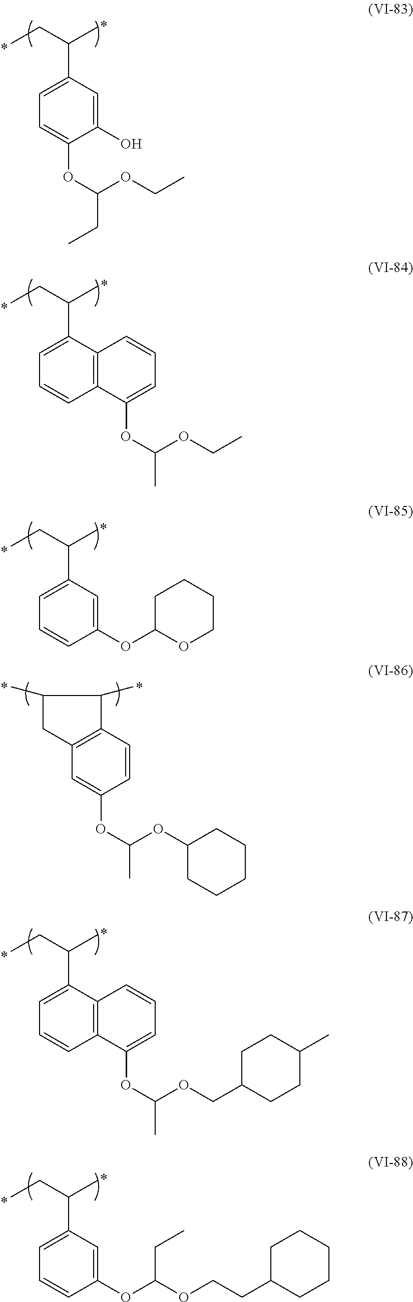

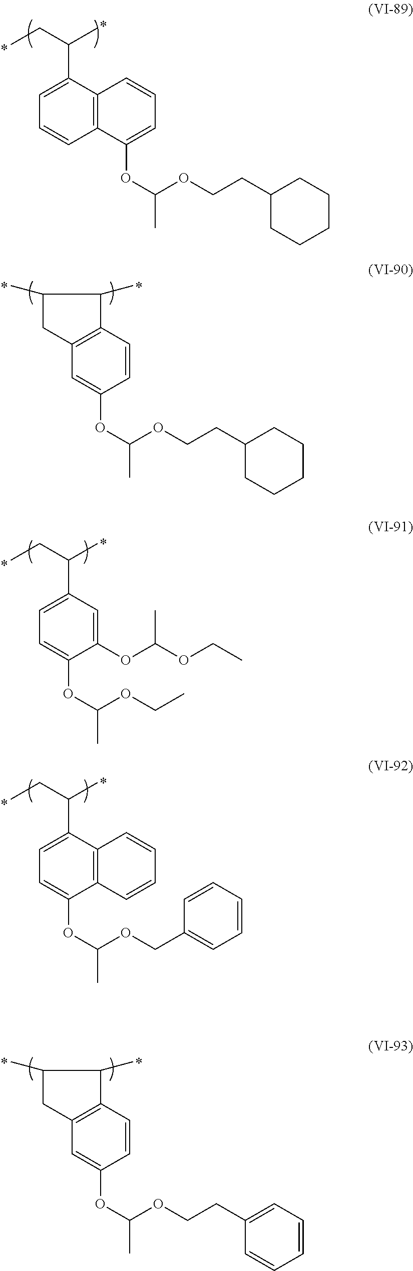

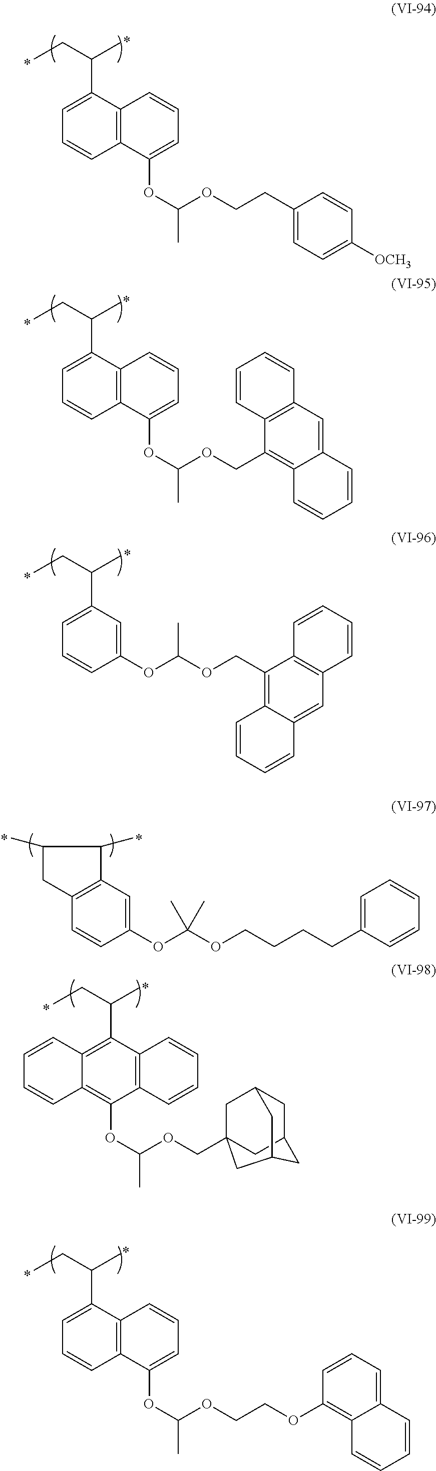

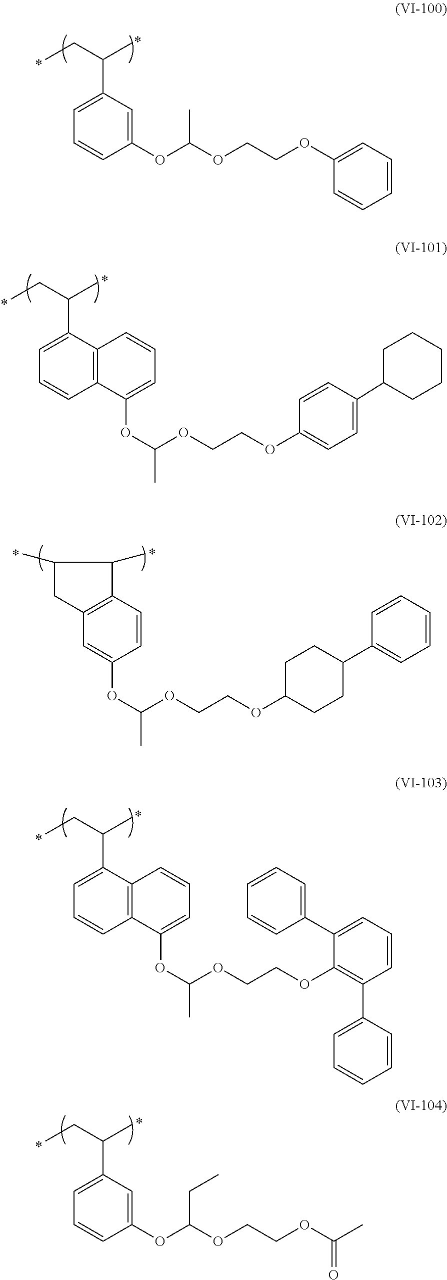

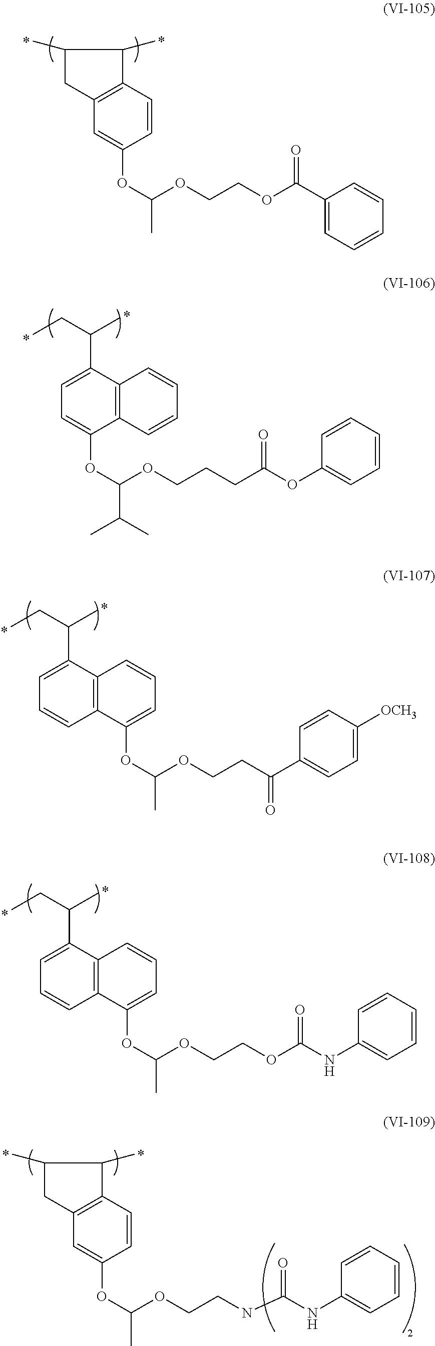

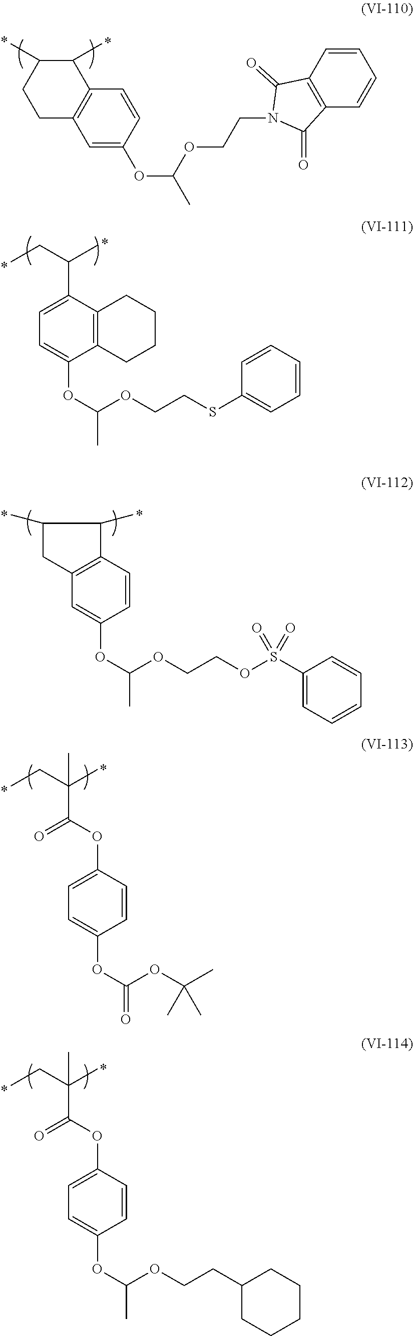

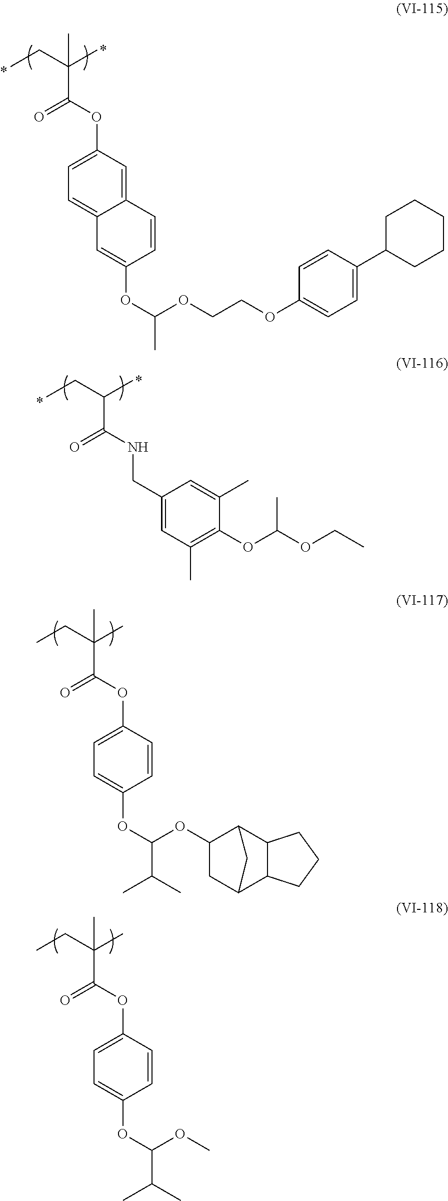

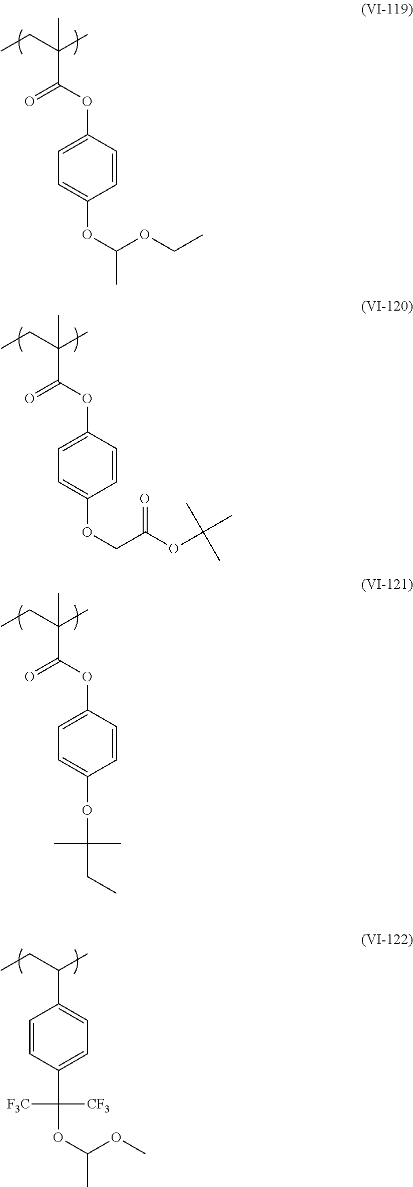

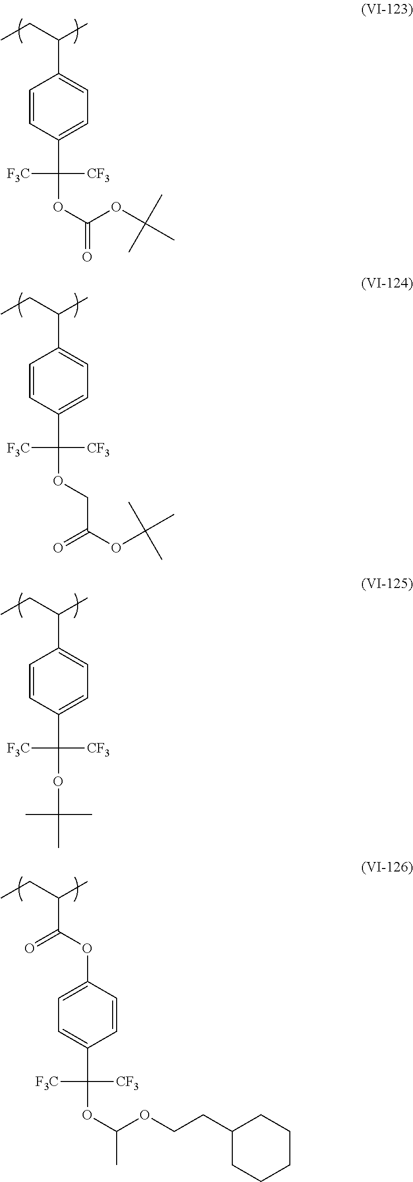

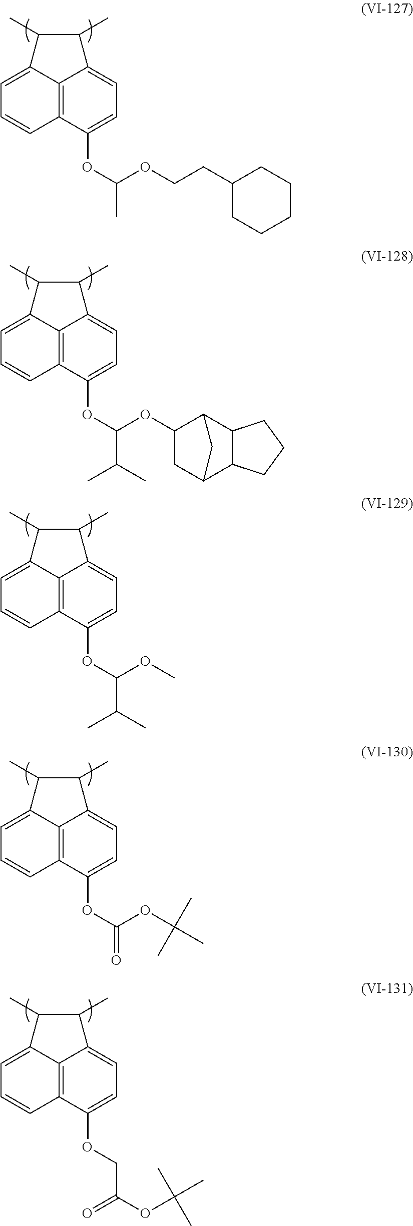

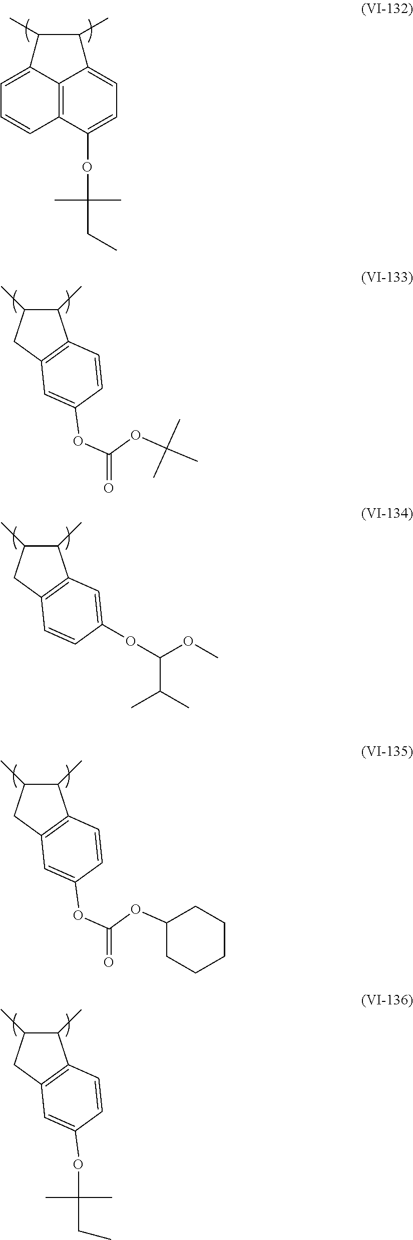

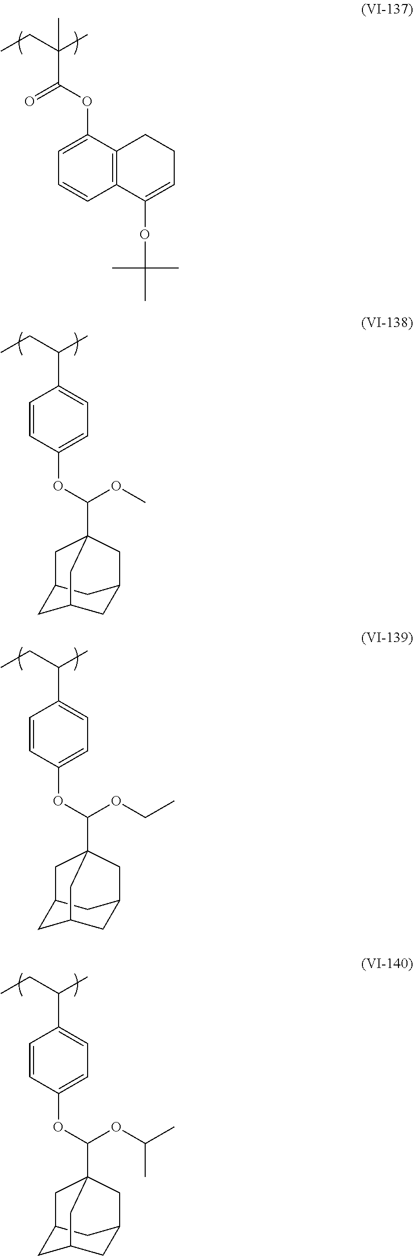

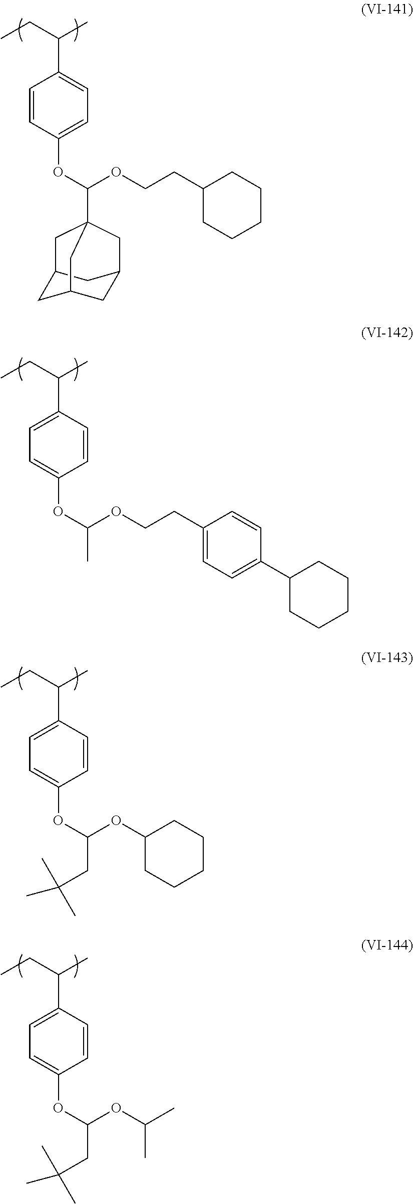

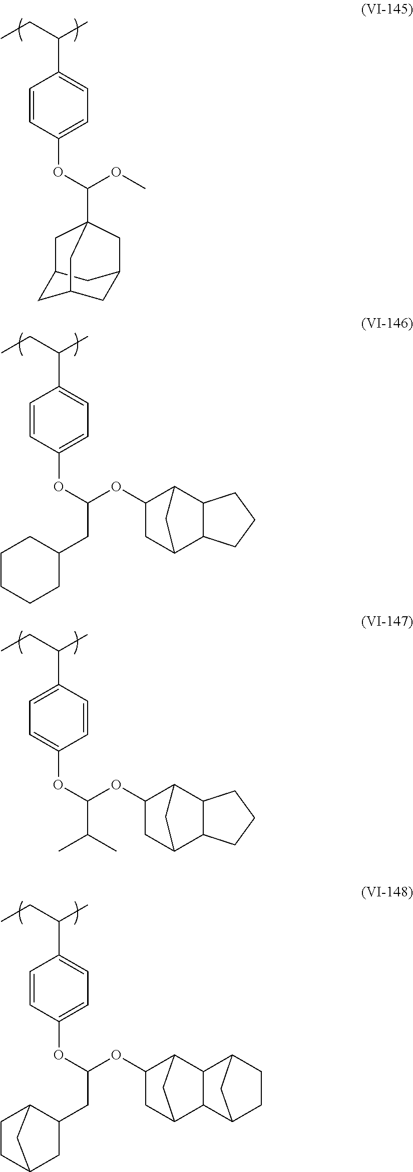

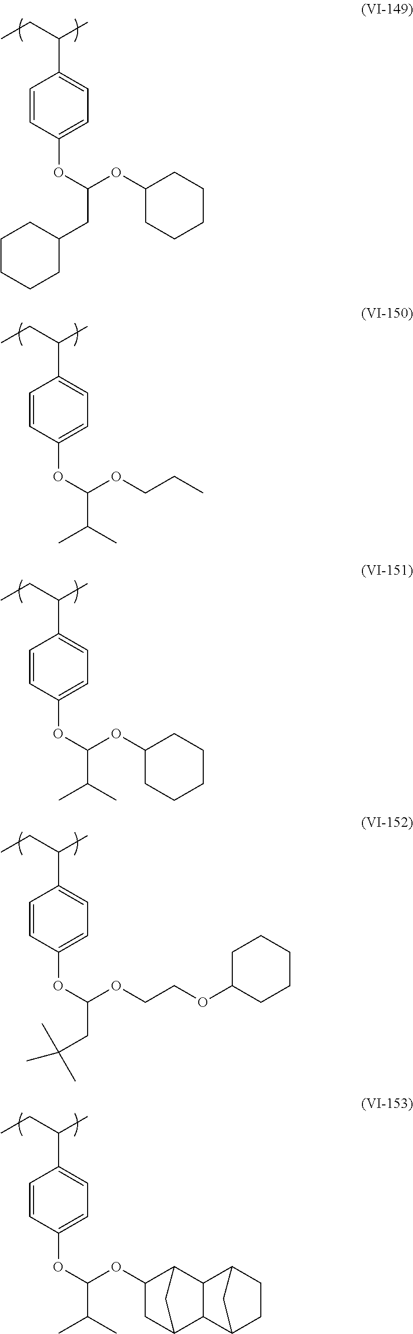

Also, as the repeating unit (a), a repeating unit represented by the following formula (BZ) can be exemplified.

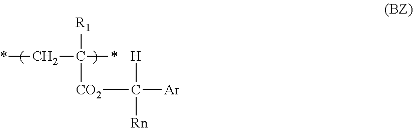

In formula (BZ), AR represents an aryl group, Rn represents an alkyl group, a cycloalkyl group or an aryl group, and Rn and AR may combine with each other to form a non-aromatic ring.

R₁ represents a hydrogen atom, an alkyl group, a cycloalkyl group, a halogen atom, a cyano group or an alkyloxycarbonyl group.

The aryl group of AR is preferably an aryl group having a carbon number 6 to 20, such as phenyl group, naphthyl group, anthryl group and fluorene group, more preferably an aryl group having a carbon number of 6 to 15.

When AR is a naphthyl group, an anthryl group or a fluorene group, the bonding position of AR to the carbon atom to which Rn is bonded is not particularly limited. For example, when AR is a naphthyl group, the carbon atom may be bonded to the α-position or β-position of the naphthyl group. When AR is an anthryl group, the carbon atom may be bonded to the 1-position, 2-position or 9-position of the anthryl group.

The aryl group as AR may have one or more substituents. Specific examples of the substituent include a linear or branched alkyl group having a carbon number of 1 to 20, such as methyl group, ethyl group, propyl group, isopropyl group, n-butyl group, isobutyl group, tert-butyl group, pentyl group, hexyl group, octyl group and dodecyl group, an alkoxy group containing such an alkyl group moiety, a cycloalkyl group such as cyclopentyl group and cyclohexyl group, a cycloalkoxy group containing such a cycloalkyl group moiety, a hydroxyl group, a halogen atom, an aryl group, a cyano group, a nitro group, an acyl group, an acyloxy group, an acylamino group, a sulfonylamino group, an alkylthio group, an arylthio group, an aralkylthio group, a thiophenecarbonyloxy group, a thiophenemethylcarbonyloxy group, and a heterocyclic residue such as pyrrolidone residue. The substituent is preferably a linear or branched alkyl group having a carbon number of 1 to 5 or an alkoxy group containing such an alkyl group moiety, more preferably a para-methyl group or a para-methoxy group.

In the case where the aryl group as AR has a plurality of substituents, at least two members of the plurality of substituents may combine with each other to form a ring. The ring is preferably a 5- to 8-membered ring, more preferably a 5- or 6-membered ring. The ring may be a heterocyclic ring containing a heteroatom such as oxygen atom, nitrogen atom and sulfur atom, in the ring members.

Furthermore, this ring may have a substituent. Examples of the substituent are the same as those described later for the further substituent which may be substituted on Rn.

In view of the roughness performance, the repeating unit (a) represented by formula (BZ) preferably contains two or more aromatic rings. Usually, the number of aromatic rings contained in the repeating unit is preferably 5 or less, more preferably 3 or less.

Also, in the repeating unit (a) represented by formula (BZ), in view of the roughness performance, AR preferably contains two or more aromatic rings, and it is more preferred that AR is a naphthyl group or a biphenyl group. Usually, the number of aromatic rings contained in AR is preferably 5 or less, more preferably 3 or less.

As described above, Rn represents an alkyl group, a cycloalkyl group or an aryl group.

The alkyl group of Rn may be a linear alkyl group or a branched alkyl group. The alkyl group is preferably an alky group having a carbon number of 1 to 20, such as methyl group, ethyl group, propyl group, isopropyl group, n-butyl group, isobutyl group, tert-butyl group, pentyl group, hexyl group, cyclohexyl group, octyl group and dodecyl group. The alkyl group of Rn is preferably an alkyl group having a carbon number of 1 to 5, more preferably an alkyl group having a carbon number of 1 to 3.

The cycloalkyl group of Rn includes, for example, a cycloalkyl group having a carbon number of 3 to 15, such as cyclopentyl group and cyclohexyl group.

The aryl group of Rn is preferably, for example, an aryl group having a carbon number of 6 to 14, such as phenyl group, xylyl group, toluoyl group, cumenyl group, naphthyl group and anthryl group.

Each of the alkyl group, cycloalkyl group and aryl group as Rn may further have a substituent. Examples of the substituent include an alkoxy group, a hydroxyl group, a halogen atom, a nitro group, an acyl group, an acyloxy group, an acylamino group, a sulfonylamino group, a dialkylamino group, an alkylthio group, an arylthio group, an aralkylthio group, a thiophenecarbonyloxy group, a thiophenemethylcarbonyloxy group, and a heterocyclic residue such as pyrrolidone residue. Among these, an alkoxy group, a hydroxyl group, a halogen atom, a nitro group, an acyl group, an acyloxy group, an acylamino group and a sulfonylamino group are preferred.

As described above, R₁ represents a hydrogen atom, an alkyl group, a cycloalkyl group, a halogen atom, a cyano group or an alkyloxycarbonyl group.

Examples of the alkyl group and cycloalkyl group of R₁ are the same as those described above for Rn. Each of these alkyl group and cycloalkyl group may have a substituent. Examples of this substituent are the same as those described above for Rn.

In the case where R₁ is an alkyl or cycloalkyl group having a substituent, particularly preferred examples of R₁ include a trifluoromethyl group, an alkyloxycarbonylmethyl group, an alkylcarbonyloxymethyl group, a hydroxymethyl group, and an alkoxymethyl group.

The halogen atom of R₁ includes fluorine atom, chlorine atom, bromine atom and iodine atom, with fluorine atom being preferred.

As the alkyl group moiety contained in the alkyloxycarbonyl group of R₁, for example, the configuration described above as the alkyl group of R₁ may be employed.

Rn and AR preferably combine with each other to form a non-aromatic ring and in this case, the roughness performance can be more improved, among others.

The non-aromatic ring which may be formed by combining Rn and AR with each other is preferably a 5- to 8-membered ring, more preferably a 5- or 6-membered ring.

The non-aromatic ring may be an aliphatic ring or a heterocyclic ring containing a heteroatom such as oxygen atom, nitrogen atom and sulfur atom, as a ring member.

The non-aromatic ring may have a substituent. Examples of the substituent are the same as those described above for the further substituent which Rn may have.

Specific examples of the repeating unit (a) represented by formula (BZ) are illustrated below, but the present invention is not limited thereto.

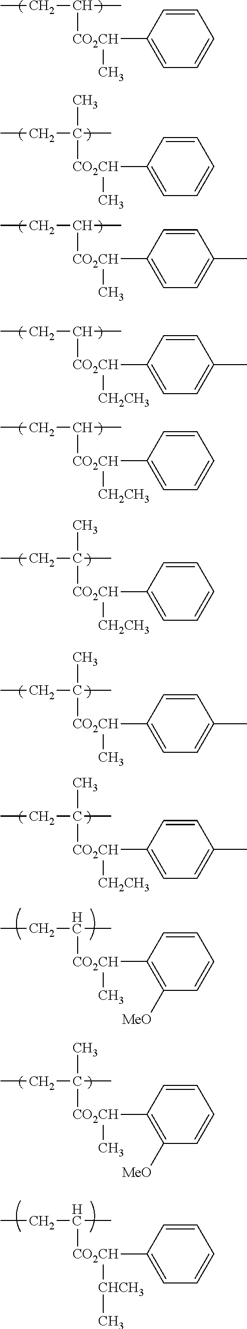

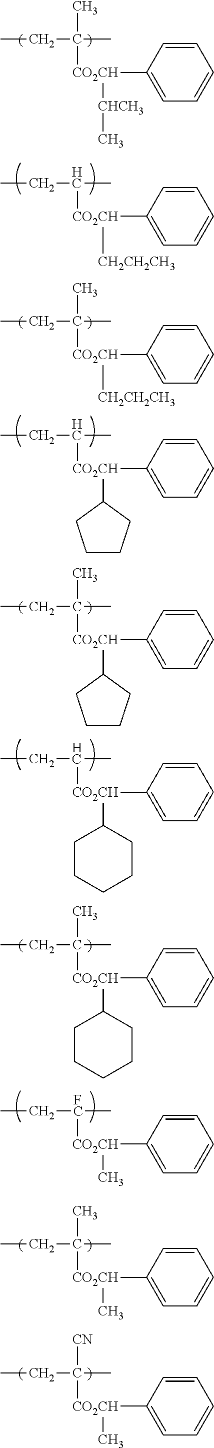

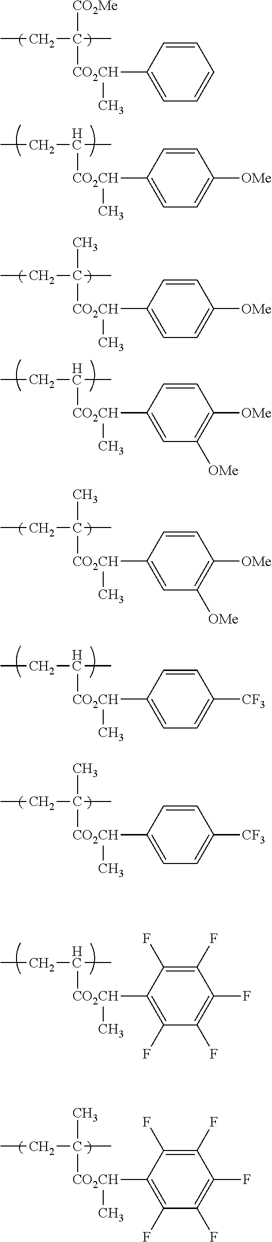

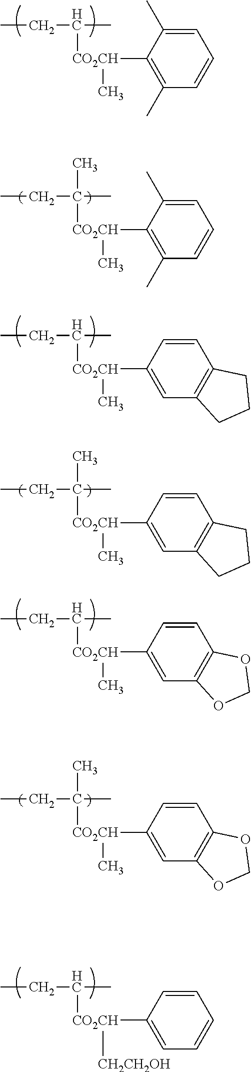

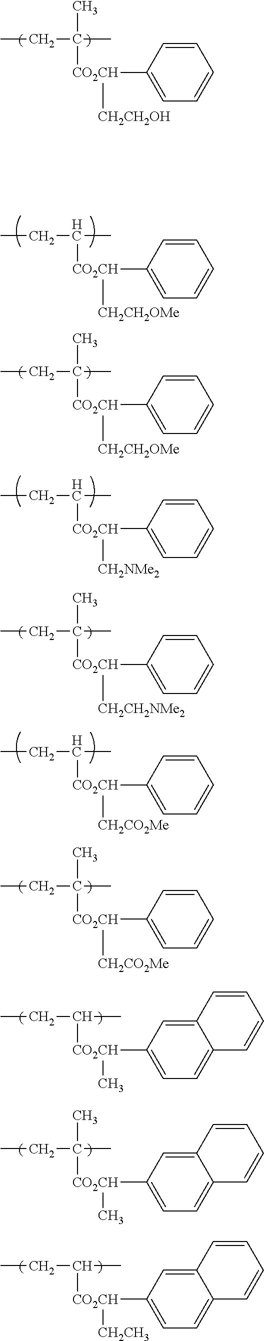

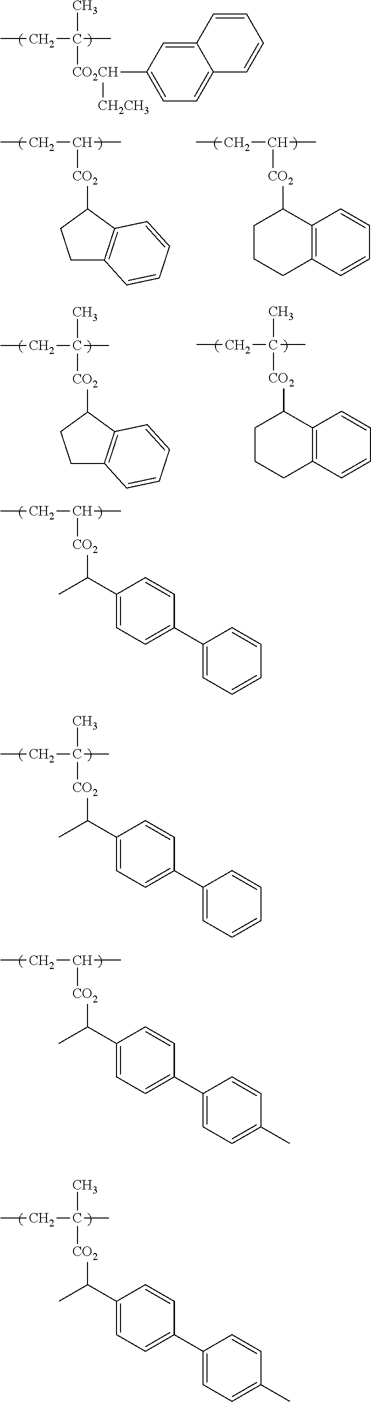

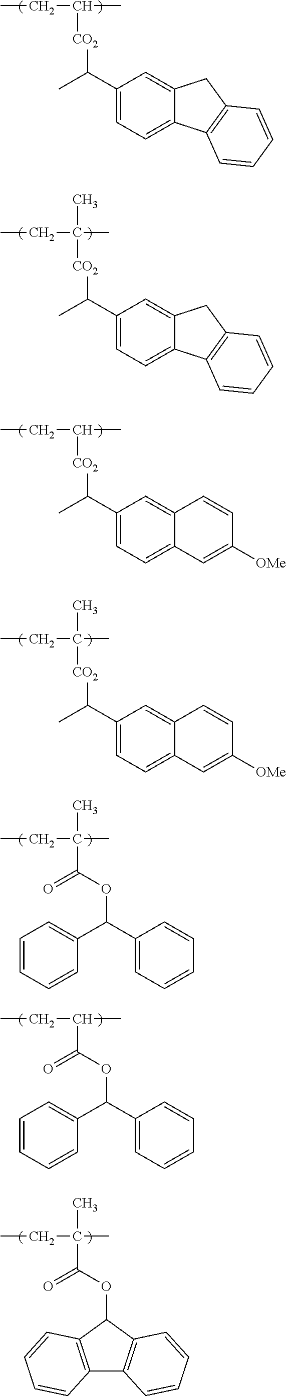

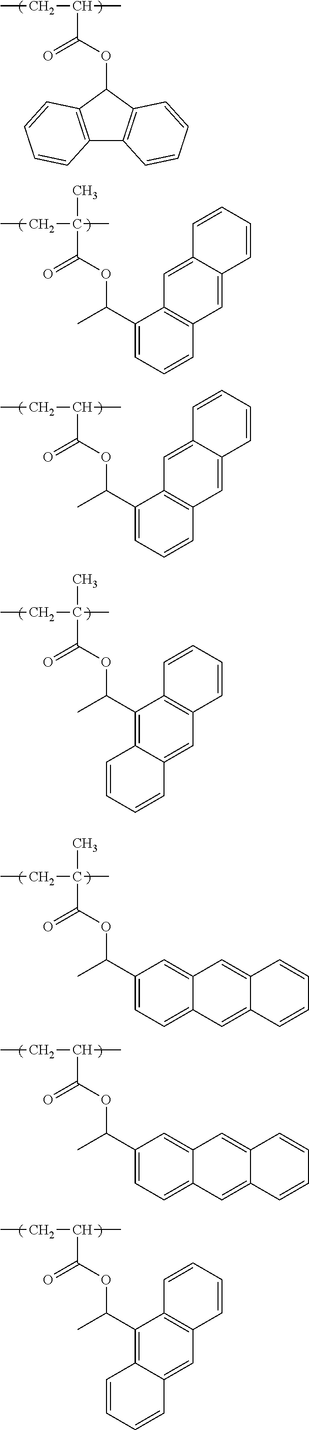

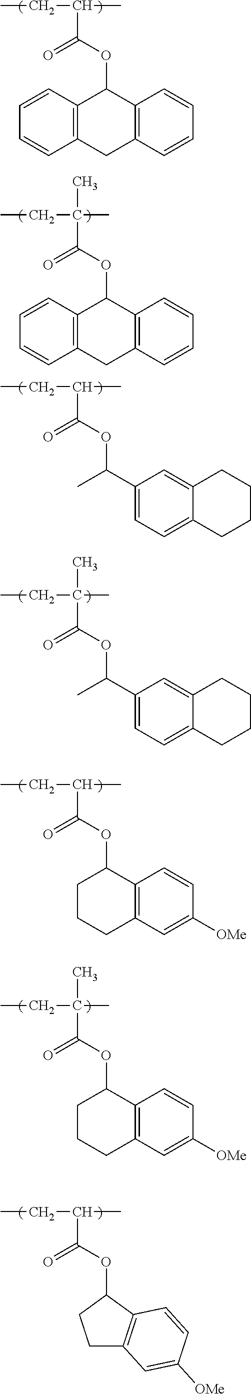

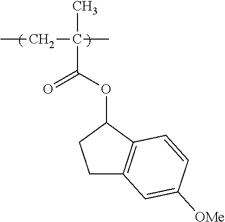

As for the repeating unit (a), one kind of a repeating unit may be used, or two or more kinds may be used in combination.

The content of the repeating unit having an acid-decomposable group (in the case of containing a plurality of kinds of repeating units, the total content thereof) in the resin (A) is preferably from 5 to 80 mol %, more preferably from 5 to 75 mol %, still more preferably from 10 to 65 mol %, based on all repeating units in the resin (A).

The resin (A) preferably contains (b) a non-acid-decomposable repeating unit having a phenolic hydroxyl group. The repeating unit (b) is preferably a repeating unit represented by the following formula (I):

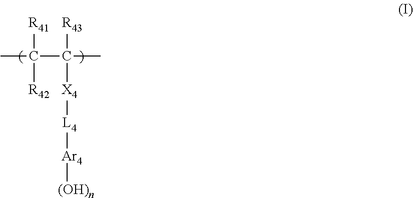

In the formula, each of R₄₁, R₄₂ and R₄₃ independently represents a hydrogen atom, an alkyl group, a halogen atom, a cyano group or an alkoxycarbonyl group. R₄₂ may combine with Ar₄ to form a ring, and in this case, R₄₂ represents a single bond or an alkylene group.

X₄ represents a single bond, —COO— or —CONR₆₄—, and R₆₄ represents a hydrogen atom or an alkyl group.

L₄ represents a single bond or an alkylene group.

Ar₄ represents an (n+11)-valent aromatic ring group, and in the case of combining with R₄₂ to form a ring, Ar₄ represents an (n+2)-valent aromatic ring group.

n represents an integer of 1 to 4.

Specific examples of the alkyl group, cycloalkyl group, halogen atom and alkoxycarbonyl group of R₄₁, R₄₂ and R₄₃ in formula (I) and the substituent which may be substituted on these groups are the same as specific examples described above for respective groups represented by R₅₁, R₅₂ and R₅₃ in formula (V).

Ar₄ represents an (n+1)-valent aromatic ring group. The divalent aromatic ring group when n is 1 may have a substituent, and preferred examples of the divalent aromatic ring group include an arylene group having a carbon number of 6 to 18, such as phenylene group, tolylene group, naphthylene group and anthracenylene group, and an aromatic ring group containing a heterocyclic ring such as thiophene, furan, pyrrole, benzothiophene, benzofuran, benzopyrrole, triazine, imidazole, benzimidazole, triazole, thiadiazole and thiazole.

Specific examples of the (n+1)-valent aromatic ring group when n is an integer of 2 or more include groups formed by removing arbitrary (n−1) hydrogen atoms from the above-described specific examples of the divalent aromatic ring group.

The (n+1)-valent aromatic ring group may further have a substituent.

Examples of the substituent which the above-described alkyl group, cycloalkyl group, alkoxycarbonyl group, alkylene group and (n+1)-valent aromatic ring group may have include the alkyl group described for R₅₁ to R₅₃ in formula (V), an alkoxy group such as methoxy group, ethoxy group, hydroxyethoxy group, propoxy group, hydroxypropoxy group and butoxy group, and an aryl group such as phenyl group.

Examples of the alkyl group of R₆₄ in —CONR₆₄— (R₆₄ represents a hydrogen atom or an alkyl group) represented by X₄ are the same as those of the alkyl group of R₆₁ to R₆₃.

X₄ is preferably a single bond, —COO— or —CONH—, more preferably a single bond or —COO—.

The alkylene group in L₄ is preferably an alkylene group having a carbon number of 1 to 8, such as methylene group, ethylene group, propylene group, butylene group, hexylene group and octylene group, which may have a substituent.

Ar₄ is preferably an aromatic ring group having a carbon number of 6 to 18, which may have a substituent, more preferably a benzene ring group, a naphthalene ring group or a biphenylene ring group.

The repeating unit (b) preferably has a hydroxystyrene structure, that is, Ar₄ is preferably a benzene ring group.

Specific examples of the repeating unit (b) represented by formula (I) are illustrated below, but the present invention is not limited thereto. In the formulae, a represents an integer of 1 or 2.

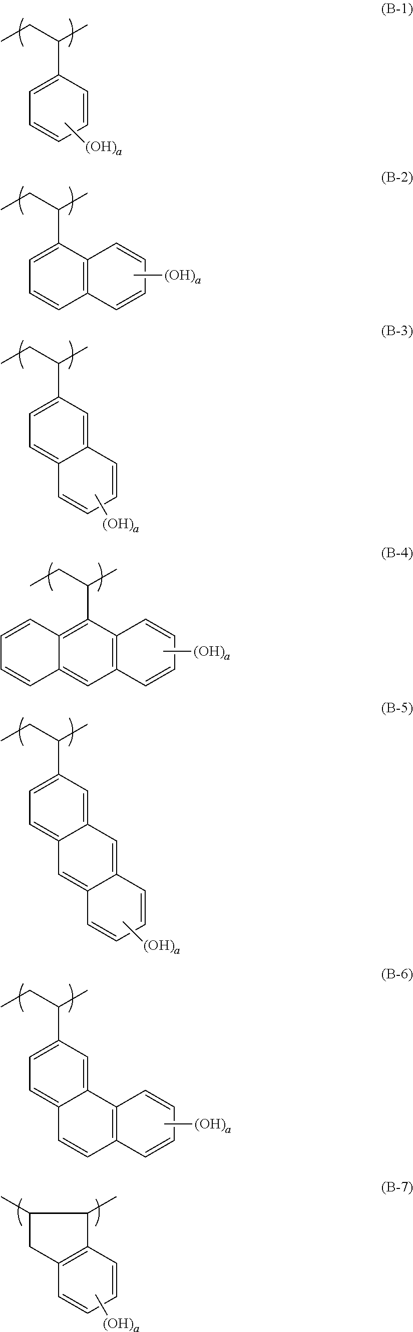

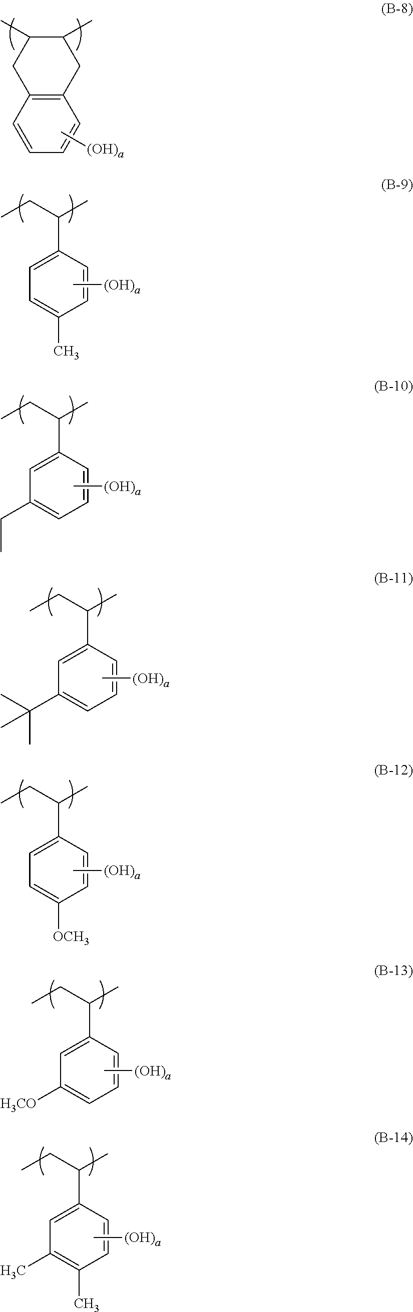

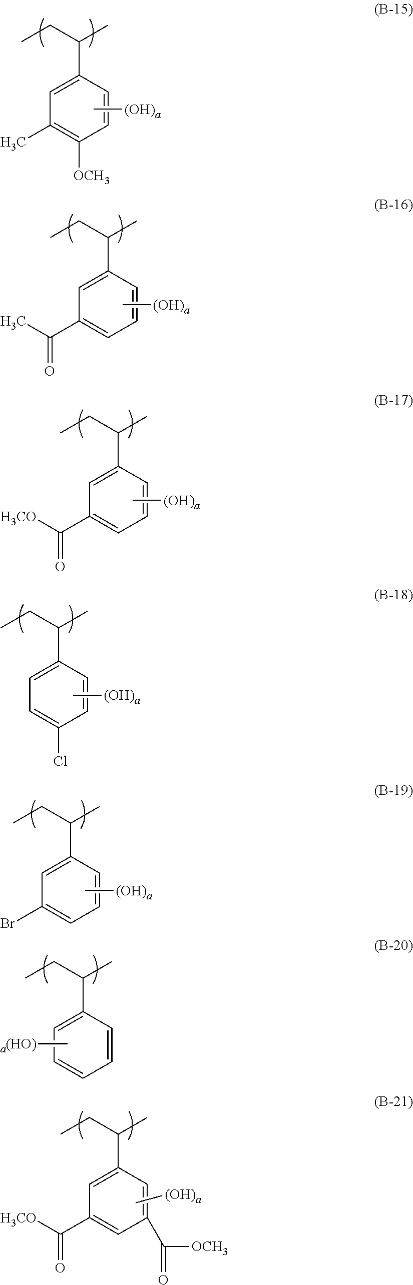

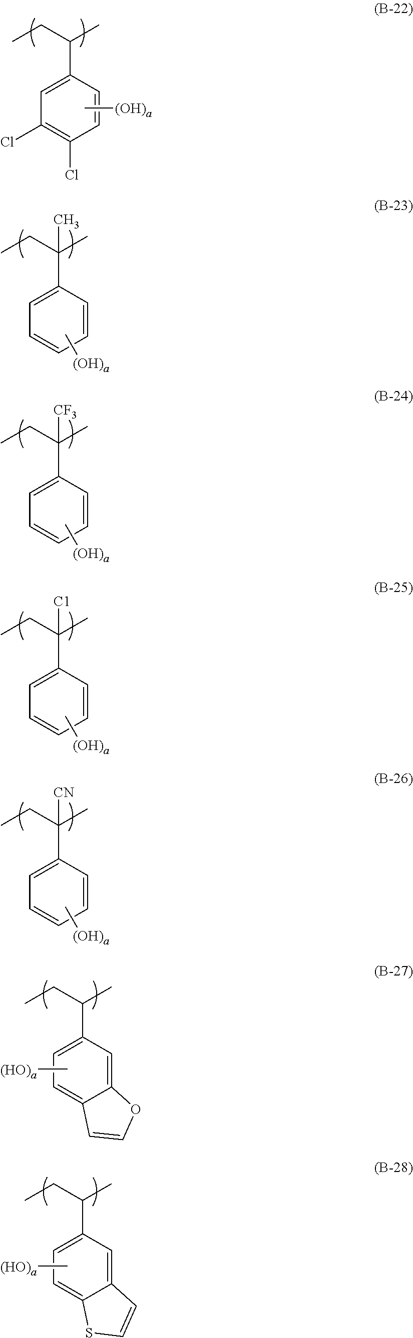

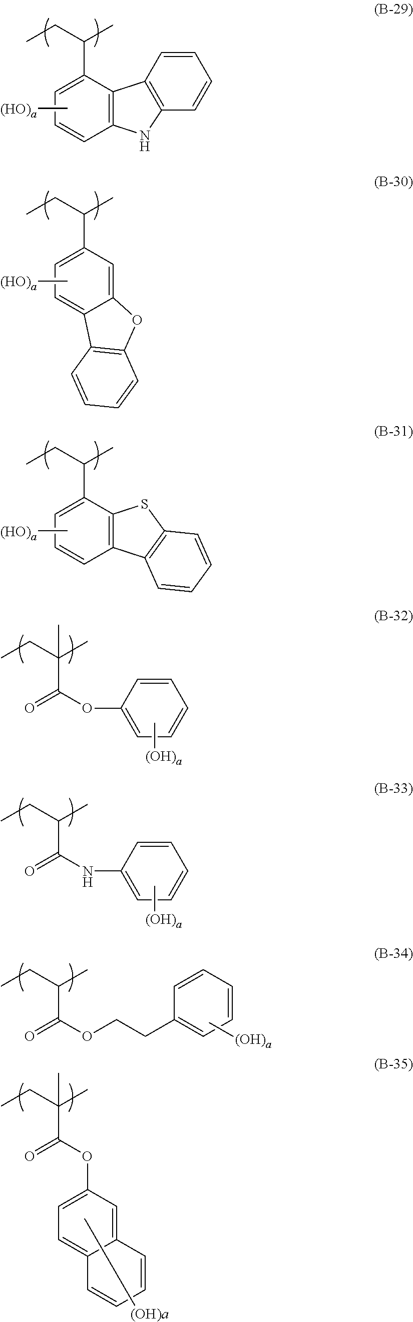

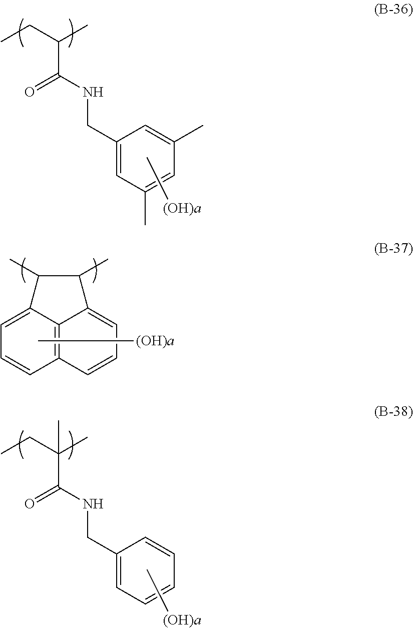

The resin (A) may contain two or more kinds of repeating units represented by formula (I).

The content of the (b) non-acid-decomposable repeating unit having a phenolic hydroxyl group (in the case of containing a plurality of kinds of repeating units, the total thereof) in the resin (A) is preferably from 20 to 90 mol %, more preferably from 25 to 85 mol %, still more preferably from 30 to 80 mol %, based on all repeating units in the resin (A).

The resin (A) may further contain a repeating unit represented by the following formula (4):

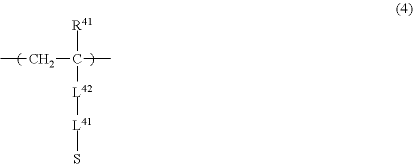

R⁴¹ represents a hydrogen atom or a methyl group. L⁴¹ represents a single bond or a divalent linking group. L⁴² represents a divalent linking group. S represents a structural moiety capable of decomposing upon irradiation with an actinic ray or radiation to generate an acid on the side chain.

R⁴¹ is a hydrogen atom or a methyl group as described above and is preferably a hydrogen atom.

Examples of the divalent linking group of L⁴¹ and L⁴² include an alkylene group, a cycloalkylene group, an arylene group, —O—, —SO₂—, —CO—, —N(R)—, —S—, —CS—, and a combination of two or more thereof, and a linking group having a total carbon number of 20 or less is preferred. Here, R represents an aryl group, an alkyl group or a cycloalkyl group.

The divalent linking group of L⁴² is preferably an arylene group, and specific examples and preferred ranges thereof are the same as specific examples and preferred ranges of the arylene group when in formula (2), Ar is an arylene group.

In the case where the resin (A) contains a repeating unit represented by formula (4), for example, at least one of resolution, roughness characteristics and EL (exposure latitude) is more improved.

The alkylene group of L⁴¹ and L⁴² is preferably an alkylene group having a carbon number of 1 to 12, such as methylene group, ethylene group, propylene group, butylene group, hexylene group, octylene group and dodecanylene group.

The cycloalkylene group of L⁴¹ and L⁴² is preferably a cycloalkylene group having a carbon number of 5 to 8, such as cyclopentylene group and cyclohexylene group.

The arylene group of L⁴¹ and L⁴² is preferably an arylene group having a carbon number of 6 to 14, such as phenylene group and naphthylene group.

These alkylene group, cycloalkylene group and arylene group may further have a substituent. Examples of the substituent include an alkyl group, a cycloalkyl group, an aryl group, an amino group, an amido group, a ureido group, a urethane group, a hydroxy group, a carboxy group, a halogen atom, an alkoxy group, a thioether group, an acyl group, an acyloxy group, an alkoxycarbonyl group, a cyano group, and a nitro group, with a halogen atom (particularly, a fluorine atom) being preferred.

S represents a structural moiety capable of decomposing upon irradiation with an actinic ray or radiation to generate an acid on the side chain. S is preferably a structural moiety capable of decomposing upon irradiation with an actinic ray or radiation to generate an acid anion on the side chain of the resin, and the structural moiety is preferably a structural moiety contained in a photoinitiator for cationic photopolymerization, a photoinitiator for radical photopolymerization, a photodecoloring agent for dyes, a photodiscoloring agent, or a known compound capable of generating an acid by light, which is used in a microresist and the like, and more preferably an ionic structural moiety.

S is more preferably an ionic structural moiety containing a sulfonium salt or an iodonium salt. More specifically, S is preferably a group represented by the following formula (PZI) or (PZII):

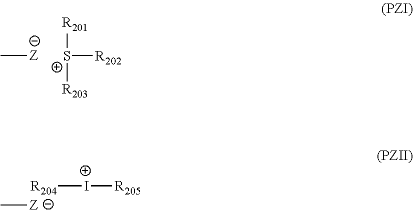

In formula (PZI), each of R₂₀₁ to R₂₀₃ independently represents an organic group.

The carbon number of the organic group as R₂₀₁ to R₂₀₃ is generally from 1 to 30, preferably from 1 to 20.

Two members out of R₂₀₁ to R₂₀₃ may combine to form a ring structure, and the ring may contain an oxygen atom, a sulfur atom, an ester bond, an amide bond or a carbonyl group. Examples of the group formed by combining two members out of R₂₀₁ to R₂₀₃ include an alkylene group (e.g., butylene, pentylene). When a repeating unit where two members out of R₂₀₁ to R₂₀₃ are combined to form a ring structure is used, it can be advantageously expected that the exposure machine can be kept from contamination by a decomposition product during exposure.

Z⁻ represents an acid anion generated resulting from decomposition upon irradiation with an actinic ray or radiation and is preferably a non-nucleophilic anion. Examples of the non-nucleophilic anion include sulfonate anion, carboxylate anion, sulfonylimide anion, bis(alkylsulfonyl)imide anion, and tris(alkylsulfonyl)methyl anion.

The non-nucleophilic anion is an anion having an extremely low ability of causing a nucleophilic reaction, and this anion can suppress the decomposition over time due to an intramolecular nucleophilic reaction. Thanks to this anion, the aging stability of the resin and in turn, the aging stability of the composition are enhanced.

Examples of the organic group of R₂₀₁ to R₂₀₃ include an aryl group, an alkyl group, a cycloalkyl group, a cycloalkenyl group, and an indolyl group. Here, in the cycloalkyl group and the cycloalkenyl group, at least one of carbon atoms forming the ring may be a carbonyl carbon.

At least one of R₂₀₁ to R₂₀₃ is preferably an aryl group, and it is more preferred that those three members all are an aryl group.

The aryl group in R₂₀₁, R₂₀₂ and R₂₀₃ is preferably a phenyl group or a naphthyl group, more preferably a phenyl group.

The alkyl group, cycloalkyl group and cycloalkenyl group of R₂₀₁, R₂₀₂ and R₂₀₃ are preferably a linear or branched alkyl group having a carbon number of 1 to 10 (e.g., methyl group, ethyl group, propyl group, butyl group, pentyl group), a cycloalkyl group having a carbon number of 3 to 10 (e.g., cyclopentyl group, cyclohexyl group, norbornyl group), and a cycloalkenyl group having a carbon number of 3 to 10 (e.g., pentadienyl group, cyclohexenyl group).

The organic group as R₂₀₁, R₂₀₂ and R₂₀₃, such as aryl group, alkyl group, cycloalkyl group, cycloalkenyl group and indolyl group, may further have a substituent. Examples of the substituent include, but are not limited to, a nitro group, a halogen atom such as fluorine atom, a carboxyl group, a hydroxyl group, an amino group, a cyano group, an alkyl group (preferably having a carbon number of 1 to 15), an alkoxy group (preferably having a carbon number of 1 to 15), a cycloalkyl group (preferably having a carbon number of 3 to 15), an aryl group (preferably having a carbon number of 6 to 14), an alkoxycarbonyl group (preferably having a carbon number of 2 to 7), an acyl group (preferably having a carbon number of 2 to 12), an alkoxycarbonyloxy group (preferably having a carbon number of 2 to 7), an arylthio group (preferably having a carbon number of 6 to 14), a hydroxyalkyl group (preferably having a carbon number of 1 to 15), an alkylcarbonyl group (preferably having a carbon number of 2 to 15), a cycloalkylcarbonyl group (preferably having a carbon number of 4 to 15), an arylcarbonyl group (preferably having a carbon number of 7 to 14), a cycloalkenyloxy group (preferably having a carbon number of 3 to 15), and a cycloalkenylalkyl group (preferably having a carbon number of 4 to 20).

In the cycloalkyl group and cycloalkenyl group as the substituent which may be substituted on each of the groups of R₂₀₁, R₂₀₂ and R₂₀₃, at least one of carbon atoms forming the ring may be a carbonyl carbon.

The substituent which each of the groups of R₂₀₁, R₂₀₂ and R₂₀₃ may have may further have a substituent, and examples of this further substituent are the same as examples of the substituent which each of the groups of R₂₀₁, R₂₀₂ and R₂₀₃ may have, but an alkyl group and a cycloalkyl group are preferred.

The preferred structure when at least one of R₂₀₁ to R₂₀₃ is not an aryl group includes cation structures such as compounds illustrated in paragraphs 0046 and 0047 of JP-A-2004-233661 and paragraphs 0040 to 0046 of JP-A-2003-35948, Compounds (I-1) to (I-70) illustrated in U.S. Patent Application Publication No. 2003/0224288, and Compounds (IA-1) to (IA-54) and (IB-1) to (IB-24) illustrated in U.S. Patent Application Publication No. 2003/0077540.

In formula (PZII), each of R₂₀₄ and R₂₀₅ independently represents an aryl group, an alkyl group or a cycloalkyl group. These aryl, alkyl and cycloalkyl groups are the same as the aryl, alkyl and cycloalkyl groups of R₂₀₁ to R₂₀₃ in the compound (PZI).

The aryl group of R₂₀₄ and R₂₀₅ may be an aryl group having a heterocyclic structure containing an oxygen atom, a nitrogen atom, a sulfur atom or the like. Examples of the aryl group having a heterocyclic structure include a pyrrole residue (a group formed by removing one hydrogen atom from a pyrrole), a furan residue (a group formed by removing one hydrogen atom from a furan), a thiophene residue (a group formed by removing one hydrogen atom from a thiophene), an indole residue (a group formed by removing one hydrogen atom from an indole), a benzofuran residue (a group formed by removing one hydrogen atom from a benzofuran), and a benzothiophene residue (a group formed by removing one hydrogen atom from a benzothiophene).

The aryl group, alkyl group and cycloalkyl group of R₂₀₄ and R₂₀₅ may have a substituent. Examples of the substituent include those of the substituent which may be substituted on the aryl group, alkyl group and cycloalkyl group of R₂₀₁ to R₂₀₃ in the compound (PZI).

Z⁻ represents an acid anion generated resulting from decomposition upon irradiation with an actinic ray or radiation and is preferably a non-nucleophilic anion, and examples thereof are the same as those for Z⁻ in formula (PZI).

Specific preferred examples of S are illustrated below, but the present invention is not limited thereto. Incidentally, the mark * indicates a bond to L⁴¹.

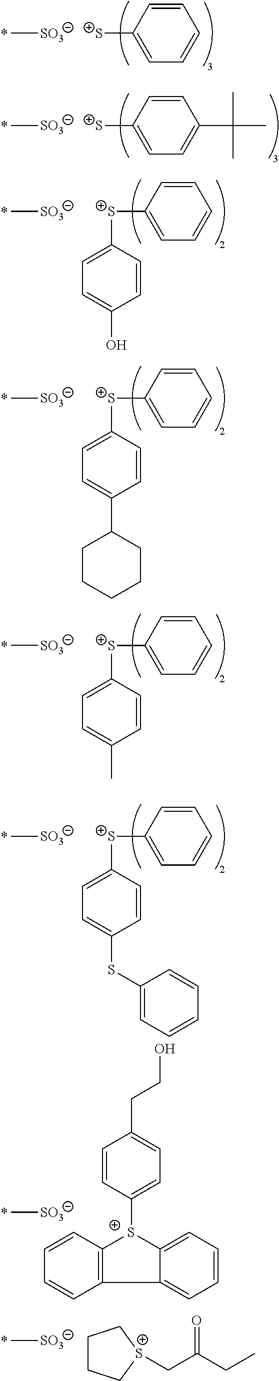

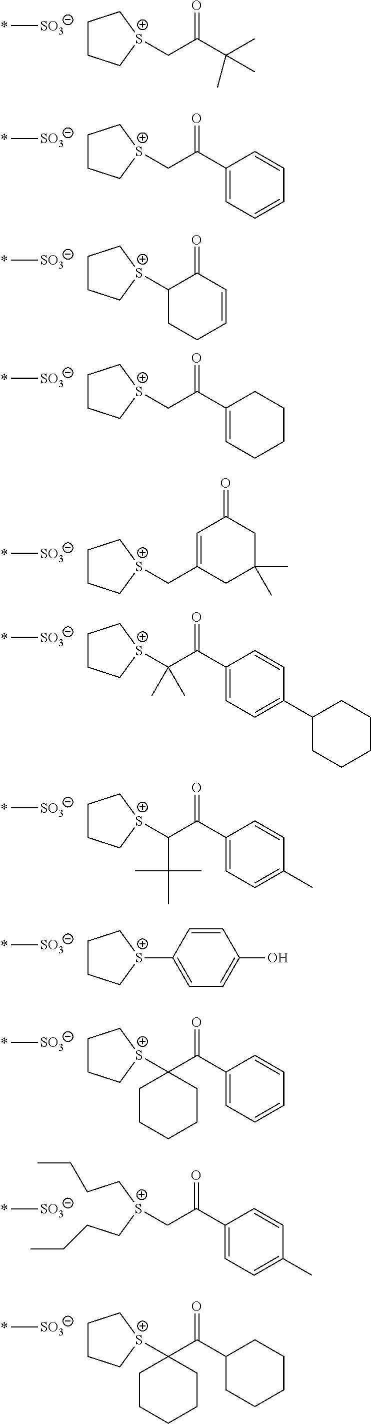

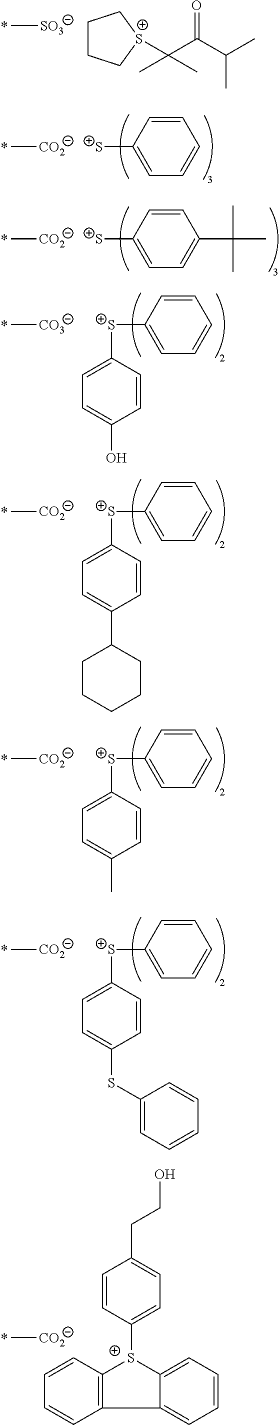

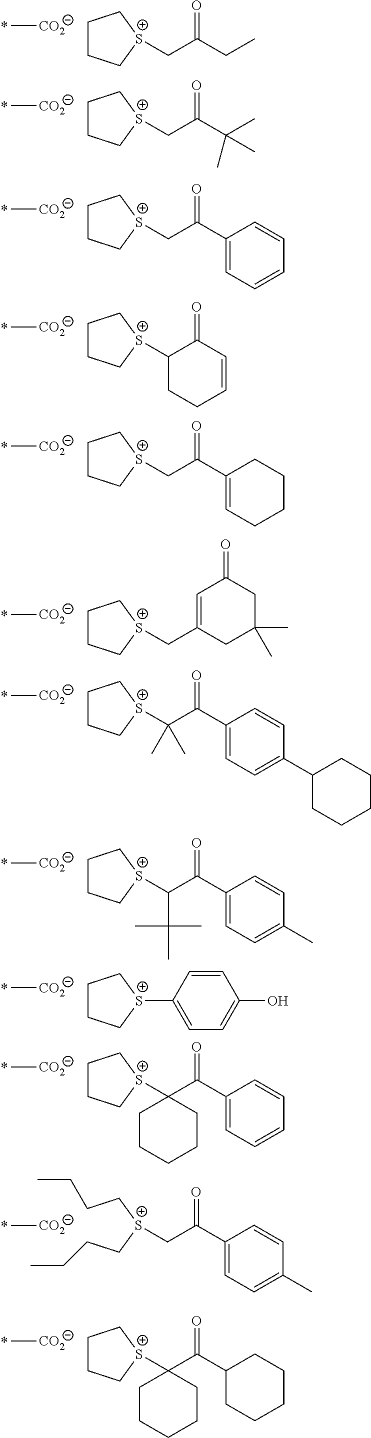

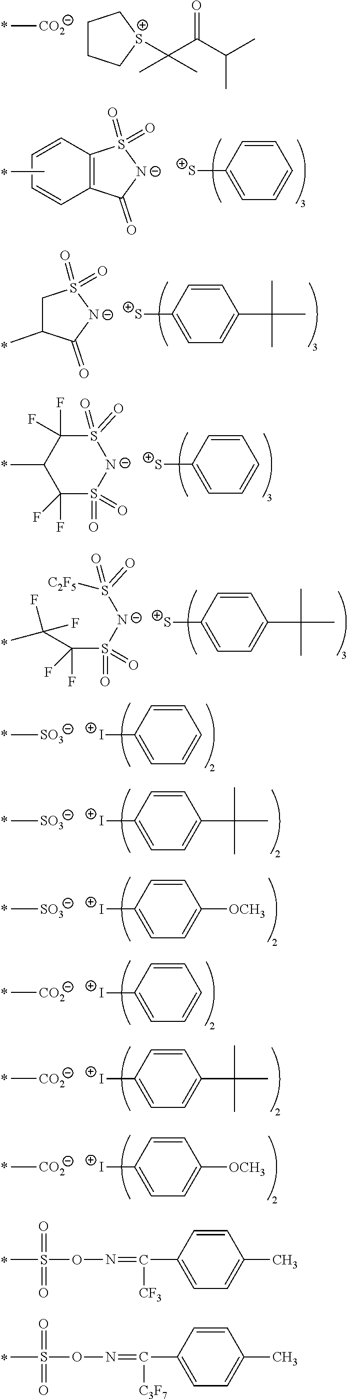

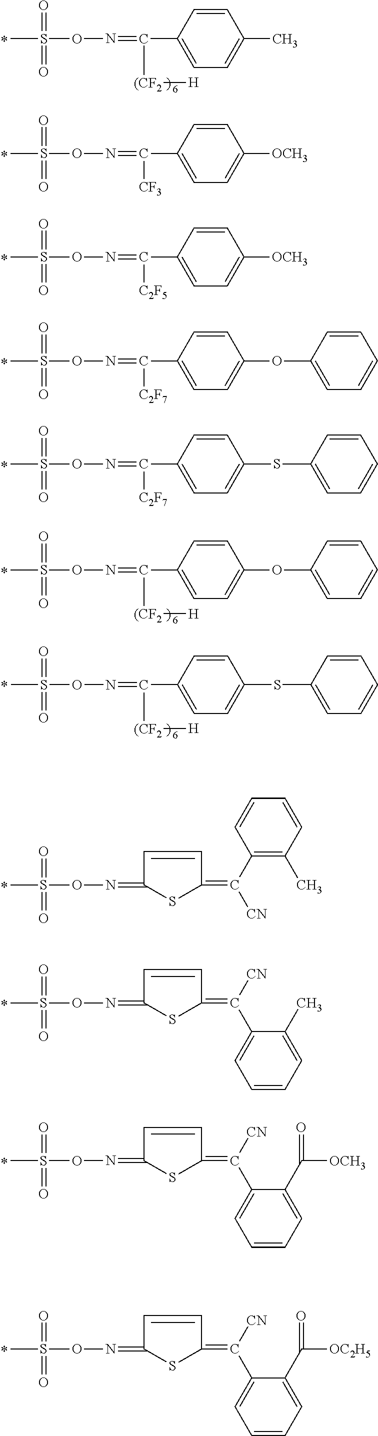

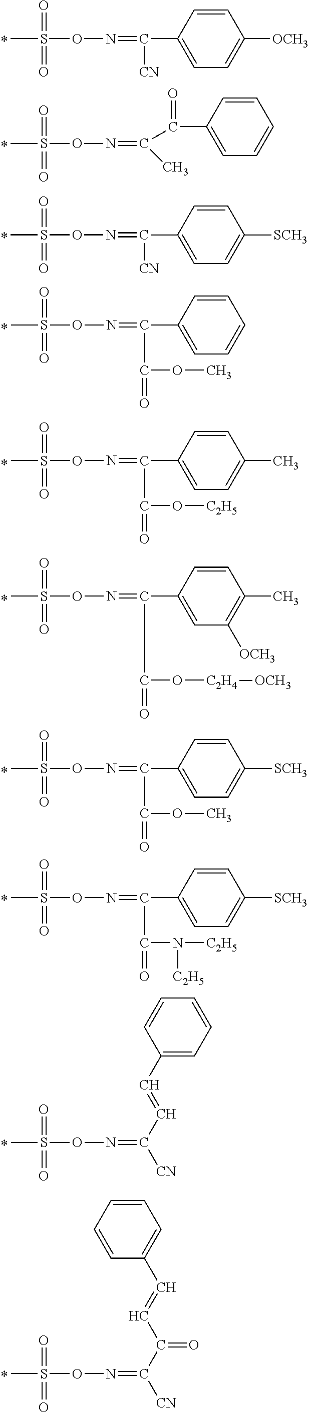

The moiety corresponding to (-L⁴¹-S) of the repeating unit represented by formula (4) is preferably represented by the following formula (6):

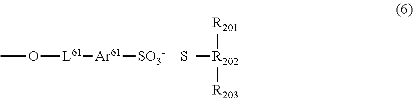

In the formula, L⁶¹ represents a divalent linking group, and Ar⁶¹ represents an arylene group. R₂₀₁, R₂₀₂ and R₂₀₃ have the same meanings as R₂₀₁, R₂₀₂ and R₂₀₃ in formula (PZI), respectively.

Examples of the divalent linking group of L⁶¹ include an alkylene group, a cycloalkylene group, —O—, —SO₂—, —CO—, —N(R)—, —S—, —CS—, and a combination thereof. Here, R has the same meaning as R in L⁴¹ of formula (4). The total carbon number of the divalent linking group of L⁶¹ is preferably from 1 to 15, more preferably from 1 to 10.

Examples of the alkylene group and cycloalkylene group of L⁶¹ are the same as those of the alkylene group and cycloalkylene group of L⁴¹ in formula (4), and preferred examples are also the same.

The group as L⁶¹ is preferably a carbonyl group, a methylene group, *—CO—(CH₂)ₙ—O—, *—CO—(CH₂)ₙ—O—CO—, *—(CH₂)ₙ—COO—, *—(CH₂)ₙ—CONR— or *—CO—(CH₂)ₙ—NR—, more preferably a carbonyl group, *—CH₂—COO—, *—CO—CH₂—O—, *—CO—CH₂—O—CO—, *—CH₂—CONR— or *—CO—CH₂—NR—. Here, n represents an integer of 1 to 10. n is preferably an integer of 1 to 6, more preferably an integer of 1 to 3, and most preferably 1. Also, * indicates a connecting site on the main chain side, that is, a connecting site to the O atom in the formula.

Ar⁶¹ represents an arylene group and may have a substituent. The substituent which may be substituted on Ar⁶¹ is an alkyl group (preferably having a carbon number of 1 to 8, more preferably a carbon number of 1 to 4), an alkoxy group (preferably having a carbon number of 1 to 8, more preferably a carbon number of 1 to 4), or a halogen atom (preferably a fluorine atom, a chlorine atom, a bromide atom or an iodine atom, more preferably a fluorine atom). The aromatic ring of Ar⁶¹ may be an aromatic hydrocarbon ring (for example, a benzene ring or a naphthalene ring) or an aromatic heterocyclic ring (for example, a quinoline ring) and preferably has a carbon number of 6 to 18, more preferably a carbon number of 6 to 12.

Ar⁶¹ is preferably an unsubstituted arylene group or an arylene group substituted with an alkyl group or a fluorine atom, more preferably a phenylene group or a naphthylene group.

Specific examples and preferred examples of R₂₀₁, R₂₀₂ and R₂₀₃ are the same as those recited for R₂₀₁, R₂₀₂ and R₂₀₃ in formula (PZI).

The synthesis method of the monomer corresponding to the repeating unit represented by formula (4) is not particularly limited but, for example, in the case of an onium structure, includes a method of exchanging an acid anion having a polymerizable unsaturated bond corresponding to the repeating unit with a halide of a known onium salt.

More specifically, a metal ion salt (for example, sodium ion or potassium ion) or ammonium salt (such as ammonium or triethylammonium salt) of an acid having a polymerizable unsaturated bond corresponding to the repeating unit and an onium salt having a halogen ion (such as chloride ion, bromide ion or iodide ion) are stirred in the presence of water or methanol to perform an anion exchange reaction, and the reaction product is subjected to separation and washing operations with an organic solvent such as dichloromethane, chloroform, ethyl acetate, methyl isobutyl ketone and tetrahydroxyfuran, and water, whereby the target monomer corresponding to the repeating unit represented by formula (4) can be synthesized.

The monomer can be also synthesized by stirring the compounds above in the presence of an organic solvent separable from water, such as dichloromethane, chloroform, ethyl acetate, methyl isobutyl ketone and tetrahydroxyfuran, and water to perform an anion exchange reaction, and subjecting the reaction product to separation and washing operations with water.

Furthermore, the repeating unit represented by formula (4) can be also synthesized by introducing an acid anion moiety into the side chain by a polymer reaction and introducing an onium salt through salt exchange.

Specific examples of the repeating unit represented by formula (4) are illustrated below, but the present invention is not limited thereto.

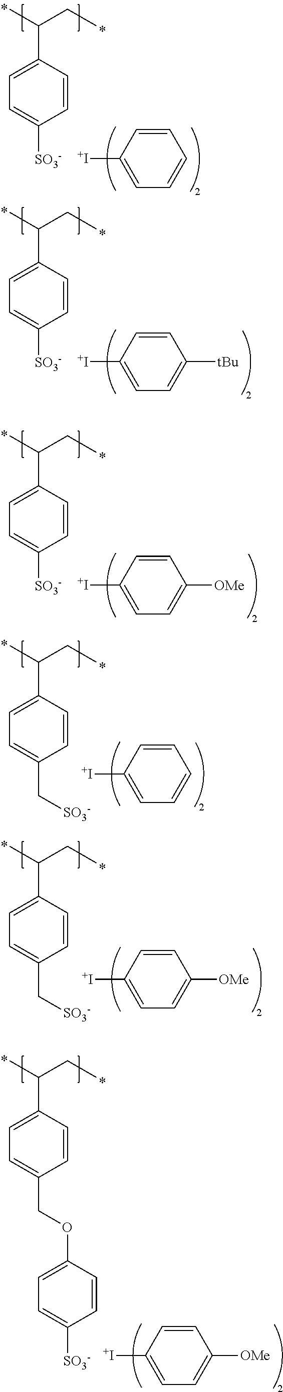

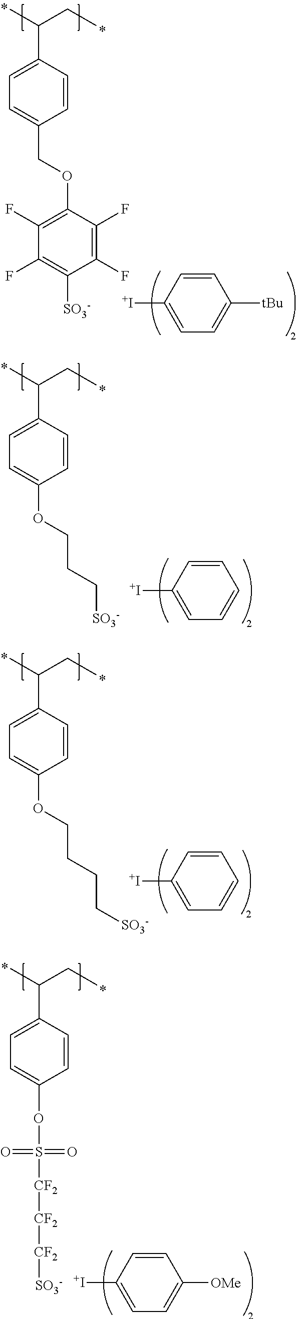

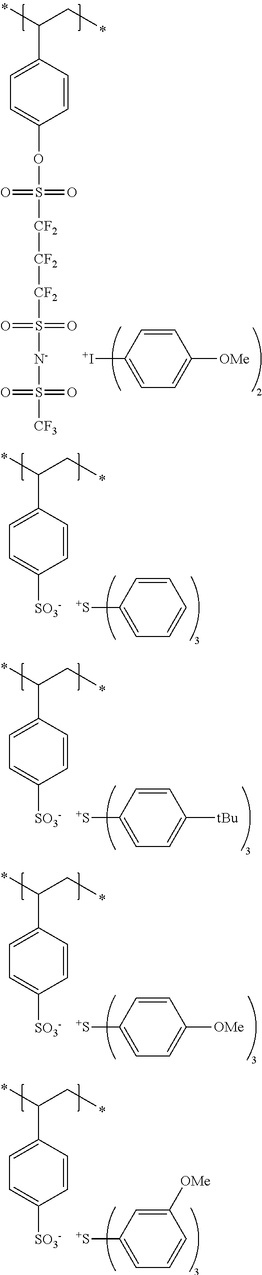

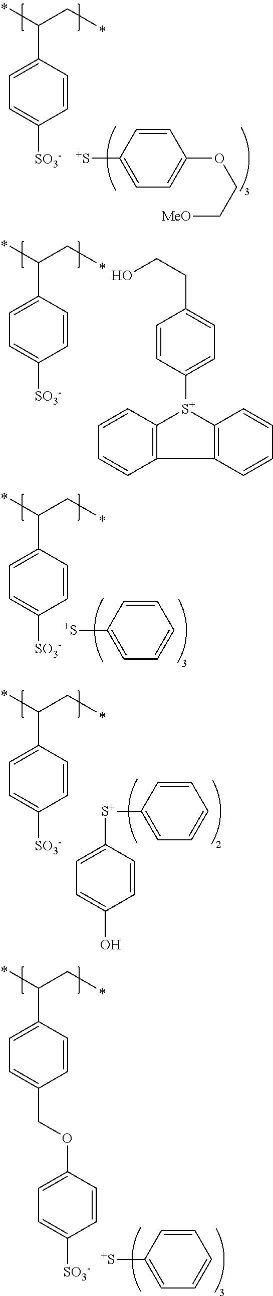

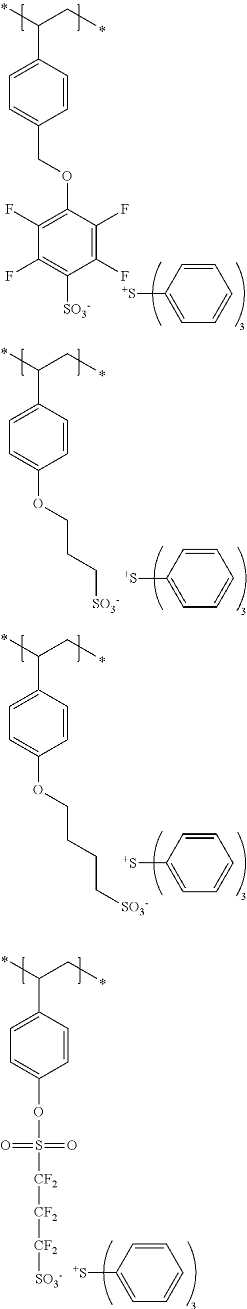

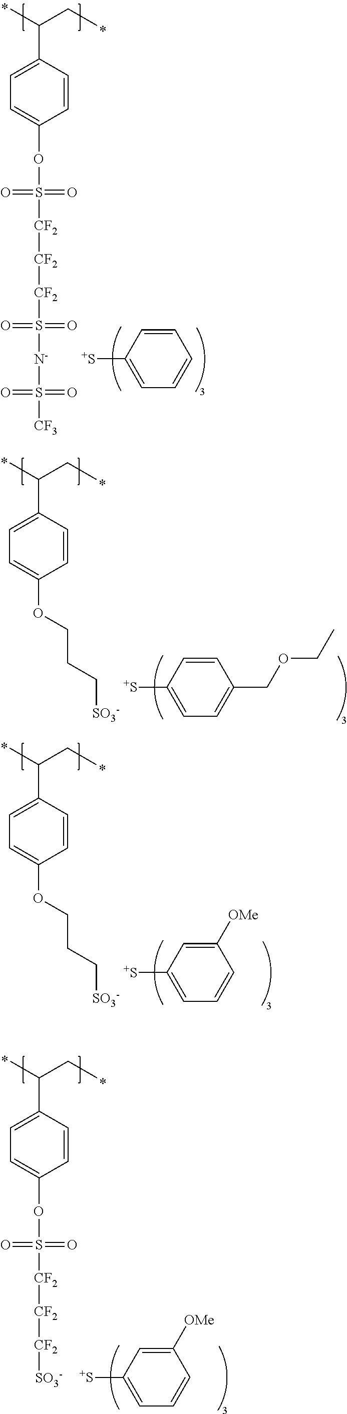

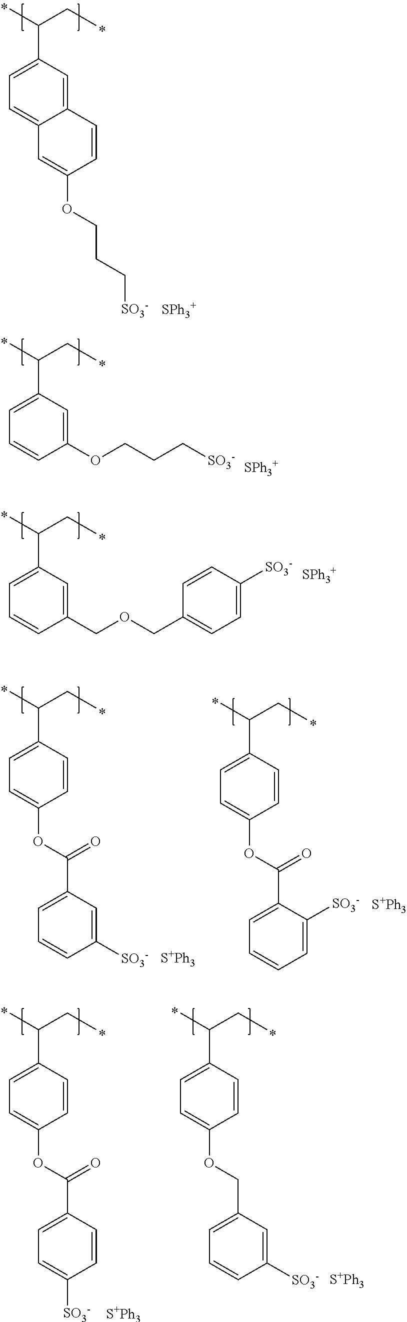

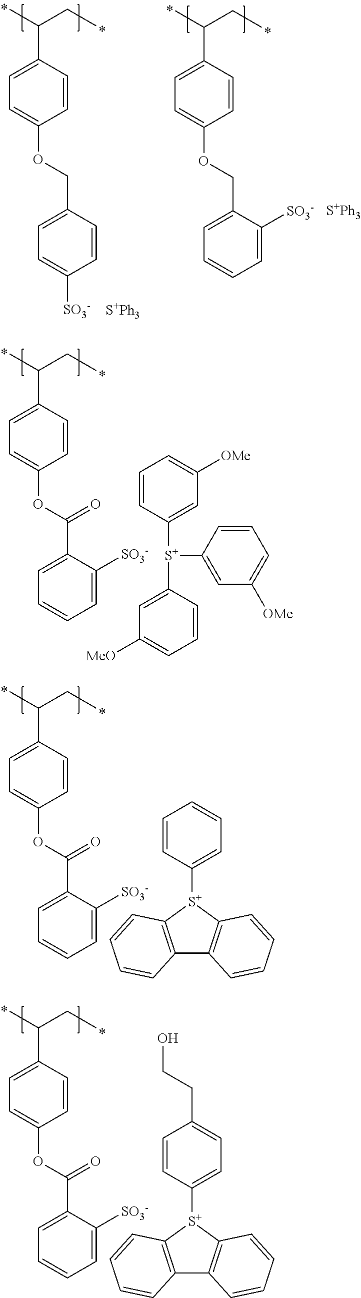

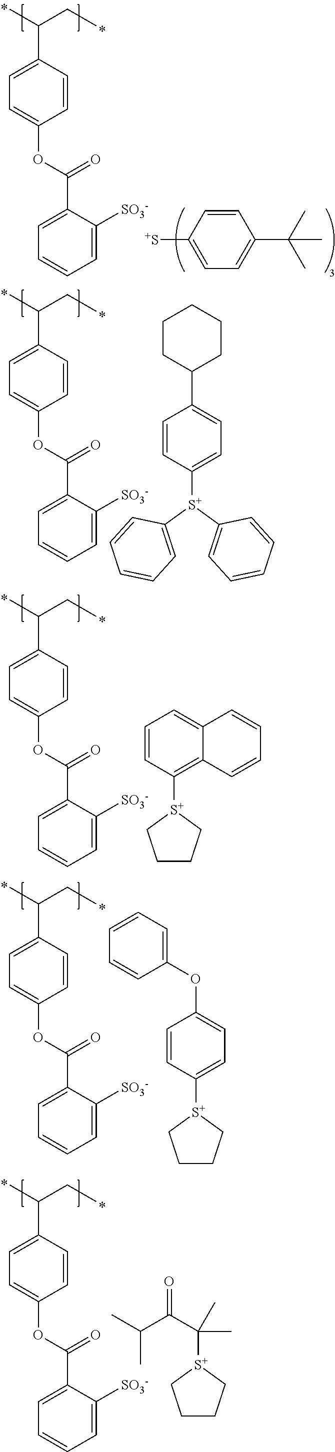

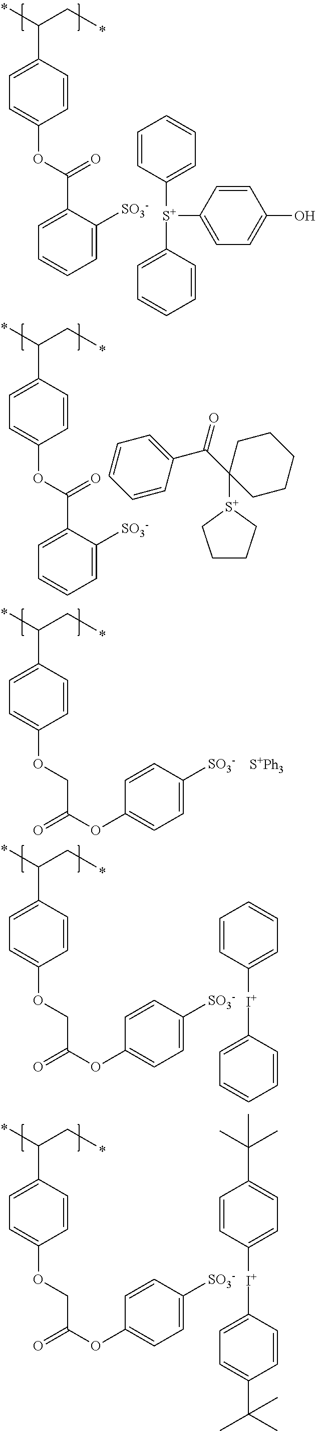

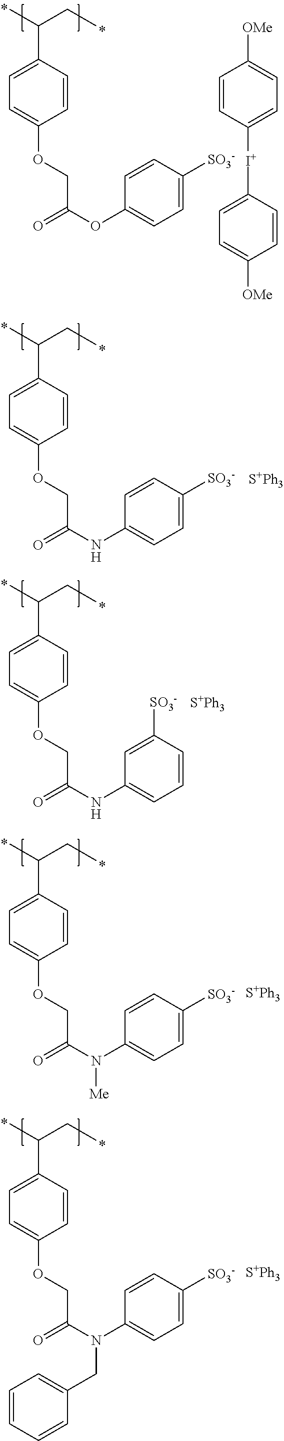

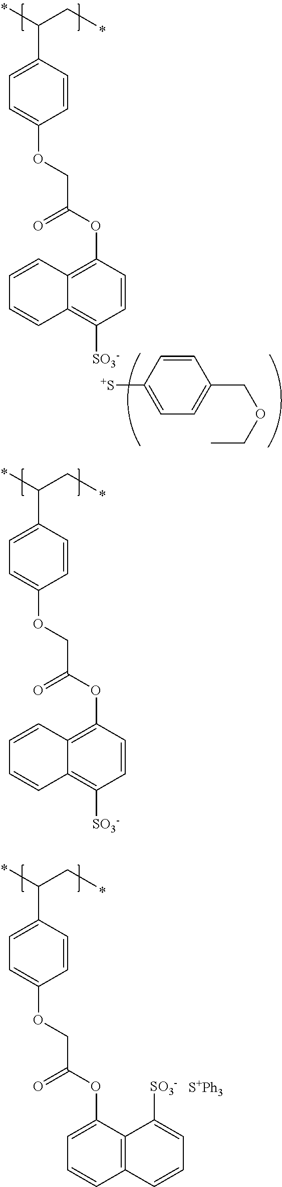

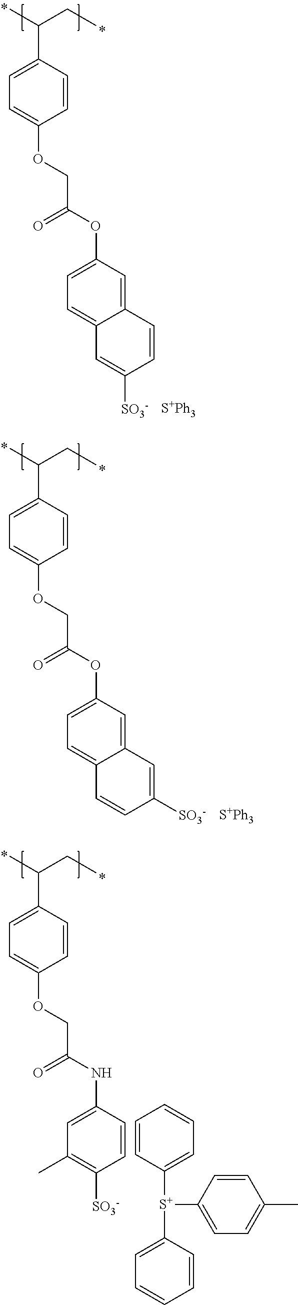

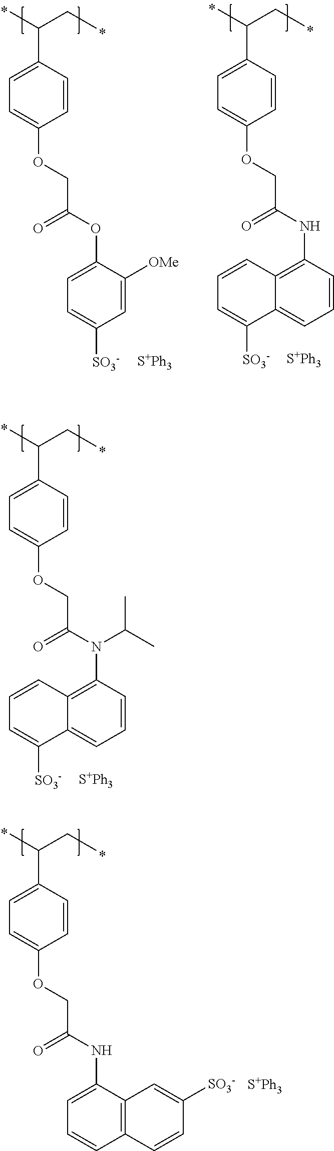

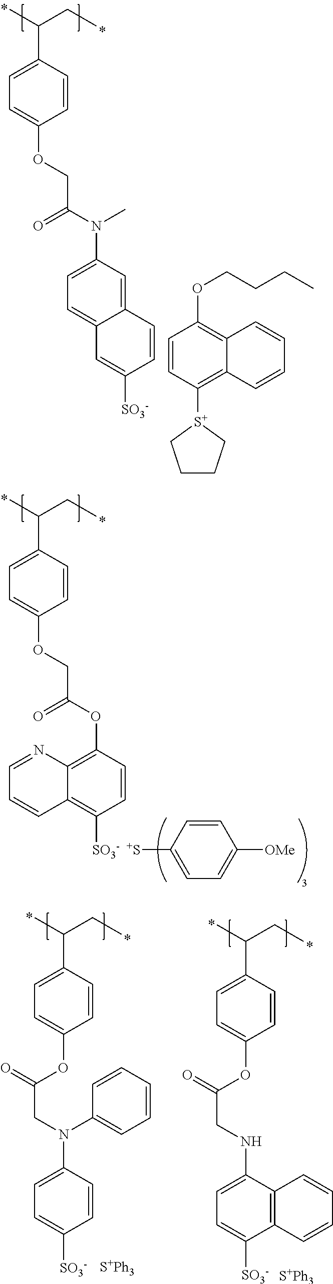

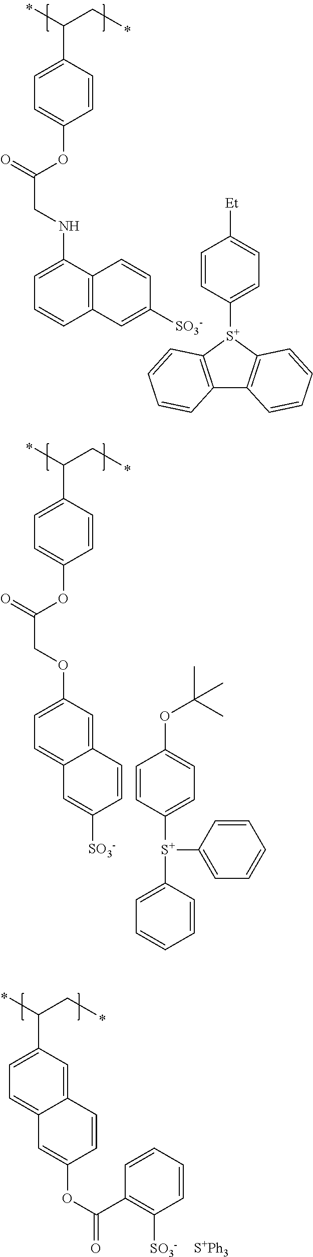

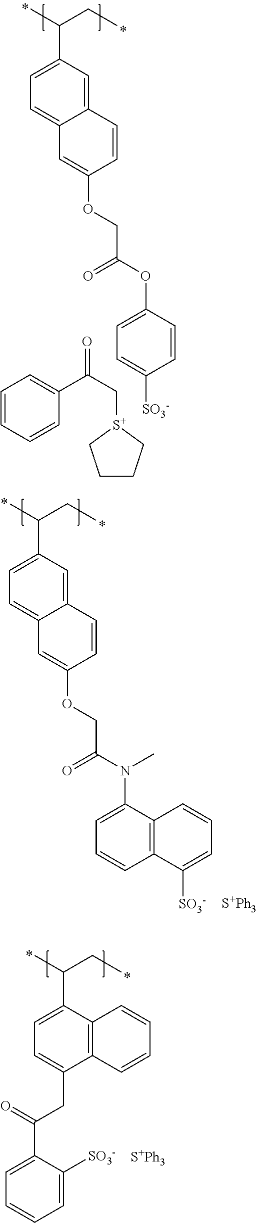

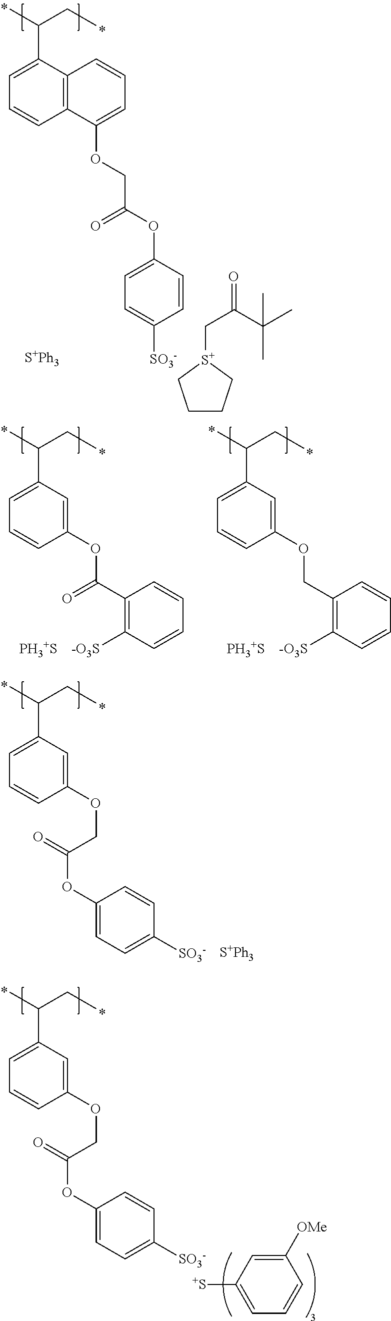

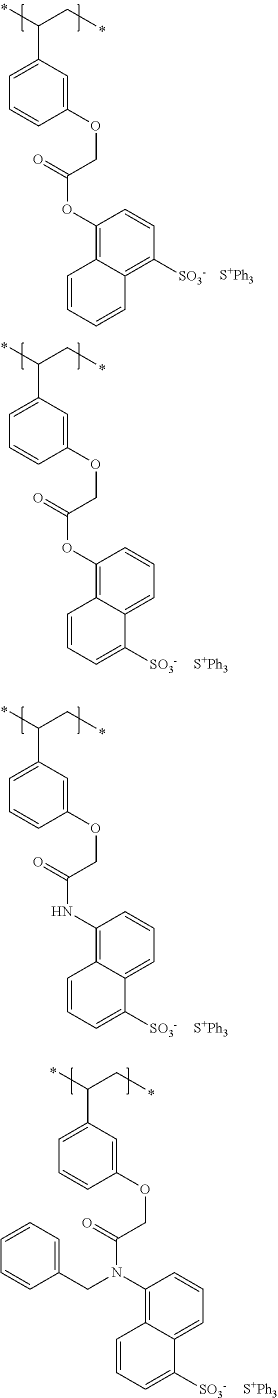

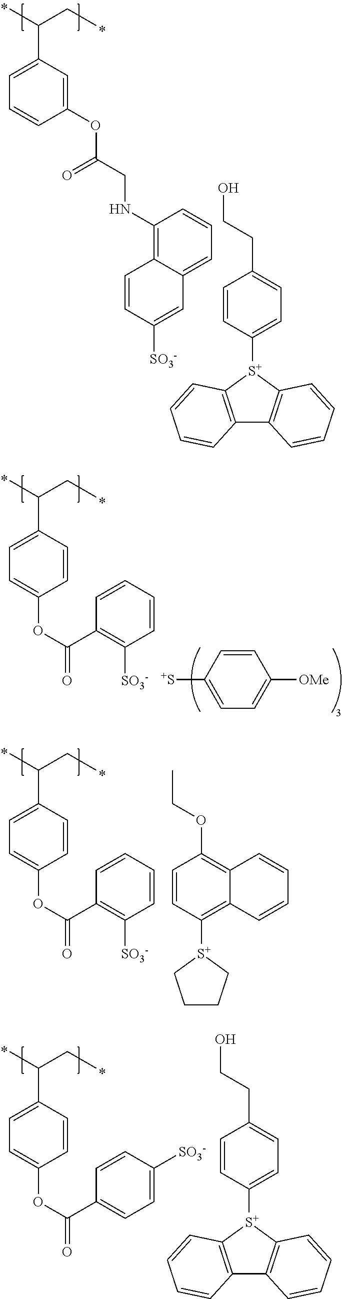

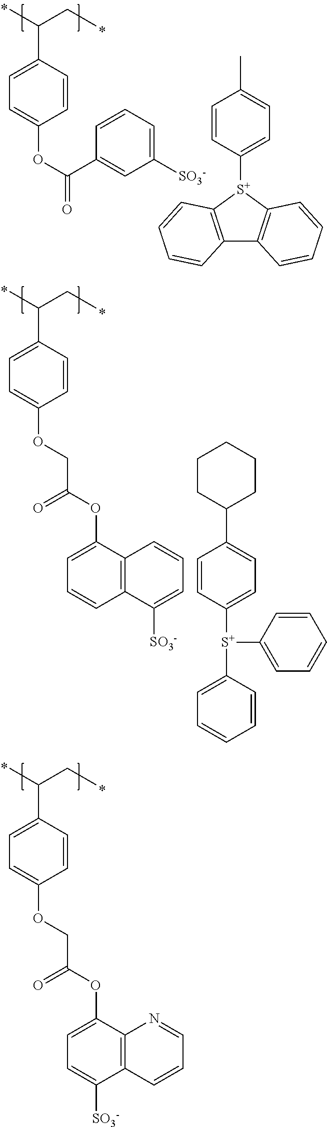

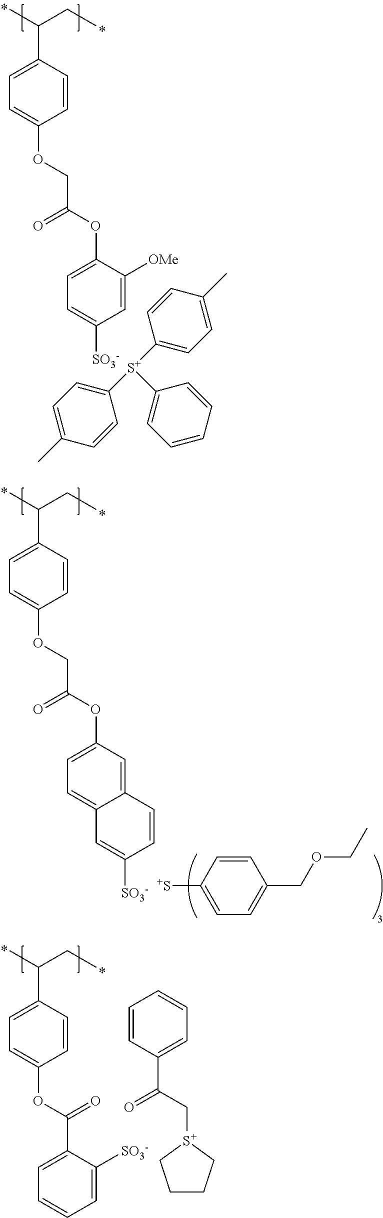

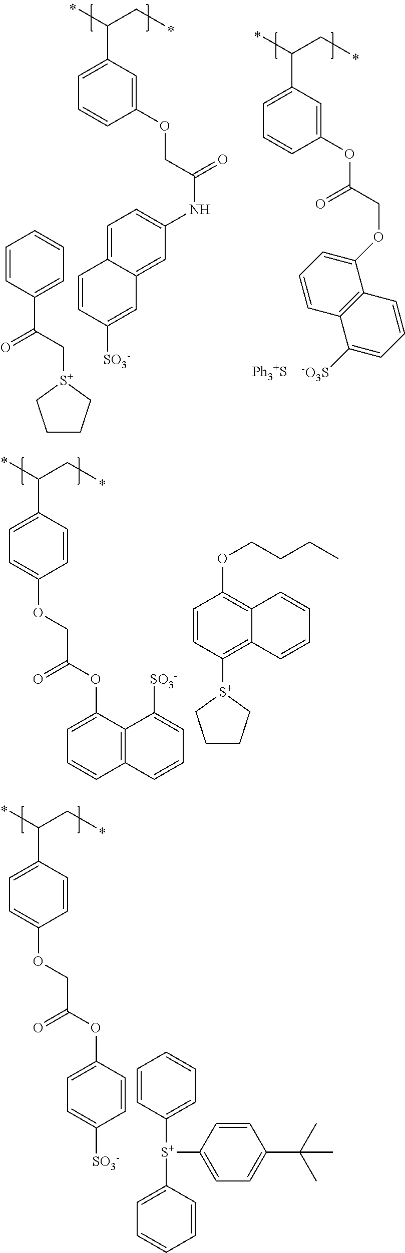

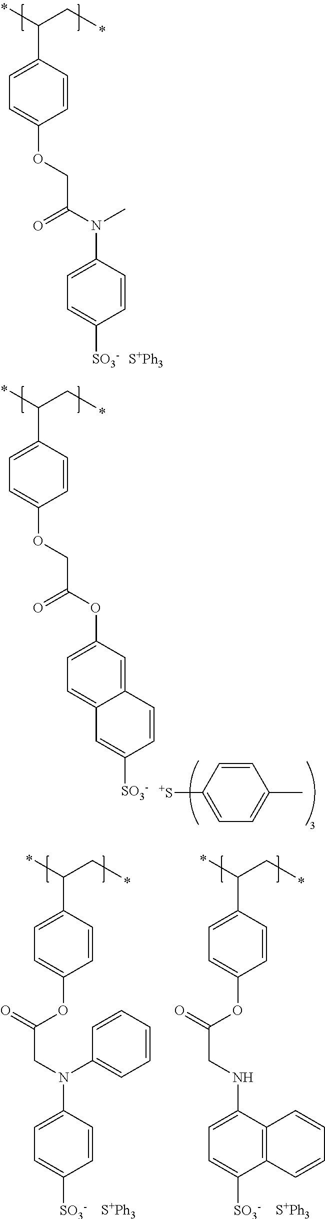

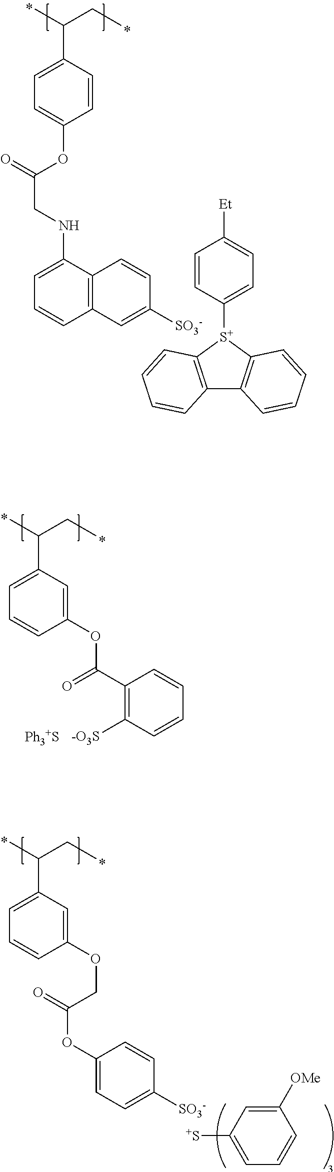

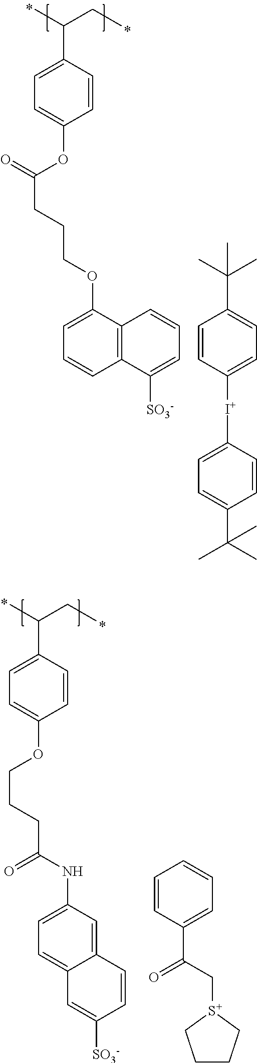

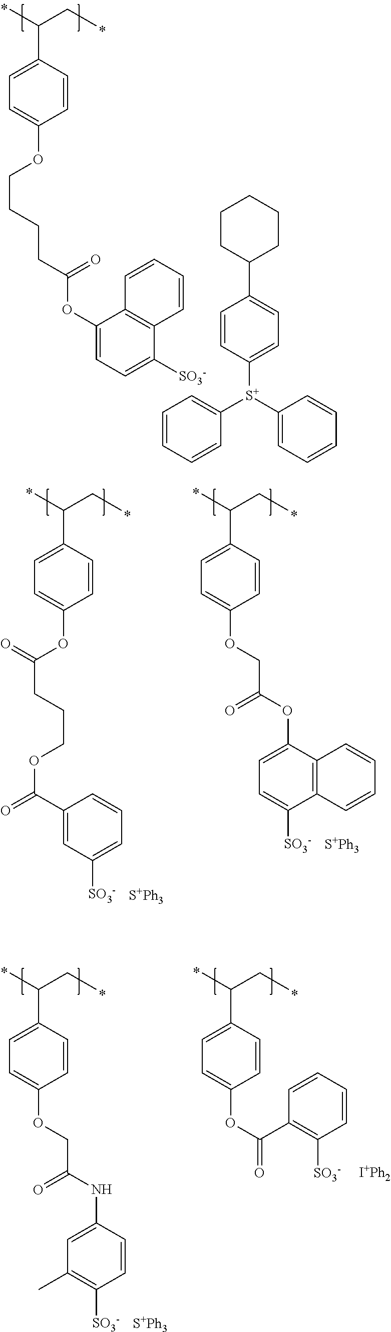

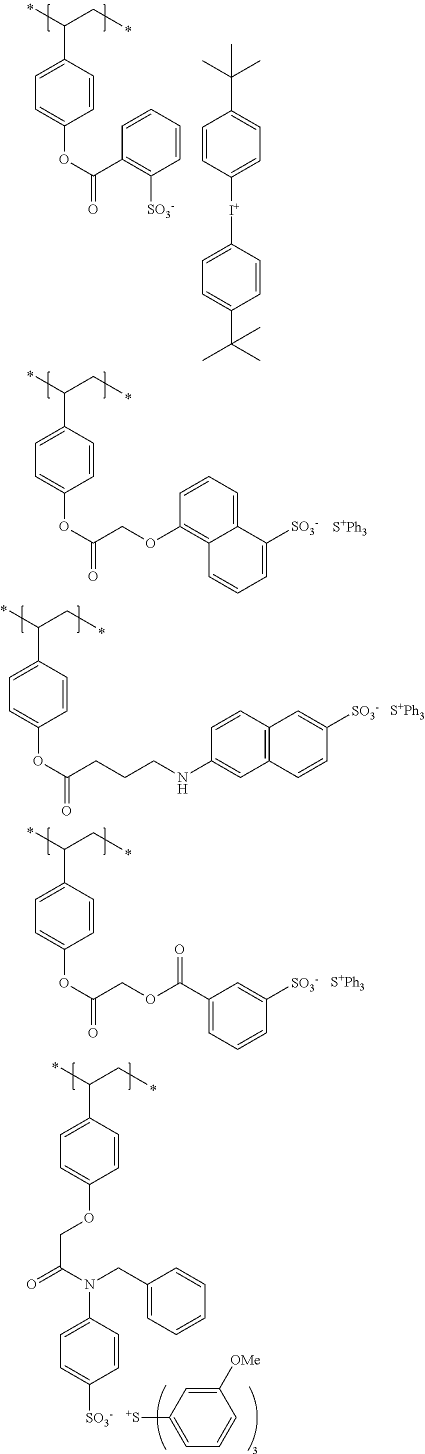

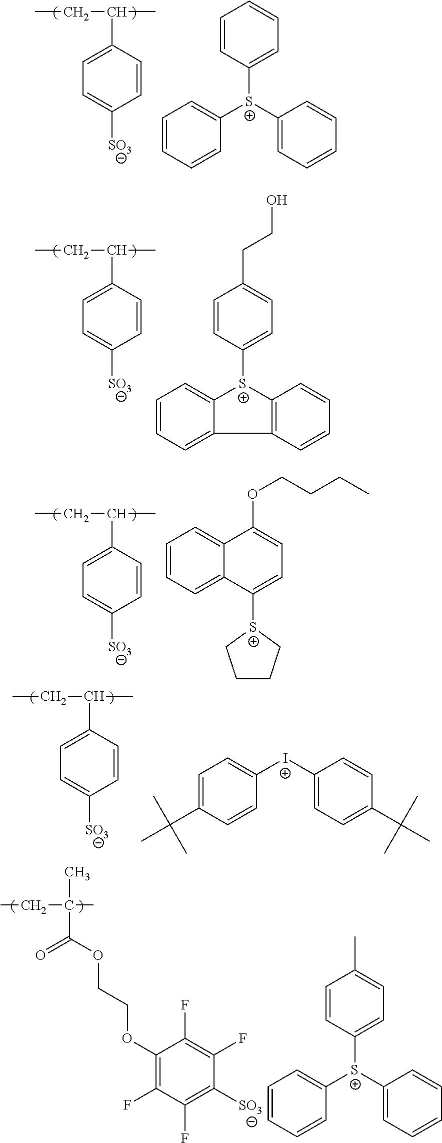

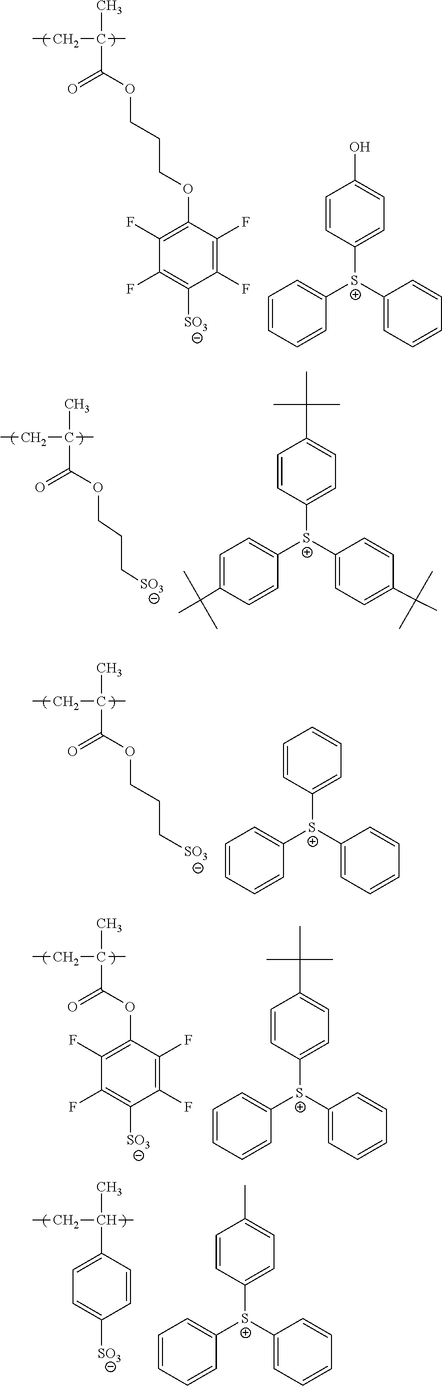

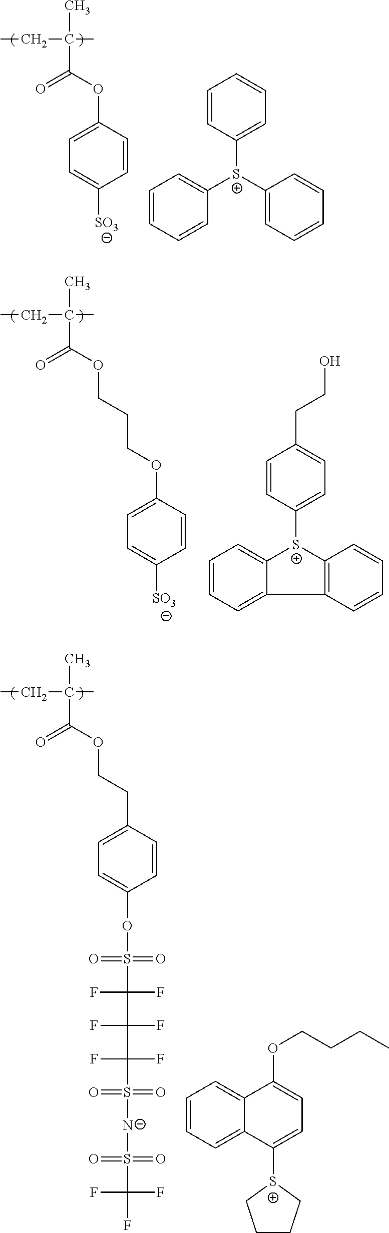

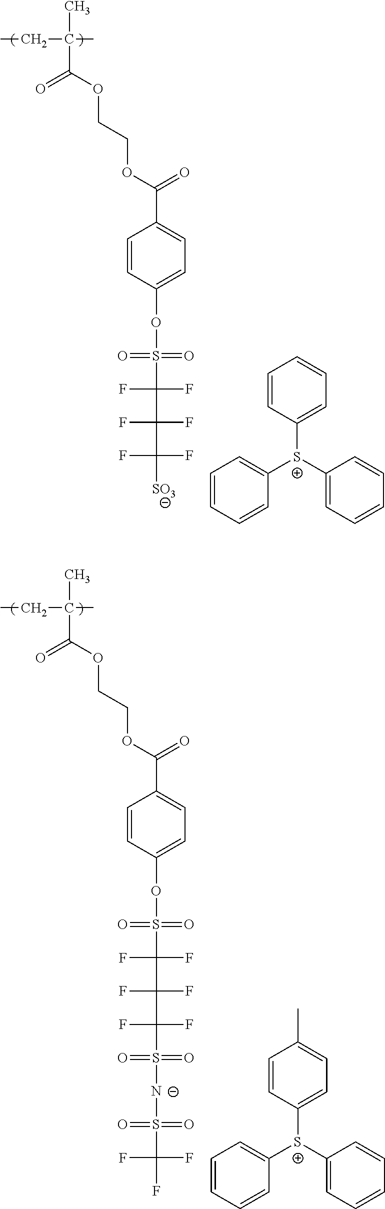

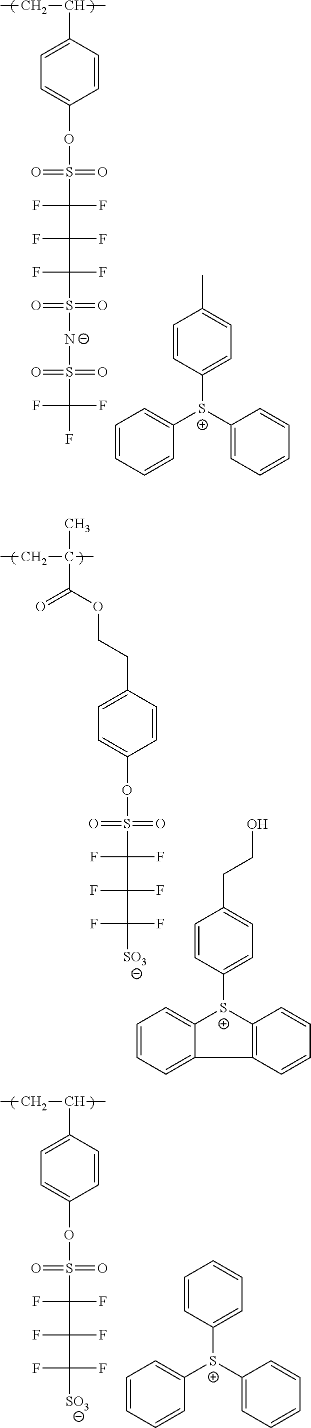

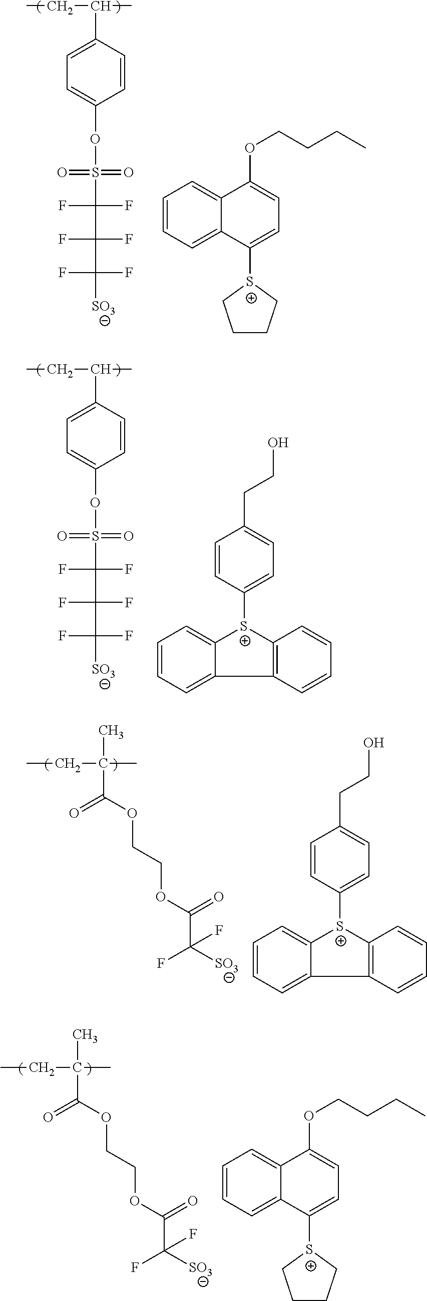

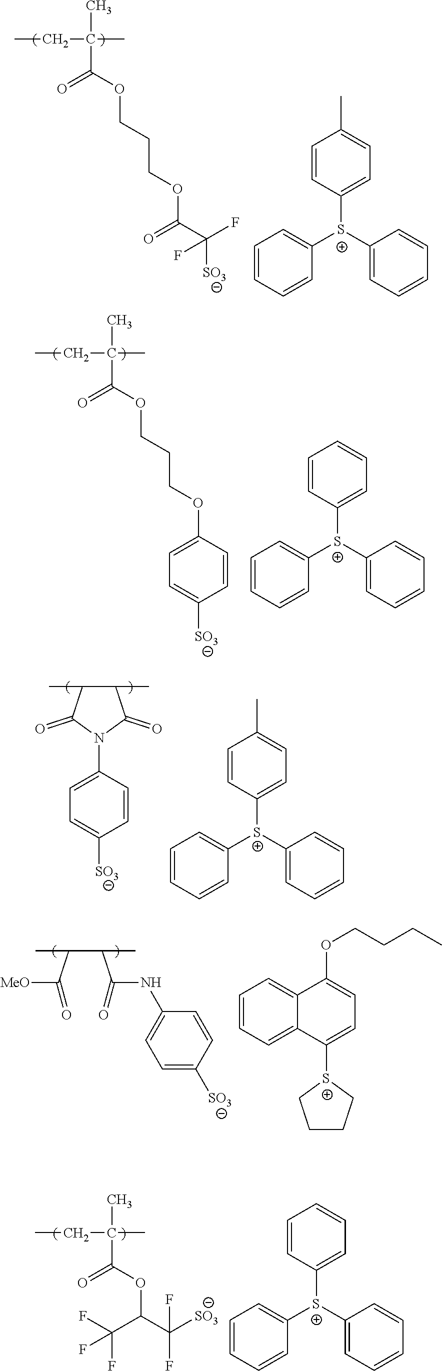

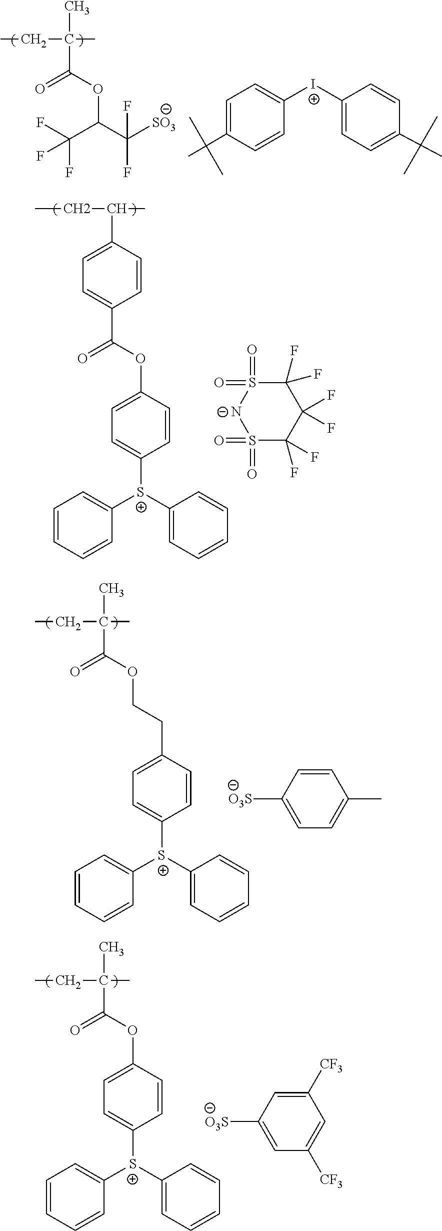

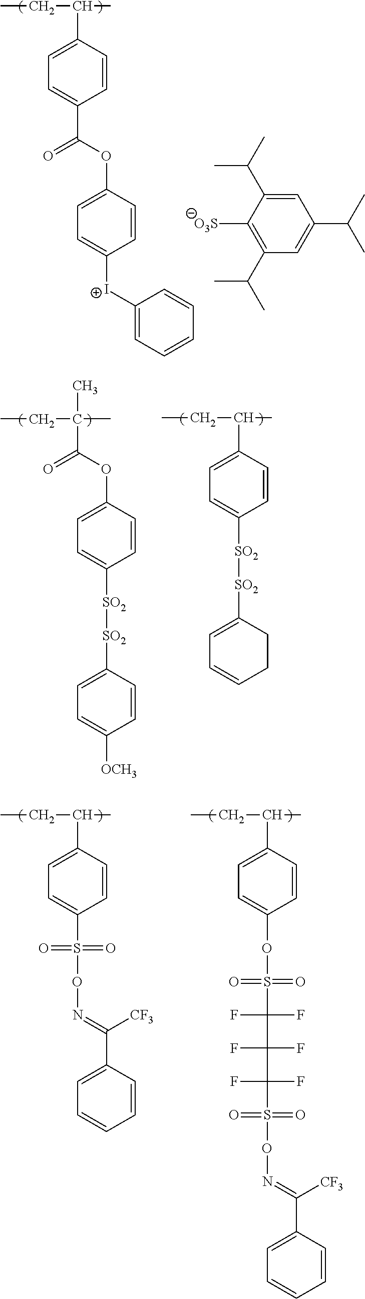

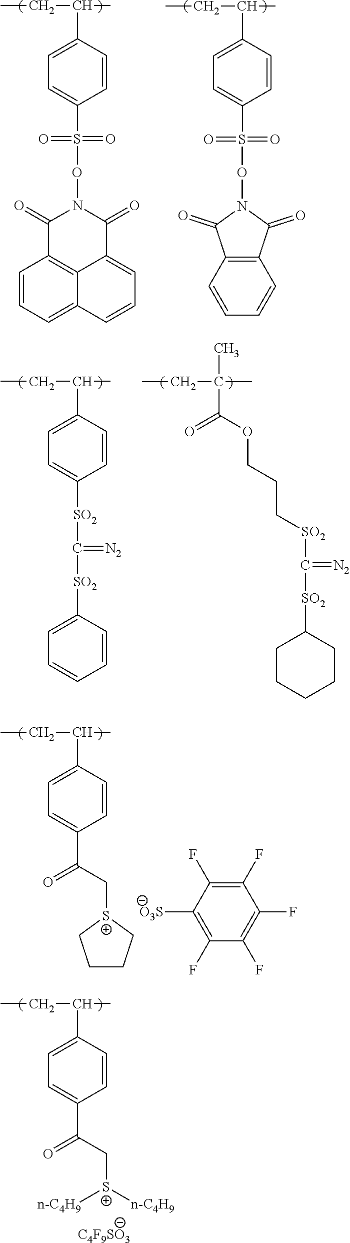

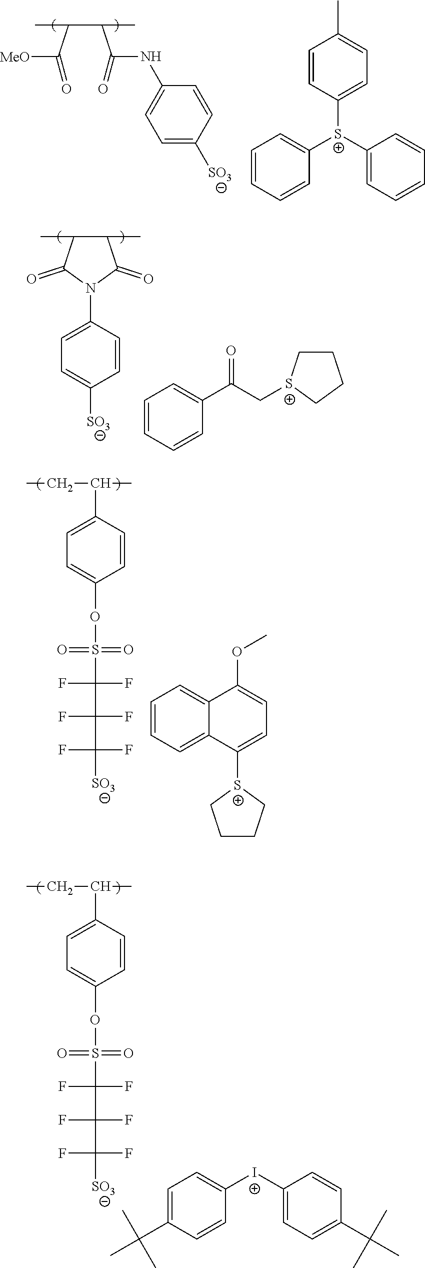

The content of the repeating unit represented by formula (4) in the resin (A) is preferably from 1 to 40 mol %, more preferably from 2 to 30 mol %, still more preferably from 5 to 25 mol %, based on all repeating units in the resin (A).

It is also preferred that the resin (A) further contains the following repeating units as other repeating units.

For example, the resin (A) may further contain a repeating unit containing a group having a lactone structure, and the repeating unit containing a group having a lactone structure is preferably a repeating unit represented by the following formula (AII):

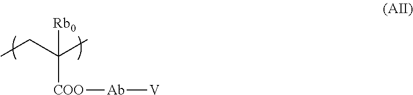

In formula (AII), V represents a group having a lactone structure, Rb₀ represents a hydrogen atom or a methyl group, and Ab represents a single bond or a divalent linking group.

As for the group having a lactone structure, any group may be used as long as it has a lactone structure, but a 5- to 7-membered ring lactone structure is preferred, and a 5- to 7-membered ring lactone structure to which another ring structure is fused to form a bicyclo structure or a spiro structure is preferred.

Ab is preferably a single bond or a divalent linking group represented by -AZ-CO₂— (wherein AZ is an alkylene group or an aliphatic ring group). AZ is preferably a methylene group, an ethylene group, a cyclohexylene group, an adamantylene group or a norbornylene group.

Specific examples are illustrated below. In the formulae, Rx represents H or CH₃.

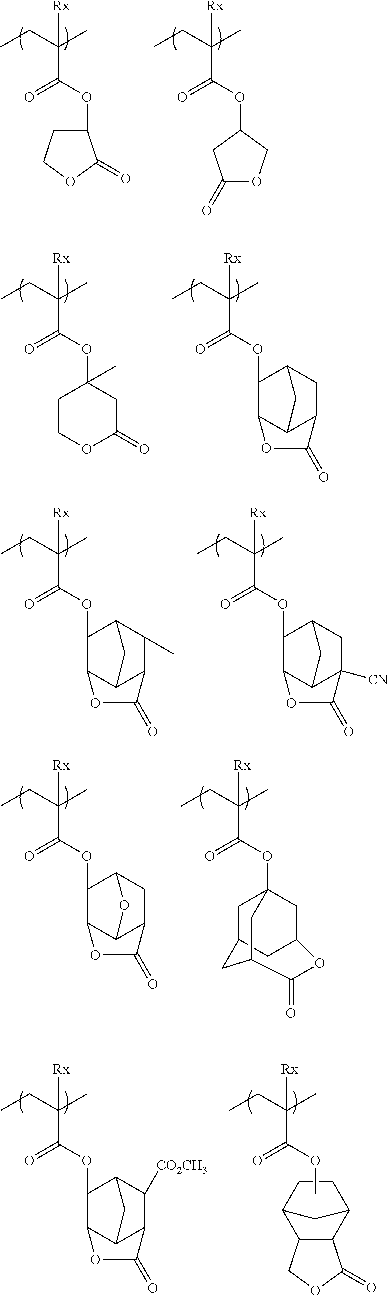

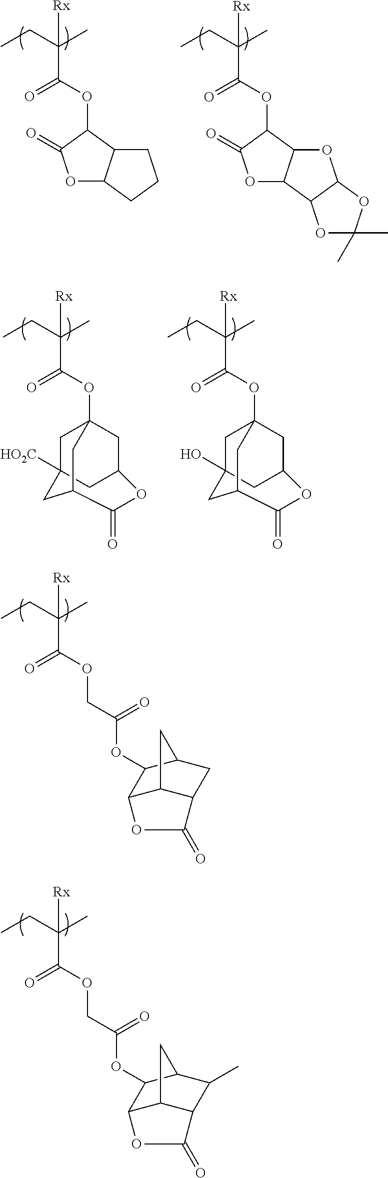

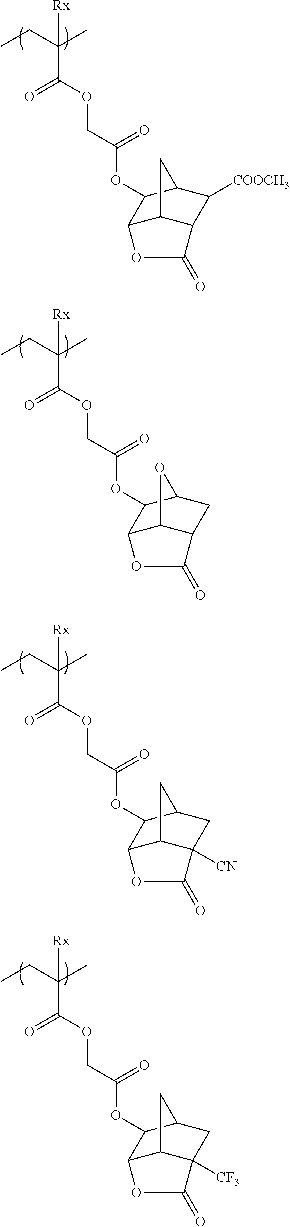

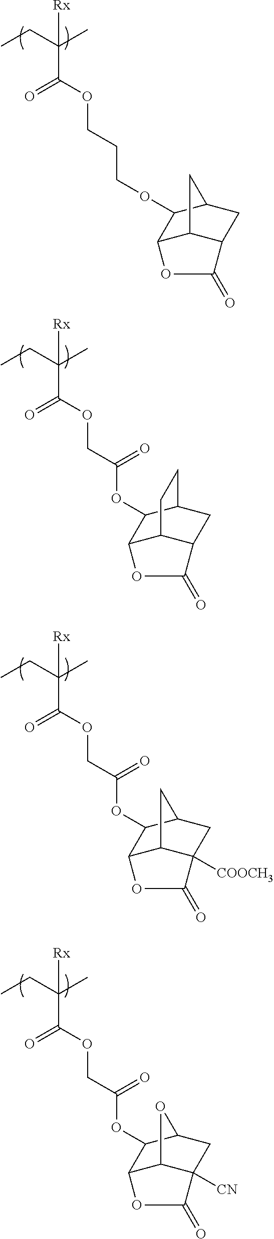

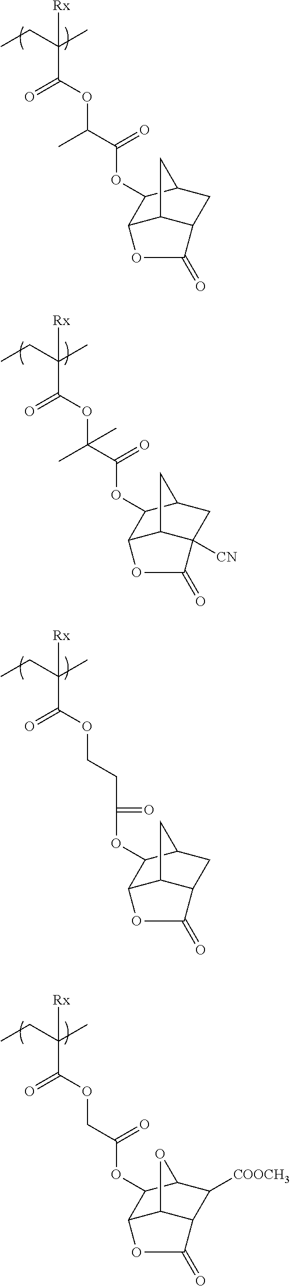

The resin (A) may or may not contain a repeating unit containing a group having a lactone structure, but in the case of containing the repeating unit having the group, the content thereof is preferably from 5 to 60 mol %, more preferably from 7 to 50 mol %, still more preferably from 10 to 40 mol %, based on all repeating units in the resin (A).

The resin (A) may further contain a fluorine atom-containing repeating unit. This fluorine atom-containing repeating unit is preferably different from the repeating unit represented by formula (4).

The fluorine atom may be contained in the main chain on the resin (A) or may be substituted on the side chain. The fluorine atom-containing repeating unit is preferably, for example, a (meth)acrylate-based repeating unit or a styryl-based repeating unit.

In one embodiment, the fluorine atom-containing repeating unit is preferably a repeating unit having, as a partial structure, a fluorine atom-containing alkyl group, a fluorine atom-containing cycloalkyl group or a fluorine atom-containing aryl group.

The fluorine atom-containing alkyl group (preferably having a carbon number of 1 to 10, more preferably a carbon number of 1 to 4) is a linear or branched alkyl group with at least one hydrogen atom being substituted for by a fluorine atom and may further have other substituents.

The fluorine atom-containing cycloalkyl group is a monocyclic or polycyclic cycloalkyl group with at least one hydrogen atom being substituted for by a fluorine atom and may further have other substituents.

The fluorine atom-containing aryl group is an aryl group (such as phenyl group or naphthyl group) with at least one hydrogen atom being substituted for by a fluorine atom and may further have other substituents.

As the fluorine atom-containing alkyl group, fluorine atom-containing cycloalkyl group and fluorine atom-containing aryl group, the groups represented by any one of the following formulae (F2) to (F4) are preferred, but the present invention is not limited thereto.

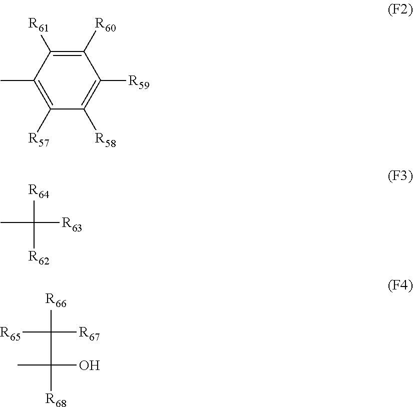

In formulae (F2) to (F4), each of R₅₇ to R₆₈ independently represents a hydrogen atom, a fluorine atom, or an alkyl group (chain), provided that at least one of R₅₇ to R₆₁ at least one of R₆₂ to R₆₄, and at least one of R₆₅ to R₆₈ each represents a fluorine atom or a fluoroalkyl group. R₆₂ and R₆₃ may combine with each other to form a ring.

Specific examples of the group represented by formula (F2) include a p-fluorophenyl group, a pentafluorophenyl group, and a 3,5-di(trifluoromethyl)phenyl group.

Specific examples of the group represented by formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-tert-butyl group, a perfluoroisopentyl group, a perfluorooctyl group, a perfluoro(trimethyl)hexyl group, a 2,2,3,3-tetrafluorocyclobutyl group, and a perfluorocyclohexyl group. Among these, a hexafluoroisopropyl group, a heptafluoroisopropyl group, a hexafluoro(2-methyl)isopropyl group, an octafluoroisobutyl group, a nonafluoro-tert-butyl group and a perfluoroisopentyl group are preferred, and a hexafluoroisopropyl group and a heptafluoroisopropyl group are more preferred.

Specific examples of the group represented by formula (F4) include —C(CF₃)₂OH, —C(C₂F₅)₂OH, —C(CF₃)(CH₃)OH and —CH(CF₃)OH, with C(CF₃)₂OH being preferred.

The fluorine atom-containing partial structure may be bonded directly to the main chain or may be bonded to the main chain through a single group selected from the group consisting of an alkylene group, a phenylene group, an ether bond, a thioether bond, a carbonyl group, an ester bond, an amide bond, a urethane bond and a ureylene bond, or a combination of two or more thereof.

Suitable fluorine atom-containing repeating units include the followings.

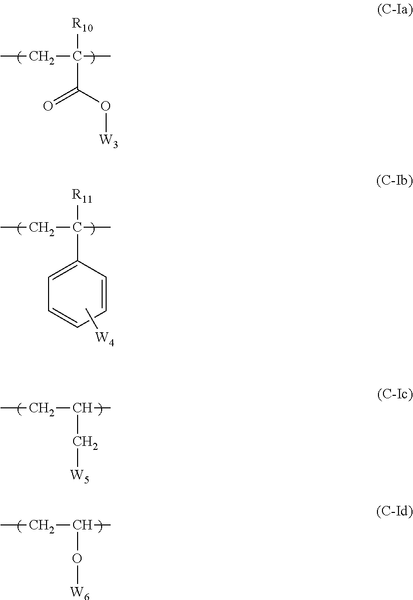

In the formulae, each of R₁₀ and R₁₁ independently represents a hydrogen atom, a fluorine atom or an alkyl group (preferably a linear or branched alkyl group having a carbon number of 1 to 4, and the alkyl group having a substituent includes, in particular, a fluorinated alkyl group).

Each of W₃ to W₆ independently represents an organic group having at least one or more fluorine atoms, and the organic group specifically includes the atomic groups of formulae (F2) to (F4).

In another embodiment, the resin (A) may contain a unit represented by formula (C-II) or (C-III):

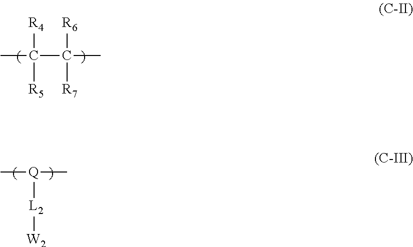

In formula (C-II), each of R₄ to R₇ independently represents a hydrogen atom, a fluorine atom or an alkyl group (preferably a linear or branched alkyl group having a carbon number of 1 to 4, and the alkyl group having a substituent includes, in particular, a fluorinated alkyl group), provided that at least one of R₄ to R₇ represents a fluorine atom. R₄ and R₅, or R₆ and R₇ may form a ring.

In formula (C-III), Q represents an alicyclic structure. The alicyclic structure may be monocyclic or polycyclic and may have a substituent. The monocyclic structure is preferably a cycloalkyl group having a carbon number of 3 to 9, and examples thereof include a cyclopentyl group, a cyclohexyl group, a cyclobutyl group, and a cyclooctyl group. The polycyclic structure includes a group having, for example, a bicyclo, tricyclo or tetracyclo structure with a carbon number of 5 or more and is preferably a cycloalkyl group having a carbon number of 6 to 20, and examples thereof include an adamantyl group, a norbornyl group, a dicyclopentyl group, a tricyclodecanyl group, and a tetracyclododecyl group. A part of carbon atoms in the cycloalkyl group may be substituted with a heteroatom such as oxygen atom. The alicyclic structure of Q is more preferably an alicyclic structure having a carbon number of 5 to 9.

W₂ represents an organic group having at least one fluorine atom, and the organic group specifically includes the atomic groups of formulae (F2) to (F4).

L₂ represents a single bond or a divalent linking group. The divalent linking group is a substituted or unsubstituted arylene group, a substituted or unsubstituted alkylene group, a substituted or unsubstituted cycloalkylene group, —O—, —SO₂—, —CO—, —N(R)— (wherein R represents a hydrogen atom or an alkyl group), —NHSO₂—, or a divalent linking group formed by combining a plurality of these groups.

Specific examples of the fluorine-containing repeating unit are illustrated below, but the present invention is not limited thereto. In specific examples, X₁ represents a hydrogen atom, —CH₃, —F or —CF₃, and X₂ represents —F or —CF₃.

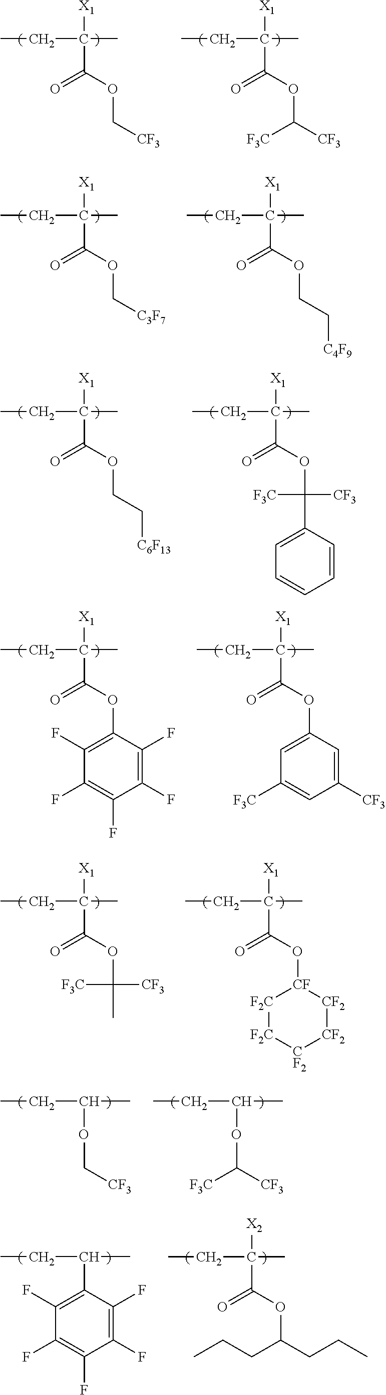

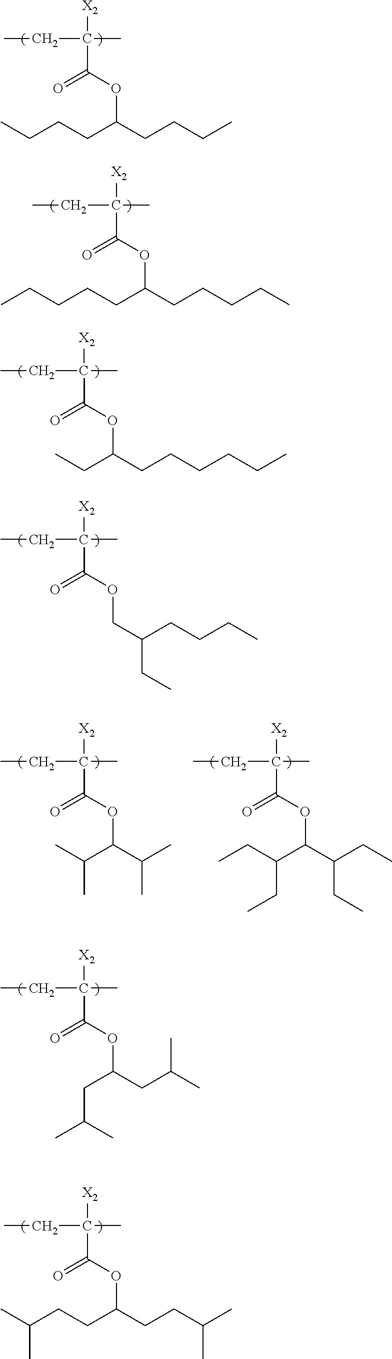

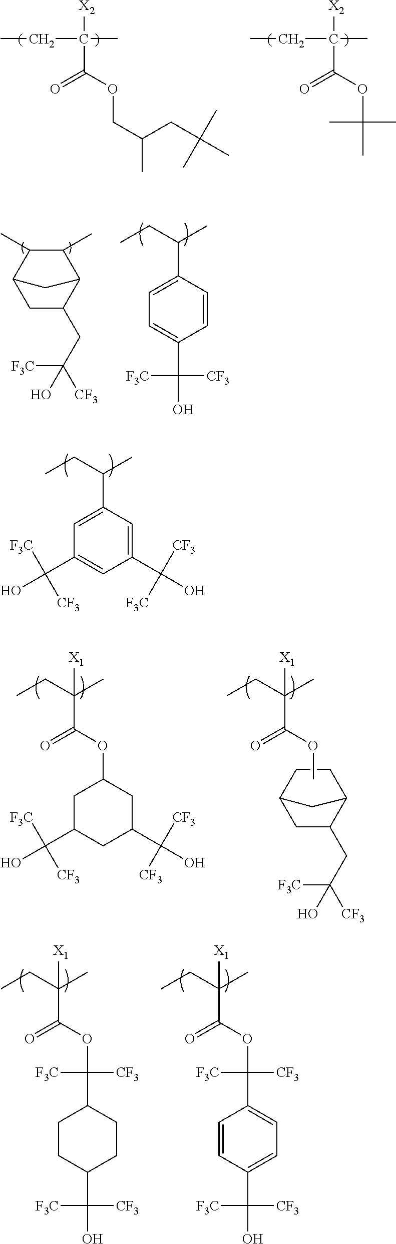

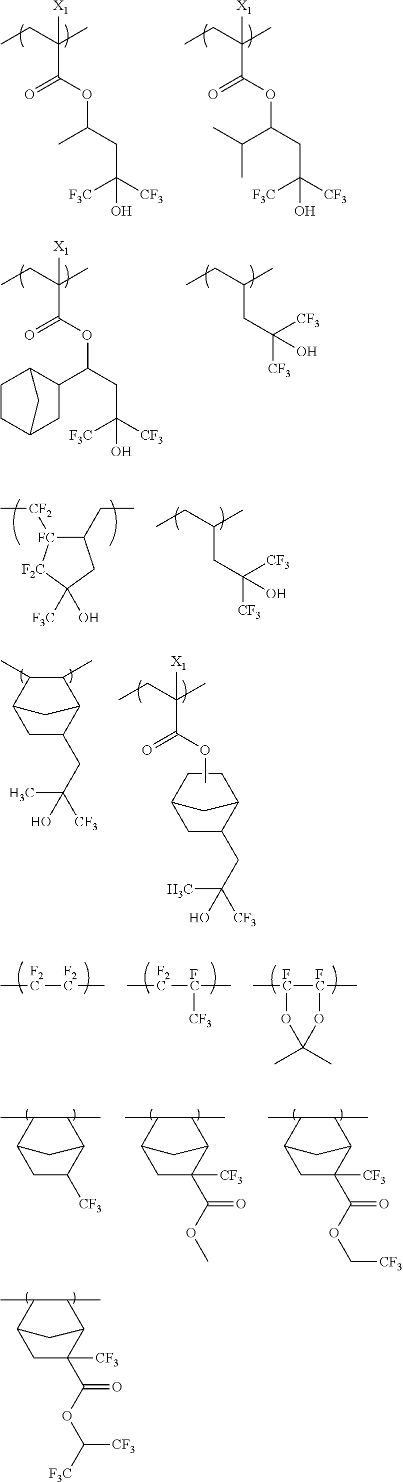

The resin (A) may or may not contain a fluorine atom-containing repeating unit, but in the case of containing a fluorine-containing repeating unit, the content thereof is preferably from 1 to 50 mol %, more preferably from 1 to 40 mol %, still more preferably from 1 to 30 mol %, yet still more preferably from 1 to 20 mol %, based on all repeating units in the resin.

Examples of the polymerizable monomer for forming a repeating unit other than those described above in the resin (A) include styrene, an alkyl-substituted styrene, an alkoxy-substituted styrene, an O-alkylated styrene, an O-acylated styrene, a hydrogenated hydroxystyrene, a maleic anhydride, an acrylic acid derivative (such as acrylic acid and acrylic acid ester), a methacrylic acid derivative (such as methacrylic acid and methacrylic acid ester), an N-substituted maleimide, an acrylonitrile, a methacrylonitrile, a vinylnaphthalene, a vinylanthracene, an acenaphthylene, and an indene which may have a substituent. Preferred examples of the substituted styrene include 4-(1-naphthylmethoxy)styrene, 4-benzyloxystyrene, 4-(4-chlorobenzyloxy)styrene, 3-(1-naphthylmethoxy)styrene, 3-benzyloxystyrene, and 3-(4-chlorobenzyloxy)styrene.

The resin (A) may or may not contain such a repeating unit, but in the case of containing such a repeating unit, the content thereof in the resin (A) is generally from 1 to 20 mol %, preferably from 2 to 10 mol %, based on all repeating units constituting the resin (A).

The resin (A) can be synthesized, for example, by radical, cationic or anionic polymerization of unsaturated monomers corresponding to respective repeating units. The resin may be also synthesized by polymerizing a polymer using unsaturated monomers corresponding to precursors of respective repeating units, and modifying the synthesized polymer with a low molecular compound to cause conversion into desired repeating units. In either case, living polymerization such as living anionic polymerization is preferably used, because the molecular weight distribution of the obtained polymer compound becomes uniform.

The weight average molecular weight of the resin (A) for use in the present invention is preferably from 1,000 to 200,000, more preferably from 2,000 to 50,000, still more preferably from 2,000 to 15,000. The polydispersity (molecular weight distribution) (Mw/Mn) of the resin (A) is preferably from 1.0 to 2.0, more preferably from 1.0 to 1.8. The weight average molecular weight and polydispersity of the resin (A) are defined as values in terms of polystyrene by GPC measurement.

The content of the resin (A) is preferably from 45 to 95 mass %, more preferably from 50 to 90 mass %, still more preferably from 55 to 85 mass %, based on the total solid content of the composition. (In this specification, mass ratio is equal to weight ratio.)

[2] Compound capable of generating an acid upon irradiation with an actinic ray or radiation

The extreme ultraviolet-sensitive composition of the present invention may further contain a compound capable of generating an acid upon irradiation with an actinic ray or radiation (hereinafter, sometimes referred to as “photoacid generator”). Above all, when the extreme ultraviolet-sensitive composition does not contain, as the resin (A), a resin containing a repeating unit represented by formula (4), the extreme ultraviolet-sensitive composition usually further contains a photoacid generator.

The photoacid generator which can be used may be appropriately selected from, for example, a photoinitiator for cationic photopolymerization, a photoinitiator for radical photopolymerization, a photo-decoloring agent, a photo-discoloring agent, a known compound capable of generating an acid upon irradiation with an actinic ray or radiation, which is used in a microresist and the like, and a mixture thereof. Examples thereof include an onium salt such as sulfonium salt and iodonium salt, and a diazodisulfone compound such as bis(alkylsulfonyldiazomethane).

Preferred examples of the photoacid generator include compounds represented by the following formulae (ZI), (ZII) and (ZIII):

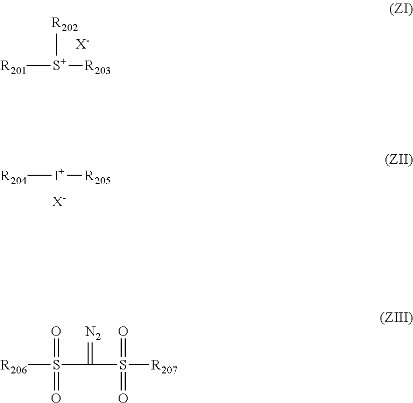

In formula (ZI), each of R₂₀₁, R₂₀₂ and R₂₀₃ independently represents an organic group. The carbon number of the organic group as R₂₀₁, R₂₀₂ and R₂₀₃ is, for example, from 1 to 30, preferably from 1 to 20.

Two members out of R₂₀₁ to R₂₀₃ may combine through a single bond or a linking group to form a ring structure. Examples of the linking group include an ether bond, a thioether bond, an ester bond, an amide bond, a carbonyl group, a methylene group, and an ethylene group. Examples of the group formed by combining two members out of R₂₀₁ to R₂₀₃ include an alkylene group such as butylene group and pentylene group.

Specific examples of R₂₀₁, R₂₀₂ and R₂₀₃ include corresponding groups in the later-described compounds (ZI-1), (ZI-2) and (ZI-3).

X⁻ represents a non-nucleophilic anion. Examples of X⁻ include a sulfonate anion, a bis(alkylsulfonyl)amide anion, a tris(alkylsulfonyl)methide anion, BF₄⁻, PF₆⁻, and SbF₆⁻. X⁻ is preferably an organic anion containing a carbon atom. Preferred examples of the organic anion include organic anions represented by the following formulae AN1 to AN3:

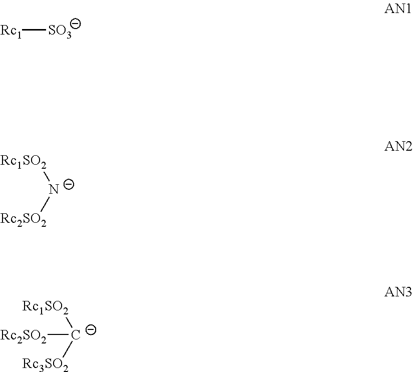

In formulae AN1 to AN3, each of Rc₁ to Rc₃ independently represents an organic group. This organic group includes, for example, an organic group having a carbon number of 1 to 30 and is preferably an alkyl group, an aryl group, or a group formed by connecting a plurality of these groups through a linking group. Examples of the linking group include a single bond, —O—, —CO₂—, —S—, —SO₃—, and —SO₂N(Rd₁)-, wherein Rd₁ represents a hydrogen atom or an alkyl group and may form a ring structure together with the alkyl or aryl group bonded thereto.

The organic group of Rc₁ to Rc₃ may be an alkyl group substituted with a fluorine atom or a fluoroalkyl group at the 1-position, or a phenyl group substituted with a fluorine atom or a fluoroalkyl group. By virtue of incorporating a fluorine atom or a fluoroalkyl group, the acidity of the acid generated upon irradiation with light can be increased and in turn, the sensitivity of the extreme ultraviolet-sensitive resin composition can be enhanced. Incidentally, Rc₁ to Rc₃ may combine with another alkyl group, aryl group or the like to form a ring structure.

Preferred X⁻ includes a sulfonate anion represented by the following formula (SA1) or (SA2):

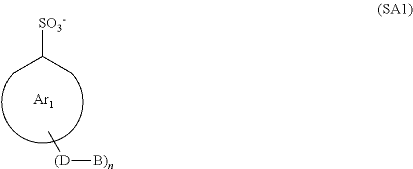

In formula (SA1), Ar₁ represents an aromatic ring and may further have a substituent other than the sulfonic acid group and the -(D-B) group.

n represents an integer of 1 or more. n is preferably from 1 to 4, more preferably 2 or 3, and most preferably 3.

D represents a single bond or a divalent linking group. The divalent linking group is preferably an ether group, a thioether group, a carbonyl group, a sulfoxide group, a sulfone group, a sulfonic acid ester bond or an ester group.

B represents a hydrocarbon group.

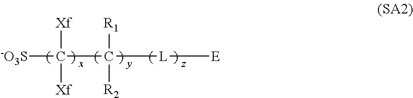

In formula (SA2), each Xf independently represents a fluorine atom or an alkyl group with at least one hydrogen atom being substituted for by a fluorine atom.

Each of R₁ and R₂ independently represents a hydrogen atom, a fluorine atom or an alkyl group, and when a plurality of R₁ or R₂ are present, each R₁ or R₂ may be the same as or different from every other R₁ or R₂.

L represents a divalent linking group, and when a plurality of L are present, each L may be the same as or different from every other L.

E represents a cyclic organic group.

x represents an integer of 1 to 20, y represents an integer of 0 to 10, and z represents an integer of 0 to 10.

The sulfonate anion represented by formula (SA1) is described in detail below.

In formula (SA1), Ar₁ is preferably an aromatic ring having a carbon number of 6 to 30. Specifically, Ar₁ is, for example, a benzene ring, a naphthalene ring, a pentalene ring, an indene ring, an azulene ring, a heptalene ring, an indecene ring, a perylene ring, a pentacene ring, an acenaphthylene ring, a phenanthrene ring, an anthracene ring, a naphthacene ring, a chrysene ring, a triphenylene ring, a fluorene ring, a biphenyl ring, a pyrrole ring, a furan ring, a thiophene ring, an imidazole ring, an oxazole ring, a thiazole ring, a pyridine ring, a pyrazine ring, a pyrimidine ring, a pyridazine ring, an indolizine ring, an indole ring, a benzofuran ring, a benzothiophene ring, an isobenzofuran ring, a quinolidine ring, a quinoline ring, a phthalazine ring, a naphthylidine ring, a quinoxaline ring, a quinoxazoline ring, an isoquinoline ring, a carbazole ring, a phenanthridine ring, an acridine ring, a phenanthroline ring, a thianthrene ring, a chromene ring, a xanthene ring, a phenoxathiin ring, a phenothiazine ring or a phenazine ring and, among others, from the standpoint of both improving the roughness and increasing the sensitivity, is preferably a benzene ring, a naphthalene ring or an anthracene ring, more preferably a benzene ring.

In the case where Ar₁ further has a substituent other than the sulfonic acid group and -(D-B) group, examples of the substituent include the followings. That is, examples of the substituent include a halogen atom such as fluorine atom, chlorine atom, bromine atom and iodine atom; an aryloxy group such as phenoxy group and p-tolyloxy group; an arylthioxy group such as phenylthioxy group and p-tolylthioxy group; an aryl group such as phenyl group and tolyl group; a hydroxy group; a carboxy group; and a sulfonic acid group.

In formula (SA1), D is preferably a single bond, an ether group or an ester group. D is more preferably a single bond.

In formula (SA1), the hydrocarbon group of B is, for example, an alkyl group, an alkenyl group, an alkynyl group, an aryl group or a cycloalkyl group. B is preferably an alkyl group or a cycloalkyl group. The alkyl group, alkenyl group, alkynyl group, aryl group or cycloalkyl group as B may have a substituent.

The alkyl group as B is preferably a branched alkyl group. Examples of the branched alkyl group include an isopropyl group, a tert-butyl group, a tert-pentyl group, a neopentyl group, a sec-butyl group, an isobutyl group, an isohexyl group, a 3,3-dimethylpentyl group, and a 2-ethylhexyl group.

The cycloalkyl group as B may be a monocyclic cycloalkyl group or a polycyclic cycloalkyl group. Examples of the monocyclic cycloalkyl group include a cyclopropyl group, a cyclobutyl group, a cyclopentyl group, a cyclohexyl group, a cycloheptyl group, and a cyclooctyl group. Examples of the polycyclic cycloalkyl group include an adamantyl group, a norbornyl group, a bornyl group, a camphenyl group, a decahydronaphthyl group, a tricyclodecanyl group, a tetracyclodecanyl group, a camphoroyl group, a dicyclohexyl group, and a pinenyl group.

In the case where the alkyl group, alkenyl group, alkynyl group, aryl group or cycloalkyl group as B has a substituent, examples of this substituent include the followings. That is, examples of the substituent include a halogen atom such as fluorine atom, chlorine atom, bromine atom and iodine atom; an alkoxy group such as methoxy group, ethoxy group and tert-butoxy group; an aryloxy group such as phenoxy group and p-tolyloxy group; an alkylthioxy group such as methylthioxy group, ethylthioxy group and tert-butylthioxy group; an arylthioxy group such as phenylthioxy group and p-tolylthioxy group; an alkoxycarbonyl group such as methoxycarbonyl group, butoxycarbonyl group and phenoxycarbonyl group; an acetoxy group; a linear alkyl group such as methyl group, ethyl group, propyl group, butyl group, heptyl group, hexyl group, dodecyl group and 2-ethylhexyl group; a branched alkyl group; a cycloalkyl group such as cyclohexyl group; an alkenyl group such as vinyl group, propenyl group and hexenyl group; an acetylene group; an alkynyl group such as propynyl group and hexynyl group; an aryl group such as phenyl group and tolyl group; a hydroxy group; a carboxy group; a sulfonic acid group; and a carbonyl group. Among these, from the standpoint of both improving the roughness and increasing the sensitivity, a linear alkyl group and a branched alkyl group are preferred.

The sulfonate anion represented by formula (SA2) is described in detail below.

In formula (SA2), Xf is a fluorine atom or an alkyl group with at least one hydrogen atom being substituted for by a fluorine atom. The alkyl group is preferably an alkyl group having a carbon number of 1 to 10, more preferably an alkyl group having a carbon number of 1 to 4. The alkyl group substituted with a fluorine atom is preferably a perfluoroalkyl group.

Xf is preferably a fluorine atom or a perfluoroalkyl group having a carbon number of 1 to 4. Specifically, Xf is preferably a fluorine atom, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ or CH₂CH₂C₄F₉, more preferably a fluorine atom or CF₃, and most preferably a fluorine atom.

In formula (SA2), each of R₁ and R₂ is a hydrogen atom, a fluorine atom or an alkyl group. The alkyl group of R₁ and R₂ may have a substituent (preferably a fluorine atom) and is preferably an alkyl group having a carbon number of 1 to 4. Specific examples of the alkyl group having a substituent of R₁ and R₂ include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ and CH₂CH₂C₄F₉, with CF₃ being preferred.

In formula (SA2), x is preferably from 1 to 8, more preferably from 1 to 4. y is preferably from 0 to 4, more preferably 0. z is preferably from 0 to 8, more preferably from 0 to 4.

In formula (SA2), L represents a single bond or a divalent linking group.

Examples of the divalent linking group include —COO—, —OCO—, —CO—, —O—, —S—, —SO—, —SO₂—, an alkylene group, a cycloalkylene group, an alkenylene group, and a linking group formed by connecting a plurality of these members. Among these, —COO—, —OCO—, —CO—, —O—, —S—, —SO— and —SO₂— are preferred, and —COO—, —OCO— and —SO₂— are more preferred.

In formula (SA2), E represents a cyclic organic group. Examples of E include a cyclic aliphatic group, an aryl group, and a heterocyclic group.

The cyclic aliphatic group as E may have a monocyclic structure or a polycyclic structure. The cyclic aliphatic group having a monocyclic structure is preferably a monocyclic cycloalkyl group such as cyclopentyl group, cyclohexyl group and cyclooctyl group. The cyclic aliphatic group having a polycyclic structure is preferably a polycyclic cycloalkyl group such as norbornyl group, tricyclodecanyl group, tetracyclodecanyl group, tetracyclododecanyl group and adamantyl group. In particular, when a cyclic aliphatic group having a bulky structure of 6-membered or higher membered ring is employed as E, diffusion into the film can be suppressed in the PEB (post-exposure baking) step, and resolution and EL (exposure latitude) can be further enhanced.

The ring in the aryl group as E is, for example, a benzene ring, a naphthalene ring, a phenanthrene ring or an anthracene ring.

The heterocyclic group as E may or may not have aromaticity. The heteroatom contained in the heterocyclic group is preferably a nitrogen atom or an oxygen atom.

Specific examples of the ring in the heterocyclic group include a furan ring, a thiophene ring, a benzofuran ring, a benzothiophene ring, a dibenzofuran ring, a dibenzothiophene ring, a pyridine ring, a piperidine ring, and a morpholine ring. Among these, a furan ring, a thiophene ring, a pyridine ring, a piperidine ring and a morpholine ring are preferred.

E may have a substituent. Examples of the substituent include an alkyl group (may be linear, branched or cyclic; preferably having a carbon number of 1 to 12), a cycloalkyl group (may be monocyclic, polycyclic or spirocyclic; preferably having a carbon number of 3 to 20), an aryl group (preferably having a carbon number of 6 to 14), a hydroxy group, an alkoxy group, an ester group, an amido group, a urethane group, a ureido group, a thioether group, a sulfonamido group, and a sulfonic acid ester group. In E, the carbon constituting the ring (the carbon contributing to ring formation) may be a carbonyl carbon.

Examples of the sulfonate anion represented by formula (SA1) or (SA2) include the followings.

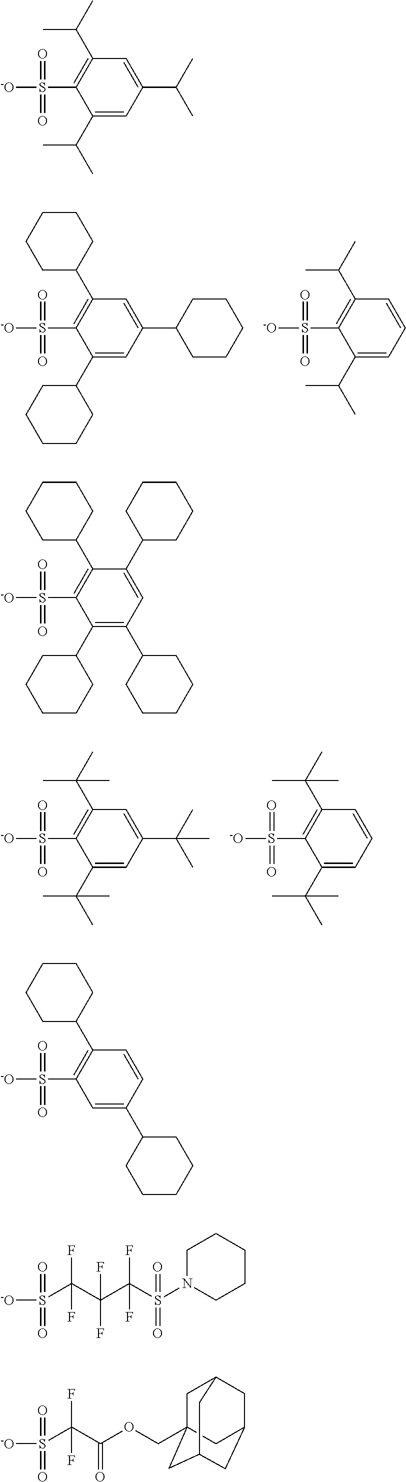

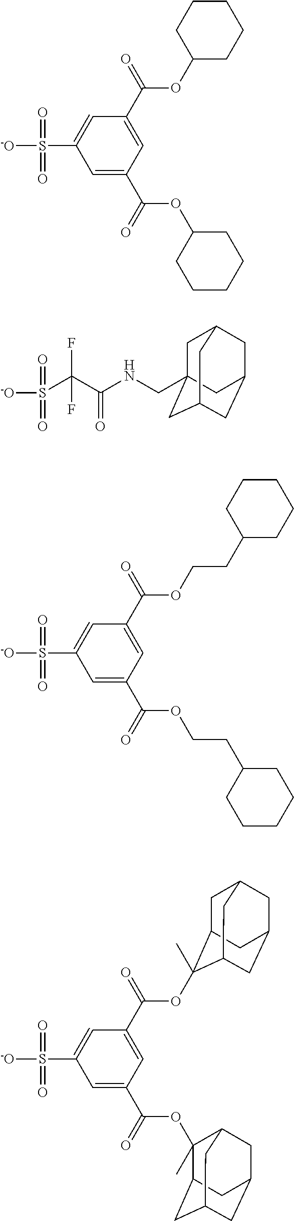

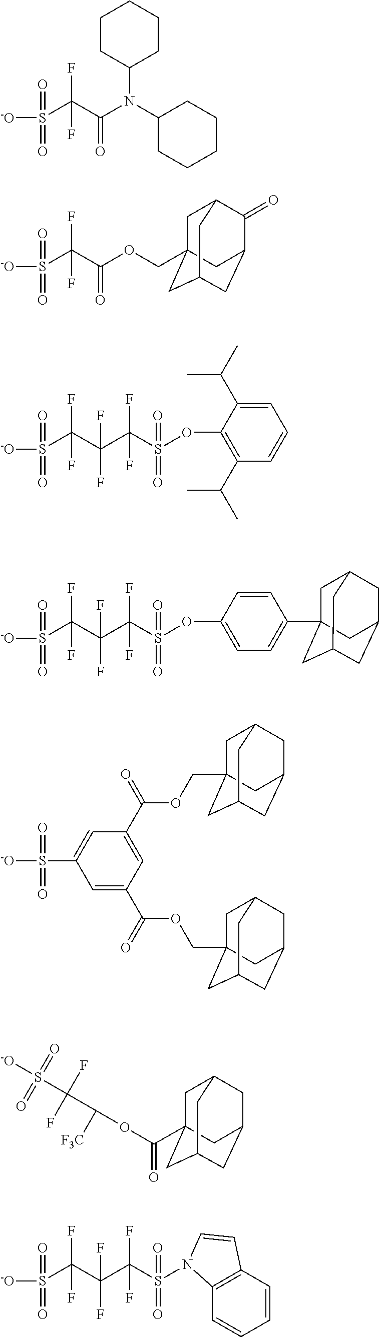

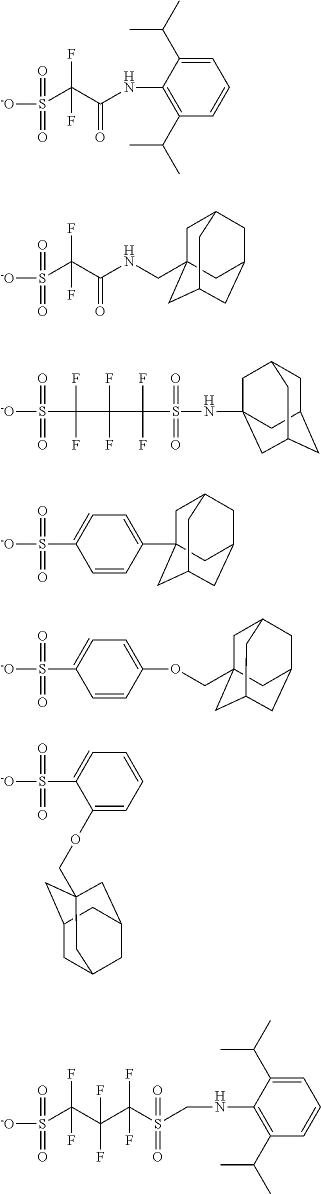

As the photoacid generator, a compound having a plurality of structures represented by formula (ZI) may be used. For example, the photoacid generator may be a compound having a structure where at least one of R₂₀₁ to R₂₀₃ in a compound represented by formula (ZI) is bonded to at least one of R₂₀₁ to R₂₀₃ in another compound represented by formula (ZI).

Compounds (ZI-1) to (ZI-4) described below are more preferred as the component (ZI).

The compound (ZI-1) is a compound where at least one of R₂₀₁ to R₂₀₃ in formula (ZI) is an aryl group. In other words, the compound (ZI-1) is an arylsulfonium compound, that is, a compound having an arylsulfonium as the cation.

In the compound (ZI-1), all of R₂₀₁ to R₂₀₃ may be an aryl group or a part of R₂₀₁ to R₂₀₃ may be an aryl group with the remaining being an alkyl group. Incidentally, in the case where the compound (ZI-1) has a plurality of aryl groups, each aryl group may be the same as or different from every other aryl group.

Examples of the compound (ZI-1) include a triarylsulfonium compound, a diarylalkylsulfonium compound, and an aryldialkylsulfonium compound.

The aryl group in the compound (ZI-1) is preferably a phenyl group, a naphthyl group or a heteroaryl group such as indole residue and pyrrole residue, more preferably a phenyl group, a naphthyl group or an indole residue.

The alkyl group which is contained, if desired, in the compound (ZI-1) is preferably a linear, branched or cyclo-alkyl group having a carbon number of 1 to 15, and examples thereof include a methyl group, an ethyl group, a propyl group, an n-butyl group, a sec-butyl group, a tert-butyl group, a cyclopropyl group, a cyclobutyl group, and a cyclohexyl group.

These aryl and alkyl groups may have a substituent. Examples of the substituent include an alkyl group (preferably having a carbon number of 1 to 15), an aryl group (preferably having a carbon number of 6 to 14), an alkoxy group (preferably having a carbon number of 1 to 15), a halogen atom, a hydroxyl group, and a phenylthio group.

The substituent is preferably a linear, branched or cyclic alkyl group having a carbon number of 1 to 12 or a linear, branched or cyclic alkoxy group having a carbon number of 1 to 12, more preferably an alkyl group having a carbon number of 1 to 6 or an alkoxy group having a carbon number of 1 to 6. The substituent may be substituted on any one of three members R₂₀₁ to R₂₀₃ or may be substituted on all of these three members. In the case where R₂₀₁ to R₂₀₃ are a phenyl group, the substituent is preferably substituted at the p-position of the aryl group.

An embodiment where one or two of R₂₀₁, R₂₀₂ and R₂₀₃ are an aryl group which may have a substituent and the remaining groups are a linear, branched or cyclic alkyl group is also preferred. Specific examples of this structure include structures described in paragraphs 0141 to 0153 of JP-A-2004-210670.

At this time, the aryl group above is specifically the same as the aryl group of R₂₀₁, R₂₀₂ and R₂₀₃ and is preferably a phenyl group or a naphthyl group. The aryl group preferably has, as a substituent, any of a hydroxyl group, an alkoxy group and an alkyl group. The substituent is more preferably an alkoxy group having a carbon number of 1 to 12, still more preferably an alkoxy group having a carbon number of 1 to 6.

The linear, branched or cyclic alkyl group as the remaining group is preferably an alkyl group having a carbon number of 1 to 6. Such a group may further have a substituent. Also, in the case where two groups are present as the remaining group, these two groups may combine with each other to form a ring structure.

The compound (ZI-1) is, for example, a compound represented by the following formula (ZI-1A):

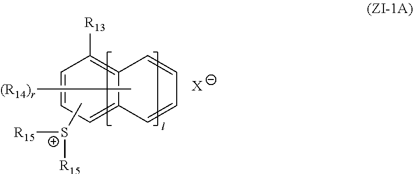

In formula (ZI-1A), R₁₃ represents a hydrogen atom, a fluorine atom, a hydroxyl group, an alkyl group, a cycloalkyl group, an alkoxy group, a cycloalkyloxy group or an alkoxycarbonyl group.

R₁₄ represents, when a plurality of R₁₄ are present, each independently represents, an alkyl group, a cycloalkyl group, an alkoxy group, an alkylsulfonyl group or a cycloalkylsulfonyl group.

Each R₁₅ independently represents an alkyl group or a cycloalkyl group, and two R₁₅ may combine with each other to form a ring structure.

l represents an integer of 0 to 2.

r represents an integer of 0 to 8.

X⁻ represents a non-nucleophilic anion, and examples thereof are the same as those for X⁻ in formula (ZI).

The alkyl group of R₁₃, R₁₄ and R₁₅ may be a linear alkyl group or a branched alkyl group. This alkyl group is preferably an alkyl group having a carbon number of 1 to 10, and examples thereof include a methyl group, an ethyl group, an n-propyl group, an i-propyl group, an n-butyl group, a 2-methylpropyl group, a 1-methylpropyl group, a tert-butyl group, an n-pentyl group, a neopentyl group, an n-hexyl group, an n-heptyl group, an n-octyl group, a 2-ethylhexyl group, an n-nonyl group, and an n-decyl group. Among these, a methyl group, an ethyl group, an n-butyl group and a tert-butyl group are preferred.

The cycloalkyl group of R₁₃, R₁₄ and R₁₅ includes a monocyclic or polycyclic cycloalkyl group (preferably a cycloalkyl group having a carbon number of 3 to 20), and examples thereof include a cyclopropyl group, a cyclobutyl group, a cyclopentyl group, a cyclohexyl group, a cycloheptyl group, a cyclooctyl group, a cyclododecanyl group, a cyclopentenyl group, a cyclohexenyl group, and a cyclooctadienyl group. Among these, a cyclopropyl group, a cyclopentyl group, a cyclohexyl group, a cycloheptyl group and a cyclooctyl are preferred.

Examples of the alkyl group moiety in the alkoxy group of R₁₃ or R₁₄ include those recited above as the alkyl group of R₁₃, R₁₄ or R₁₅. The alkoxy group is preferably a methoxy group, an ethoxy group, an n-propoxy group or an n-butoxy group.

Examples of the cycloalkyl group moiety in the cycloalkyloxy group of R₁₃ include those recited above as the cycloalkyl group of R₁₃, R₁₄ or R₁₅. The cycloalkyloxy group is preferably a cyclopentyloxy group or a cyclohexyloxy group.

Examples of the alkoxy group moiety in the alkoxycarbonyl group of R₁₃ include those recited above as the alkoxy group of R₁₃ or R₁₄. The alkoxycarbonyl group is preferably a methoxycarbonyl group, an ethoxycarbonyl group or an n-butoxycarbonyl group.

Examples of the alkyl group moiety in the alkylsulfonyl group of R₁₄ include those recited above as the alkyl group of R₁₃, R₁₄ or R₁₅. Examples of the cycloalkyl group moiety in the cycloalkylsulfonyl group of R₁₄ include those recited above as the cycloalkyl group of R₁₃, R₁₄ or R₁₅. This alkylsulfonyl or cycloalkylsulfonyl group is preferably a methanesulfonyl group, an ethanesulfonyl group, an n-propanesulfonyl group, an n-butanesulfonyl group, a cyclopentanesulfonyl group or a cyclohexanesulfonyl group.

l is preferably 0 or 1, more preferably 1. r is preferably from 0 to 2.

Each of the groups of R₁₃, R₁₄ and R₁₅ may further have a substituent. Examples of the substituent include a halogen atom such as fluorine atom, a hydroxy group, a carboxy group, a cyano group, a nitro group, an alkoxy group, a cycloalkyloxy group, an alkoxyalkyl group, a cycloalkyloxyalkyl group, an alkoxycarbonyl group, a cycloalkyloxycarbonyl group, an alkoxycarbonyloxy group, and a cycloalkyloxycarbonyloxy group.

The alkoxy group may be linear or branched. The alkoxy group includes, for example, an alkoxy group having a carbon number of 1 to 20, such as methoxy group, ethoxy group, n-propoxy group, i-propoxy group, n-butoxy group, 2-methylpropoxy group, 1-methylpropoxy group and tert-butoxy group.

The cycloalkyloxy group includes, for example, a cycloalkyloxy group having a carbon number of 3 to 20, such as cyclopentyloxy group and cyclohexyloxy group.

The alkoxyalkyl group may be linear or branched. The alkoxyalkyl group includes, for example, an alkoxyalkyl group having a carbon number of 2 to 21, such as methoxymethyl group, ethoxymethyl group, 1-methoxyethyl group, 2-methoxyethyl group, 1-ethoxyethyl group and 2-ethoxyethyl group.

The cycloalkyloxyalkyl group includes, for example, a cycloalkyloxyalkyl group having a carbon number of 4 to 21, such as cyclohexyloxymethyl group, cyclopentyloxymethyl group and cyclohexyloxyethyl group.

The alkoxycarbonyl group may be linear or branched. The alkoxycarbonyl group includes, for example, an alkoxycarbonyl group having a carbon number of 2 to 21, such as methoxycarbonyl group, ethoxycarbonyl group, n-propoxycarbonyl group, i-propoxycarbonyl group, n-butoxycarbonyl group, 2-methylpropoxycarbonyl group, 1-methylpropoxycarbonyl group and tert-butoxycarbonyl group.

The cycloalkyloxycarbonyl group includes, for example, a cycloalkyloxycarbonyl group having a carbon number of 4 to 21, such as cyclopentyloxycarbonyl group and cyclohexyloxycarbonyl group.

The alkoxycarbonyloxy group may be linear or branched. The alkoxycarbonyloxy group includes, for example, an alkoxycarbonyloxy group having a carbon number of 2 to 21, such as methoxycarbonyloxy group, ethoxycarbonyloxy group, n-propoxycarbonyloxy group, i-propoxycarbonyloxy group, n-butoxycarbonyloxy group and tert-butoxycarbonyloxy group.

The cycloalkyloxycarbonyloxy group includes, for example, a cycloalkyloxycarbonyloxy group having a carbon number of 4 to 21, such as cyclopentyloxycarbonyloxy group and cyclohexyloxycarbonyloxy group.

The ring structure which may be formed by combining two R₁₅ with each other is preferably a structure capable of forming a 5- or 6-membered ring, preferably a 5-membered ring (that is, a tetrahydrothiophene ring), together with the S atom in formula (ZI-1A).

The ring structure may further have a substituent. Examples of the substituent include a hydroxy group, a carboxy group, a cyano group, a nitro group, an alkoxy group, an alkoxyalkyl group, an alkoxycarbonyl group, and an alkoxycarbonyloxy group.

R₁₅ is preferably a methyl group, an ethyl group, or a divalent group capable of forming a tetrahydrothiophene ring structure together with the sulfur atom when two R₁₅ are combined with each other.

The alkyl group, cycloalkyl group, alkoxy group and alkoxycarbonyl group of R₁₃ and the alkyl group, cycloalkyl group, alkoxy group, alkylsulfonyl group and cycloalkylsulfonyl group of R₁₄ may further have a substituent. The substituent is preferably a hydroxy group, an alkoxy group, an alkoxycarbonyl group or a halogen atom (particularly a fluorine atom).

Specific preferred examples of the cation in the compound represented by formula (ZI-1A) are illustrated below.

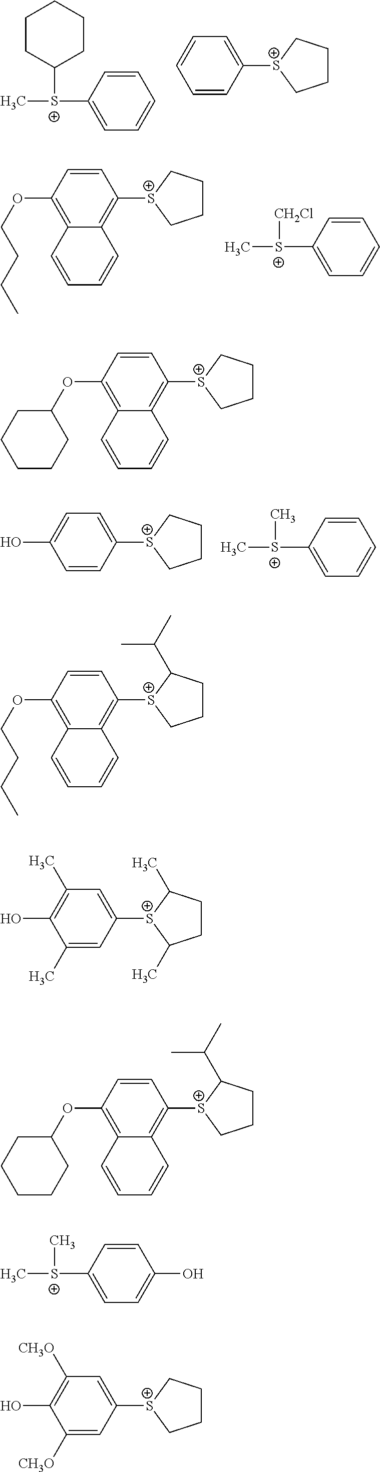

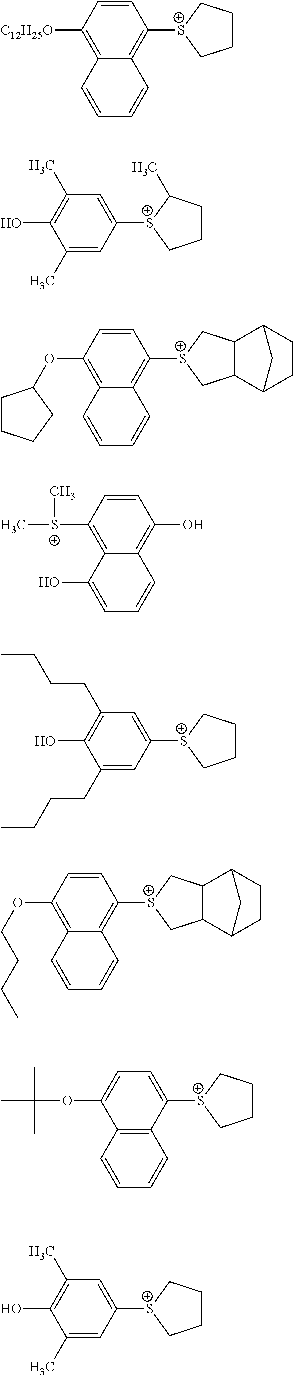

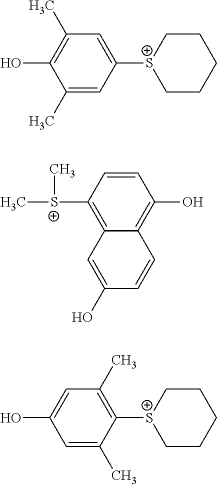

The compound (ZI-2) is described below.

The compound (ZI-2) is a compound where each of R₂₀₁ to R₂₀₃ in formula (ZI) independently represents an aromatic ring-free organic group. The aromatic ring as used herein encompasses an aromatic ring containing a heteroatom.

The aromatic ring-free organic group as R₂₀₁ to R₂₀₃ has a carbon number of, for example, from 1 to 30, preferably from 1 to 20.

Each of R₂₀₁ to R₂₀₃ independently represents preferably an alkyl group, a 2-oxoalkyl group, an alkoxycarbonylmethyl group, an allyl group or a vinyl group, more preferably a linear, branched or cyclic 2-oxoalkyl group or an alkoxycarbonylmethyl group, still more preferably a linear or branched 2-oxoalkyl group.

The alkyl group as R₂₀₁ to R₂₀₃ may be linear, branched or cyclic, and preferred examples thereof include a linear or branched alkyl group having a carbon number of 1 to 10 (e.g., methyl group, ethyl group, propyl group, butyl group, pentyl group) and a cycloalkyl group having a carbon number of 3 to 10 (e.g., cyclopentyl group, cyclohexyl group, norbornyl group).

The 2-oxoalkyl group as R₂₀₁ to R₂₀₃ may be linear, branched or cyclic and is preferably a group having >C═O at the 2-position of the above-described alkyl group.

Preferred examples of the alkoxy group in the alkoxycarbonylmethyl group as R₂₀₁ to R₂₀₃ include an alkoxy group having a carbon number of 1 to 5 (e.g., methoxy, ethoxy, propoxy, butoxy, pentoxy).

Each of R₂₀₁ to R₂₀₃ may be further substituted, for example, with a halogen atom, an alkoxy group (for example, having a carbon number of 1 to 5), a hydroxyl group, a cyano group and/or a nitro group.

Two members out of R₂₀₁ to R₂₀₃ may combine with each other to form a ring structure. This ring structure may contain an oxygen atom, a sulfur atom, an ester bond, an amide bond and/or a carbonyl group in the ring. Examples of the group formed by combining two members out of R₂₀₁ to R₂₀₃ include an alkylene group (e.g., butylenes group, pentylene group).

The compound (ZI-3) is described below.

The compound (ZI-3) is a compound represented by the following formula (ZI-3), and this is a compound having a phenacylsulfonium salt structure.

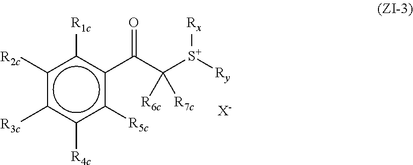

In formula (ZI-3), each of R_{1c} to R_{5c} independently represents a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group or an arylthio group.

Each of R_{6c} and R_{7c} independently represents a hydrogen atom, an alkyl group, a cycloalkyl group, a halogen atom, a cyano group or an aryl group.

Each of Rₓ and R_{y} independently represents an alkyl group, a cycloalkyl group, a 2-oxoalkyl group, a 2-oxocycloalkyl group, an alkoxycarbonylalkyl group, an allyl group or a vinyl group.

Any two or more members out of R_{1c} to R_{5c}, a pair of R₅ₛ and R_{6c}, a pair of R_{6c} and R_{7c}, a pair of R₅ₑ and Rₓ, or a pair of Rₓ and R_{y} may combine with each other to form a ring structure. This ring structure may contain an oxygen atom, a sulfur atom, a ketone group, an ester bond or an amide bond.

The ring structure above includes an aromatic or non-aromatic hydrocarbon ring, an aromatic or non-aromatic heterocyclic ring, and a polycyclic condensed ring formed by combining two or more of these rings. The ring structure includes a 3- to 10-membered ring and is preferably a 4- to 8-membered ring, more preferably a 5- or 6-membered ring.

Examples of the group formed by combining any two or more members of R_{1c} to R_{5c}, a pair of R_{6c} and R_{7c}, or a pair of Rₓ and R_{y} include a butylene group and a pentylene group.

The group formed by combining a pair of R₅ₛ and R_{6c} or a pair of R₅ₛ and Rₓ is preferably a single bond or an alkylene group, and examples of the alkylene group include a methylene group and an ethylene group.

X⁻ represents a non-nucleophilic anion, and examples thereof are the same as those of the non-nucleophilic anion of X⁻ in formula (ZI).

The alkyl group as R_{1c} to R_{7c} may be either linear or branched and is, for example, an alkyl group having a carbon number of 1 to 20, preferably a linear or branched alkyl group having a carbon number of 1 to 12 (such as methyl group, ethyl group, linear or branched propyl group, linear or branched butyl group, or linear or branched pentyl group). The cycloalkyl group includes, for example, a cycloalkyl group having a carbon number of 3 to 10 (such as cyclopentyl group and cyclohexyl group).

The aryl group as R_{1c} to R_{7c} is preferably an aryl group having a carbon number of 5 to 15, and examples thereof include a phenyl group and a naphthyl group.

The alkoxy group as R_{1c} to R_{5c} may be linear, branched or cyclic and is, for example, an alkoxy group having a carbon number of 1 to 10, preferably a linear or branched alkoxy group having a carbon number of 1 to 5 (such as methoxy group, ethoxy group, linear or branched propoxy group, linear or branched butoxy group, or linear or branched pentoxy group), or a cyclic alkoxy group having a carbon number of 3 to 10 (such as cyclopentyloxy group or cyclohexyloxy group).

Specific examples of the alkoxy group in the alkoxycarbonyl group as R_{1c} to R_{5c} are the same as specific examples of the alkoxy group of R_{1c} to R_{5c}.

Specific examples of the alkyl group in the alkylcarbonyloxy group and alkylthio group as R_{1c} to R_{5c} are the same as specific examples of the alkyl group of R_{1c} to R_{5c}.

Specific examples of the cycloalkyl group in the cycloalkylcarbonyloxy group as R_{1c} to R_{5c} are the same as specific examples of the cycloalkyl group of R_{1c} to R_{5c}.

Specific examples of the aryl group in the aryloxy group and arylthio group as R_{1c} to R_{5c} are the same as specific examples of the aryl group of R_{1c} to R_{5c}.

A compound where any one of R_{1c} to R_{5c} is a linear or branched alkyl group, a cycloalkyl group or a linear, branched or cyclic alkoxy group is preferred, and a compound where the sum of carbon numbers of R_{1c} to R_{5c} is from 2 to 15 is more preferred. Thanks to such a configuration, the solvent solubility is more enhanced and production of particles during storage can be suppressed.

The ring structure which may be formed by combining any two or more members of R_{1c} to R_{5c} with each other is preferably a 5- or 6-membered ring, more preferably a 6-membered ring (such as phenyl ring).

The ring structure which may be formed by combining R_{5c} and R_{6c} with each other includes a 4-membered or higher membered ring (preferably a 5- or 6-membered ring) formed together with the carbonyl carbon atom and carbon atom in formula (ZI-3) by combining R_{5c} and R_{6c} with each other to constitute a single bond or an alkylene group (such as methylene group or ethylene group).

An embodiment where both of R_{6c} and R_{7c} are an alkyl group is preferred, an embodiment where each of R_{6c} and R_{7c} is a linear or branched alkyl group having a carbon number of 1 to 4 is more preferred, and an embodiment where both are a methyl group is still more preferred.

In the case where R_{6c} and R_{7c} are combined to form a ring, the group formed by combining R_{6c} and R_{7c} is preferably an alkylene group having a carbon number of 2 to 10, and examples thereof include an ethylene group, a propylene group, a butylene group, a pentylene group, and a hexylene group. Also, the ring formed by combining R₆% and R_{7c} may contain a heteroatom such as oxygen atom in the ring.

Examples of the alkyl group and cycloalkyl group as Rₓ and R_{y} are the same as those of the alkyl group and cycloalkyl group of R_{1c} to R_{7c}.

Examples of the 2-oxoalkyl group and 2-oxocycloalkyl group as Rₓ and R_{y} include a group having >C═O at the 2-position of the alkyl group or cycloalkyl group as R_{1c} to R_{7c}.

Examples of the alkoxy group in the alkoxycarbonylalkyl group as Rₓ and R_{y} are the same as those of the alkoxy group of R_{1c} to R_{5c}. The alkyl group is, for example, an alkyl group having a carbon number of 1 to 12, preferably a linear alkyl group having a carbon number of 1 to 5 (such as methyl group or ethyl group).

The allyl group as Rₓ and R_{y} is not particularly limited but is preferably an unsubstituted allyl group or an allyl group substituted with a monocyclic or polycyclic cycloalkyl group (preferably a cycloalkyl group having a carbon number of 3 to 10).

The vinyl group as Rₓ and R_{y} is not particularly limited but is preferably an unsubstituted vinyl group or a vinyl group substituted with a monocyclic or polycyclic cycloalkyl group (preferably a cycloalkyl group having a carbon number of 3 to 10).

The ring structure which may be formed by combining R_{5c} and Rₓ with each other includes a 5-membered or higher membered ring (preferably a 5-membered ring) formed together with the sulfur atom and carbonyl carbon atom in formula (I) by combining R_{5c} and Rₓ with each other to constitute a single bond or an alkylene group (such as methylene group or ethylene group).

The ring structure which may be formed by combining Rₓ and R_{y} with each other includes a 5- or 6-membered ring, preferably a 5-membered ring (that is, tetrahydrothiophene ring), formed by divalent Rₓ and R_{y} (for example, a methylene group, an ethylene group or a propylene group) together with the sulfur atom in formula (ZI-3).

Each of Rₓ and R_{y} is preferably an alkyl or cycloalkyl group having a carbon number of 4 or more, more preferably 6 or more, still more preferably 8 or more.

Each of R_{1c} to R_{7c}, Rₓ and R_{y} may further have a substituent, and examples of such a substituent include a halogen atom (e.g., fluorine atom), a hydroxyl group, a carboxyl group, a cyano group, a nitro group, an alkyl group, a cycloalkyl group, an aryl group, an alkoxy group, an aryloxy group, an acyl group, an arylcarbonyl group, an alkoxyalkyl group, an aryloxyalkyl group, an alkoxycarbonyl group, an aryloxycarbonyl group, an alkoxycarbonyloxy group, and an aryloxycarbonyloxy group.

The alkyl group above includes, for example, a linear or branched alkyl group having a carbon number of 1 to 12, such as methyl group, ethyl group, n-propyl group, i-propyl group, n-butyl group, 2-methylpropyl group, 1-methylpropyl group and tert-butyl group.

The cycloalkyl group above includes, for example, a cycloalkyl group having a carbon number of 3 to 10, such as cyclopentyl group and cyclohexyl group.

The aryl group above includes, for example, an aryl group having a carbon number of 6 to 15, such as phenyl group and naphthyl group.

The alkoxy group above includes, for example, a linear, branched or cyclic alkoxy group having a carbon number of 1 to 20, such as methoxy group, ethoxy group, n-propoxy group, i-propoxy group, n-butoxy group, 2-methylpropoxy group, 1-methylpropoxy group, tert-butoxy group, cyclopentyloxy group and cyclohexyloxy group.

The aryloxy group above includes, for example, an aryloxy group having a carbon number of 6 to 10, such as phenyloxy group and naphthyloxy group.

The acyl group above includes, for example, a linear or branched acyl group having a carbon number of 2 to 12, such as acetyl group, propionyl group, n-butanoyl group, i-butanoyl group, n-heptanoyl group, 2-methylbutanoyl group, 1-methylbutanoyl group and tert-heptanoyl group.

The arylcarbonyl group above includes, for example, an arylcarbonyl group having a carbon number of 6 to 10, such as phenylcarbonyl group and naphthylcarbonyl group.

The alkoxyalkyl group above includes, for example, a linear, branched or cyclic alkoxyalkyl group having a carbon number of 2 to 21, such as methoxymethyl group, ethoxymethyl group, 1-methoxyethyl group, 2-methoxyethyl group, 1-ethoxyethyl group and 2-ethoxyethyl group.

The aryloxyalkyl group above includes, for example, an aryloxyalkyl group having a carbon number of 7 to 12, such as phenyloxymethyl group, phenyloxyethyl group, naphthyloxymethyl group and naphthyloxyethyl group.

The alkoxycarbonyl group above includes, for example, a linear, branched or cyclic alkoxycarbonyl group having a carbon number of 2 to 21, such as methoxycarbonyl group, ethoxycarbonyl group, n-propoxycarbonyl group, i-propoxycarbonyl group, n-butoxycarbonyl group, 2-methylpropoxycarbonyl group, 1-methylpropoxycarbonyl group, tert-butoxycarbonyl group, cyclopentyloxycarbonyl group and cyclohexyloxycarbonyl group.

The aryloxycarbonyl group above includes, for example, an aryloxycarbonyl group having a carbon number of 7 to 11, such as phenyloxycarbonyl group and naphthyloxycarbonyl group.

The alkoxycarbonyloxy group above includes, for example, a linear, branched or cyclic alkoxycarbonyloxy group having a carbon number of 2 to 21, such as methoxycarbonyloxy group, ethoxycarbonyloxy group, n-propoxycarbonyloxy group, i-propoxycarbonyloxy group, n-butoxycarbonyloxy group, tert-butoxycarbonyloxy group, cyclopentyloxycarbonyloxy group and cyclohexyloxycarbonyloxy group. The aryloxycarbonyloxy group above includes, for example, an aryloxycarbonyloxy group having a carbon number of 7 to 11, such as phenyloxycarbonyloxy group and naphthyloxycarbonyloxy group.

In formula (ZI-3), it is more preferred that each of R_{1c}, R_{2c}, R_{4c} and R_{5c} independently represents a hydrogen atom and R_{3c} represents a group except for a hydrogen atom, that is, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group or an arylthio group.

Specific examples of the compound (ZI-3) include compounds illustrated in paragraphs 0047 and 0048 of JP-A-2004-233661 and paragraphs 0040 to 0046 of JP-A-2003-35948.

The compound (ZI-4) is described below.

The compound (ZI-4) is a compound having a cation represented by the following formula (ZI-4). The compound (ZI-4) is effective to suppress outgassing.

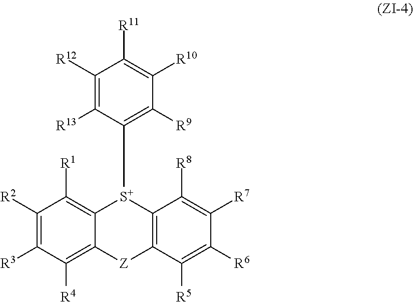

In formula (ZI-4), each of R¹ to R¹³ independently represents a hydrogen atom or a substituent, and at least one of R¹ to R¹³ is preferably a substituent containing an alcoholic hydroxyl group. The “alcoholic hydroxyl group” as used herein means a hydroxyl group bonded to a carbon atom of an alkyl group.

Z represents a single bond or a divalent linking group.

In the case where R¹ to R¹³ are a substituent containing an alcoholic hydroxyl group, each of R¹ to R¹³ is preferably a group represented by —(W—Y), wherein Y is an alkyl group substituted with a hydroxyl group and W is a single bond or a divalent linking group.

Preferred examples of the alkyl group represented by Y include an ethyl group, a propyl group and an isopropyl group. In particular, Y preferably contains a structure represented by —CH₂CH₂OH.

The divalent linking group represented by W is not particularly limited but is preferably a single bond or a divalent group formed by substituting a single bond for an arbitrary hydrogen atom in an alkoxyl group, an acyloxy group, an acylamino group, an alkyl- or aryl-sulfonylamino group, an alkylthio group, an alkylsulfonyl group, an acyl group, an alkoxycarbonyl group or a carbamoyl group, more preferably a single bond or a divalent group formed by substituting a single bond for an arbitrary hydrogen atom in an acyloxy group, an alkylsulfonyl group, an acyl group or an alkoxycarbonyl group.

In the case where R¹ to R¹³ are a substituent containing an alcoholic hydroxyl group, the number of carbons contained therein is preferably from 2 to 10, more preferably from 2 to 6, still more preferably from 2 to 4.

The alcoholic hydroxyl group-containing substituent as R¹ to R¹³ may have two or more alcoholic hydroxyl groups. The number of alcoholic hydroxyl groups in the alcoholic hydroxyl group-containing substituent as R¹ to R¹³ is from 1 to 6, preferably from 1 to 3, more preferably 1.

The number of alcoholic hydroxyl groups in the compound represented by formula (ZI-4) is, including all of R¹ to R¹³, from 1 to 10, preferably from 1 to 6, more preferably from 1 to 3.

In the case where R¹ to R¹³ are free of an alcoholic hydroxyl group, examples of the substituent as R¹ to R¹³ include a halogen atom, an alkyl group, a cycloalkyl group, an alkenyl group, a cycloalkenyl group, an alkynyl group, an aryl group, a heterocyclic group, a cyano group, a nitro group, a carboxy group, an alkoxy group, an aryloxy group, a silyloxy group, a heterocyclic oxy group, an acyloxy group, a carbamoyloxy group, an alkoxycarbonyloxy group, an aryloxycarbonyloxy group, an amino group (including an anilino group), an ammonio group, an acylamino group, an aminocarbonylamino group, an alkoxycarbonylamino group, an aryloxycarbonylamino group, a sulfamoylamino group, an alkyl- or aryl-sulfonylamino group, a mercapto group, an alkylthio group, an arylthio group, a heterocyclic thio group, a sulfamoyl group, a sulfo group, an alkyl- or aryl-sulfinyl group, an alkyl- or aryl-sulfonyl group, an acyl group, an aryloxycarbonyl group, an alkoxycarbonyl group, a carbamoyl group, an aryl- or heterocyclic azo group, an imido group, a phosphino group, a phosphinyl group, a phosphinyloxy group, a phosphinylamino group, a phosphono group, a silyl group, a hydrazino group, a ureido group, a boronic acid group [—B(OH)₂], a phosphato group [—OPO(OH)₂], a sulfato group (—OSO₃H), and other known substituents.

In the case where R¹ to R¹³ are free of an alcoholic hydroxyl group, each of R¹ to R¹³ is preferably a hydrogen atom, a halogen atom, an alkyl group, a cycloalkyl group, an alkenyl group, a cycloalkenyl group, an alkynyl group, an aryl group, a cyano group, a carboxy group, an alkoxy group, an aryloxy group, an acyloxy group, a carbamoyloxy group, an acylamino group, an aminocarbonylamino group, an alkoxycarbonylamino group, an aryloxycarbonylamino group, a sulfamoylamino group, an alkyl- or aryl-sulfonylamino group, an alkylthio group, an arylthio group, a sulfamoyl group, an alkyl- or aryl-sulfonyl group, an aryloxycarbonyl group, an alkoxycarbonyl group, a carbamoyl group, an imido group, a silyl group or a ureido group.

In the case where R¹ to R¹³ are free of an alcoholic hydroxyl group, each of R¹ to R¹³ is more preferably a hydrogen atom, a halogen atom, an alkyl group, a cycloalkyl group, a cyano group, an alkoxy group, an acyloxy group, an acylamino group, an aminocarbonylamino group, an alkoxycarbonylamino group, an alkyl- or aryl-sulfonylamino group, an alkylthio group, a sulfamoyl group, an alkyl- or aryl-sulfonyl group, an alkoxycarbonyl group or a carbamoyl group.

In the case where R¹ to R¹³ are free of an alcoholic hydroxyl group, each of R¹ to R¹³ is still more preferably a hydrogen atom, an alkyl group, a cycloalkyl group, a halogen atom or an alkoxy group.

Two adjacent members out of R¹ to R¹³ may combine with each other to form a ring.

This structure ring includes an aromatic or non-aromatic hydrocarbon ring and a heterocyclic ring. These rings may further combine to form a condensed ring.

The compound (ZI-4) preferably has a structure where at least one of R¹ to R¹³ contains an alcoholic hydroxyl group, more preferably a structure where at least one of R⁹ to R¹³ contains an alcoholic hydroxyl group.

Z represents, as described above, a single bond or a divalent linking group. Examples of the divalent linking group include an alkylene group, an arylene group, a carbonyl group, a sulfonyl group, a carbonyloxy group, a carbonylamino group, a sulfonylamide group, an ether group, a thioether group, an amino group, a disulfide group, an acyl group, an alkylsulfonyl group, —CH═CH—, an aminocarbonylamino group, and an aminosulfonylamino group.

The divalent linking group may have a substituent. Examples of the substituent thereon are the same as those recited for R¹ to R¹³.

Z is preferably a single bond or a non-electron-withdrawing bond or group such as alkylene group, arylene group, ether group, thioether group, amino group, —CH═CH—, aminocarbonylamino group and aminosulfonylamino group, more preferably a single bond, an ether group or a thioether group, still more preferably a single bond.

Formulae (ZII) and (ZIII) are described below.

In formulae (ZII) and (ZII), each of R₂₀₄ to R₂₀₇ independently represents an aryl group, an alkyl group or a cycloalkyl group. These aryl, alkyl and cycloalkyl groups may have a substituent.

Preferred examples of the aryl group as R₂₀₄ to R₂₀₇ are the same as those recited for R₂₀₁ to R₂₀₃ in the compound (ZI-1).

Preferred examples of the alkyl group and cycloalkyl group as R₂₀₄ to R₂₀₇ include linear, branched and cyclo-alkyl groups recited for R₂₀₁ to R₂₀₃ in the compound (ZI-2).

X⁻ in formula (ZII) has the same meaning as X⁻ in formula (ZI).

Other preferred examples of the photoacid generator include compounds represented by the following formulae (ZIV), (ZV) and (ZVI):

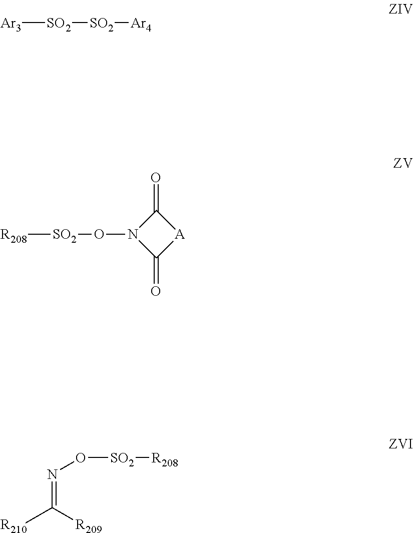

In formulae (ZIV) to (ZVI), each of Ar₃ and Ar₄ independently represents a substituted or unsubstituted aryl group.

A represents an alkylene group, an alkenylene group or an arylene group.

R₂₀₈ represents an alkyl group, a cycloalkyl group or an aryl group independently of each other between formulae (ZV) and (ZVI). These alkyl, cycloalkyl and aryl groups may or may not be substituted.

Such a group is preferably substituted with a fluorine atom. In this case, the strength of the acid generated from the photoacid generator can be enhanced.

Each of R₂₀₉ and R₂₁₀ independently represents an alkyl group, a cycloalkyl group, an aryl group or an electron-withdrawing group. These alkyl, cycloalkyl, aryl and electron-withdrawing groups may or may not be substituted.

Specific examples of the aryl group of Ar₃, Ar₄, R₂₀₈, R₂₀₉ and R₂₁₀ are the same as specific examples of the aryl group of R₂₀₁, R₂₀₂ and R₂₀₃ in formula (ZI-1).

Specific examples of the alkyl group and cycloalkyl group of R₂₀₈, R₂₀₉ and R₂₁₀ are the same as specific examples of the alkyl group and cycloalkyl group of R₂₀₁, R₂₀₂ and R₂₀₃ in formula (ZI-2).

R₂₀₉ is preferably a substituted or unsubstituted aryl group.

R₂₁₀ is preferably an electron-withdrawing group. The electron-withdrawing group is preferably a cyano group or a fluoroalkyl group.

The alkylene group of A includes an alkylene group having a carbon number of 1 to 12 (e.g., methylene group, ethylene group, propylene group, isopropylene group, butylenes group, isobutylene group); the alkenylene group of A includes an alkenylene group having a carbon number of 2 to 12 (e.g., ethenylene group, propenylene group, butenylene group); and the arylene group of A includes an arylene group having a carbon number of 6 to 10 (e.g., phenylene group, tolylene group, naphthylene group). These alkylene, alkenylene and arylene groups may have a substituent.

A compound having a plurality of structures represented by formula (ZVI) is also preferred as the photoacid generator. Examples of such a compound include a compound having a structure where R₂₀₉ or R₂₁₀ in a compound represented by formula (ZVI) is bonded to R₂₀₉ or R₂₁₀ in another compound represented by formula (ZVI).

As the photoacid generator, the compounds represented by formulae (ZI) to (ZIII) are preferred, the compound represented by formula (ZI) is more preferred, and compounds (ZI-1) to (ZI-3) are still more preferred.

As the photoacid generator for use in the present invention, a compound having an acid-decomposable group may be also preferably used. Examples of such an acid generator include compounds described in JP-A-2005-97254 and JP-A-2007-199692.

In the present invention, from the standpoint of improving the resolution or pattern profile by preventing the acid generated upon exposure from diffusing into the unexposed area, the acid generator is preferably a compound capable of generating an acid having a size of 240 Å³ or more in volume, more preferably a compound capable of generating an acid having a size of 270 Å³ or more in volume, still more preferably a compound capable of generating an acid having a size of 400 Å³ or more in volume. However, in view of sensitivity and solubility in a coating solvent, the volume above is preferably 2,000 Å³ or less, more preferably 1,500 Å³ or less. The value of this volume is determined using “WinMOPAC” produced by Fujitsu Limited. That is, first, the chemical structure of the acid according to each example is input, and next, using this structure as the initial structure, the most stable conformation of each acid is determined by molecular force field calculation using an MM3 method. Thereafter, with respect to the most stable conformation, molecular orbital calculation using a PM3 method is performed, whereby the “accessible volume” of each acid can be computed.

Examples of the acid generator particularly preferred in the present invention are illustrated below. In some of these examples, a computed value of volume (unit: Å³) is shown together. The computed value determined here is a volume value of an acid in which a proton is bonded to the anion moiety.

In the present invention, the heating temperature T_{PEB} is appropriately selected, specifically, selected to satisfy formula (1) based on the glass transition temperature of the resin (A), whereby high resolution, good pattern cross-sectional profile and high roughness performance can be satisfied all at the same time.

Here, if the volume of the acid generated from the photoacid generator upon exposure is too small, the acid may excessively diffuse into the unexposed area to deteriorate those effects, but as described above, by using a compound capable of generating an acid having a size of 240 Å³ or more in volume upon exposure, the effects of the present invention can be more unfailingly satisfied.

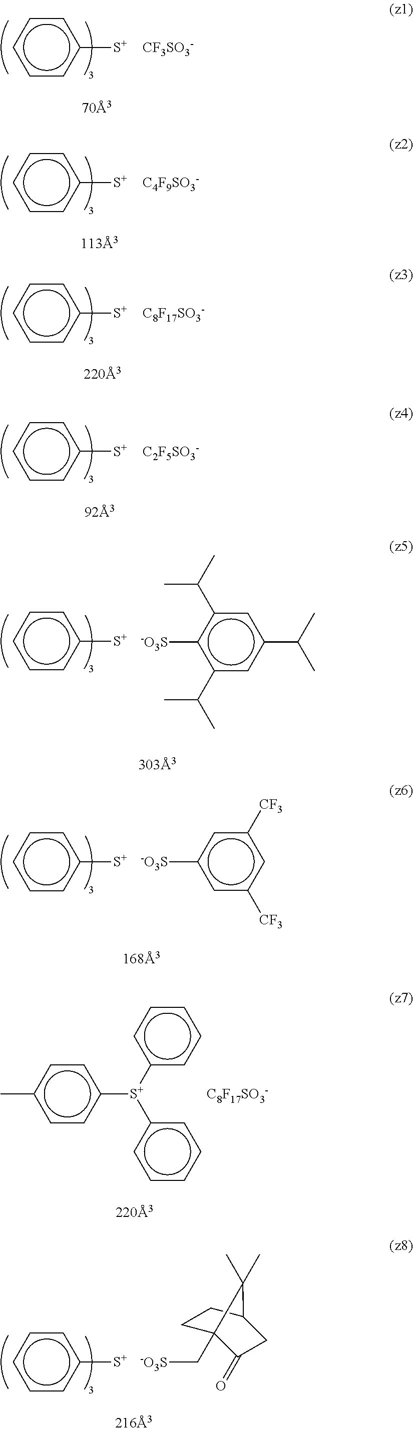

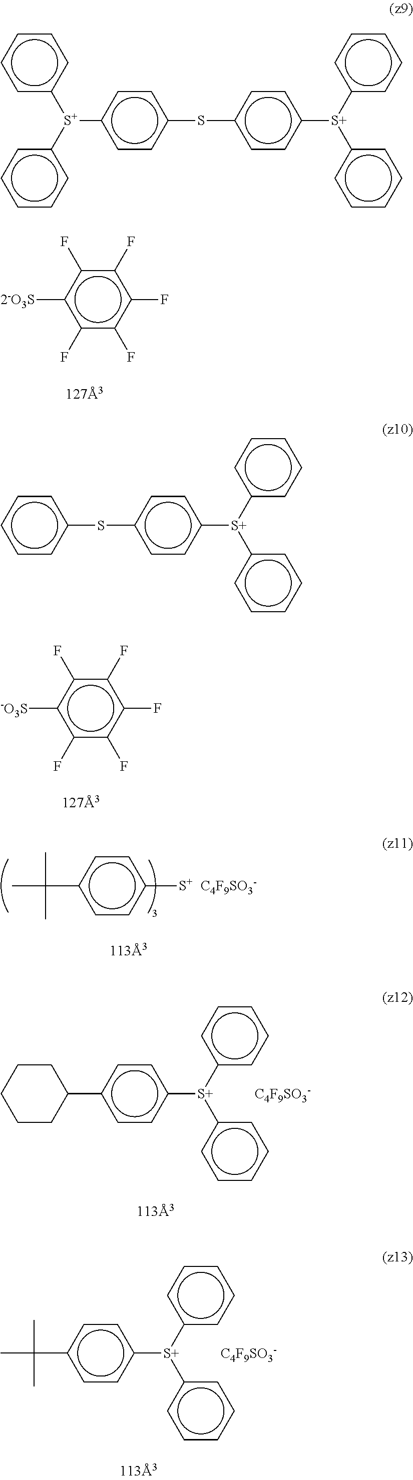

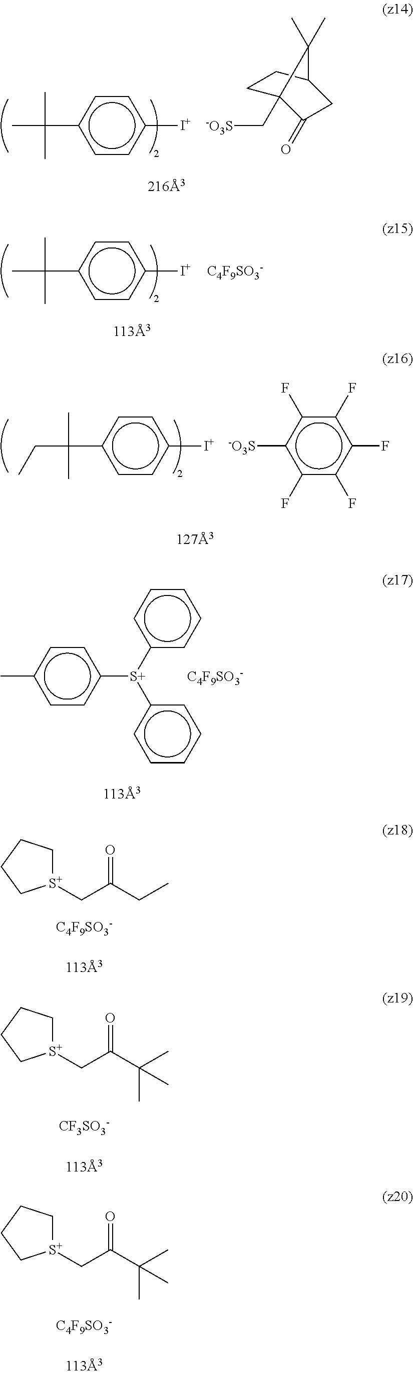

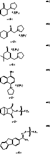

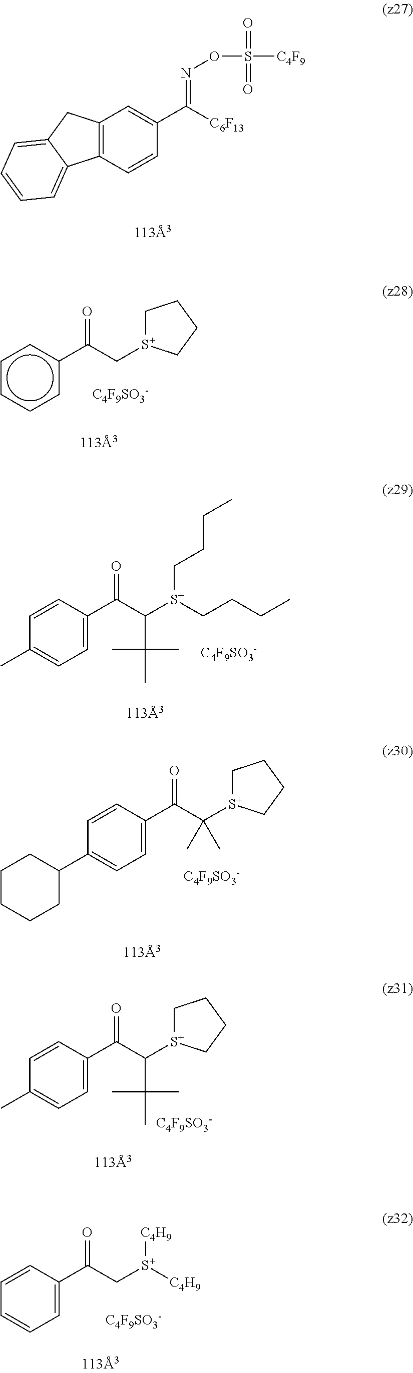

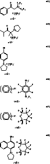

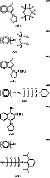

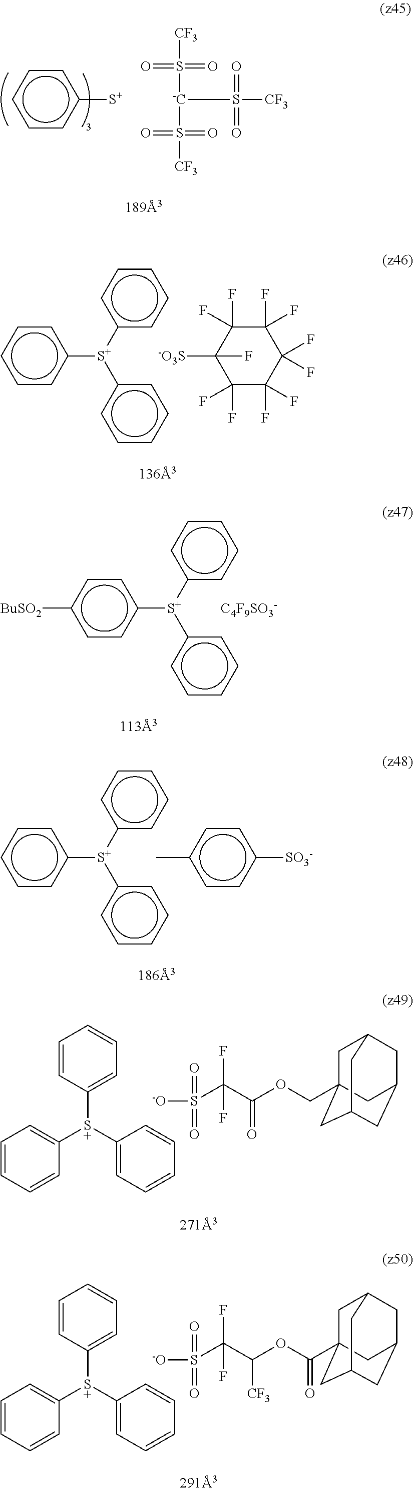

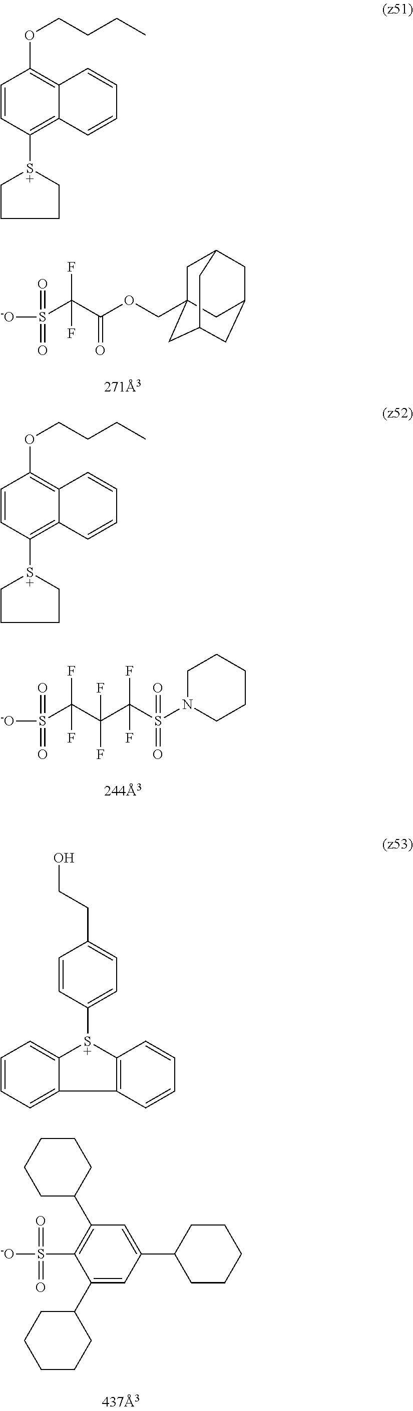

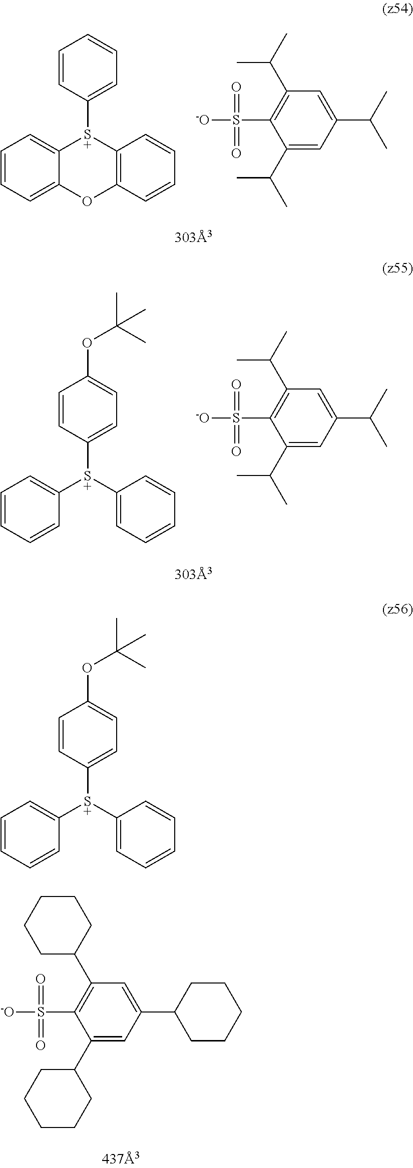

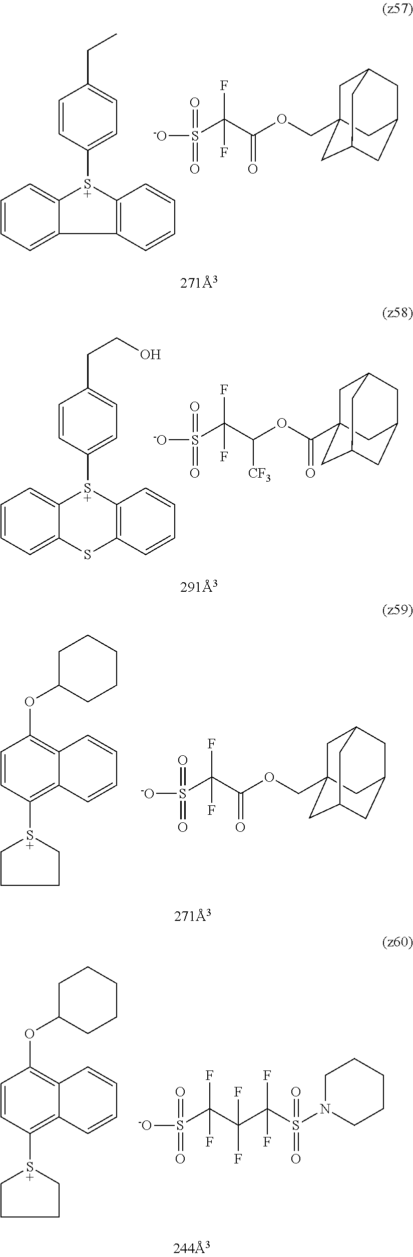

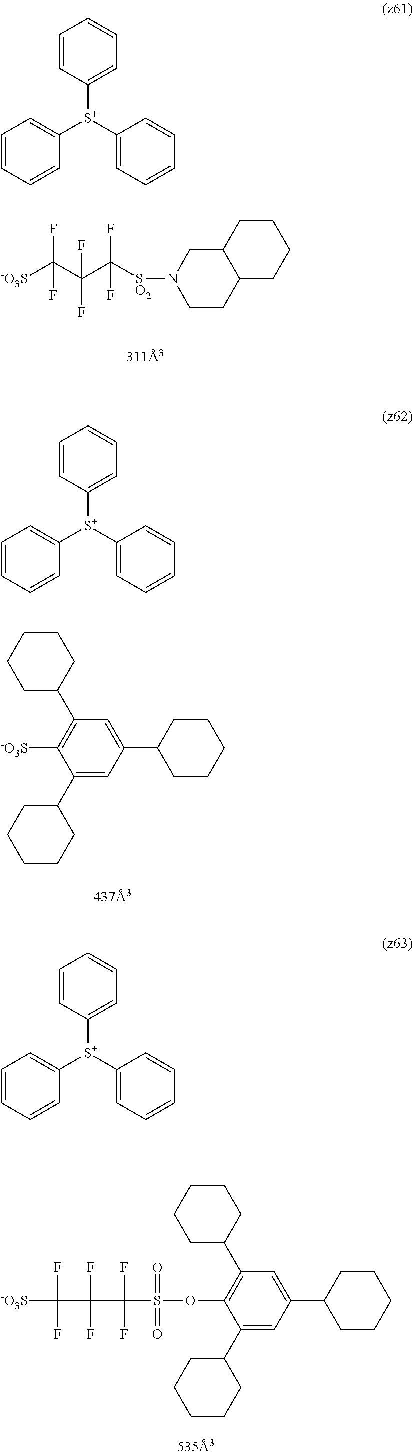

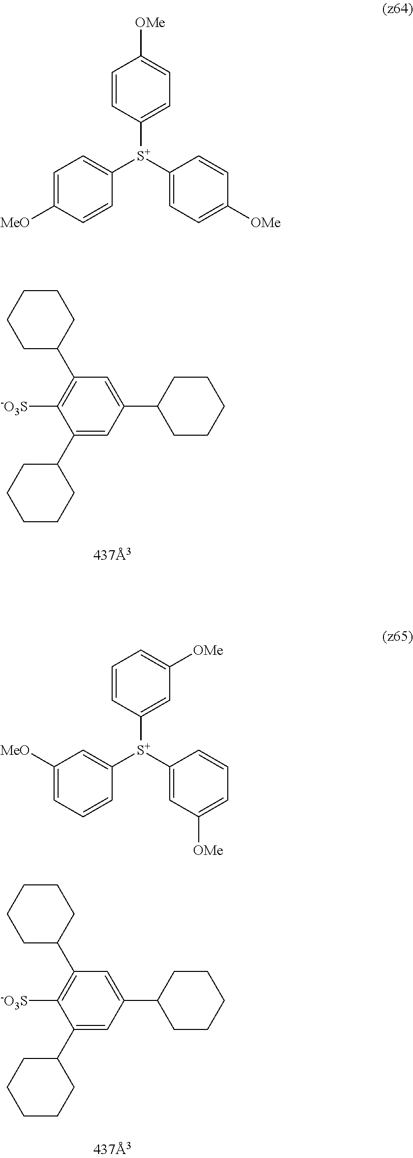

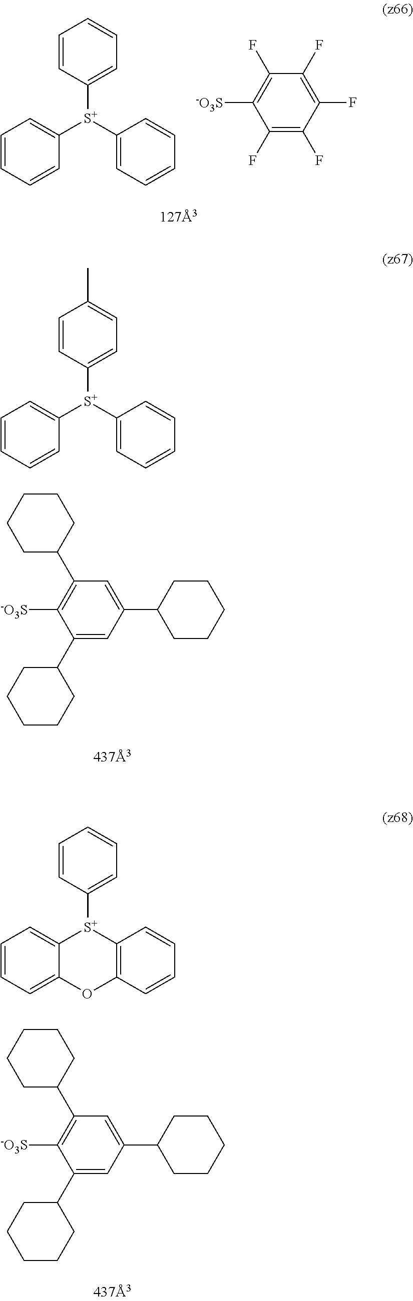

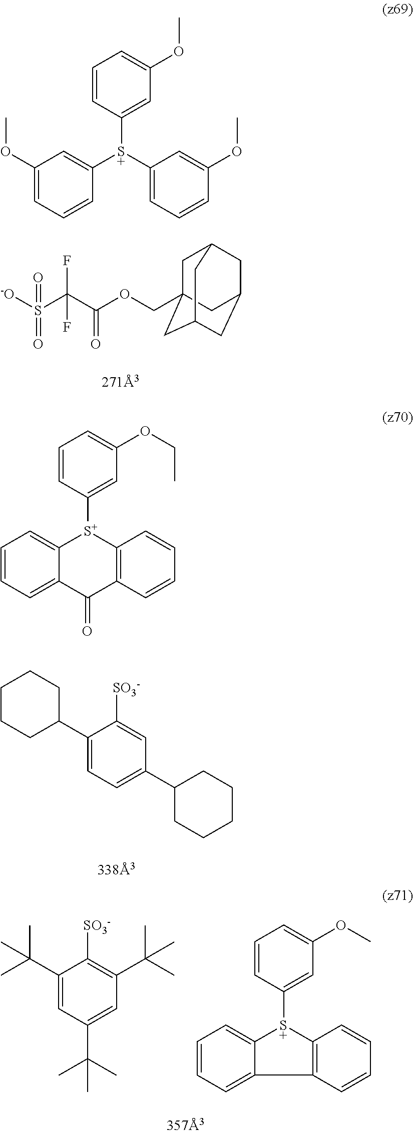

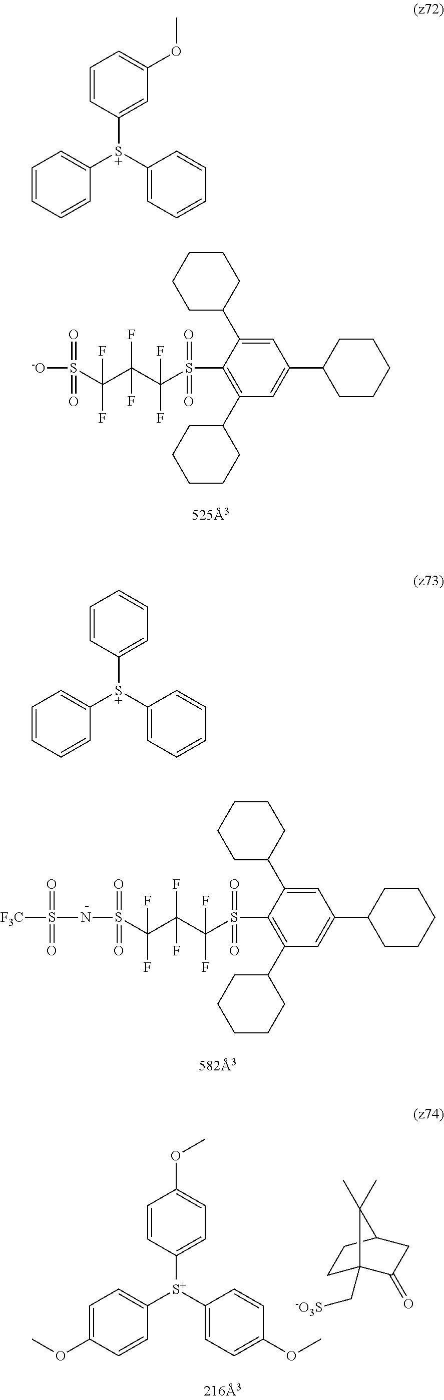

The content of the photoacid generator is preferably from 5 to 55 mass %, more preferably from 10 to 50 mass %, still more preferably from 20 to 45 mass %, based on the total solid content of the extreme ultraviolet-sensitive resin composition.

One kind of a photoacid generator may be used alone, or two or more kinds of photoacid generators may be used in combination.

### [3] Basic Compound

The extreme ultraviolet-sensitive resin composition of the present invention may further contain a basic compound. The basic compound is preferably a compound having basicity stronger than that of phenol. The basic compound is preferably an organic basic compound, more preferably a nitrogen-containing basic compound.

The nitrogen-containing basic compound which can be used is not particularly limited, but, for example, compounds classified into the following (1) to (7) may be used.

(1) Compound represented by formula (BS-1):

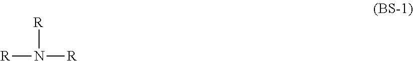

In formula (BS-1), each R independently represents a hydrogen atom or an organic group, provided that at least one of three R is an organic group. The organic group is a linear or branched alkyl group, a monocyclic or polycyclic cycloalkyl group, an aryl group or an aralkyl group.

The carbon number of the alkyl group as R is not particularly limited but is usually from 1 to 20, preferably from 1 to 12.

The carbon number of the cycloalkyl group as R is not particularly limited but is usually from 3 to 20, preferably from 5 to 15.

The carbon number of the aryl group as R is not particularly limited but is usually from 6 to 20, preferably from 6 to 10. Specific examples thereof include a phenyl group and a naphthyl group.

The carbon number of the aralkyl group as R is not particularly limited but is usually from 7 to 20, preferably from 7 to 11. Specific examples thereof include a benzyl group.

In the alkyl group, cycloalkyl group, aryl group and aralkyl group as R, a hydrogen atom may be substituted for by a substituent. Examples of the substituent include an alkyl group, a cycloalkyl group, an aryl group, an aralkyl group, a hydroxy group, a carboxy group, an alkoxy group, an aryloxy group, an alkylcarbonyloxy group, and an alkyloxycarbonyl group.

In the compound represented by formula (BS-1), it is preferred that at least two R are an organic group.

Specific examples of the compound represented by formula (BS-1) include tri-n-butylamine, tri-n-pentylamine, tri-n-octylamine, tri-n-decylamine, triisodecylamine, dicyclohexylmethylamine, tetradecylamine, pentadecylamine, hexadecylamine, octadecylamine, didecylamine, methyloctadecylamine, dimethylundecylamine, N,N-dimethyldodecylamine, methyldioctadecylamine, N,N-dibutylaniline, N,N-dihexylaniline, 2,6-diisopropylaniline, and 2,4,6-tri(tert-butyl)aniline.

Also, the preferred basic compound represented by formula (BS-1) includes a compound where at least one R is an alkyl group substituted with a hydroxy group. Specific examples thereof include triethanolamine and N,N-dihydroxyethylaniline.

The alkyl group as R may have an oxygen atom in the alkyl chain. That is, an oxyalkylene chain may be formed. The oxyalkylene chain is preferably —CH₂CH₂O—. Specific examples thereof include tris(methoxyethoxyethyl)amine and compounds illustrated in column 3, line 60 et seq. of U.S. Pat. No. 6,040,112.

Examples of the basic compound represented by formula (BS-1) include the followings.

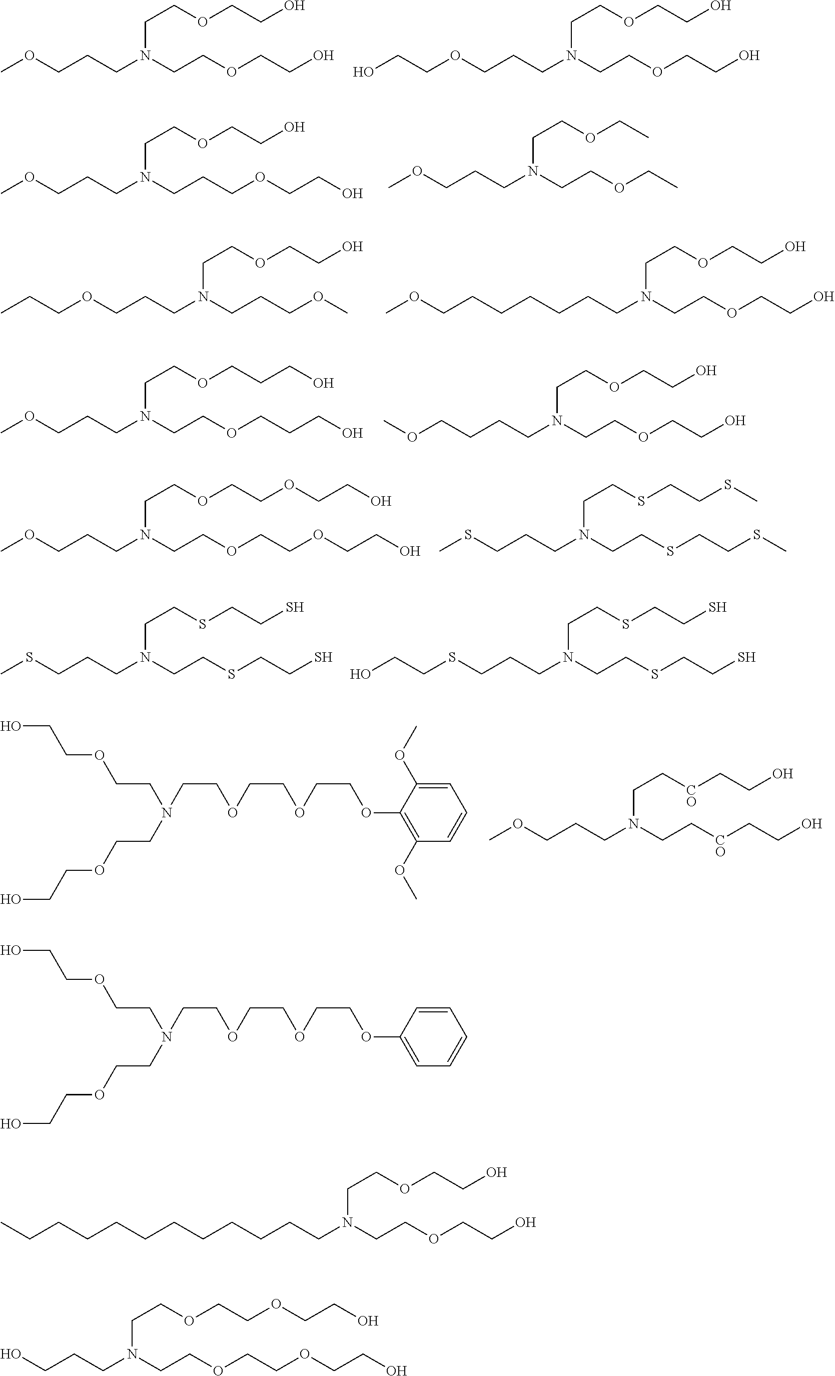

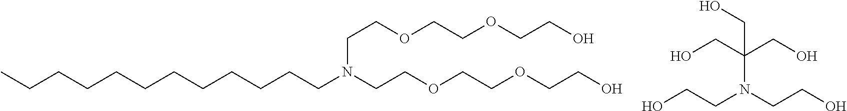 [SMILES: CCCCCCCCCCCCN(CCOCCOCCO)CCOCCOCCO ; OCCN(CCO)C(CO)(CO)CO]

(2) Compound having a nitrogen-containing heterocyclic structure

The nitrogen-containing heterocyclic ring may or may not have aromaticity, may contain a plurality of nitrogen atoms, and may further contain a heteroatom other than nitrogen. Specific examples of the compound include a compound having an imidazole structure (e.g., 2-phenylbenzimidazole, 2,4,5-triphenylimidazole), a compound having a piperidine structure [e.g., N-hydroxyethylpiperidine, bis(1,2,2,6,6-pentamethyl-4-piperidyl)sebacate], a compound having a pyridine structure (e.g., 4-dimethylaminopyridine), and a compound having an antipyrine structure (e.g., antipyrine, hydroxyantipyrine).

A compound having two or more ring structures is also suitably used. Specific examples thereof include 1,5-diazabicyclo[4.3.0]non-5-ene and 1,8-diazabicyclo[5.4.0]-undec-7-ene.

### (3) Phenoxy Group-Containing Amine Compound

The phenoxy group-containing amine compound is a compound where the alkyl group contained in an amine compound has a phenoxy group at the terminal opposite the N atom. The phenoxy group may have a substituent such as alkyl group, alkoxy group, halogen atom, cyano group, nitro group, carboxy group, carboxylic acid ester group, sulfonic acid ester group, aryl group, aralkyl group, acyloxy group and aryloxy group.

The compound preferably has at least one oxyalkylene chain between the phenoxy group and the nitrogen atom. The number of oxyalkylene chains per molecule is preferably from 3 to 9, more preferably from 4 to 6. Among oxyalkylene chains, —CH₂CH₂O— is preferred.

Specific examples of the compound include 2-[2-{2-(2,2-dimethoxy-phenoxyethoxy)ethyl}-bis-(2-methoxyethyl)]-amine and Compounds (C1-1) to (C3-3) illustrated in paragraph [0066] of U.S. Patent Application Publication No. 2007/0224539A1.

The phenoxy group-containing amine compound is obtained, for example, by reacting a primary or secondary amine having a phenoxy group with a haloalkyl ether under heating and after adding an aqueous solution of a strong base such as sodium hydroxide, potassium hydroxide and tetraalkylammonium, extracting the reaction product with an organic solvent such as ethyl acetate and chloroform. The phenoxy group-containing amine compound may be also obtained by reacting a primary or secondary amine with a haloalkyl ether having a phenoxy group at the terminal under heating and after adding an aqueous solution of a strong base such as sodium hydroxide, potassium hydroxide and tetraalkylammonium, extracting the reaction product with an organic solvent such as ethyl acetate and chloroform.

### (4) Ammonium Salt

An ammonium salt may be also appropriately used as the basic compound. Examples of the anion of the ammonium salt include a halide, a sulfonate, a borate and a phosphate. Among these, a halide and a sulfonate are preferred.

The halide is preferably chloride, bromide or iodide.

The sulfonate is preferably an organic sulfonate having a carbon number of 1 to 20. Examples of the organic sulfonate include an alkylsulfonate having a carbon number of 1 to 20, and an arylsulfonate.

The alkyl group contained in the alkylsulfonate may have a substituent, and examples of the substituent include a fluorine atom, a chlorine atom, a bromine atom, an alkoxy group, an acyl group, and an aryl group. Specific examples of the alkylsulfonate include methanesulfonate, ethanesulfonate, butanesulfonate, hexanesulfonate, octanesulfonate, benzylsulfonate, trifluoromethanesulfonate, pentafluoroethanesulfonate, and nonafluorobutanesulfonate.

Examples of the aryl group contained in the arylsulfonate include a phenyl group, a naphthyl group and an anthryl group. Such an aryl group may have a substituent. The substituent is preferably, for example, a linear or branched alkyl group having a carbon number of 1 to 6, or a cycloalkyl group having a carbon number of 3 to 6. Specific preferred examples thereof include methyl group, ethyl group, n-propyl group, isopropyl group, n-butyl group, i-butyl group, tert-butyl group, n-hexyl group, and cyclohexyl group. Other substituents include an alkoxy group having a carbon number of 1 to 6, a halogen atom, cyano, nitro, an acyl group, and an acyloxy group.

The ammonium salt may be a hydroxide or a carboxylate. In this case, the ammonium salt is preferably a tetraalkylammonium hydroxide having a carbon number of 1 to 8 (e.g., tetramethylammonium hydroxide, tetraethylammonium hydroxide, tetra-(n-butyl)ammonium hydroxide).

Preferred examples of the basic compound include guanidine, aminopyridine, aminoalkylpyridine, aminopyrrolidine, indazole, imidazole, pyrazole, pyrazine, pyrimidine, purine, imidazoline, pyrazoline, piperazine, aminomorpholine, and aminoalkylmorpholine. These compounds may further have a substituent.

Preferred examples of the substituent include an amino group, an aminoalkyl group, an alkylamino group, an aminoaryl group, an arylamino group, an alkyl group, an alkoxy group, an acyl group, an acyloxy group, an aryl group, an aryloxy group, a nitro group, a hydroxyl group, and a cyano group.

More preferred examples of the basic compound include guanidine, 1,1-dimethylguanidine, 1,1,3,3-tetramethylguanidine, imidazole, 2-methylimidazole, 4-methylimidazole, N-methylimidazole, 2-phenylimidazole, 4,5-diphenylimidazole, 2,4,5-triphenylimidazole, 2-aminopyridine, 3-aminopyridine, 4-aminopyridine, 2-dimethylaminopyridine, 4-dimethylaminopyridine, 2-diethylaminopyridine, 2-(aminomethyl)pyridine, 2-amino-3-methylpyridine, 2-amino-4-methylpyridine, 2-amino-5-methylpyridine, 2-amino-6-methylpyridine, 3-aminoethylpyridine, 4-aminoethylpyridine, 3-aminopyrrolidine, piperazine, N-(2-aminoethyl)piperazine, N-(2-aminoethyl)piperidine, 4-amino-2,2,6,6-tetramethylpiperidine, 4-piperidinopiperidine, 2-iminopiperidine, 1-(2-aminoethyl)pyrrolidine, pyrazole, 3-amino-5-methylpyrazole, 5-amino-3-methyl-1-p-tolylpyrazole, pyrazine, 2-(aminomethyl)-5-methylpyrazine, pyrimidine, 2,4-diaminopyrimidine, 4,6-dihydroxypyrimidine, 2-pyrazoline, 3-pyrazoline, N-aminomorpholine, and N-(2-aminoethyl)morpholine.

(5) (PA) Compound Having a Proton Acceptor Functional Group and Undergoing Decomposition Upon Irradiation with an Actinic Ray or Radiation to Generate a Compound Reduced in or Deprived of the Proton Acceptor Property or Changed from Proton Acceptor-Functioning to Acidic

The composition of the present invention may further contain, as a basic compound, a compound having a proton acceptor functional group and undergoing decomposition upon irradiation with an actinic ray or radiation to generate a compound reduced in or deprived of the proton acceptor property or changed from proton acceptor-functioning to acidic [hereinafter, sometimes referred to as “compound (PA)”].

The proton acceptor functional group is a functional group having a group or electron capable of electrostatically interacting with a proton and means, for example, a functional group having a macrocyclic structure such as cyclic polyether, or a functional group containing a nitrogen atom having an unshared electron pair not contributing to π-conjugation. The nitrogen atom having an unshared electron pair not contributing to π-conjugation is, for example, a nitrogen atom having a partial structure represented by the following formulae:

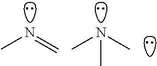

unshared electron pair

Preferred examples of the partial structure for the proton acceptor functional group include a crown ether structure, an aza-crown ether structure, a primary to tertiary amine structure, a pyridine structure, an imidazole structure, and a pyrazine structure.

The compound (PA) decomposes upon irradiation with an actinic ray or radiation to generate a compound reduced in or deprived of the proton acceptor property or changed from proton acceptor-functioning to acidic. The “reduced in or deprived of the proton acceptor property or changed from proton acceptor-functioning to acidic” as used herein indicates a change in the proton acceptor property due to addition of a proton to the proton acceptor functional group and specifically means that when a proton adduct is produced from the proton acceptor functional group-containing compound (PA) and a proton, the equilibrium constant in the chemical equilibrium decreases.

The proton acceptor property can be confirmed by measuring the pH. In the present invention, the acid dissociation constant pKa of the compound generated resulting from decomposition of the compound (PA) upon irradiation with an actinic ray or radiation preferably satisfies pKa<−1, more preferably −13<pKa<−1, still more preferably −13<pKa<−3.

In the present invention, the acid dissociation constant pKa indicates an acid dissociation constant pKa in an aqueous solution and is a value described, for example, in Kagaku Binran (Chemical Handbook) (II) (4th revised edition, compiled by The Chemical Society of Japan, Maruzen (1993)). As this value is lower, the acid strength is higher. Specifically, the acid dissociation constant at 25° C. is measured using an aqueous infinite dilution solution, whereby the acid dissociation constant pKa in an aqueous solution can be actually measured. Alternatively, a value based on Hammett's substituent constants and data base containing values known in publications can be determined by computation using the following software package 1. The pKa values referred to in the description of the present invention all are a value determined by computation using this software package.

Software Package 1: Advanced Chemistry Development (ACD/Labs) Software V8.14 for Solaris (1994-2007 ACD/Labs)

The compound (PA) decomposes upon irradiation with an actinic ray or radiation to produce, for example, a compound represented by the following formula (PA-1) as the above-described proton adduct. The compound represented by formula (PA-1) is a compound having an acidic group together with a proton acceptor functional group and thereby being reduced in or deprived of the proton acceptor property or changed from proton acceptor-functioning to acidic, as compared with the compound (PA).

Q-A-(X)ₙ—B—R (PA-1)

In formula (PA-1), Q represents —SO₃H, —CO₂H or —X₁NHX₂Rf, wherein Rf represents an alkyl group, a cycloalkyl group or an aryl group and each of X₁ and X₂ independently represents —SO₂— or —CO—.

A represents a single bond or a divalent linking group.

X represents —SO₂— or —CO—.

n represents 0 or 1.

B represents a single bond, an oxygen atom or —N(Rx)Ry-, wherein Rx represents a hydrogen atom or a monovalent organic group, Ry represents a single bond or a divalent organic group, and Rx may combine with Ry to form a ring or combine with R to form a ring.

R represents a monovalent organic group having a proton acceptor functional group.

Formula (PA-1) is described in detail below.

The divalent linking group in A is preferably a divalent linking group having a carbon number of 2 to 12, and examples thereof include an alkylene group and a phenylene group. An alkylene group having at least one fluorine atom is preferred, and the carbon number thereof is preferably from 2 to 6, more preferably from 2 to 4. The alkylene chain may contain a linking group such as oxygen atom and sulfur atom. The alkylene group is preferably an alkylene group where from 30 to 100% by number of hydrogen atoms are substituted for by a fluorine atom, more preferably an alkylene group where the carbon atom bonded to the Q site has a fluorine atom, still more preferably a perfluoroalkylene group, yet still more preferably a perfluoroethylene group, a perfluoropropylene group or a perfluorobutylene group.

The monovalent organic group in Rx preferably has a carbon number of 1 to 30, and examples thereof include an alkyl group, a cycloalkyl group, an aryl group, an aralkyl group, and an alkenyl group. These groups may further have a substituent.

The alkyl group in Rx may have a substituent and is preferably a linear or branched alkyl group having a carbon number of 1 to 20, and the alkyl chain may contain an oxygen atom, a sulfur atom or a nitrogen atom.

The divalent organic group in R^{y} is preferably an alkylene group.

The ring structure which may be formed by combining R^{x} and R^{y} with each other includes a 5- to 10-membered ring, preferably a 6-membered ring, containing a nitrogen atom.

The alkyl group having a substituent includes particularly a group where a cycloalkyl group is substituted on a linear or branched alkyl group (for example, an adamantylmethyl group, an adamantylethyl group, a cyclohexylethyl group and a camphor residue).

The cycloalkyl group in Rx, which may have a substituent, is preferably a cycloalkyl group having a carbon number of 3 to 20 and may contain an oxygen atom in the ring.

The aryl group in Rx may have a substituent and is preferably an aryl group having a carbon number of 6 to 14.

The aralkyl group in Rx may have a substituent and is preferably an aralkyl group having a carbon number of 7 to 20.

The alkenyl group in Rx may have a substituent and includes, for example, a group having a double bond at an arbitrary position of the alkyl group described as Rx.

The proton acceptor functional group of R is as described above and includes a group containing, for example, a nitrogen-containing heterocyclic aromatic structure such as aza-crown ether, primary to tertiary amine, pyridine and imidazole.

The organic group containing such a structure preferably has a carbon number of 4 to 30, and examples thereof include an alkyl group, a cycloalkyl group, an aryl group, an aralkyl group, and an alkenyl group.

Examples of the alkyl group, cycloalkyl group, aryl group, aralkyl group and alkenyl group in the proton acceptor functional group- or ammonium group-containing alkyl group, cycloalkyl group, aryl group, aralkyl group and alkenyl group of R are the same as those of the alkyl group, cycloalkyl group, aryl group, aralkyl group and alkenyl group recited for Rx.

Examples of the substituent which each of the above-described groups may have include a halogen atom, a hydroxyl group, a nitro group, a cyano group, a carboxy group, a carbonyl group, a cycloalkyl group (preferably having a carbon number of 3 to 10), an aryl group (preferably having a carbon number of 6 to 14), an alkoxy group (preferably having a carbon number of 1 to 10), an acyl group (preferably having a carbon number of 2 to 20), an acyloxy group (preferably having a carbon number of 2 to 10), an alkoxycarbonyl group (preferably having a carbon number of 2 to 20), and an aminoacyl group (preferably having a carbon number of 2 to 20). The cyclic structure in the aryl group, cycloalkyl group and the like and the aminoacyl group may further have an alkyl group (preferably having a carbon number of 1 to 20) as a substituent.

When B is —N(Rx)Ry-, R and Rx preferably combine with each other to form a ring. By forming a ring structure, the stability is enhanced and the composition using this compound is also increased in the storage stability. The number of carbons constituting the ring is preferably from 4 to 20, and the ring may be monocyclic or polycyclic and may contain an oxygen atom, a sulfur atom or a nitrogen atom.

Examples of the monocyclic structure include a 4-membered ring, a 5-membered ring, a 6-membered ring, a 7-membered ring and a 8-membered ring each containing a nitrogen atom. Examples of the polycyclic structure include a structure composed of a combination of two monocyclic structures or three or more monocyclic structures. The monocyclic structure and the polycyclic structure may have a substituent, and preferred examples of the substituent include a halogen atom, a hydroxyl group, a cyano group, a carboxy group, a carbonyl group, a cycloalkyl group (preferably having a carbon number of 3 to 10), an aryl group (preferably having a carbon number of 6 to 14), an alkoxy group (preferably having a carbon number of 1 to 10), an acyl group (preferably having a carbon number of 2 to 15), an acyloxy group (preferably having a carbon number of 2 to 15), an alkoxycarbonyl group (preferably having a carbon number of 2 to 15), and an aminoacyl group (preferably having a carbon number of 2 to 20). The cyclic structure in the aryl group, cycloalkyl group and the like may further have an alkyl group (preferably having a carbon number of 1 to 15) as a substituent. The aminoacyl group may further have an alkyl group (preferably having a carbon number of 1 to 15) as a substituent.

Rf in —X₁NHX₂Rf represented by Q is preferably an alkyl group having a carbon number of 1 to 6, which may have a fluorine atom, more preferably a perfluoroalkyl group having a carbon number of 1 to 6. Also, at least one of X₁ and X₂ is preferably —SO₂—, and it is more preferred that both of X₁ and X₂ are —SO₂—.

Out of the compounds represented by formula (PA-1), the compound where the Q site is a sulfonic acid can be synthesized using a general sulfonamidation reaction. For example, the compound may be obtained by a method of selectively reacting one sulfonyl halide moiety of a bis-sulfonyl halide compound with an amine compound to form a sulfonamide bond and then hydrolyzing the other sulfonyl halide moiety, or a method of ring-opening a cyclic sulfonic anhydride through a reaction with an amine compound.

The compound (PA) is preferably an ionic compound. The proton acceptor functional group may be contained in either the anion moiety or the cation moiety but is preferably contained in the anion moiety.

The compound (PA) is preferably a compound represented by the following formula (4) to (6):

R_{f}—X₂—N⁻—X₁-A—(X)ₙ—B—R[C]⁺ (4)

R—SO₃⁻[C]⁺ (5)

R—CO₂⁻[C]⁺ (6)

In formulae (4) to (6), A, X, n, B, R, Rf, X₁ and X₂ have the same meanings as those in formula (PA-1).

C⁺ represents a counter cation.

The counter cation is preferably an onium cation. More specifically, preferred examples thereof include a sulfonium cation described above as S⁺(R₂₀₁)(R₂₀₂)(R₂₀₃) in formula (ZI) and an iodonium cation described as I⁺(R₂₀₄)(R₂₀₅) in formula (ZII), which are compounds used as a photoacid generator.

Specific examples of compound (PA) are illustrated below, but the present invention is not limited thereto.

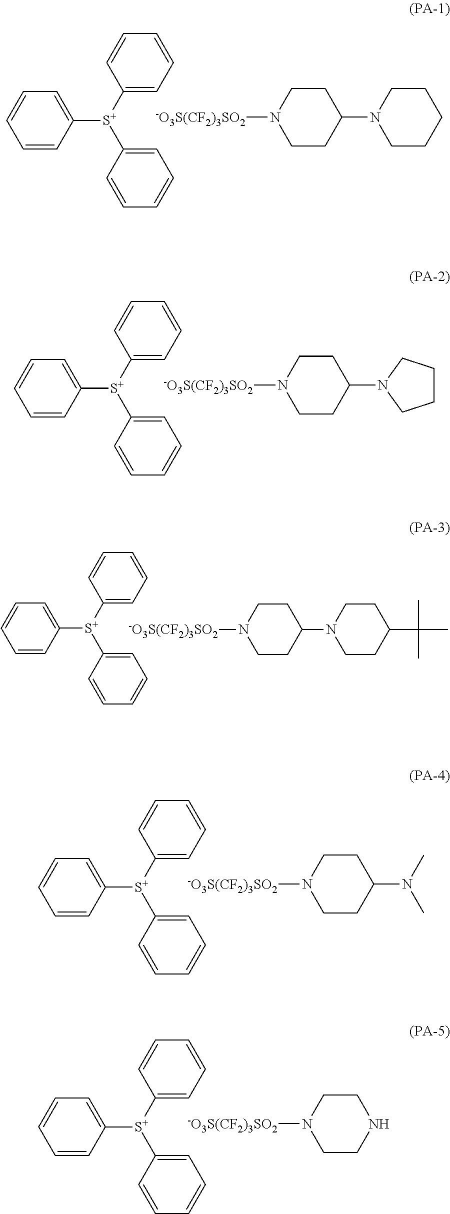

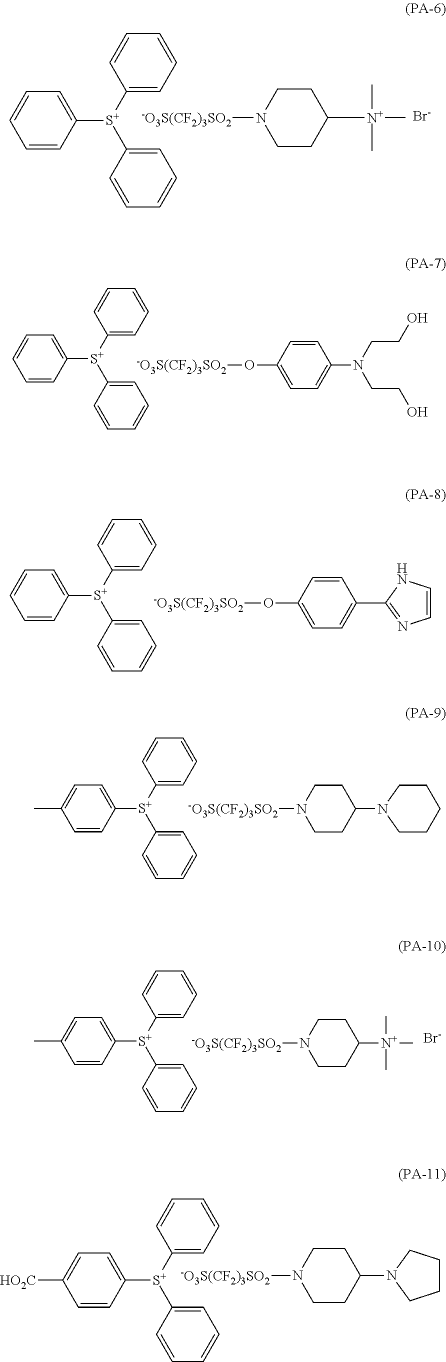

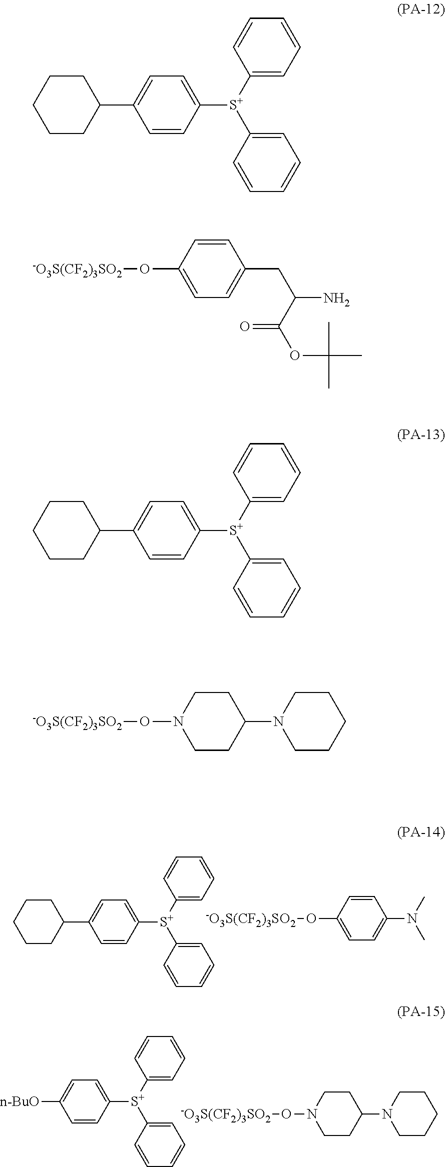

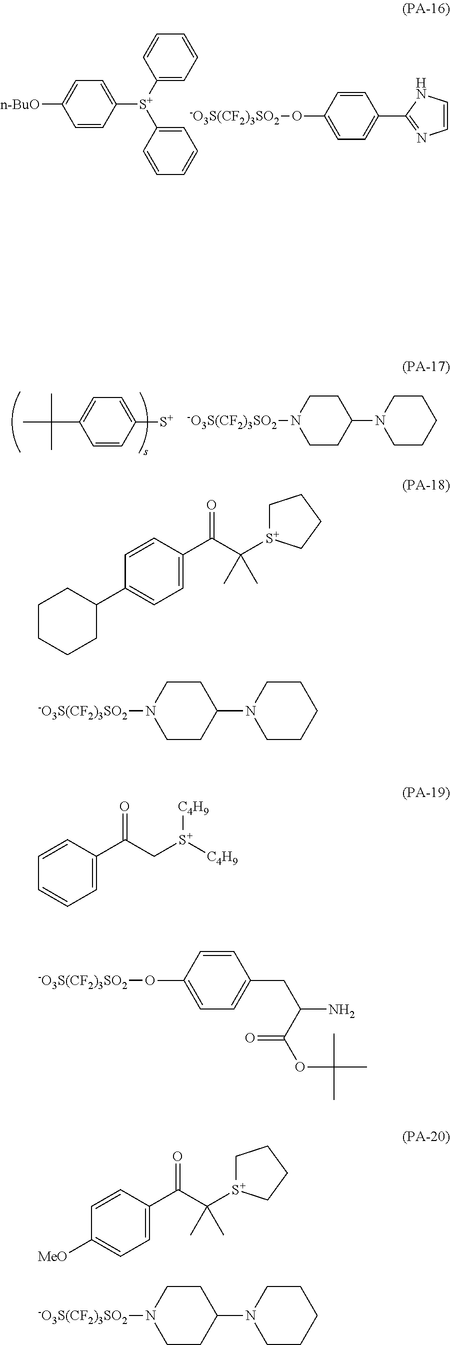

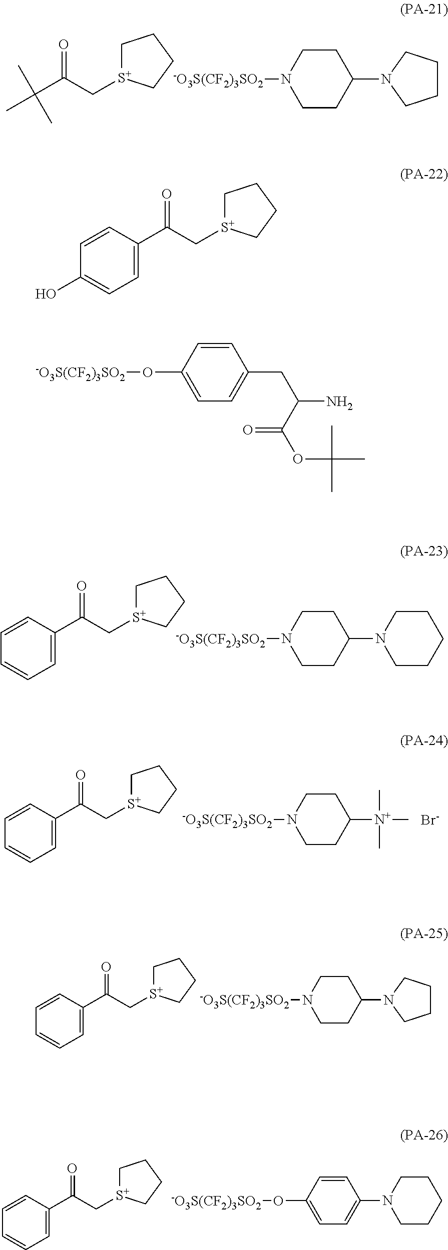

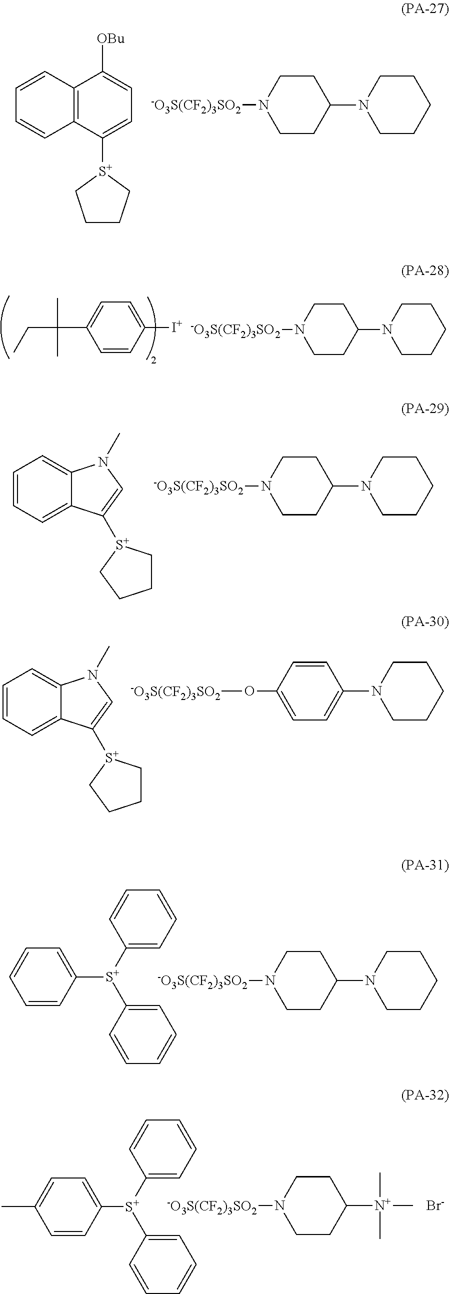

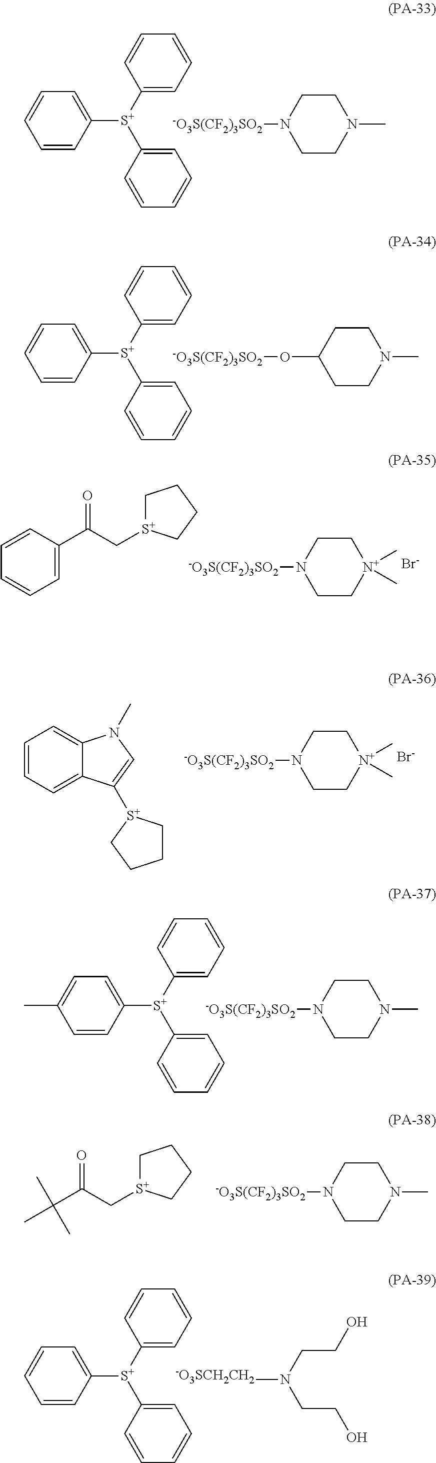

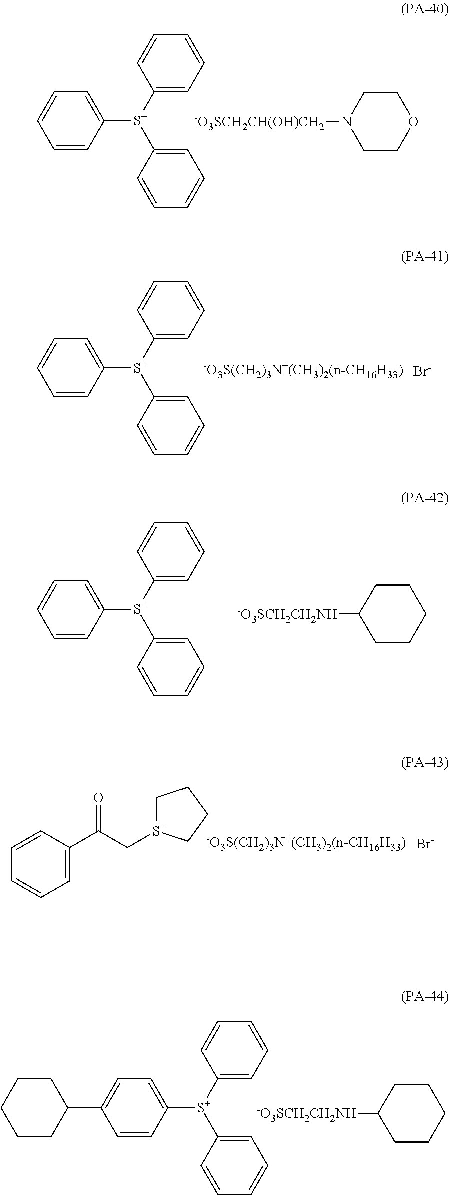

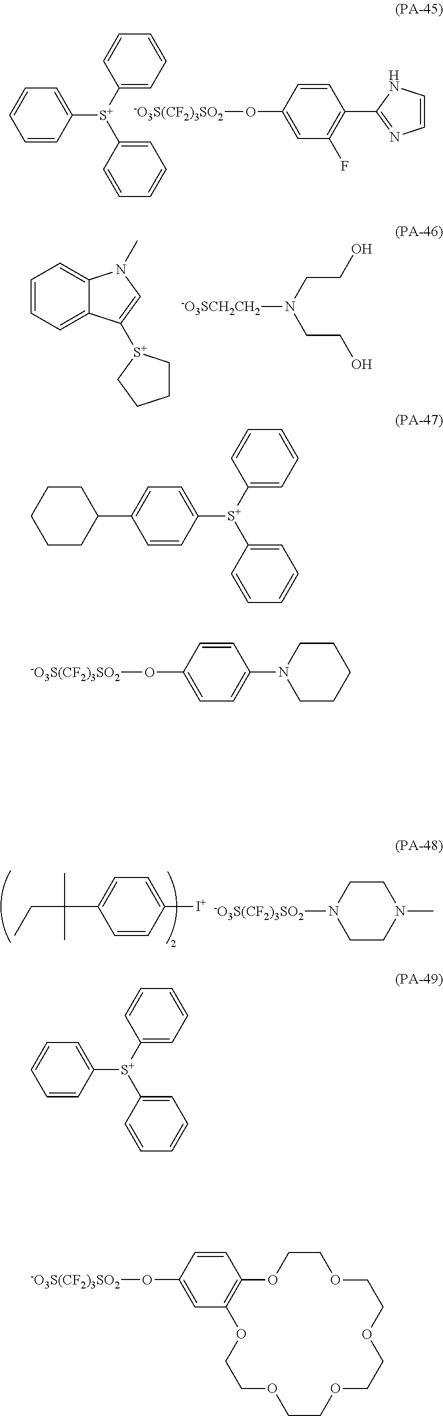

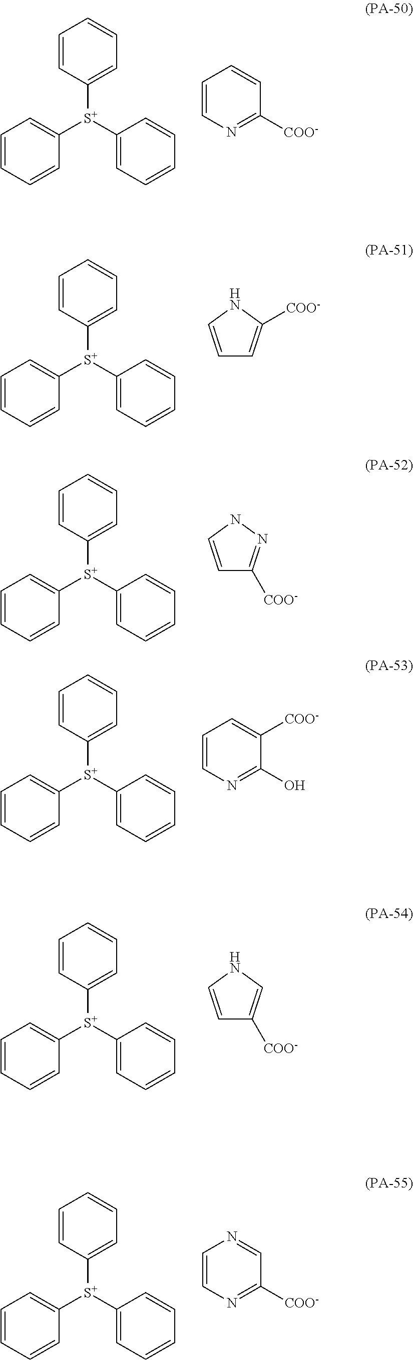

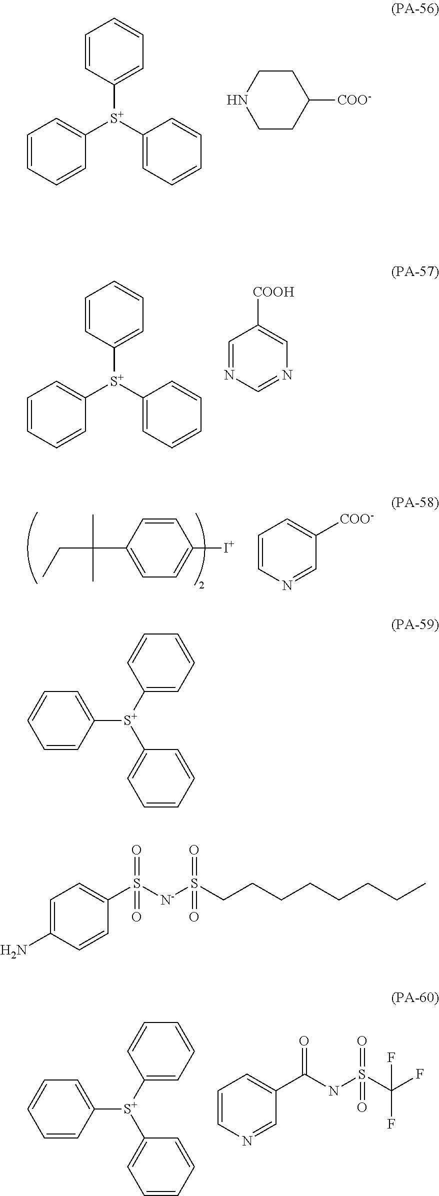

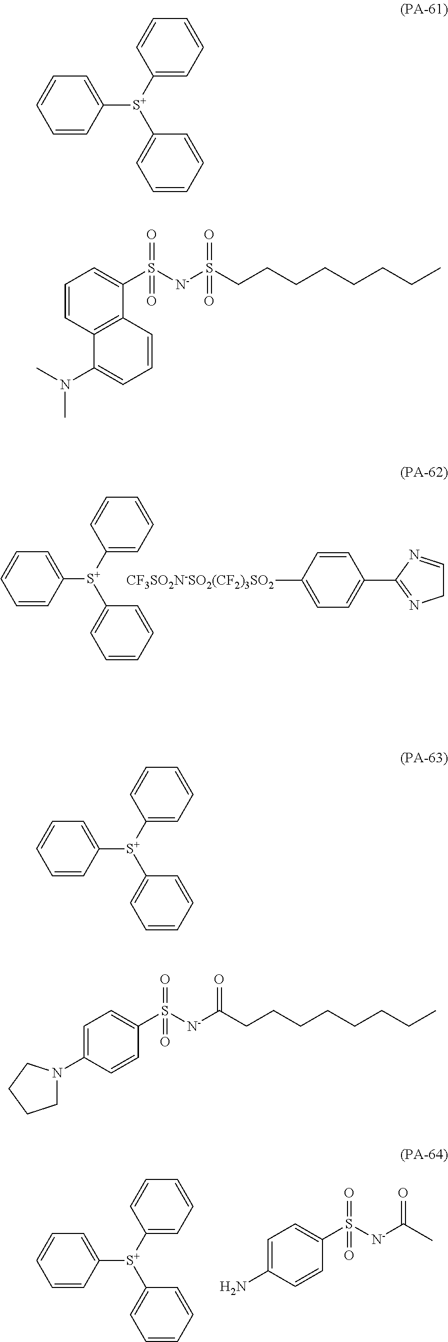

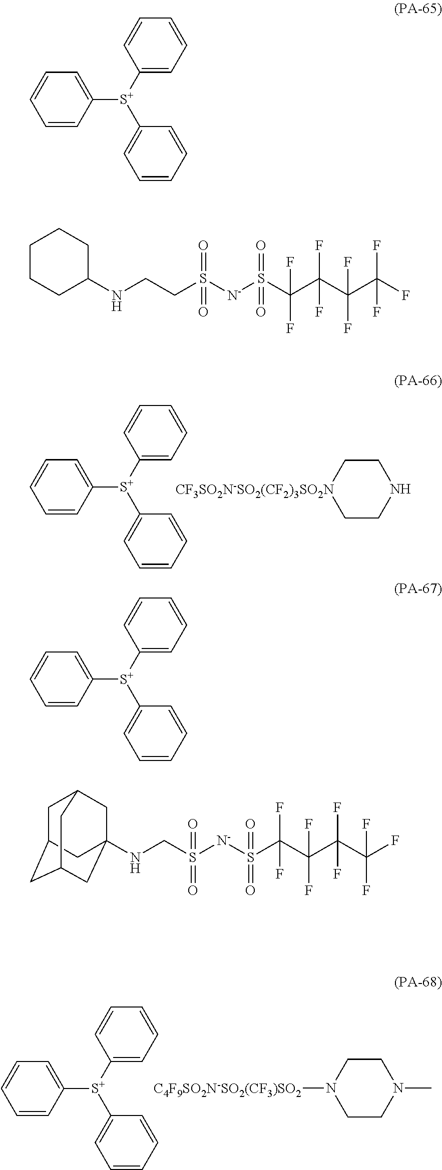

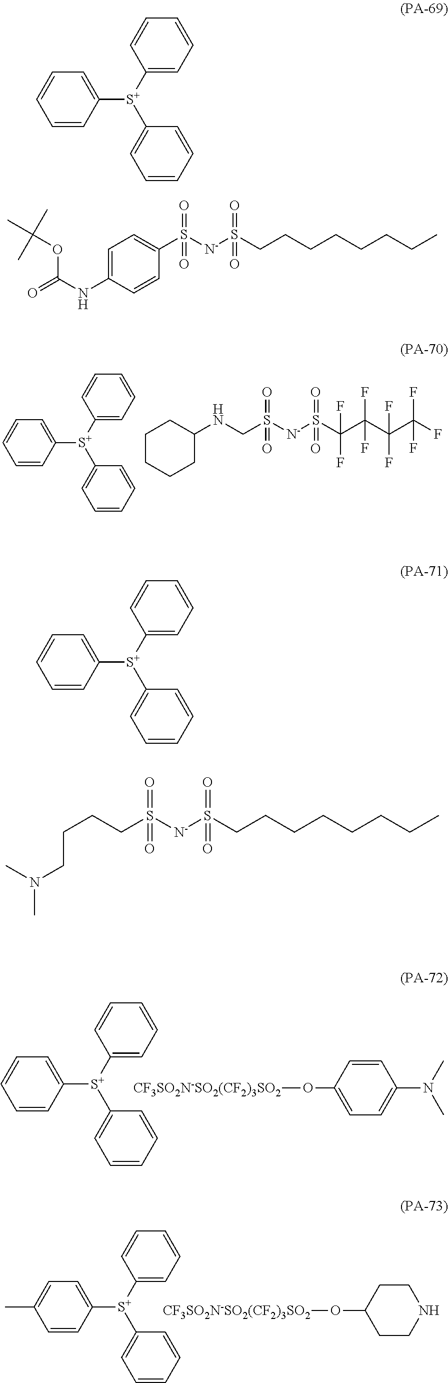

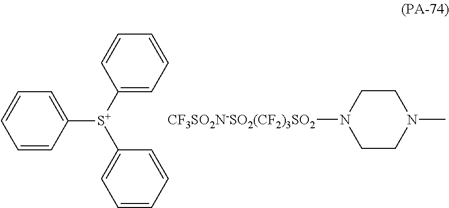

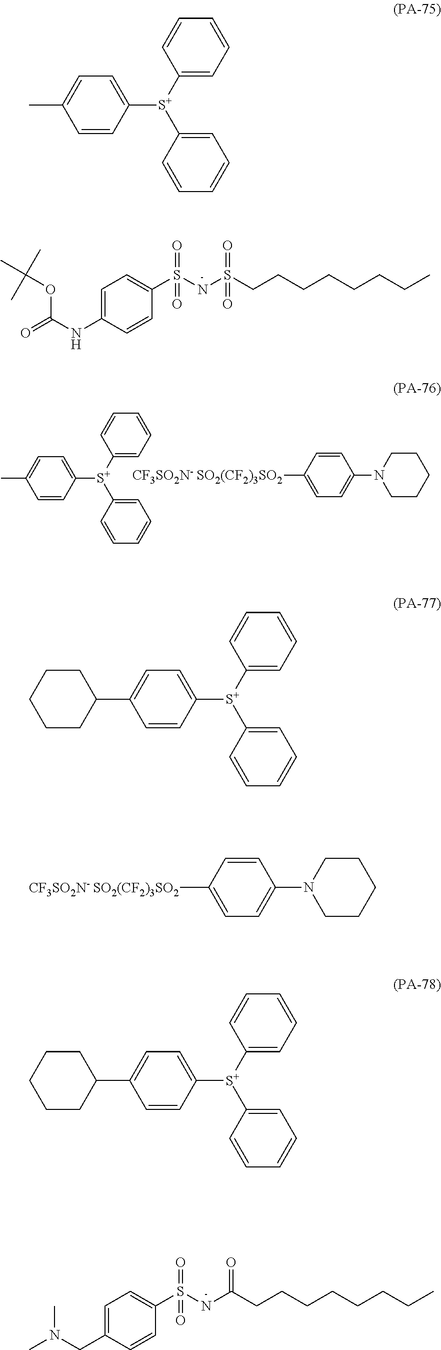

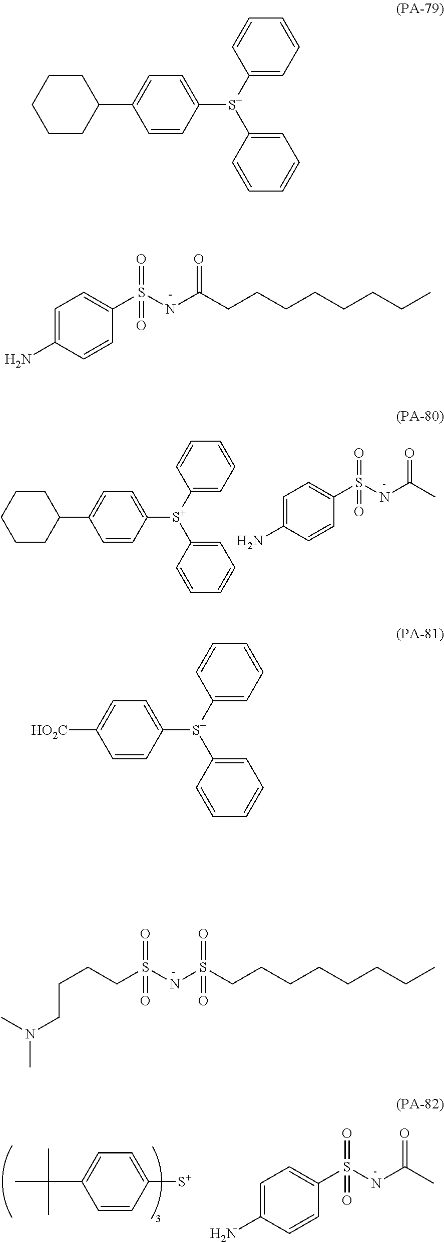

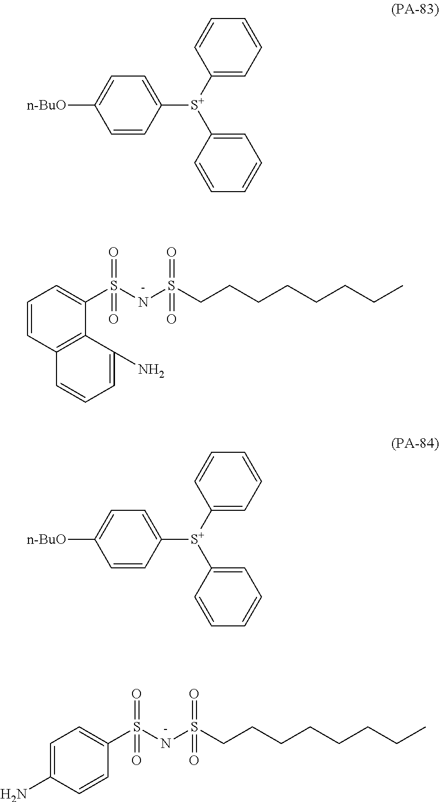

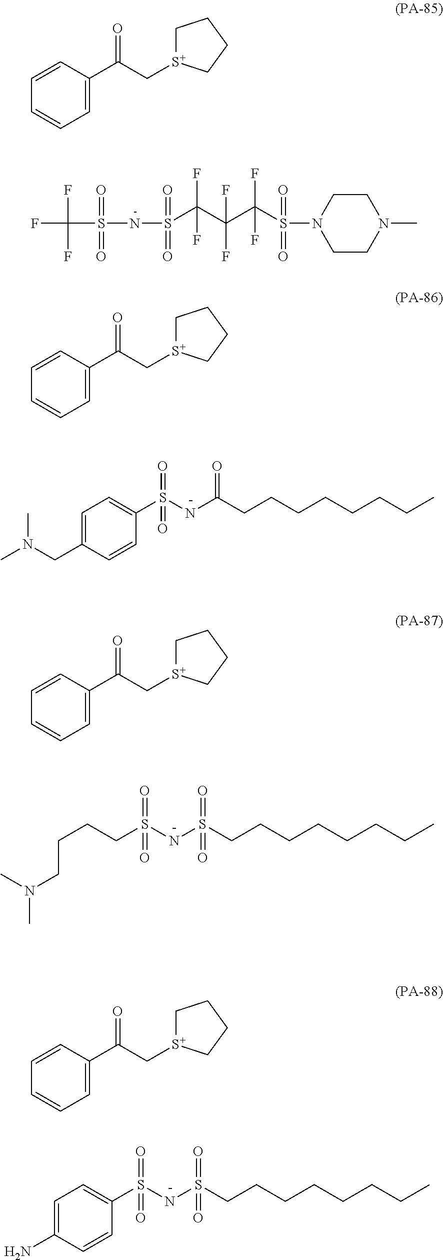

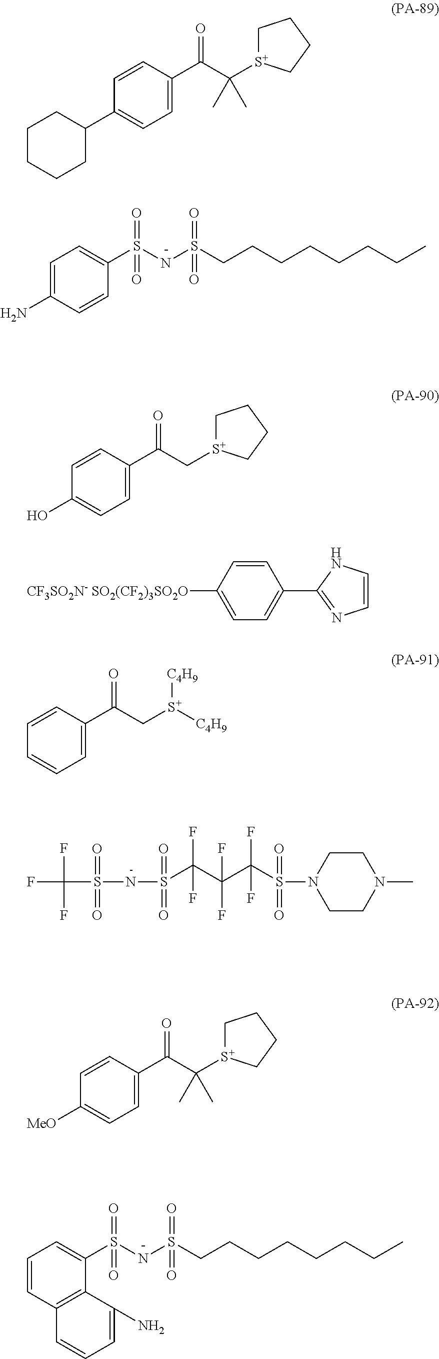

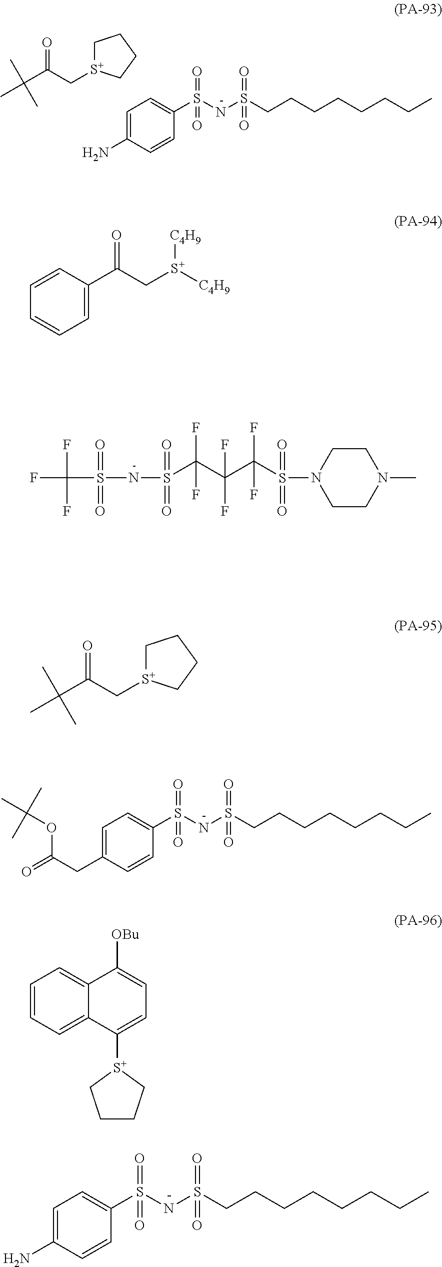

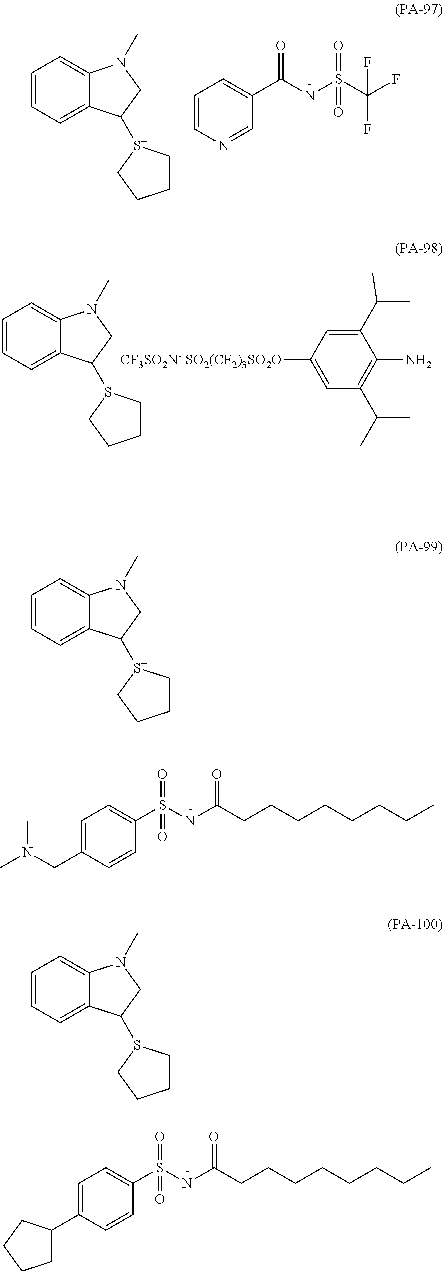

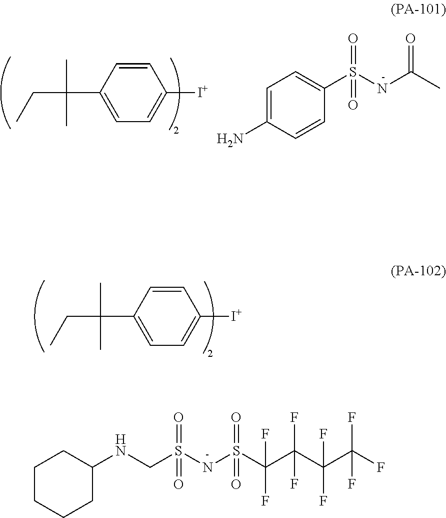

In the present invention, a compound (PA) other than the compound capable of generating a compound represented by formula (PA-1) can be also appropriately selected. For example, a compound that is an ionic compound and has a proton acceptor site in the cation moiety may be used. More specifically, examples of such a compound include a compound represented by the following formula (7):

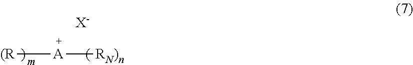

In the formula, A represents a sulfur atom or an iodine atom.

m represents 1 or 2, and n represents 1 or 2, provided that when A is a sulfur atom, m+n=3 and when A is an iodine atom, m+n=2.

R represents an aryl group.

R_{N} represents an aryl group substituted with a proton acceptor functional group.

X⁻ represents a counter anion.

Specific examples of X⁻ are the same as those of X⁻ in formula (ZI).

Specific preferred examples of the aryl group of R and R_{N} include a phenyl group.

Specific examples of the proton acceptor functional group contained in R_{N} are the same as those of the proton acceptor functional group described above in formula (PA-1).

In the composition of the present invention, the blending ratio of the compound (PA) in the entire composition is preferably from 0.1 to 10 mass %, more preferably from 1 to 8 mass %, based on the total solid content.

### (6) Guanidine Compound

The composition of the present invention may further contain a guanidine compound having a structure represented by the following formula:

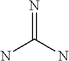

The guanidine compound exhibits strong basicity because thanks to three nitrogens, dispersion of positive electric charges of the conjugate acid is stabilized.

As for the basicity of the guanidine compound (A) for use in the present invention, the pKa of the conjugate acid is preferably 6.0 or more, more preferably from 7.0 to 20.0 in view of high neutralization reactivity with an acid and excellent roughness characteristics, and still more preferably from 8.0 to 16.0.

Such strong basicity makes it possible to suppress diffusion of the acid and contribute to formation of an excellent pattern profile.

The “pKa” as used herein is determined according to the above-described method.

In the present invention, the logP is a logarithmic value of the n-octanol/water partition coefficient (P) and is an effective parameter capable of characterizing the hydrophilicity/hydrophobicity over a wide range of compounds. The partition coefficient is generally determined by computation but not from experiments and in the present invention, a value computed using CS ChemDraw Ultra Ver. 8.0 software package (Crippen's fragmentation method) is employed.

The logP of the guanidine compound (A) is preferably 10 or less. With this value or less, the compound can be uniformly incorporated in the resist film.

The logP of the guanidine compound (A) for use in the present invention is preferably from 2 to 10, more preferably from 3 to 8, still more preferably 4 to 8.

The guanidine compound (A) for use in the present invention preferably contains no nitrogen atom except for in the guanidine structure.

Specific examples of the guanidine compound are illustrated below, but the present invention is not limited thereto.

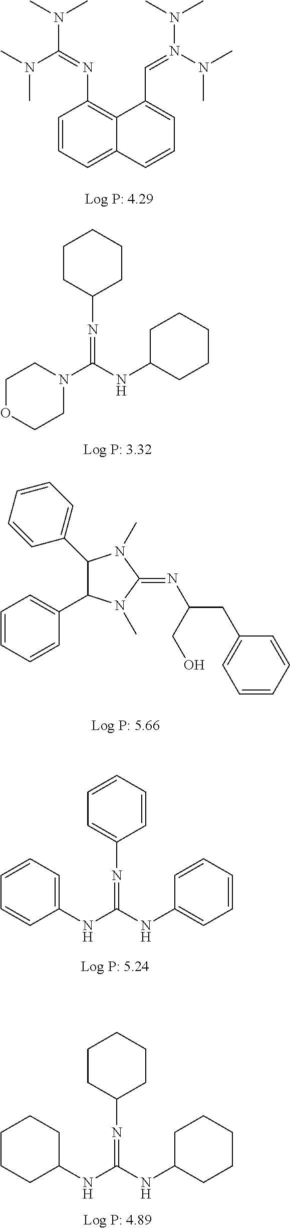

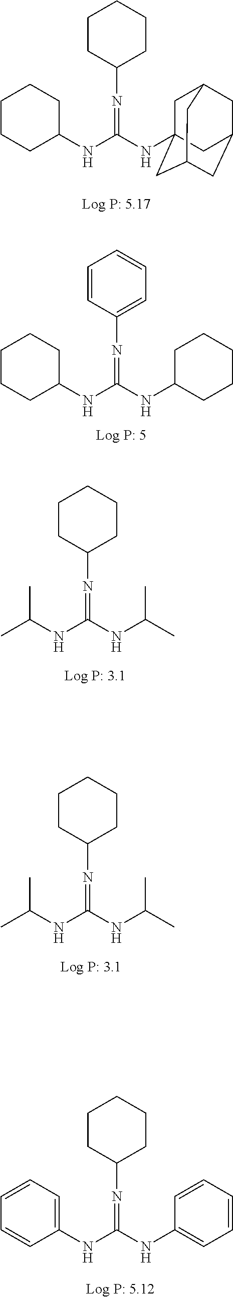

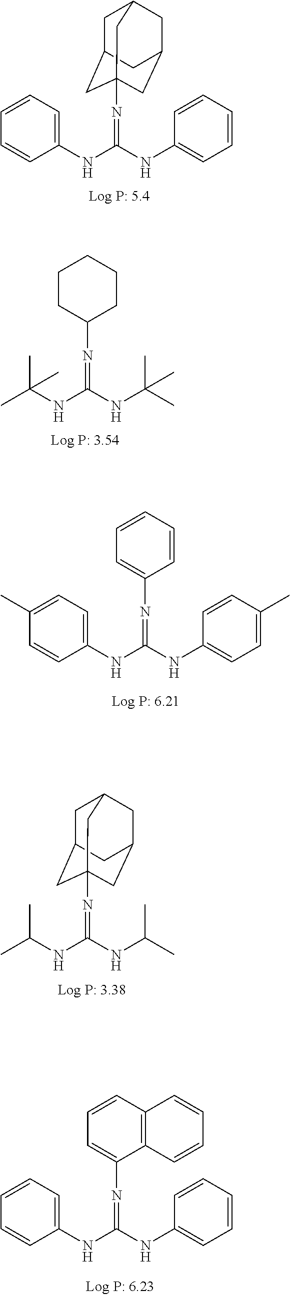

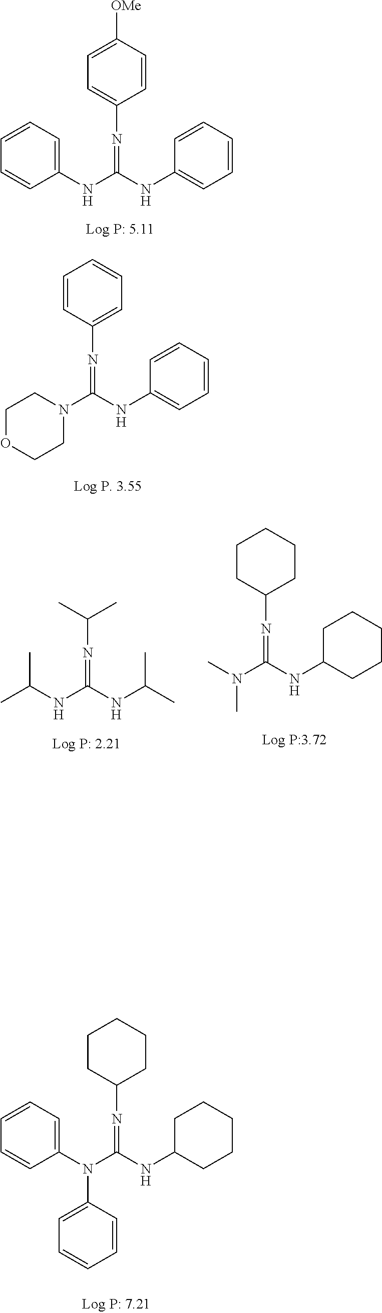 [SMILES: COc1ccc(N=C(Nc2ccccc2)Nc2ccccc2)cc1 ; c1ccc(N=C(Nc2ccccc2)N2CCOCC2)cc1 ; CC(C)N=C(NC(C)C)NC(C)C ; CN(C)C(=NC1CCCCC1)NC1CCCCC1 ; c1ccc(N(C(=NC2CCCCC2)NC2CCCCC2)c2ccccc2)cc1]

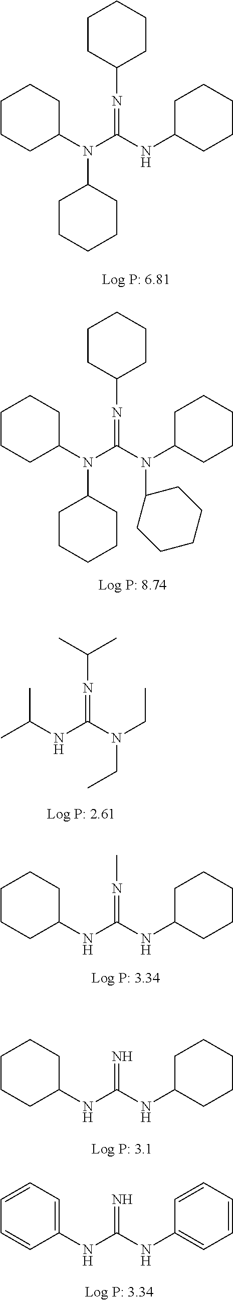 [SMILES: C1CCC(N=C(NC2CCCCC2)N(C2CCCCC2)C2CCCCC2)CC1 ; C1CCC(N=C(N(C2CCCCC2)C2CCCCC2)N(C2CCCCC2)C2CCCCC2)CC1 ; CCN(CC)C(=NC(C)C)NC(C)C ; CN=C(NC1CCCCC1)NC1CCCCC1 ; N=C(NC1CCCCC1)NC1CCCCC1 ; N=C(Nc1ccccc1)Nc1ccccc1]

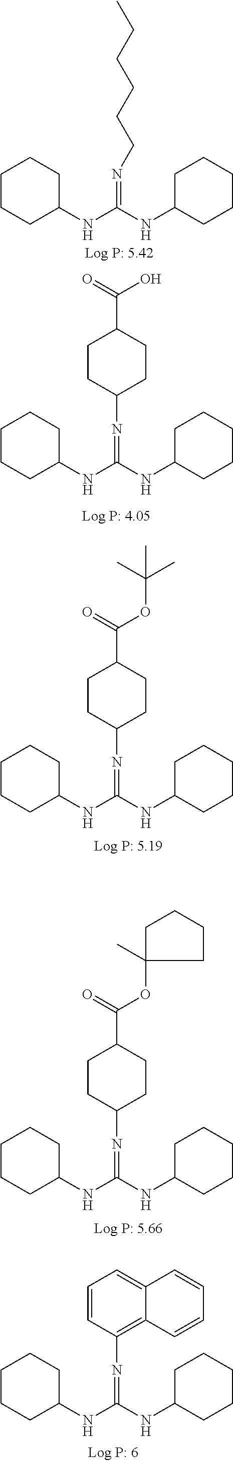 [SMILES: CCCCCCN=C(NC1CCCCC1)NC1CCCCC1 ; O=C(O)C1CCC(N=C(NC2CCCCC2)NC2CCCCC2)CC1 ; CC(C)(C)OC(=O)C1CCC(N=C(NC2CCCCC2)NC2CCCCC2)CC1 ; CC1(OC(=O)C2CCC(N=C(NC3CCCCC3)NC3CCCCC3)CC2)CCCC1 ; c1ccc2c(N=C(NC3CCCCC3)NC3CCCCC3)cccc2c1]

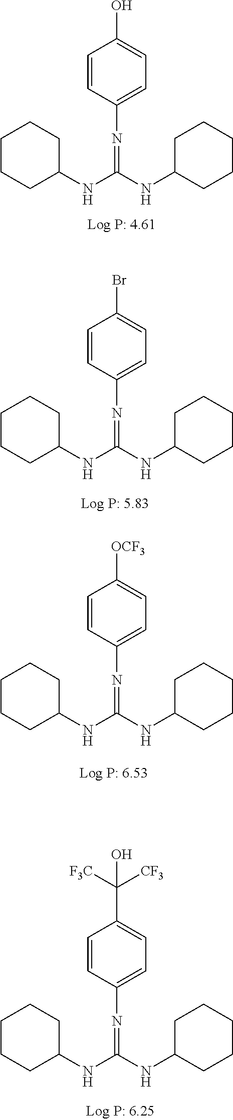 [SMILES: Oc1ccc(N=C(NC2CCCCC2)NC2CCCCC2)cc1 ; Brc1ccc(N=C(NC2CCCCC2)NC2CCCCC2)cc1 ; FC(F)(F)Oc1ccc(N=C(NC2CCCCC2)NC2CCCCC2)cc1 ; OC(c1ccc(N=C(NC2CCCCC2)NC2CCCCC2)cc1)(C(F)(F)F)C(F)(F)F]

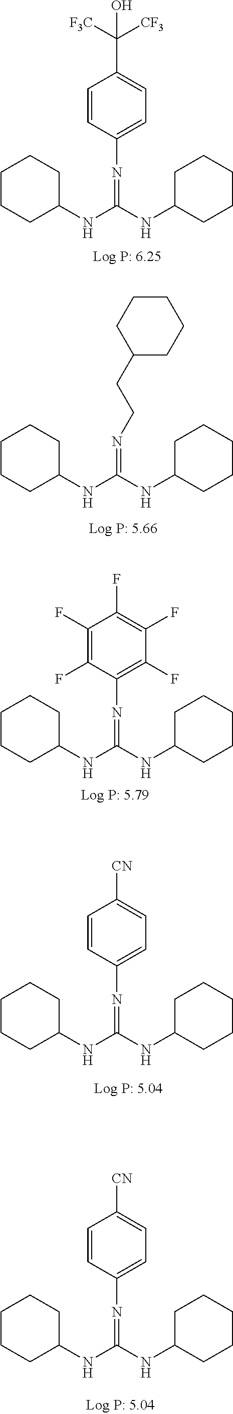 [SMILES: OC(c1ccc(N=C(NC2CCCCC2)NC2CCCCC2)cc1)(C(F)(F)F)C(F)(F)F ; C1CCC(CCN=C(NC2CCCCC2)NC2CCCCC2)CC1 ; Fc1c(F)c(F)c(N=C(NC2CCCCC2)NC2CCCCC2)c(F)c1F ; N#Cc1ccc(N=C(NC2CCCCC2)NC2CCCCC2)cc1 ; N#Cc1ccc(N=C(NC2CCCCC2)NC2CCCCC2)cc1]

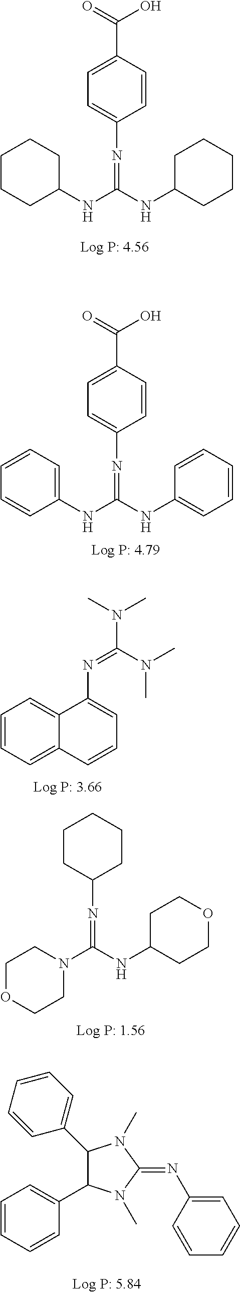 [SMILES: O=C(O)c1ccc(N=C(NC2CCCCC2)NC2CCCCC2)cc1 ; O=C(O)c1ccc(N=C(Nc2ccccc2)Nc2ccccc2)cc1 ; CN(C)C(=Nc1cccc2ccccc12)N(C)C ; C1CCC(N=C(NC2CCOCC2)N2CCOCC2)CC1 ; CN1C(=Nc2ccccc2)N(C)C(c2ccccc2)C1c1ccccc1]

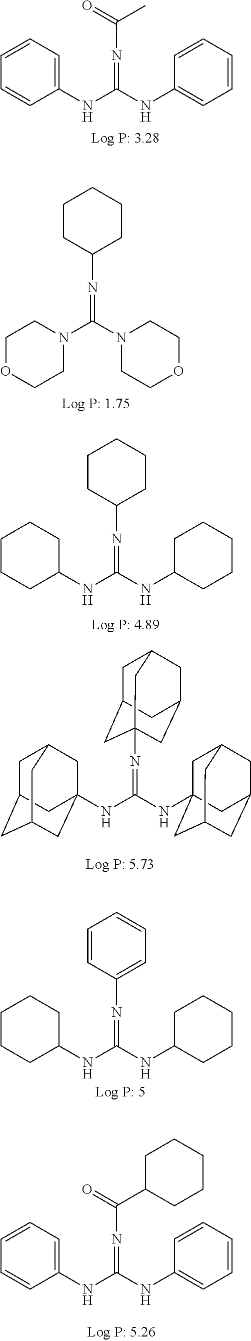 [SMILES: CC(=O)N=C(Nc1ccccc1)Nc1ccccc1 ; C1CCC(N=C(N2CCOCC2)N2CCOCC2)CC1 ; C1CCC(N=C(NC2CCCCC2)NC2CCCCC2)CC1 ; C1C2CC3CC1CC(N=C(NC14CC5CC(CC(C5)C1)C4)NC14CC5CC(CC(C5)C1)C4)(C2)C3 ; c1ccc(N=C(NC2CCCCC2)NC2CCCCC2)cc1 ; O=C(N=C(Nc1ccccc1)Nc1ccccc1)C1CCCCC1]

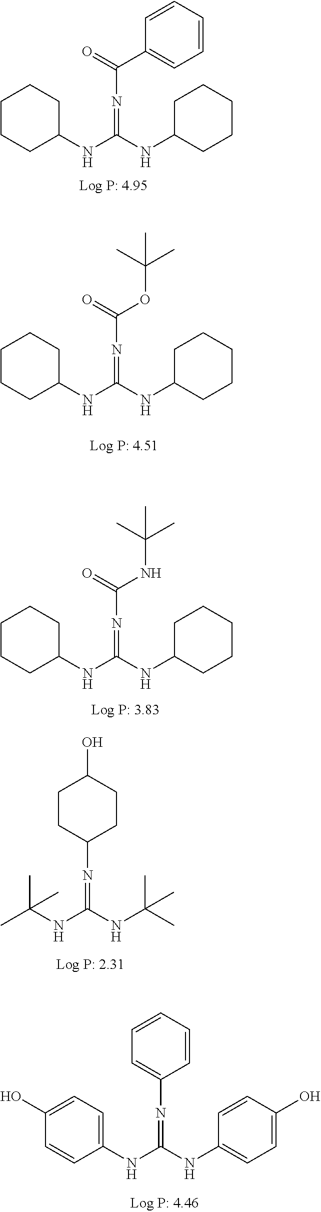 [SMILES: O=C(N=C(NC1CCCCC1)NC1CCCCC1)c1ccccc1 ; CC(C)(C)OC(=O)N=C(NC1CCCCC1)NC1CCCCC1 ; CC(C)(C)NC(=O)N=C(NC1CCCCC1)NC1CCCCC1 ; CC(C)(C)NC(=NC1CCC(O)CC1)NC(C)(C)C ; Oc1ccc(NC(=Nc2ccccc2)Nc2ccc(O)cc2)cc1]

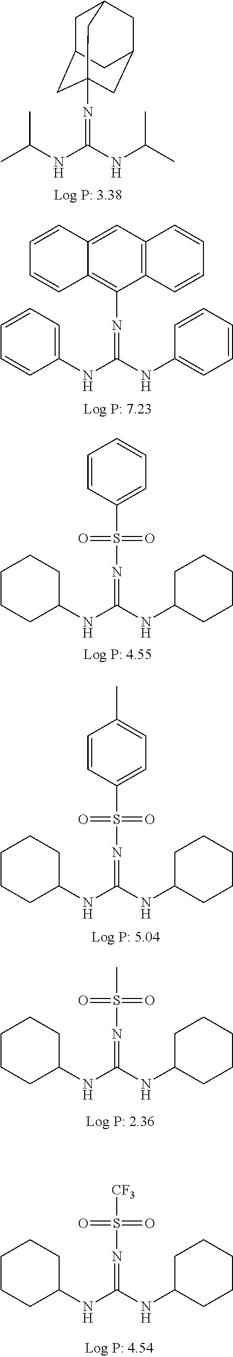 [SMILES: CC(C)NC(=NC12CC3CC(CC(C3)C1)C2)NC(C)C ; c1ccc(NC(=Nc2c3ccccc3cc3ccccc23)Nc2ccccc2)cc1 ; O=S(=O)(N=C(NC1CCCCC1)NC1CCCCC1)c1ccccc1 ; Cc1ccc(S(=O)(=O)N=C(NC2CCCCC2)NC2CCCCC2)cc1 ; CS(=O)(=O)N=C(NC1CCCCC1)NC1CCCCC1 ; O=S(=O)(N=C(NC1CCCCC1)NC1CCCCC1)C(F)(F)F]

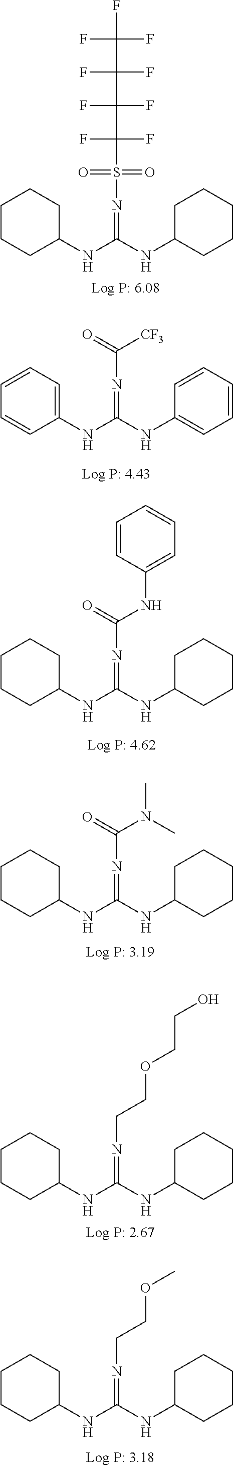 [SMILES: O=S(=O)(N=C(NC1CCCCC1)NC1CCCCC1)C(F)(F)C(F)(F)C(F)(F)C(F)(F)F ; O=C(N=C(Nc1ccccc1)Nc1ccccc1)C(F)(F)F ; O=C(N=C(NC1CCCCC1)NC1CCCCC1)Nc1ccccc1 ; CN(C)C(=O)N=C(NC1CCCCC1)NC1CCCCC1 ; OCCOCCN=C(NC1CCCCC1)NC1CCCCC1 ; COCCN=C(NC1CCCCC1)NC1CCCCC1]

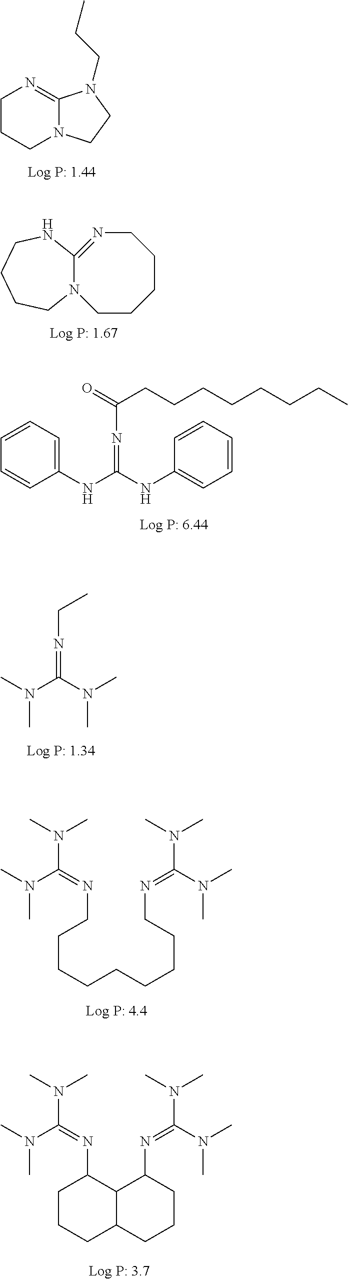

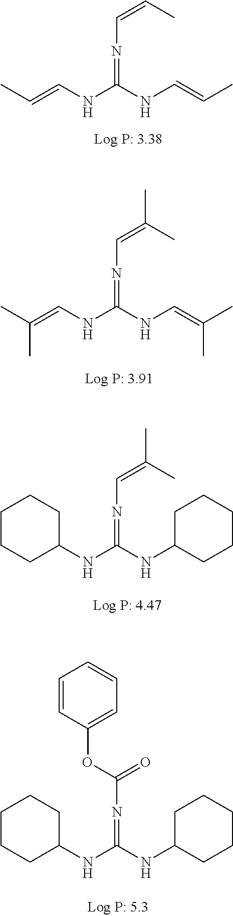

[7] Low molecular compound having a nitrogen atom and having a group capable of leaving by the action of an acid

The composition of the present invention may contain a low molecular compound having a nitrogen atom and having a group capable of leaving by the action of an acid (hereinafter, sometimes referred to as “low molecular compound (D)” or “compound (D)”). The low molecular compound (D) preferably has basicity after the group capable of leaving by the action of an acid is eliminated.

The group capable of leaving by the action of an acid is not particularly limited but is preferably an acetal group, a carbonate group, a carbamate group, a tertiary ester group, a tertiary hydroxyl group or a hemiaminal ether group, more preferably a carbamate group or a hemiaminal ether group.

The molecular weight of (D) the low molecular compound having a group capable of leaving by the action of an acid is preferably from 100 to 1,000, more preferably from 100 to 700, still more preferably from 100 to 500.

The compound (D) is preferably an amine derivative having on the nitrogen atom a group capable of leaving by the action of an acid.

The compound (D) may have a protective group-containing carbamate group on the nitrogen atom. The protective group constituting the carbamate group can be represented by the following formula (d-1):

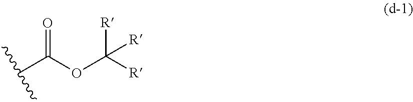

In formula (d-1), each R′ independently represents a hydrogen atom, a linear or branched alkyl group, a cycloalkyl group, an aryl group, an aralkyl group or an alkoxyalkyl group. R′ may combine with each other to form a ring.

R′ is preferably a linear or branched alkyl group, a cycloalkyl group or an aryl group, more preferably a linear or branched alkyl group or a cycloalkyl group.

Specific structures of the protective group above are illustrated below.

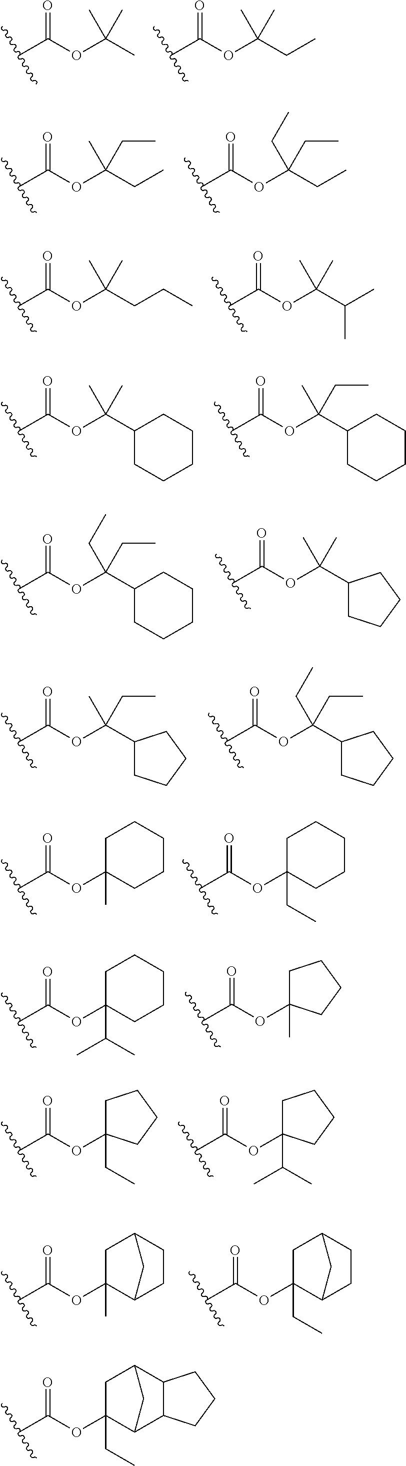

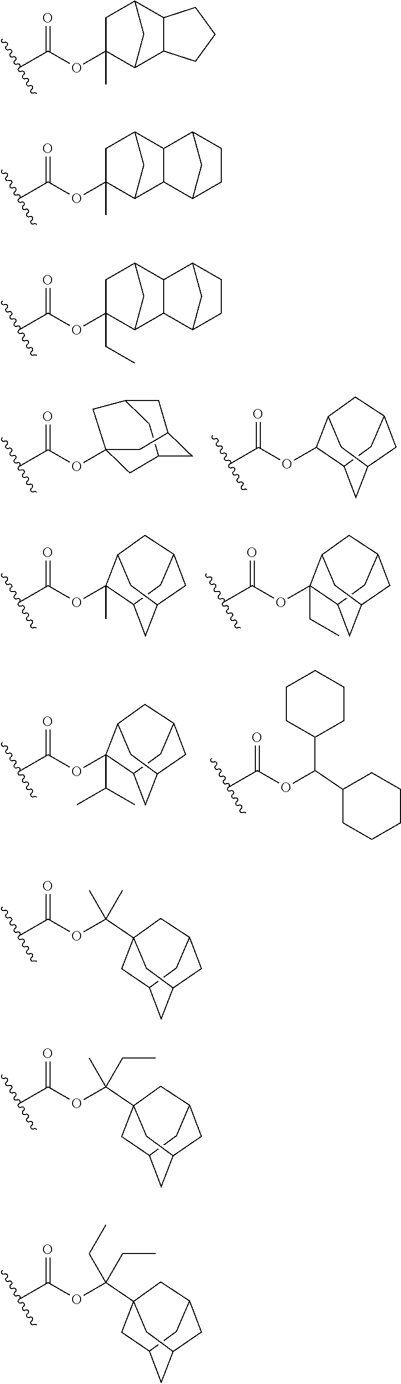

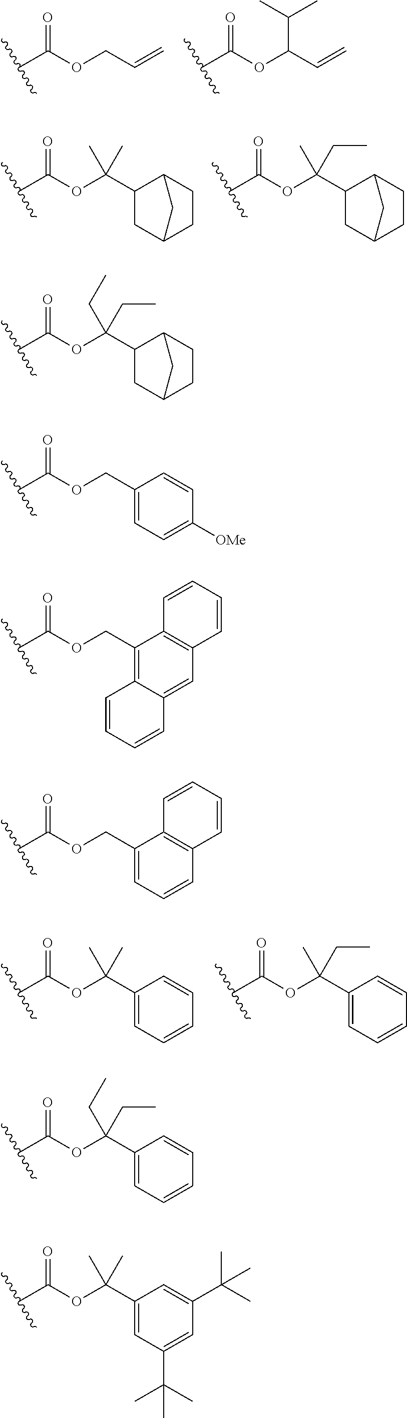

The compound (D) may be also composed by arbitrarily combining the above-described basic compound and the structure represented by formula (d-1).

The compound (D) is more preferably a compound having a structure represented by the following formula (A).

Incidentally, the compound (D) may be a compound corresponding to the above-described basic compound as long as it is a low molecular compound having a group capable of leaving by the action of an acid.

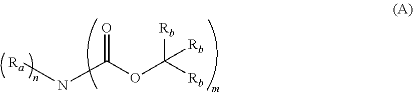

In formula (A), Ra represents a hydrogen atom, an alkyl group, a cycloalkyl group, an aryl group or an aralkyl group. Also, when n=2, two Ra may be the same or different, and two Ra may combine with each other to form a divalent heterocyclic hydrocarbon group (preferably having a carbon number of 20 or less) or a derivative thereof.

Each Rb independently represents a hydrogen atom, an alkyl group, a cycloalkyl group, an aryl group, an aralkyl group or an alkoxyalkyl group, provided that in —C(Rb)(Rb)(Rb), when one or more Rb are a hydrogen atom, at least one of the remaining Rb is a cyclopropyl group, a 1-alkoxyalkyl group or an aryl group.

At least two Rb may combine to form an alicyclic hydrocarbon group, an aromatic hydrocarbon group, a heterocyclic hydrocarbon group, or a derivative thereof.

n represents an integer of 0 to 2, m represents an integer of 1 to 3, and n+m=3.

In formula (A), the alkyl group, cycloalkyl group, aryl group and aralkyl group represented by Ra and Rb may be substituted with a functional group such as hydroxyl group, cyano group, amino group, pyrrolidino group, piperidino group, morpholino group and oxo group, an alkoxy group, or a halogen atom. The same applies to the alkoxyalkyl group represented by Rb.

Examples of the alkyl group, cycloalkyl group, aryl group and aralkyl group (these alkyl, cycloalkyl, aryl and aralkyl groups may be substituted with the above-described functional group, an alkoxy group or a halogen atom) of Ra and/or Rb include:

a group derived from a linear or branched alkane such as methane, ethane, propane, butane, pentane, hexane, heptane, octane, nonane, decane, undecane and dodecane, or a group where the group derived from an alkane is substituted with one or more kinds of or one or more groups of cycloalkyl groups such as cyclobutyl group, cyclopentyl group and cyclohexyl group;

a group derived from a cycloalkane such as cyclobutane, cyclopentane, cyclohexane, cycloheptane, cyclooctane, norbornane, adamantane and noradamantane, or a group where the group derived from a cycloalkane is substituted with one or more kinds of or one or more groups of linear or branched alkyl groups such as methyl group, ethyl group, n-propyl group, i-propyl group, n-butyl group, 2-methylpropyl group, 1-methylpropyl group and tert-butyl group;

a group derived from an aromatic compound such as benzene, naphthalene and anthracene, or a group where the group derived from an aromatic compound is substituted with one or more kinds of or one or more groups of linear or branched alkyl groups such as methyl group, ethyl group, n-propyl group, i-propyl group, n-butyl group, 2-methylpropyl group, 1-methylpropyl group and tert-butyl group;

a group derived from a heterocyclic compound such as pyrrolidine, piperidine, morpholine, tetrahydrofuran, tetrahydropyran, indole, indoline, quinoline, perhydroquinoline, indazole and benzimidazole, or a group where the group derived from a heterocyclic compound is substituted with one or more kinds of or one or more groups of linear or branched alkyl groups or aromatic compound-derived groups; a group where the group derived from a linear or branched alkane or the group derived from a cycloalkane is substituted with one or more kinds of or one or more groups of aromatic compound-derived groups such as phenyl group, naphthyl group and anthracenyl group; and a group where the substituent above is substituted with a functional group such as hydroxyl group, cyano group, amino group, pyrrolidino group, piperidino group, morpholino group and oxo group.

Examples of the divalent heterocyclic hydrocarbon group (preferably having a carbon number of 1 to 20) formed by combining Ra with each other or a derivative thereof include a group derived from a heterocyclic compound such as pyrrolidine, piperidine, morpholine, 1,4,5,6-tetrahydropyrimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1S,4S)-(+)-2,5-diazabicyclo[2.2.1]heptane, 1,5,7-triazabicyclo[4.4.0]dec-5-ene, indole, indoline, 1,2,3,4-tetrahydroquinoxaline, perhydroquinoline and 1,5,9-triazacyclododecane, and a group where the group derived from a heterocyclic compound is substituted with one or more kinds of or one or more groups of linear or branched alkane-derived groups, cycloalkane-derived groups, aromatic compound-derived groups, heterocyclic compound-derived groups, and functional groups such as hydroxyl group, cyano group, amino group, pyrrolidino group, piperidino group, morpholino group and oxo group.

Specific examples of the compound (D) particularly preferred in the present invention are illustrated below, but the present invention is not limited thereto.

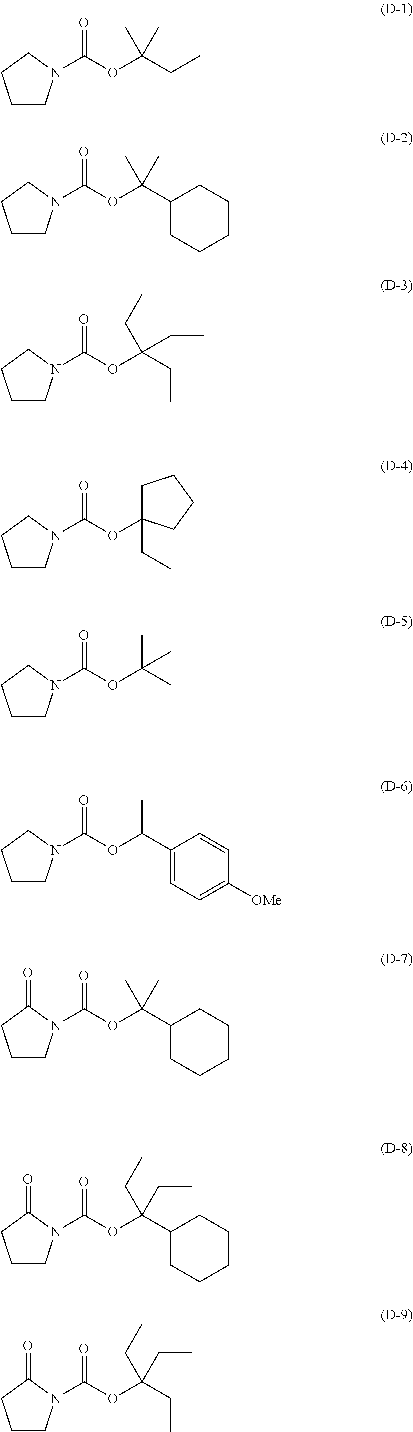

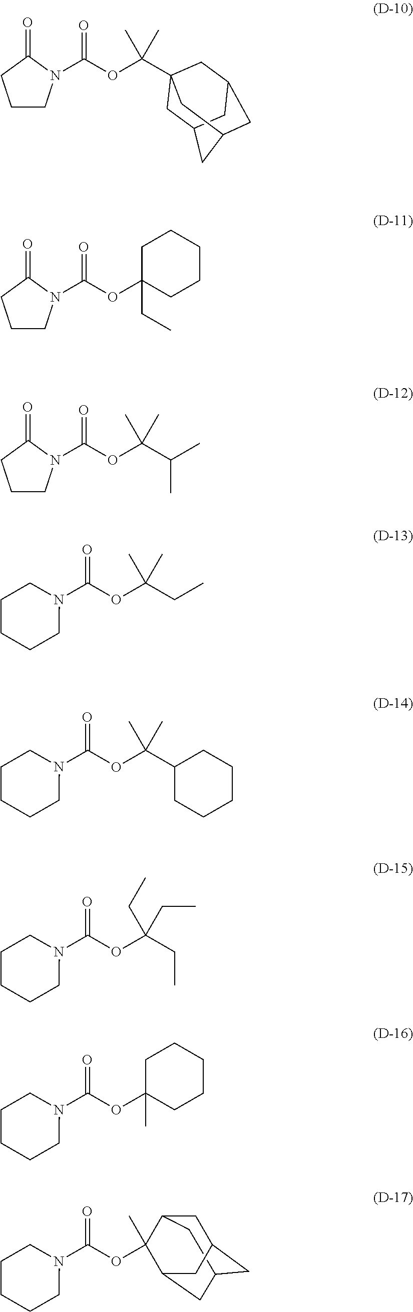

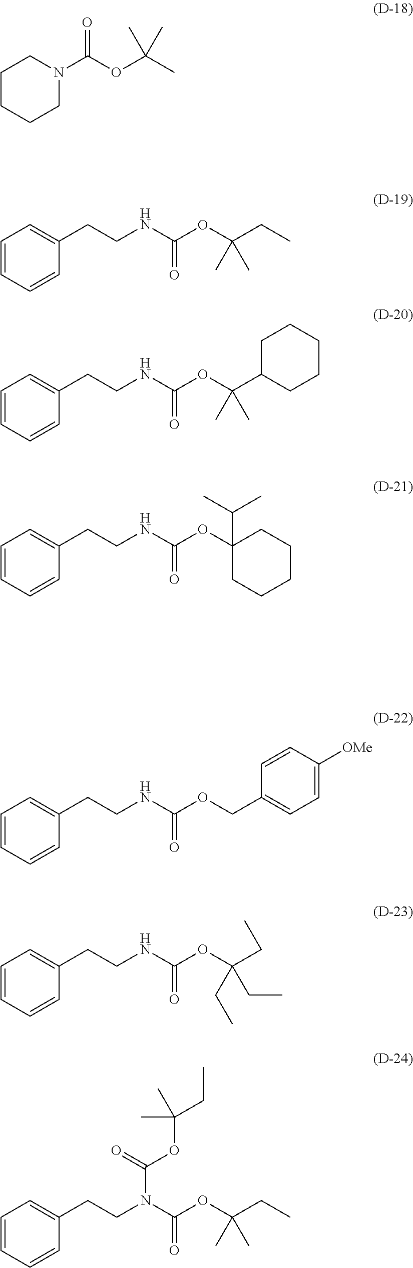

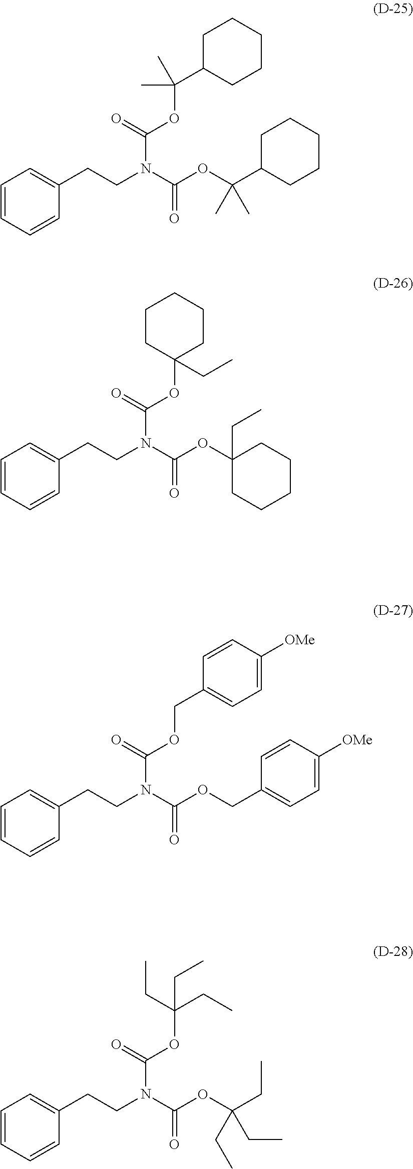 [SMILES: CC(C)(OC(=O)N(CCc1ccccc1)C(=O)OC(C)(C)C1CCCCC1)C1CCCCC1 ; CCC1(OC(=O)N(CCc2ccccc2)C(=O)OC2(CC)CCCCC2)CCCCC1 ; COc1ccc(COC(=O)N(CCc2ccccc2)C(=O)OCc2ccc(OC)cc2)cc1 ; CCC(CC)(CC)OC(=O)N(CCc1ccccc1)C(=O)OC(CC)(CC)CC]

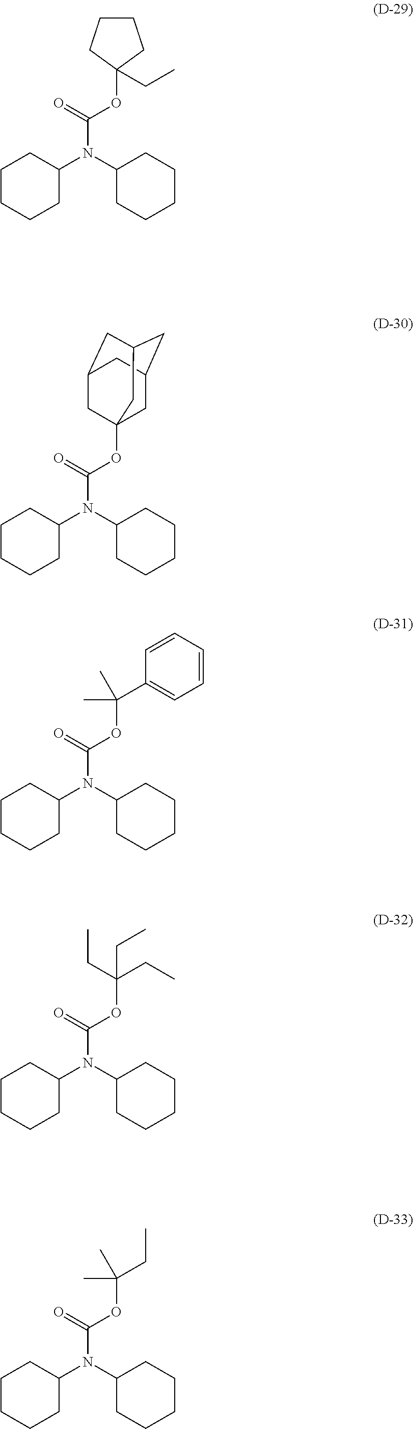 [SMILES: CCC1(OC(=O)N(C2CCCCC2)C2CCCCC2)CCCC1 ; O=C(OC12CC3CC(CC(C3)C1)C2)N(C1CCCCC1)C1CCCCC1 ; CC(C)(OC(=O)N(C1CCCCC1)C1CCCCC1)c1ccccc1 ; CCC(CC)(CC)OC(=O)N(C1CCCCC1)C1CCCCC1 ; CCC(C)(C)OC(=O)N(C1CCCCC1)C1CCCCC1]

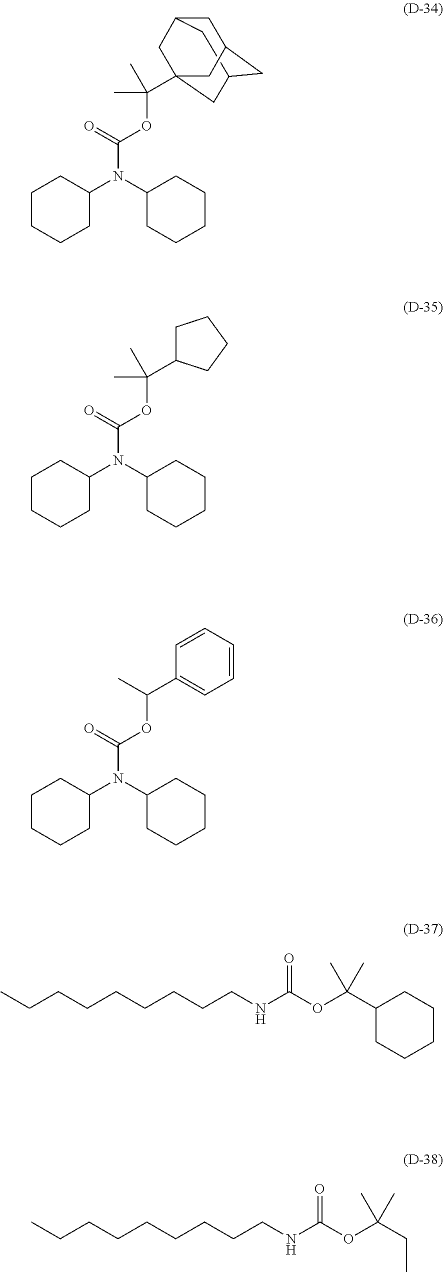 [SMILES: CC(C)(OC(=O)N(C1CCCCC1)C1CCCCC1)C12CC3CC(CC(C3)C1)C2 ; CC(C)(OC(=O)N(C1CCCCC1)C1CCCCC1)C1CCCC1 ; CC(OC(=O)N(C1CCCCC1)C1CCCCC1)c1ccccc1 ; CCCCCCCCCNC(=O)OC(C)(C)C1CCCCC1 ; CCCCCCCCCNC(=O)OC(C)(C)CC]

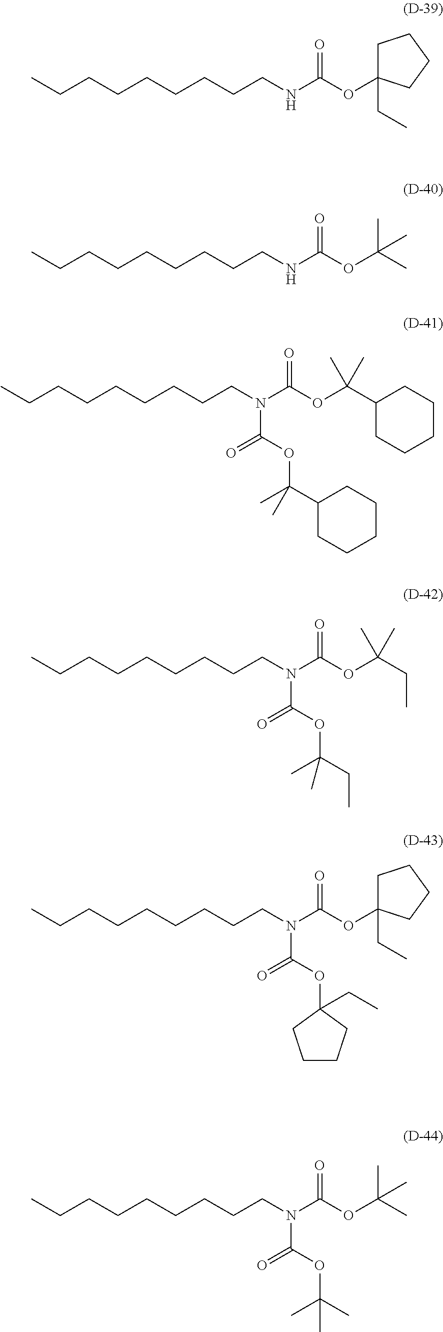

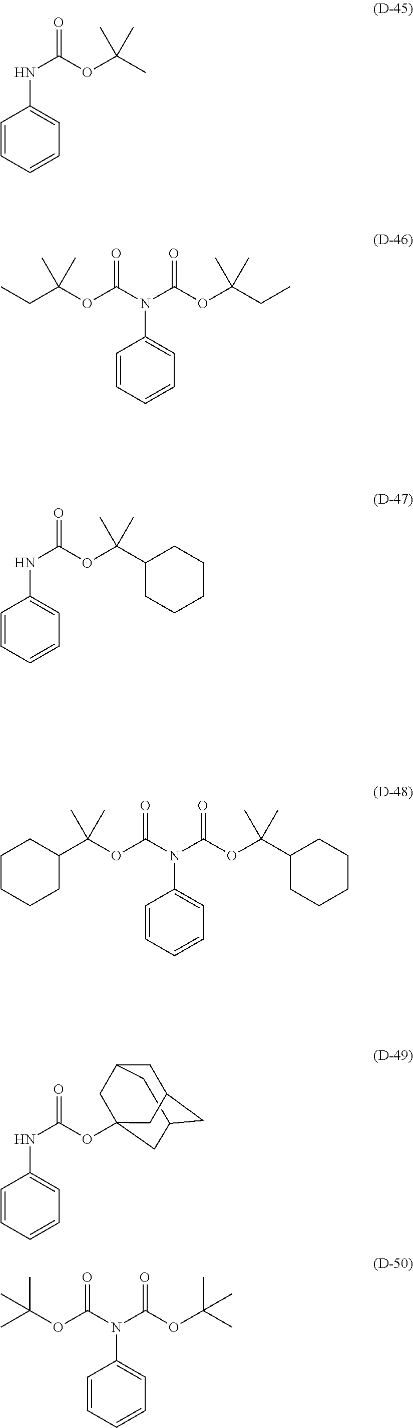

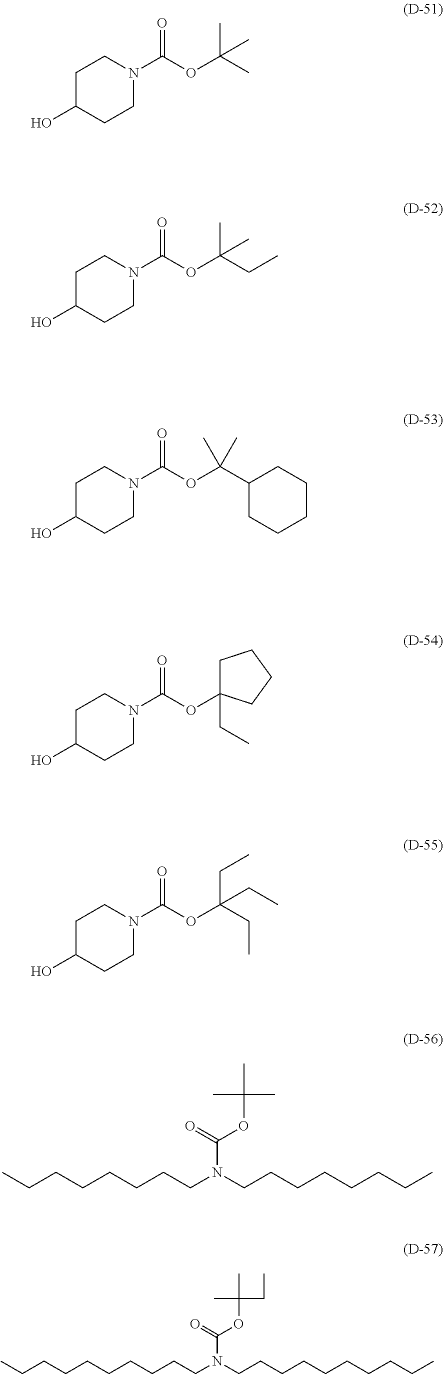

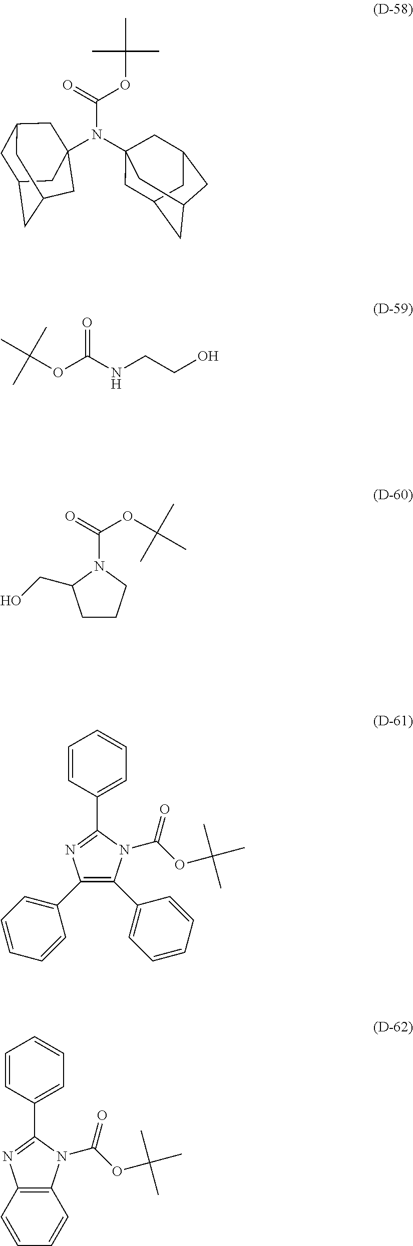 [SMILES: CC(C)(C)OC(=O)N(C12CC3CC(CC(C3)C1)C2)C12CC3CC(CC(C3)C1)C2 ; CC(C)(C)OC(=O)NCCO ; CC(C)(C)OC(=O)N1CCCC1CO ; CC(C)(C)OC(=O)n1c(-c2ccccc2)nc(-c2ccccc2)c1-c1ccccc1 ; CC(C)(C)OC(=O)n1c(-c2ccccc2)nc2ccccc21]

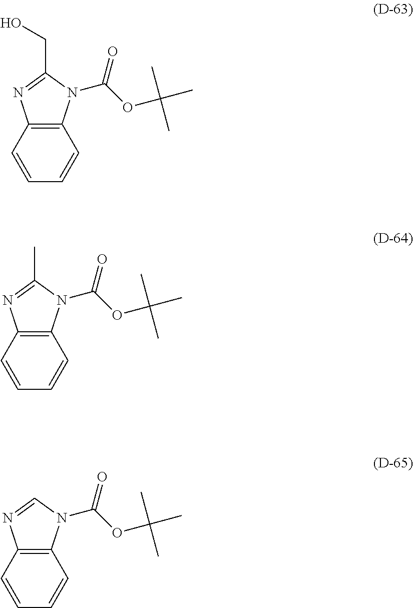 [SMILES: CC(C)(C)OC(=O)n1c(CO)nc2ccccc21 ; Cc1nc2ccccc2n1C(=O)OC(C)(C)C ; CC(C)(C)OC(=O)n1cnc2ccccc21]

The compound represented by formula (A) may be synthesized by referring to, for example, JP-A-2007-298569 and JP-A-2009-199021.

In the present invention, as for the low molecular weight compound (D), one kind of a compound may be used alone, or two or more kinds of compounds may be mixed and used.

The composition of the present invention may or may not contain the low molecular compound (D), but in the case of containing the compound (D), the content thereof is usually from 0.001 to 20 mass %, preferably from 0.001 to 10 mass %, more preferably from 0.01 to 5 mass %, based on the total solid content of the composition combined with the basic compound.

In the case where the composition of the present invention contains a photoacid generator, the ratio between the photoacid generator and the compound (D) used in the composition is preferably photoacid generator/[compound (D)+basic compound] (by mol)=from 2.5 to 300. That is, the molar ratio is preferably 2.5 or more in view of sensitivity and resolution and preferably 300 or less from the standpoint of suppressing the reduction in resolution due to thickening of the resist pattern over time after exposure until heat treatment.

The photoacid generator/[compound (D)+basic compound] (by mol) is more preferably from 5.0 to 200, still more preferably from 7.0 to 150.

Other examples of the compound which can be used in the composition of the present invention include compounds synthesized in Examples of JP-A-2002-363146, and compounds described in paragraph 0108 of JP-A-2007-298569.

A photosensitive basic compound may be also used as the basic compound. Examples of the photosensitive basic compound which can be used include compounds described in JP-T-2003-524799 (the term “JP-T” as used herein means a “published Japanese translation of a PCT patent application”) and J. Photopolym. Sci. & Tech., Vol. 8, pp. 543-553 (1995).

The molecular weight of the basic compound is usually from 100 to 1,500, preferably from 150 to 1,300, more preferably from 200 to 1,000.

One kind of these basic compounds may be used alone, or two or more kinds thereof may be used in combination.

In the case where the composition of the present invention contains a basic compound, the content thereof is preferably from 0.01 to 8.0 mass %, more preferably from 0.1 to 5.0 mass %, still more preferably from 0.2 to 4.0 mass %, based on the total solid content of the composition.

The molar ratio of the basic compound to the photoacid generator is preferably from 0.01 to 10, more preferably from 0.05 to 5, still more preferably from 0.1 to 3. If the molar ratio is excessively large, the sensitivity and/or resolution may be reduced, whereas if the molar ratio is excessively small, thinning of the pattern may occur between exposure and heating (post-baking). The molar ratio is more preferably from 0.05 to 5, still more preferably from 0.1 to 3. In this molar ratio, the amount of the photoacid generator is based on the total amount of a repeating unit represented by formula (4) which may be contained in the resin and a photoacid generator which may be further contained in the resin.

### [4] Surfactant

The extreme ultraviolet-sensitive composition of the present invention may further contain a surfactant. Among others, the surfactant is preferably a fluorine-containing and/or silicon-containing surfactant.

Examples of the fluorine-containing and/or silicon-containing surfactant include Megaface F176 and Megaface R08 produced by DIC Corporation; PF656 and PF6320 produced by OMNOVA; Troysol S-366 produced by Troy Chemical; Florad FC430 produced by Sumitomo 3M Inc.; and Polysiloxane Polymer KP-341 produced by Shin-Etsu Chemical Co., Ltd.

A surfactant other than the fluorine-containing and/or silicon-containing surfactant may be also used. Examples of this surfactant include a nonionic surfactant such as polyoxyethylene alkyl ethers and polyoxyethylene alkylaryl ethers.

In addition, known surfactants may be appropriately used. Examples of the surfactant which can be used include surfactants described in paragraph [0273] et seq. of U.S. Patent Application Publication No. 2008/0248425A1.

One kind of a surfactant may be used alone, or two or more kinds of surfactants may be used in combination.

In the case where the composition of the present invention further contains a surfactant, the amount used thereof is preferably from 0.0001 to 2 mass %, more preferably from 0.001 to 1 mass %, based on the total solid content of the composition.

### [5] Other Additives

### (Dye)

The extreme ultraviolet-sensitive composition of the present invention may further contain a dye. Preferred dyes include, for example, an oil dye and a basic dye. Specific examples thereof include Oil Yellow #101, Oil Yellow #103, Oil Pink #312, Oil Green BG, Oil Blue BOS, Oil Blue #603, Oil Black BY, Oil Black BS, Oil Black T-505 (all produced by Orient Chemical Industries, Ltd.), Crystal Violet (CI 42555), Methyl Violet (CI 42535), Rhodamine B (CI 45170B), Malachite Green (CI 42000), and Methylene Blue (CI 52015).

### (Photo-Base Generator)

The extreme ultraviolet-sensitive composition of the present invention may further contain a photo-base generator. When a photo-base generator is contained, a more excellent pattern can be formed.

Examples of the photo-base generator include compounds described in JP-A-4-151156, JP-A-4-162040, JP-A-5-197148, JP-A-5-5995, JP-A-6-194834, JP-A-8-146608, JP-A-10-83079 and European Patent No. 622682.

Preferred photo-base generators specifically include 2-nitrobenzyl carbamate, 2,5-dinitrobenzylcyclohexyl carbamate, N-cyclohexyl-4-methylphenylsulfonamide, and 1,1-dimethyl-2-phenylethyl-N-isopropyl carbamate.

### (Antioxidant)

The extreme ultraviolet-sensitive composition of the present invention may further contain an antioxidant. When an antioxidant is contained, the organic material can be prevented from oxidation in the presence of oxygen.

Examples of the antioxidant include a phenol-based antioxidant, an antioxidant composed of an organic acid derivative, a sulfur-containing antioxidant, a phosphorus-based antioxidant, an amine-based antioxidant, an antioxidant composed of an amine-aldehyde condensate, and an antioxidant composed of an amine-ketone condensate. Among these antioxidants, a phenol-based antioxidant and an antioxidant composed of an organic acid derivative are preferably used. When such an antioxidant is used, the function as an antioxidant can be brought out without deteriorating the performance of the composition.

As the phenol-based antioxidant, for example, substituted phenols and bis-, tris- and poly-phenols can be used.

Examples of the substituted phenols include 1-oxy-3-methyl-4-isopropylbenzene, 2,6-di-tert-butylphenol, 2,6-di-tert-butyl-4-ethylphenol, 2,6-di-tert-butyl-4-methylphenol, 4-hydroxymethyl-2,6-di-tert-butylphenol, butylhydroxyanisole, 2-(1-methylcyclohexyl)-4,6-dimethylphenol, 2,4-dimethyl-6-tert-butylphenol, 2-methyl-4,6-dinonylphenol, 2,6-di-tert-butyl-α-dimethylamino-p-cresol, 6-(4-hydroxy-3,5-di-tert-butylanilino)-2,4-bis*octyl-thio-1,3,5-triazine, n-octadecyl-3-(4′-hydroxy-3′,5′-di-tert-butyl*phenyl)propionate, octylated phenol, aralkyl-substituted phenols, alkylated p-cresol, and hindered phenol.

Examples of the bis-, tris- and poly-phenols include 4,4′-dihydroxydiphenyl, methylenebis(dimethyl-4,6-phenol), 2,2′-methylene-bis-(4-methyl-6-tert-butylphenol), 2,2′-methylene-bis-(4-methyl-6-cyclohexyl*phenol), 2,2′-methylene-bis-(4-ethyl-6-tert-butylphenol), 4,4′-methylene-bis-(2,6-di-tert-butylphenol), 2,2′-methylene-bis-(6-alphamethyl-benzyl-p-cresol), methylene-crosslinked polyvalent alkylphenol, 4,4′-butylidenebis-(3-methyl-6-tert-butylphenol), 1,1-bis-(4-hydroxyphenyl)-cyclohexane, 2,2′-dihydroxy-3,3′-di-α-methylcyclohexyl)-5,5′-dimethyldiphenylmethane, alkylated bisphenol, hindered bisphenol, 1,3,5-trimethyl-2,4,6-tris(3,5-di-tert-butyl-4-hydroxybenzyl)benzene, tris-(2-methyl-4-hydroxy-5-tert-butylphenyl)butane, and tetrakis-[methylene-3-(3′,5′-di-tert-butyl-4′-hydroxyphenyl)propionate]methane.

Preferred antioxidants include 2,6-di-tert-butyl-4-methylphenol, 4-hydroxymethyl-2,6-di-tert-butylphenol, 2,2′-methylenebis(4-methyl-6-tert-butylphenol), butylhydroxyanisole, tert-butylhydroquinone, 2,4,5-trihydroxybutyrophenone, nordihydro-guaiaretic acid, propyl gallate, octyl gallate, lauryl gallate, and isopropyl citrate. Among these, 2,6-di-tert-butyl-4-methylphenol, 4-hydroxymethyl-2,6-di-tert-butylphenol, butylhydroxyanisole and tert-butylhydroquinone are more preferred, and 2,6-di-tert-butyl-4-methylphenol and 4-hydroxymethyl-2,6-di-tert-butylphenol are still more preferred.

One kind of an antioxidant may be used alone, or two or more kinds of antioxidants may be used in combination.

In the case of incorporating an antioxidant into the composition of the present invention, the amount added thereof is preferably 1 ppm or more, more preferably 5 ppm or more, still more preferably 10 ppm or more, yet still more preferably 50 ppm or more, even yet still more preferably 100 ppm or more, and most preferably from 100 to 1,000 ppm.

### [6] Solvent

The extreme ultraviolet-sensitive composition of the present invention may further contain a solvent. As the solvent, an organic solvent is typically used. Examples of the organic solvent include an alkylene glycol monoalkyl ether carboxylate, an alkylene glycol monoalkyl ether, an alkyl lactate ester, an alkyl alkoxypropionate, a cyclic lactone (preferably having a carbon number of 4 to 10), a monoketone compound (preferably having a carbon number of 4 to 10) which may contain a ring, an alkylene carbonate, an alkyl alkoxyacetate, and an alkyl pyruvate.

Preferred examples of the alkylene glycol monoalkyl ether carboxylate include propylene glycol monomethyl ether acetate (PGMEA, another name: 1-methoxy-2-acetoxypropane), propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate, and ethylene glycol monoethyl ether acetate.

Examples of the alkylene glycol monoalkyl ether include propylene glycol monomethyl ether (PGME, another name: 1-methoxy-2-propanol), propylene glycol monoethyl ether, propylene glycol monopropyl ether, propylene glycol monobutyl ether, ethylene glycol monomethyl ether, and ethylene glycol monoethyl ether.

Examples of the alkyl lactate ester include methyl lactate, ethyl lactate, propyl lactate, and butyl lactate.

Examples of the alkyl alkoxypropionate include ethyl 3-ethoxypropionate, methyl 3-methoxypropionate, methyl 3-ethoxypropionate, and ethyl 3-methoxypropionate.

Examples of the cyclic lactone include β-propiolactone, β-butyrolactone, γ-butyrolactone, α-methyl-γ-butyrolactone, β-methyl-γ-butyrolactone, γ-valerolactone, γ-caprolactone, γ-octanoic lactone, and α-hydroxy-γ-butyrolactone.

Examples of the monoketone compound which may contain a ring include 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-penten-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone, and 3-methylcycloheptanone.

Examples of the alkylene carbonate include propylene carbonate, vinylene carbonate, ethylene carbonate, and butylene carbonate.

Examples of the alkyl alkoxyacetate include 2-methoxyethyl acetate, 2-ethoxyethyl acetate, 2-(2-ethoxyethoxy)ethyl acetate, 3-methoxy-3-methylbutyl acetate, and 1-methoxy-2-propyl acetate.

Examples of the alkyl pyruvate include methyl pyruvate, ethyl pyruvate, and propyl pyruvate.

As the solvent, a solvent having a boiling point of 130° C. or more at ordinary temperature under atmospheric pressure is preferably used. Specific examples thereof include cyclopentanone, γ-butyrolactone, cyclohexanone, ethyl lactate, ethylene glycol monoethyl ether acetate, PGMEA, ethyl 3-ethoxypropionate, ethyl pyruvate, 2-ethoxyethyl acetate, 2-(2-ethoxyethoxy)ethyl acetate, and propylene carbonate.

As for these solvents, one kind may be used alone, or two or more kinds may be mixed and used. In the latter case, a mixed solvent of a solvent containing a hydroxyl group and a solvent not containing a hydroxyl group is preferably used.

Examples of the solvent containing a hydroxyl group include ethylene glycol, ethylene glycol monomethyl ether, ethylene glycol monoethyl ether, propylene glycol, PGME, propylene glycol monoethyl ether, and ethyl lactate. Among these, PGME and ethyl lactate are preferred.

Examples of the solvent not containing a hydroxyl group include PGMEA, ethyl ethoxypropionate, 2-heptanone, γ-butyrolactone, cyclohexanone, butyl acetate, N-methylpyrrolidone, N,N-dimethylacetamide, and dimethylsulfoxide. Among these, propylene glycol monomethyl ether acetate, ethyl ethoxypropionate, 2-heptanone, γ-butyrolactone, cyclohexanone and butyl acetate are preferred, and PGMEA, ethyl ethoxypropionate and 2-heptanone are more preferred.

In the case of using a mixed solvent of a solvent containing a hydroxyl group and a solvent not containing a hydroxyl group, the mass ratio therebetween is preferably from 1/99 to 99/1, more preferably from 10/90 to 90/10, still more preferably from 20/80 to 60/40.

Incidentally, when a mixed solvent containing 50 mass % or more of a hydroxyl group-free solvent is used, excellent coating uniformity can be achieved in particular. Among others, the solvent is preferably a mixed solvent of PGMEA and one or more other solvents.

The content of the solvent in the extreme ultraviolet-sensitive composition may be appropriately adjusted according to the desired film thickness or the like, but the content is generally adjusted such that the total solid content concentration of the composition becomes from 0.5 to 15 mass %, preferably from 1.0 to 10 mass %, more preferably from 1.2 to 5 mass %.

In the foregoing pages, the extreme ultraviolet-sensitive resin composition usable in the pattern forming method of the present invention is described in detail, but in the case where an ultrafine pattern such as pattern having a line part with a line width of 20 nm or less is formed by exposure using an extreme ultraviolet ray (EUV light), the weight average molecular weight of the acid-decomposable resin is preferably not excessively high so as to obtain excellent roughness performance and specifically, as described above, is preferably from 1,000 to 200,000, more preferably from 2,000 to 50,000, still more preferably from 2,000 to 15,000. As a result, the glass transition temperature (Tg) of the acid-decomposable resin tends to be low and in turn, the temperature range in formula (1) tends to be low.

This brings about a tendency that the upper limit of T_{PEB} is also low and an acid-induced decomposition reaction is less likely to occur in the acid-decomposable resin.

For this reason, the activation energy for an acid-induced decomposition reaction of the acid-decomposable resin is preferably low (in other words, the sensitivity is high) and from this standpoint, it is preferred that the acid-decomposable resin contains a repeating unit represented by formula (VI) and at the same time, Y₂ in formula (VI) is a structure represented by formula (VI-A).

On the other hand, having a low activation energy for an acid-induced decomposition reaction of the acid-decomposable resin means that the reaction readily proceeds even with a small amount of an acid, and in particular, when the resin (A) contains a repeating unit represented by formula (VI) and Y₂ in formula (VI) is a structure represented by formula (VI-A), in order to reduce the diffusibility of the acid, it is preferred that:

(i) the extreme ultraviolet-sensitive resin composition further contains (B) a compound capable of generating an acid upon irradiation with an actinic ray or radiation and at the same time, the volume of the acid generated from the compound (B) upon irradiation with an actinic ray or radiation is 240 Å³ or more, or

(ii) the resin (A) is a resin further containing a repeating unit represented by formula (4).

### [7] Pattern Forming Method

As described above, the pattern forming method of the present invention comprises, in order,

(i) a step of forming a film (resist film) by using an extreme ultraviolet-sensitive resin composition containing (A) a resin having an acid-decomposable group,

(ii) a step of exposing the film by using an extreme ultraviolet ray (EUV light),

(iii) a step of heating the film (PEB; Post Exposure Bake), and

(iv) a step of developing the film to form a pattern.

The extreme ultraviolet-sensitive resin composition is typically used as follows. That is, the extreme ultraviolet-sensitive resin composition is typically coated on a support such as substrate to form a film. The thickness of the film is preferably from 20 to 150 nm, more preferably from 30 to 100 nm. The method for coating the composition on a substrate is preferably spin coating, and the rotation speed of spin coating is preferably from 1,000 to 3,000 rpm.

For example, the composition is coated on such a substrate (e.g., silicon/silicon dioxide-coated substrate, silicon nitride and chromium-deposited quartz substrate) as used in the production of a precision integrated circuit device, an imprint mold or the like, by using a spinner, a coater or the like. The coating is then dried, whereby an actinic ray-sensitive or radiation-sensitive film can be formed.

The resist film is irradiated with an actinic ray or radiation through a predetermined mask, then preferably baked (heated), and further subjected to development and rinsing.

It is also preferred to include, after film formation, a preheating step (PB; Prebake) before entering the exposure step.

As for the heating temperature, the preheating step (PB) is preferably performed at 70 to 120° C., more preferably at 80 to 110° C.

The heating time in the preheating step (PB) is preferably from 30 to 300 seconds, more preferably from 30 to 180 seconds, still more preferably from 30 to 90 seconds.

In the pattern forming method of the present invention, in order to form an ultrafine pattern having a line part with a line width of 20 nm or less, the optical image formed by exposure on the film surface in the step (ii) is an optical image having a line part with a line width of 20 nm or less as an exposed area or an unexposed area.

In the case where the line part of the optical image is an unexposed area, an ultrafine pattern having a line part with a line width of 20 nm or less can be formed by using an alkali developer for the developer. The pattern obtained here is a positive pattern.

On the other hand, in the case where the line part of the optical image is an exposed area, an ultrafine pattern having a line part with a line width of 20 nm or less can be formed by using an organic solvent-containing developer for the developer. The pattern obtained here is a negative pattern.

In the case where the line part of the optical image is an unexposed area and at the same time, the developer is an alkali developer, that is, in the positive pattern forming method, the line width in the line part of the optical image can be defined as [the width of a line-shaped shadow from an extreme ultraviolet ray (EUV light) formed on the surface of the resist film by a mask].

On the other hand, in the case where the line part of the optical image is an exposed area and at the same time, the developer is an organic developer, that is, in the negative pattern forming method, the line width in the line part of the optical image can be defined as [the width of a line-shaped exposed area defined by “shadows from an extreme ultraviolet ray (EUV light) formed on the surface of the resist film by a mask” (in other words, the distance between the outer edge of a shadow part and the outer edge of another shadow part located adjacently to the shadow part above)].

Also, as described above, the heating temperature T_{PEB}(° C.) in the step (iii) is selected to satisfy formula (1). Here, in the case where a plurality of kinds of resins (A) are present, more specifically, in the case where the resin (A) is composed of resin 1, resin 2, . . . and resin x, the “glass transition temperature (Tg) of the resin (A)” in the following formulae (1), (1′) and (1″) is calculated based on the following formula (T):

Tg=ρ[(ω1×Tg1)+(ω2×Tg2)+ . . . +(ωx×Tgx)] (T)

In formula (T), Tg1, Tg2, . . . , and Tgx are the glass transition temperatures of resin 1, resin 2, . . . , and resin x, respectively.

ω1, ω2, . . . , and ωx are the contents of resin 1, resin 2, . . . , and resin x, respectively, based on the total amount of resins constituting the resin (A).

[Glass transition temperature (Tg) of the resin (A)−30](° C.)≦T_{PEB}≦glass transition temperature (Tg)(° C.) of the resin (A) (1)

The heating temperature T_{PEB}(° C.) is more preferably selected to satisfy the following formula (1′), still more preferably selected to satisfy the following formula (1″):

[Glass transition temperature (Tg) of the resin (A)−20](° C.)≦T_{PEB}≦[glass transition temperature (Tg) of the resin (A)−5](° C.) (1′)

[Glass transition temperature (Tg) of the resin (A)−15](° C.) T_{PEB}≦[glass transition temperature (Tg) of the resin (A)−5](° C.) (1″)

The heating temperature T_{PEB} satisfies the above-described range, whereby, as described above, a pattern having a line part with a line width of 20 nm or less can be formed in the state of satisfying high resolution, good pattern cross-sectional profile and high roughness performance all at the same time.

The glass transition temperature (Tg) of the resin (A) is not particularly limited but is typically from 70 to 200° C., more typically from 75 to 200° C., and therefore, the heating temperature T_{PEB} is typically from 40 to 200° C.

The glass transition temperature (Tg) varies according to the kind of the resin and in turn, the upper limit value and the lower limit value in formulae (1) and (1′) are changed, but the heating temperature T_{PEB} is preferably from 60 to 150° C., more preferably from 70 to 130° C.

The heating time in the heating step (PEB) is preferably from 30 to 300 seconds, more preferably from 30 to 180 seconds, still more preferably from 30 to 90 seconds.

The heating in the preheating step (PB), the step (iii) (PEB) and the later-described step (v) can be performed using a device attached to an ordinary exposure/developing machine or may be performed using a hot plate or the like.

Before forming the resist film, an antireflection film may be previously provided by coating on the substrate.

The antireflection film used may be either an inorganic film type such as titanium, titanium dioxide, titanium nitride, chromium oxide, carbon and amorphous silicon, or an organic film type composed of a light absorber and a polymer material. A commercially available organic antireflection film such as DUV30 Series and DUV-40 Series produced by Brewer Science, Inc. and AR-2, AR-3 and AR-5 produced by Shipley Co., Ltd. may be also used as the organic antireflection film.

In the development step, an alkali developer or an organic solvent-containing developer (hereinafter, sometimes referred to as an organic developer) is used.

Examples of the alkali developer include an alkaline aqueous solution containing inorganic alkalis such as sodium hydroxide, potassium hydroxide, sodium carbonate, sodium silicate, sodium metasilicate and aqueous ammonia, primary amines such as ethylamine and n-propylamine, secondary amines such as diethylamine and di-n-butylamine, tertiary amines such as triethylamine and methyldiethylamine, alcohol amines such as dimethylethanolamine and triethanolamine, quaternary ammonium salts such as tetramethylammonium hydroxide and tetraethylammonium hydroxide, or cyclic amines such as pyrrole and piperidine.

In the alkali developer, alcohols and/or a surfactant may be added each in an appropriate amount.

The concentration of the alkali developer is usually from 0.1 to 20 mass %. The pH of the alkali developer is usually from 10.0 to 15.0.

In the case where the developer is an alkali developer, as for the rinsing solution, pure water is used, and an appropriate amount of a surfactant may be added thereto before use.

As the organic developer, a polar solvent such as ketone-based solvent, ester-based solvent, alcohol-based solvent, amide-based solvent and ether-based solvent, and a hydrocarbon-based solvent can be used.

The percentage of water content of the entire organic developer is preferably less than 10 mass %, and it is more preferred to contain substantially no water.

In other words, the amount of the organic solvent used in the organic developer is preferably from 90 to 100 mass %, more preferably from 95 to 100 mass %, based on the total amount of the developer.

In the case where the developer is an organic developer, the rinsing solution used is preferably a rinsing solution containing at least one kind of an organic solvent selected from a ketone-based solvent, an ester-based solvent, an alcohol-based solvent and an amide-based solvent.

As regards the developing method, for example, a method of dipping the substrate in a bath filled with the developer for a fixed time (dipping method), a method of raising the developer on the substrate surface by the effect of a surface tension and keeping it still for a fixed time, thereby performing the development (puddling method), a method of spraying the developer on the substrate surface (spraying method), and a method of continuously ejecting the developer on the substrate spinning at a constant speed while scanning a developer ejecting nozzle at a constant rate (dynamic dispense method) may be applied.

In the rinsing step, the wafer after development is rinsed using a rinsing solution. The method for the rinsing treatment is not particularly limited but, for example, a method of continuously ejecting the rinsing solution on the substrate spinning at a constant speed (spin coating method), a method of dipping the substrate in a bath filled with the rinsing solution for a fixed time (dipping method), and a method of spraying the rinsing solution on the substrate surface (spraying method) may be applied. Above all, it is preferred to perform the rinsing treatment by the spin coating method and after the rinsing, remove the rinsing solution from the substrate surface by spinning the substrate at a rotational speed of 2,000 to 4,000 rpm. It is also preferred to include a heating step (Post Bake) after the rinsing step. The developer and rinsing solution remaining between patterns and in the inside of the pattern are removed by the baking. The heating step after the rinsing step is performed at usually from 40 to 160° C., preferably from 70 to 95° C., for usually from 10 seconds to 3 minutes, preferably from 30 to 90 seconds.

After the development step or rinsing step, a treatment of removing the developer or rinsing solution adhering on the pattern by a supercritical fluid may be performed.

Alternatively, the developer or rinsing solution may be removed by performing (v) a step of heating the pattern (PDB; Post Development Bake).

The heating temperature T_{PDB}(° C.) in the step (v) is preferably selected to satisfy the following formula (2). Here, when a plurality of kinds of resins (A) are present, the “glass transition temperature (Tg) of the resin (A)” in the following formula (2) is determined in the same manner as above.

[Glass transition temperature (Tg) of the resin (A)−20](° C.)≦T_{PDB}≦[glass transition temperature (Tg)(° C.) of the resin (A)+10](° C.) (2)

By setting the heating temperature T_{PDB} to the above-described range, fine unevenness on the side wall of the obtained pattern is appropriately smoothed, so that the roughness performance can be more improved and the resolution can be more enhanced.

In consideration of, for example, the above-described typical range of the glass transition temperature (Tg) of the resin (A), the heating temperature T_{PDB} is from 50 to 210° C.

The glass transition temperature (Tg) varies according to the kind of the resin and in turn, the upper limit value and the lower limit value in formula (2) are changed, but the heating temperature T_{PDB} is preferably from 60 to 160° C., more preferably from 70 to 100° C.

The heating time in the heating step (PDB) is preferably from 30 to 300 seconds, more preferably from 30 to 180 seconds, still more preferably from 30 to 90 seconds.

The present invention also relates to a method for selecting a heating temperature in a pattern forming method, wherein the pattern forming method comprises, in order,

(i) a step of forming a film by using an extreme ultraviolet-sensitive resin composition containing (A) a resin having an acid-decomposable group,

(ii) a step of exposing the film by using an extreme ultraviolet ray,

(iii) a step of heating the film, and

(iv) a step of developing the film to form a pattern, and wherein:

in the step (ii), the optical image formed by exposure on the surface of the film is an optical image having a line part with a line width of 20 nm or less as an exposed area or an unexposed area, and,

the method for selecting a heating temperature comprises selecting the heating temperature T_{PEB} in the step (iii) to satisfy formula (1) above.

In the method for selecting a heating temperature in a pattern forming method of the present invention, it is preferred that:

the pattern forming method further comprises (v) a step of heating the pattern, after the step (iv), and,

the method for selecting a heating temperature comprises selecting the heating temperature further comprises selecting the heating temperature T_{PDB}(° C.) in the step (v) to satisfy formula (2) above.

In addition, an imprint mold may be produced using the composition of the present invention. For details, refer to, for example, Japanese Patent 4,109,085, JP-A-2008-162101, and “Yoshihiko Hirai (compiler), Nanoimprint no Kiso to Gijutsu Kaihatsu•Oyo Tenkai-Nanoimprint no Kiban Gijutsu to Saishin no Gijutsu Tenkai (Basic and Technology Expansion•Application Development of Nanoimprint-Substrate Technology of Nanoimprint and Latest Technology Expansion), Frontier Shuppan”.

The present invention also relates to a method for manufacturing an electronic device, comprising the above-described pattern forming method of the present invention, and an electronic device manufactured by this manufacturing method.

The electronic device of the present invention is suitably mounted on electric/electronic equipment (such as home electronic device, OA*media-related device, optical device and communication device).

### EXAMPLES

### Synthesis Example

### Synthesis of Resin Poly-1

4.66 Parts by mass of 1-methoxy-2-propanol was heated at 80° C. in a nitrogen stream, and while stirring this solution, a mixed solution containing 5.0 parts by mass of 4-hydroxystyrene, 5.0 parts by mass of Monomer (M-5), 18.6 parts by mass of 1-methoxy-2-propanol and 1.36 parts by mass of dimethyl 2,2′-azobisisobutyrate [V-601, produced by Wako Pure Chemical Industries, Ltd.] was added dropwise over 2 hours. After the completion of dropwise addition, the solution was further stirred at 80° C. for 4 hour. The reaction solution was left standing to cool, then reprecipitated from a large amount of hexane/ethyl acetate and vacuum-dried to obtain 5.9 parts by mass of the resin Poly-1 of the present invention.

The weight average molecular weight (Mw: in terms of polystyrene) determined by GPC was Mw=5,000, and the polydispersity (Mw/Mn) was 1.1.

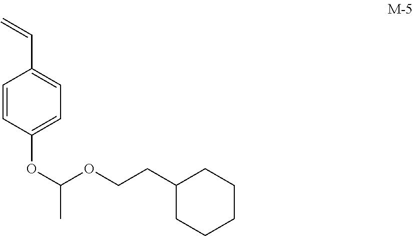 [SMILES: C=Cc1ccc(OC(C)OCCC2CCCCC2)cc1]

Resins Poly-2 to Poly-24 were synthesized by the same method. The polymer structure, weight average molecular weight (Mw) and polydispersity (Mw/Mn) of each of the resins synthesized are shown below. Also, the compositional ratio of respective repeating units in the polymer structure is shown by molar ratio.

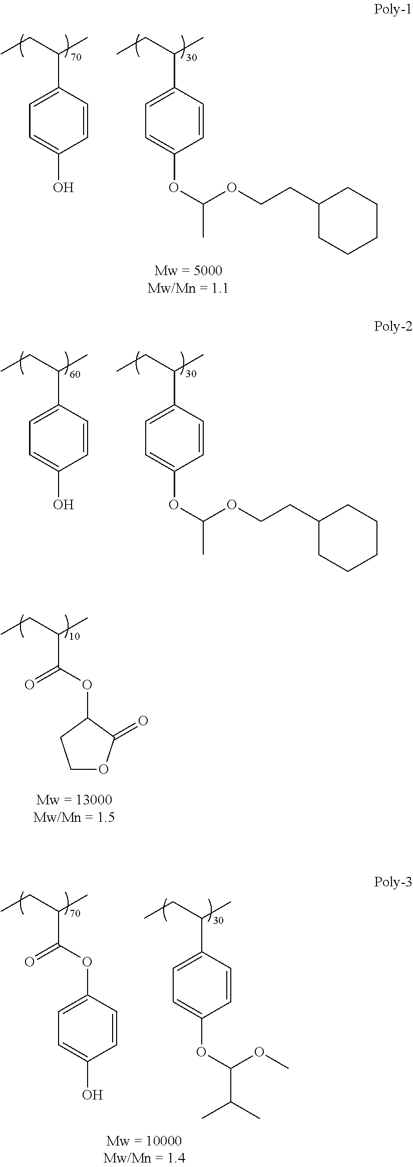

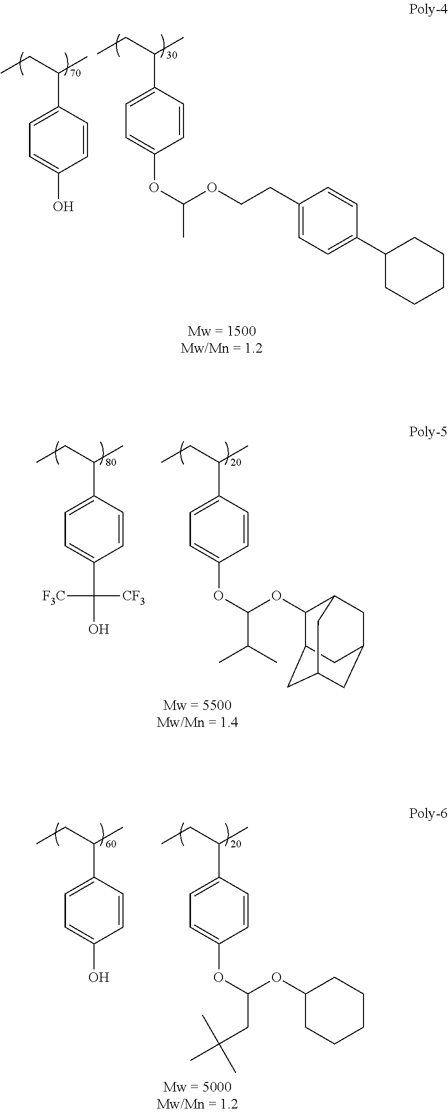

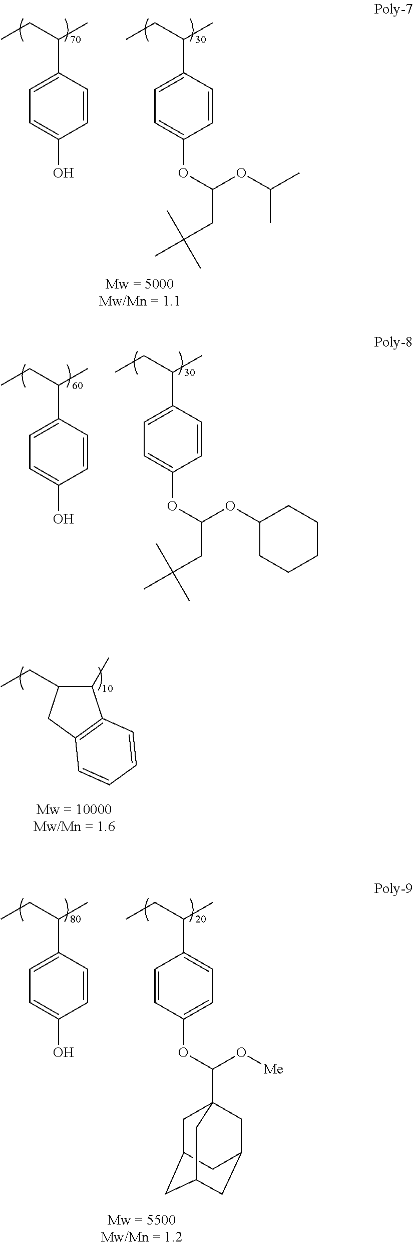

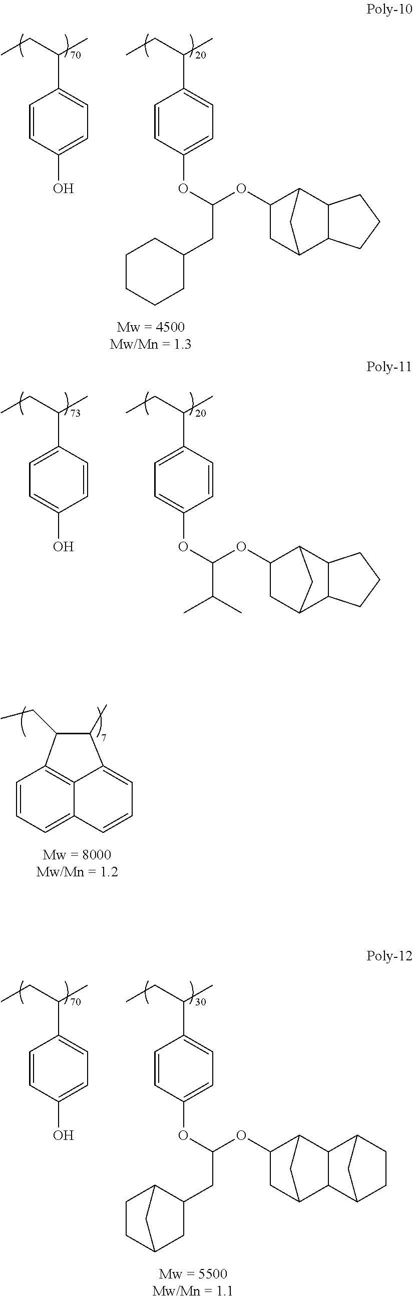

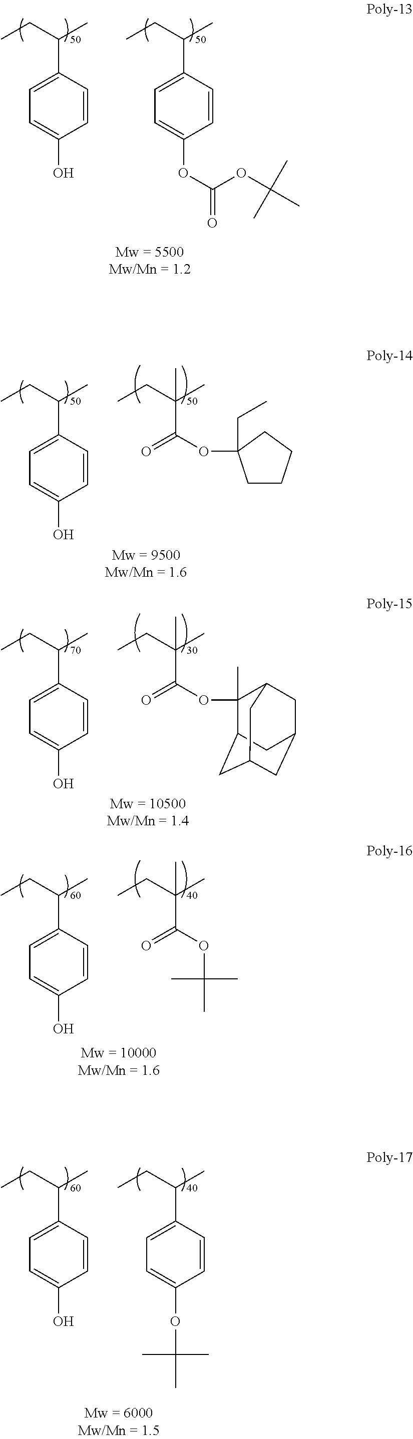

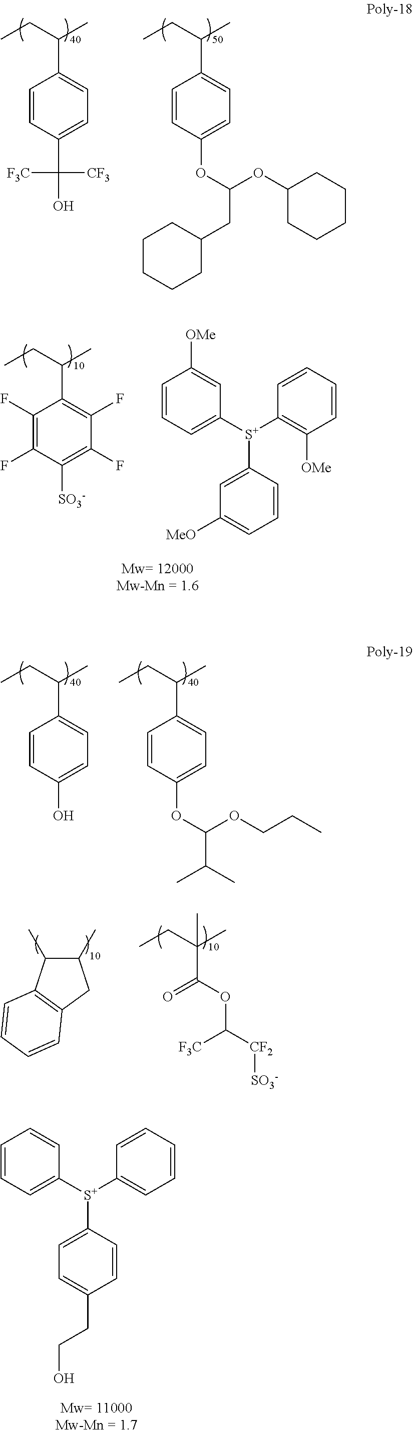

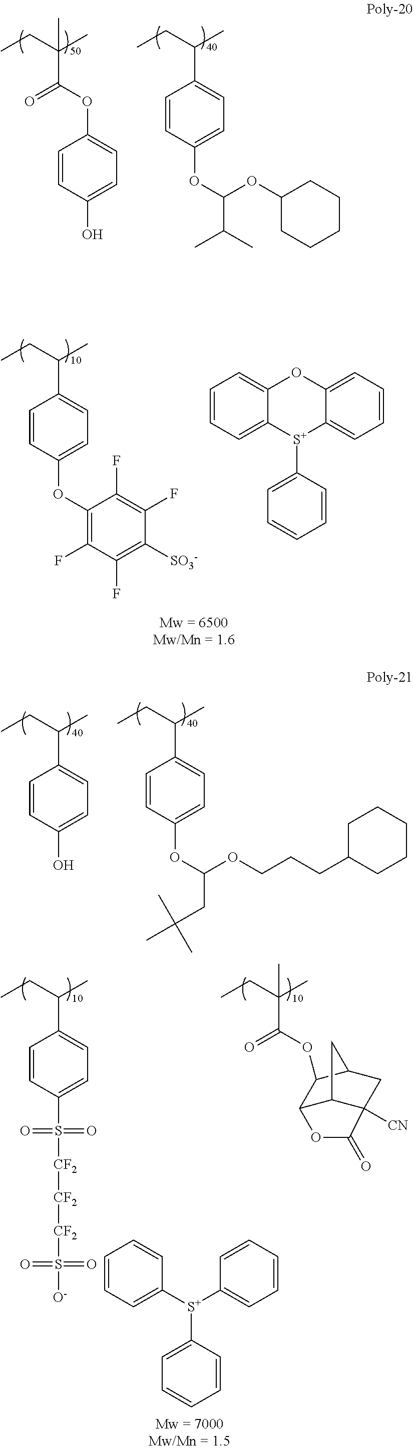

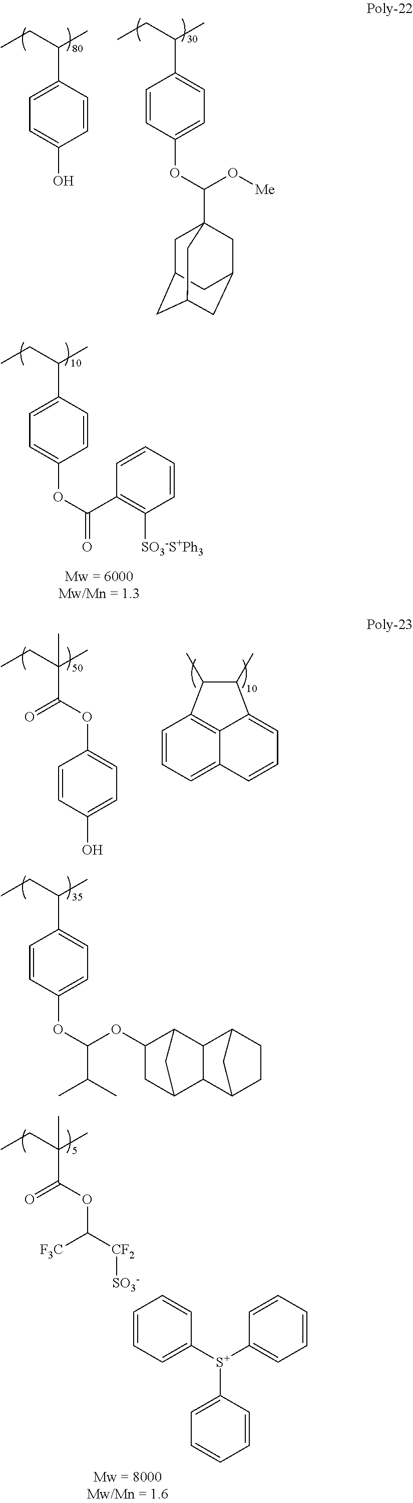

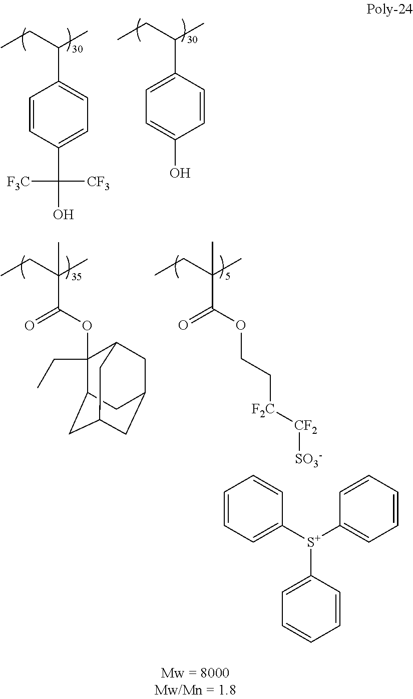

### [Photoacid Generator]

Photoacid generators used in Examples are shown below together with the volume value of the acid generated from the photoacid generator upon irradiation with an actinic ray or radiation.

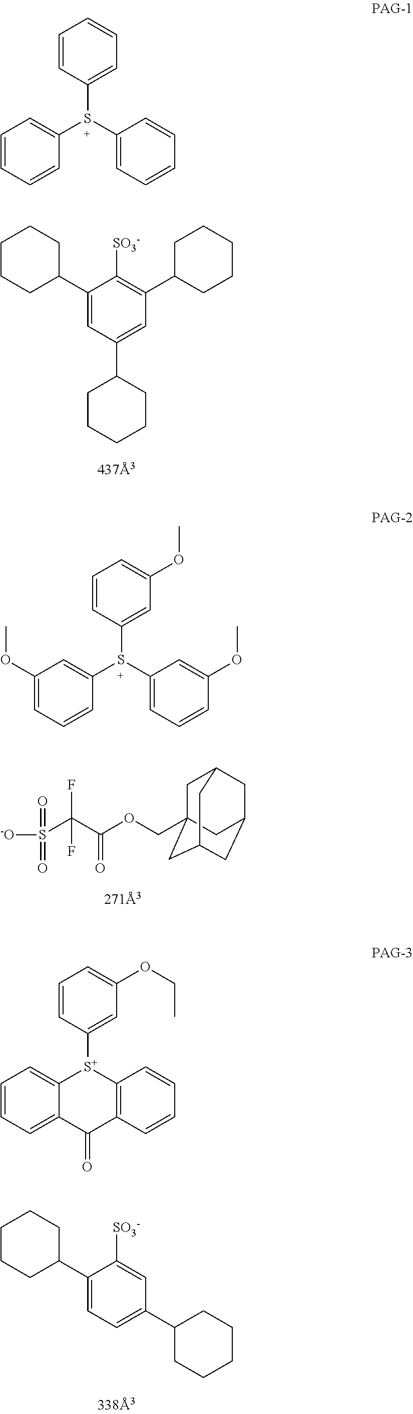

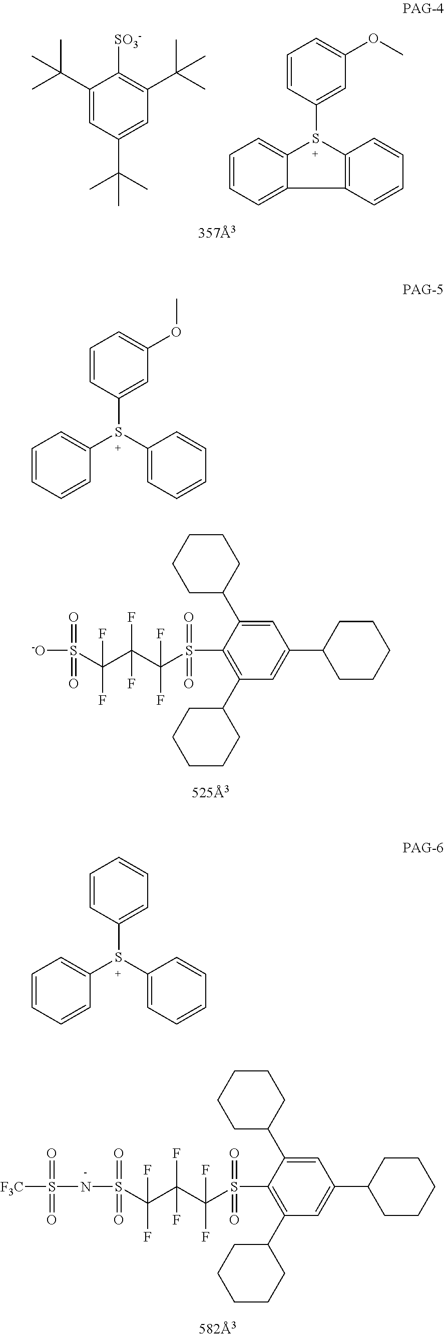

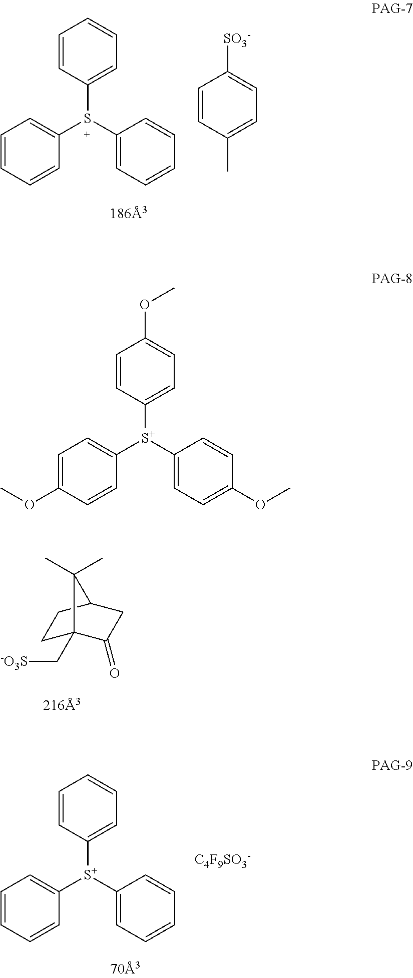

### [Basic Compound]

As the basic compound, any one of the following Compounds (C-1) to (C-3) was used.
C-1: 2,4,5-Triphenylimidazole
C-2: Tetrabutylammonium hydroxide
C-3: 1,5-Diazabicyclo[4.3.0]-non-5-ene

### [Surfactant]

As the surfactant, the following W-1 to W-4 were used.
W-1: Megaface F176 (produced by DIC Corp.; fluorine-containing)
W-2: Megaface R08 (produced by DIC Corp.; fluorine- and silicon-containing)
W-3: Polysiloxane Polymer KP-341 (produced by Shin-Etsu Chemical Co., Ltd.; silicon-containing)
W-4: Troysol S-366 (produced by Troy Chemical; fluorine-containing)

### [Solvent]

As the solvent, the following A1 to A4, B1 and B2 were used. These solvents were appropriately mixed and used.
A1: Propylene glycol monomethyl ether acetate
A2: 2-Heptanone
A3: Cyclohexanone
A4: γ-Butyrolactone
B1: Propylene glycol monomethyl ether
B2: Ethyl lactate

### Examples 1 to 32 and Comparative Examples 1 to 4

### Evaluation of Resist

The components shown in Table 1 below were dissolved in the solvent to prepare a solution having a solid content concentration of 1.5 mass % and the obtained solution was filtered through a polytetrafluoroethylene filter having a pore size of 0.10 μm to prepare an extreme ultraviolet-sensitive resin composition (positive resist composition). The content (mass %) of each component in Table 1 is based on the total solid content of the composition.

TABLE 1

| | Resist Composition | | | | | | | | | | | Process Conditions | |
|---|---|---|---|---|---|---|---|---|---|---|---|---|---|
| | Acid- | | | | | | | | | | | PEB | PDB |
| | Decom- | | Acid | | Basic | | | | | | Physical | Temper- | Temper- |
| | posable | Content | Gener- | Content | Com- | Content | Surfac- | Content | | Mass | Properties | ature | ature |
| | Resin | (mass %) | ator | (mass %) | pound | (mass %) | tant | (mass %) | Solvent | Ratio | Tg (° C.) | (° C.) | (° C.) |
| Example 1 | Poly-1 | 77.6 | PAG-1 | 20 | C-1 | 2.3 | W-1 | 0.1 | A1/B1 | 6/4 | 90 | 80 | 80 |
| Example 2 | Poly-2 | 74.7 | PAG-1 | 23 | C-1 | 2.2 | W-2 | 0.1 | A1/A3 | 3/7 | 130 | 120 | 120 |
| Example 3 | Poly-3 | 73.3 | PAG-1 | 24 | C-2 | 2.6 | W-2 | 0.1 | A1 | — | 120 | 120 | 110 |
| Example 4 | Poly-4 | 65.1 | PAG-1 | 32 | C-1 | 2.8 | W-1 | 0.1 | A1/B1 | 7/3 | 80 | 70 | 60 |
| Example 5 | Poly-5 | 71.7 | PAG-2 | 26 | C-2 | 2.1 | W-1 | 0.2 | A1 | | 120 | 100 | 110 |
| Example 6 | Poly-6 | 71.7 | PAG-3 | 25 | C-2 | 3.2 | W-3 | 0.1 | A1/B1 | 2/8 | 100 | 70 | 90 |
| Example 7 | Poly-7 | 81.8 | PAG-4 | 15 | C-1 | 3.1 | W-1 | 0.1 | A1/B1/B2 | 6/3/1 | 110 | 80 | 100 |
| Example 8 | Poly-8 | 71.5 | PAG-5 | 26 | C-3 | 2.4 | W-4 | 0.1 | A1 | — | 160 | 150 | 140 |
| Example 9 | Poly-9 | 66.3 | PAG-2 | 31 | C-1 | 2.6 | W-4 | 0.1 | A1/B1 | 5/5 | 150 | 130 | 140 |
| Example 10 | Poly-10 | 58.6 | PAG-6 | 38 | C-3 | 3.3 | W-1 | 0.1 | A1/B1/B2 | 5/4/1 | 140 | 110 | 120 |
| Example 11 | Poly-11 | 65.4 | PAG-2 | 32 | C-1 | 2.6 | — | — | A1/A3 | 7/3 | 150 | 130 | 140 |
| Example 12 | Poly-12 | 70.4 | PAG-3 | 27 | C-1 | 2.5 | W-4 | 0.1 | A1/A4 | 7/3 | 130 | 120 | 130 |
| Example 13 | Poly-13 | 56.5 | PAG-6 | 41 | C-1 | 2.4 | W-2 | 0.1 | A1/A3 | 6/4 | 90 | 80 | 90 |
| Example 14 | Poly-14 | 74.8 | PAG-1 | 23 | C-3 | 2.1 | W-1 | 0.1 | A1/B1 | 4/6 | 140 | 120 | 130 |
| Example 15 | Poly-15 | 65.9 | PAG-5 | 32 | C-3 | 2.0 | W-1 | 0.1 | A1 | — | 160 | 150 | 150 |
| Example 16 | Poly-16 | 56.7 | PAG-4 | 41 | C-1 | 2.2 | W-2 | 0.1 | A1/A3 | 3/7 | 140 | 130 | 130 |
| Example 17 | Poly-17 | 70.9 | PAG-3 | 26 | C-2 | 2.8 | W-3 | 0.3 | A1/A4 | 5/5 | 125 | 110 | 110 |
| Example 18 | Poly-18 | 51.4 | PAG-6 | 46 | C-3 | 2.5 | W-1 | 0.1 | A1/A3 | 7/3 | 140 | 130 | 140 |
| Example 19 | Poly-19 | 62.5 | PAG-1 | 34 | C-2 | 3.4 | W-4 | 0.1 | A1 | | 130 | 130 | 130 |
| Example 20 | Poly-20 | 72.7 | PAG-1 | 24 | C-2 | 3.2 | W-4 | 0.1 | A1/B1 | 2/8 | 120 | 100 | 120 |
| Example 21 | Poly-21 | 61.3 | PAG-1 | 36 | C-1 | 2.6 | W-1 | 0.1 | A1/A3 | 3/7 | 100 | 90 | 90 |
| Example 22 | Poly-22 | 73.6 | PAG-2 | 24 | C-3 | 2.3 | W-1 | 0.1 | A1/A4 | 3/7 | 105 | 90 | 90 |
| Example 23 | Poly-23 | 75.4 | PAG-1 | 22 | C-1 | 2.5 | W-1 | 0.1 | A1/B1 | 4/6 | 150 | 130 | 130 |
| Example 24 | Poly-24 | 76.2 | PAG-2 | 21 | C-1 | 2.6 | W-3 | 0.2 | A1/A4 | 6/4 | 140 | 130 | 130 |
| Example 25 | Poly-1/ | 31.2/ | PAG-1 | 35 | C-1 | 2.4 | W-1 | 0.2 | A2 | — | 105 | 90 | 90 |
| | Poly-3 | 31.2 | | | | | | | | | | | |
| Example 26 | Poly-1 | 65.7 | PAG-7 | 31 | C-2 | 3.1 | W-1 | 0.2 | A1/B1 | 5/5 | 90 | 80 | 90 |
| Example 27 | Poly-1 | 67.6 | PAG-8 | 29 | C-3 | 3.2 | W-2 | 0.2 | A1/B1/B2 | 3/3/4 | 90 | 80 | 90 |
| Example 28 | Poly-1 | 69.4 | PAG-9 | 28 | C-1 | 2.4 | W-1 | 0.2 | A1/B1 | 2/8 | 90 | 80 | 90 |
| Example 29 | Poly-1 | 60.2 | PAG-5/ | 27/10 | C-1 | 2.6 | W-3 | 0.2 | A1/A3 | 5/5 | 90 | 80 | 80 |
| | | | PAG-3 | | | | | | | | | | |
| Example 30 | Poly-1 | 56.0 | PAG-1 | 42 | C-1 | 1.8 | W-3 | 0.2 | A1/B1 | 7/3 | 90 | 80 | 110 |
| Example 31 | Poly-1 | 60.6 | PAG-2 | 36 | C-2 | 3.2 | W-1 | 0.2 | A1/A4 | 6/4 | 90 | 80 | 120 |
| Example 32 | Poly-1 | 60.2 | PAG-5 | 37 | C-1 | 2.6 | W-3 | 0.2 | A1/A3 | 5/5 | 90 | 80 | 50 |
| Comparative | Poly-1 | 64.3 | PAG-3 | 33 | C-1 | 2.5 | W-1 | 0.2 | A1/B1 | 6/4 | 90 | 100 | 90 |
| Example 1 | | | | | | | | | | | | | |
| Comparative | Poly-1 | 66.0 | PAG-2 | 31 | C-1 | 2.8 | W-2 | 0.2 | A1/B1/B2 | 4/4/2 | 90 | 110 | 90 |
| Example 2 | | | | | | | | | | | | | |
| Comparative | Poly-1 | 69.1 | PAG-3 | 28 | C-1 | 2.7 | W-4 | 0.2 | A1/B1/B2 | 4/4/2 | 90 | 120 | 90 |
| Example 3 | | | | | | | | | | | | | |
| Comparative | Poly-1 | 63.9 | PAG-6 | 33 | C-2 | 2.9 | W-3 | 0.2 | A1/B1 | 7/3 | 90 | 50 | 90 |
| Example 4 | | | | | | | | | | | | | |

The extreme ultraviolet-sensitive resin compositions were evaluated by the following methods, and the results are shown in Table 2 below.

### <Evaluation of Resist (EUV)>

The positive resist composition prepared above was uniformly coated on a hexamethyldisilazane-treated silicon substrate by a spin coater and dried under heating on a hot plate at 100° C. over 90 seconds to obtain a resist film having an average thickness of 50 nm.

The obtained resist film was irradiated with EUV light by using an extreme ultraviolet (EUV light) exposure apparatus NXE3100 (σ=0.7/0.5, wavelength=13.5 nm, NA=0.3) through a mask capable of giving the line-and-space pattern described below. Immediately after the irradiation, the film was heated at the temperature shown in Table 1 on a hot plate over 90 seconds. This heating operation is referred to as Post Exposure Bake (PEB), and the temperature here is referred to as PEB temperature. Thereafter, the film was developed using an aqueous tetramethylammonium hydroxide solution having a concentration of 2.38 mass % at 23° C. for 30 seconds, rinsed with pure water for 30 seconds, and dried at the temperature shown in Table 1. This drying operation is referred to as Post Development Bake (PDB), and the temperature here is referred to as PDB temperature. In this way, a line-and-space pattern (line:space=1:1) was formed.

### <Glass Transition Temperature (Tg) of Acid-Decomposable Resin>

Using a differential scanning calorimeter (DSC), Q2000, manufactured by TA Instruments, about 2 mg of the sample of the vacuum-dried acid-decomposable resin was weighed into an aluminum pan and after setting the aluminum pan in the DSC measurement holder and raising the temperature to 300° C. from 10° C. at 2° C./min, the glass transition temperature (Tg) of the acid-decomposable resin was determined from the inflection point in the temperature rise of the acid-decomposable resin.

### <Pattern Cross-Sectional Profile>

The obtained pattern was observed using a scanning electron microscope (S-9260, manufactured by Hitachi, Ltd.). Here, the exposure was performed by setting the conditions such that the width in the line part of the optical image on the resist film surface (that is, the width of the line-shaped shadow from the extreme ultraviolet ray (EUV light) formed on the surface of the resist film by the mask) became 16 nm, 18 nm and 26 nm. Also, the exposure dose was set to an exposure dose when resolving a 1:1 line-and-space pattern having each line width of 16 nm, 18 nm or 26 nm (hereinafter, this exposure dose is sometimes referred to as “Eₒₚₜ”). With respect to each of line-and-space patters having line widths of 16 nm, 18 nm and 26 nm obtained through exposure at Eₒₚₜ and development, the cross-sectional profile of the line part was observed using a scanning electron microscope (S-4800, manufactured by Hitachi, Ltd.). This profile was evaluated on the following two-point scale.
AA: 85°<θ<95°
A: 65°<θ≦85° or 95°≦θ<105°

The taper angle θ indicates, in the widthwise cross-section of the line part, an angle between a line segment defined by the contact of the substrate with the bottom of the pattern and a line segment constituting the side wall of the pattern.

Specifically, the taper angle θ in the evaluation criteria above was calculated as follows. That is, with respect to each of cross-sections at 5 different positions of the line part, the angle above was measured at both the left edge and the right edge of the line part, and a value obtained by averaging the thus-obtained 10 measured values was taken as the taper angle θ.

<Roughness Performance (LWR performance)>

Each of 1:1 line-and-space patterns having line widths of 16 nm, 18 nm and 26 nm obtained as above was observed by a scanning electron microscope (S-9380, manufactured by Hitachi, Ltd.), and with respect to 50 equally-spaced points in its longitudinal 2 μm region, the distance between edges was measured. The standard deviation of the distance was determined, and 3σ was computed. This 3 σ was taken as “LWR (nm)”.

### <Resolution>

The resolution was rated AA when the 1:1 line-and-pattern obtained as above was resolved without collapse, bridge and line break, rated A when less than 20% of the entire pattern was in the collapse, bridge or line break condition, and rated C when 20% or more of the entire pattern produced any one condition of collapse, bridge or line break.

These measurement results are shown in Table 2 below.

TABLE 2

| | Line Width of 26 nm | | | Line Width of 18 nm | | | Line Width of 16 nm | | |
|---|---|---|---|---|---|---|---|---|---|
| | | | LWR | | | LWR | | | LWR |
| | Resolution | Profile | (nm) | Resolution | Profile | (nm) | Resolution | Profile | (nm) |
| Example 1 | AA | AA | 4.3 | AA | AA | 4.3 | AA | AA | 4.8 |
| Example 2 | AA | AA | 4.5 | AA | AA | 4.4 | AA | AA | 4.9 |
| Example 3 | AA | AA | 4.5 | AA | AA | 5.3 | AA | AA | 5.9 |
| Example 4 | AA | AA | 4.2 | AA | AA | 4.2 | AA | AA | 4.7 |
| Example 5 | AA | AA | 4.3 | AA | AA | 4.8 | AA | AA | 5.3 |
| Example 6 | AA | AA | 4.6 | AA | AA | 5.1 | AA | AA | 5.6 |
| Example 7 | AA | AA | 4.7 | AA | AA | 5.2 | AA | AA | 5.7 |
| Example 8 | AA | AA | 4.2 | AA | AA | 4 | AA | AA | 4.7 |
| Example 9 | AA | AA | 4.4 | AA | AA | 4.5 | AA | AA | 5.4 |
| Example 10 | AA | AA | 4.6 | AA | AA | 5.2 | AA | AA | 6 |
| Example 11 | AA | AA | 4.5 | AA | AA | 4.8 | AA | AA | 5.3 |
| Example 12 | AA | AA | 4.4 | AA | AA | 4.3 | AA | AA | 4.4 |
| Example 13 | AA | AA | 5.6 | AA | AA | 6.4 | AA | AA | 6.9 |
| Example 14 | AA | AA | 6.2 | AA | AA | 7.1 | A | A | 8.2 |
| Example 15 | AA | AA | 5.8 | AA | AA | 6.6 | A | A | 7.3 |
| Example 16 | AA | AA | 5.7 | AA | AA | 6.8 | A | A | 7.9 |
| Example 17 | AA | AA | 5.9 | AA | AA | 7 | A | A | 8.3 |
| Example 18 | AA | AA | 4.3 | AA | AA | 4.4 | AA | AA | 4.6 |
| Example 19 | AA | AA | 4.6 | AA | AA | 5.3 | AA | AA | 5.9 |
| Example 20 | AA | AA | 4.5 | AA | AA | 4.9 | AA | AA | 5.3 |
| Example 21 | AA | AA | 4.3 | AA | AA | 4.4 | AA | AA | 4.9 |
| Example 22 | AA | AA | 4.8 | AA | AA | 4.8 | AA | AA | 5.5 |
| Example 23 | AA | AA | 4.5 | AA | AA | 4.9 | AA | AA | 5.3 |
| Example 24 | AA | AA | 5.6 | AA | AA | 6.3 | AA | AA | 6.8 |
| Example 25 | AA | AA | 4.7 | AA | AA | 4.9 | AA | AA | 5.2 |
| Example 26 | AA | AA | 6.3 | AA | AA | 7.6 | A | A | 8.8 |
| Example 27 | AA | AA | 6.5 | AA | AA | 8.3 | A | A | 8.9 |
| Example 28 | AA | AA | 6.4 | AA | AA | 7.9 | A | A | 8.6 |
| Example 29 | AA | AA | 6.3 | AA | AA | 8.2 | A | A | 7.6 |
| Example 30 | A | AA | 7.3 | A | AA | 8.4 | A | A | 9.3 |
| Example 31 | A | AA | 9.6 | A | AA | 10.2 | A | A | 10.3 |
| Example 32 | A | AA | 6.3 | A | AA | 8.2 | A | A | 7.6 |
| Comparative | A | A | 6.4 | C | — | — | C | — | — |
| Example 1 | | | | | | | | | |
| Comparative | A | A | 7.3 | C | — | — | C | — | — |
| Example 2 | | | | | | | | | |
| Comparative | A | A | 8.6 | C | — | — | C | — | — |
| Example 3 | | | | | | | | | |
| Comparative | A | A | 7.1 | C | — | — | C | — | — |
| Example 4 | | | | | | | | | |

As seen from the results shown in the Table above, at the formation of a pattern with a line width of 26 nm, that is, a line width of more than 20 nm, the line part could be resolved irrespectively of whether the heating temperature T_{PEB} was within or out of the range specified in the present invention. However, at the formation of a pattern with a line width of 18 nm or 16 nm, that is, a line width of 20 nm or less, when the heating temperature T_{PEB} was within the range specified in the present invention, the line part could be resolved, but when out of the range, the line part could not be resolved and the profile and LWR could not be particularly evaluated.

Also, according to the pattern forming method of Examples, at the formation of a pattern with a line width of 18 nm or 16 nm, that is, a line width of 20 nm or less, high resolution, good pattern cross-sectional profile and high roughness performance could be satisfied at the same time.

### INDUSTRIAL APPLICABILITY

According to the present invention, a pattern forming method capable of forming a pattern having a line part with a line width of 20 nm or less while satisfying high resolution, good pattern cross-sectional profile and high roughness performance all at the same time, a method for selecting a heating temperature in a pattern forming method, an extreme ultraviolet-sensitive resin composition, a resist film, a manufacturing method of an electronic device using the same, and an electronic device can be provided.

This application is based on a Japanese patent application filed on Mar. 29, 2012 (Japanese Patent Application No. 2012-78093), and the contents thereof are incorporated herein by reference.

1. A pattern forming method comprising, in order,
(i) a step of forming a film by using an extreme ultraviolet-sensitive resin composition containing (A) a resin having an acid-decomposable group,
(ii) a step of exposing the film by using an extreme ultraviolet ray,
(iii) a step of heating the film, and
(iv) a step of developing the film to form a pattern,
wherein,
in the step (ii), an optical image formed by exposure on the surface of the film is an optical image having a line part with a line width of 20 nm or less as an exposed area or an unexposed area, and,
the heating temperature T_{PEB}(° C.) in the step (iii) satisfies the following formula (1):
[glass transition temperature (Tg) of the resin (A)−30](° C.)≦T_{PEB}≦glass transition temperature (Tg) (° C.) of the resin (A) (1)

2. The pattern forming method as claimed in claim 1,
wherein,
the method further comprises (v) a step of heating the pattern, after the step (iv), and,
the heating temperature T_{PDB}(° C.) in the step (v) satisfies the following formula (2):
[glass transition temperature (Tg) of the resin (A)−20](° C.)≦T_{PDB}≦[glass transition temperature (Tg)(° C.) of the resin (A)+10](° C.) (2)

3. The pattern forming method as claimed in claim 1,
wherein,
the extreme ultraviolet-sensitive resin composition further contains (B) a compound capable of generating an acid upon irradiation with an actinic ray or radiation, and
a volume of the acid generated from the compound (B) upon irradiation with an actinic ray or radiation is 240 Å³ or more.

4. The pattern forming method as claimed in claim 1,
wherein the resin (A) is a resin further containing a repeating unit represented by the following formula (4): 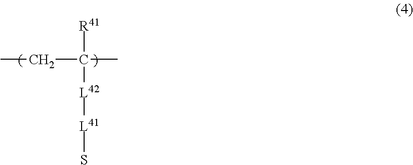
wherein R⁴¹ represents a hydrogen atom or a methyl group,
L⁴¹ represents a single bond or a divalent linking group,
L⁴² represents a divalent linking group, and
S represents a structural moiety capable of decomposing upon irradiation with an actinic ray or radiation to generate an acid on the side chain.

5. The pattern forming method as claimed in claim 1,
wherein the pattern is a positive pattern.

6. The pattern forming method as claimed in claim 5,
wherein the resin (A) is a resin containing a repeating unit represented by the following formula (VI): 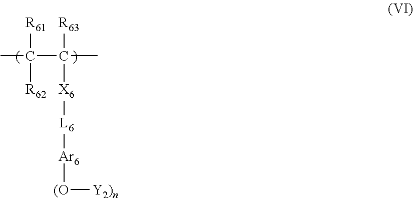
wherein
each of R₆₁, R₆₂ and R₆₃ independently represents a hydrogen atom, an alkyl group, a cycloalkyl group, a halogen atom, a cyano group or an alkoxycarbonyl group, provided that R₆₂ may combine with Ar₆ to form a ring and in this case, R₆₂ represents a single bond or an alkylene group,
X₆ represents a single bond, —COO— or —CONR₆₄—, and R₆₄ represents a hydrogen atom or an alkyl group,
L₆ represents a single bond or an alkylene group,
Ar₆ represents a (n+1)-valent aromatic ring group and in the case of combining with R₆₂ to form a ring, represents a (n+2)-valent aromatic ring group,
Y₂ represents a hydrogen atom or a group capable of leaving by the action of an acid, and in the case where a plurality of Y₂ are present, each Y₂ may be the same as or different from every other Y₂, provided that at least one Y₂ represents a group capable of leaving by the action of an acid; and
n represents an integer of 1 to 4.

7. The pattern forming method as claimed in claim 6,
wherein Y₂ in formula (VI) is a structure represented by the following formula (VI-A): 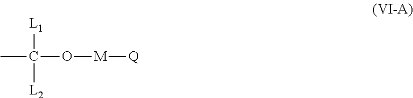
wherein each of L₁ and L₂ independently represents a hydrogen atom, an alkyl group, a cycloalkyl group, a monovalent aromatic ring group, or a group formed by combining an alkylene group and a monovalent aromatic ring group,
M represents a single bond or a divalent linking group,
Q represents an alkyl group, a cycloalkyl group which may contain a heteroatom, a monovalent aromatic ring group which may contain a heteroatom, an amino group, an ammonium group, a mercapto group, a cyano group or an aldehyde group, and
at least two members of Q, M and L₁ may combine to form a ring.

8. A method for selecting a heating temperature in a pattern forming method,
wherein the pattern forming method comprises, in order,
(i) a step of forming a film by using an extreme ultraviolet-sensitive resin composition containing (A) a resin having an acid-decomposable group,
(ii) a step of exposing the film by using an extreme ultraviolet ray,
(iii) a step of heating the film, and
(iv) a step of developing the film to form a pattern, and wherein,
in the step (ii), an optical image formed by exposure on the surface of the film is an optical image having a line part with a line width of 20 nm or less as an exposed area or an unexposed area, and,
the method for selecting a heating temperature comprises selecting the heating temperature T_{PEB}(° C.) in the step (iii) to satisfy the following formula (1):
[glass transition temperature (Tg) of the resin (A)−30](° C.)≦T_{PEB}≦glass transition temperature (Tg)(° C.) of the resin (A) (1)

9. The method for selecting a heating temperature in a pattern forming method as claimed in claim 8,
wherein,
the pattern forming method further comprises (v) a step of heating the pattern, after the step (iv), and,
the method for selecting a heating temperature further comprises selecting the heating temperature T_{PDB}(° C.) in the step (v) to satisfy the following formula (2):
[glass transition temperature (Tg) of the resin (A)−20](° C.)≦T_{PDB}≦[glass transition temperature (Tg)(° C.) of the resin (A)+10](° C.) (2)

10. An extreme ultraviolet-sensitive resin composition used in the pattern forming method claimed in claim 1.

11. A resist film formed using the extreme ultraviolet-sensitive composition claimed in claim 10.

12. A method for manufacturing an electronic device, comprising the pattern forming method claimed in claim 1.

13. An electronic device manufactured by the manufacturing method of an electronic device claimed in claim 12.
